(19) United States
(12) Patent Application Publication
(10) Pub. No.: US 2016/0195814 A1
(43) Pub. Date: Jul. 7, 2016

(54) PATTERN FORMATION METHOD, ELECTRONIC-DEVICE PRODUCTION METHOD, AND PROCESSING AGENT

(71) Applicant: FUJIFILM Corporation, Tokyo (JP)

(72) Inventors: Yuichiro ENOMOTO, Haibara-gun (JP); Ryosuke UEBA, Haibara-gun (JP); Michihiro SHIRAKAWA, Haibara-gun (JP); Hajime FURUTANI, Haibara-gun (JP); Akiyoshi GOTO, Haibara-gun (JP); Masafumi KOJIMA, Haibara-gun (JP)

(73) Assignee: FUJIFILM Corporation, Tokyo (JP)

(21) Appl. No.: 15/069,300

(22) Filed: Mar. 14, 2016

Related U.S. Application Data
(63) Continuation of application No. PCT/JP2014/072960, filed on Sep. 1, 2014.

(30) Foreign Application Priority Data
Sep. 13, 2013 (JP) 2013-190735

(51) Int. Cl. G03F 7/40; G03F 7/32; G03F 7/20

(52) U.S. Cl. CPC G03F 7/405; G03F 7/20; G03F 7/325

(57) ABSTRACT

There is provided a pattern formation method comprising: a step (1) of forming a film using an actinic ray-sensitive or radiation-sensitive resin composition which contains a resin of which, due to a polarity being increased by an action of an acid, solubility decreases with respect to a developer which includes an organic solvent; a step (2) of exposing the film to an actinic ray or radiation; a step (3) of forming a target process pattern by developing the film using a developer which includes an organic solvent; and a step (4) of obtaining a processed pattern by applying a processing agent which includes a compound (x) which has at least one of a primary amino group and a secondary amino group with respect to the target process pattern.

### CROSS REFERENCE TO RELATED APPLICATION

This is a continuation of International Application No. PCT/JP2014/072960 filed on Sep. 1, 2014, and claims priority from Japanese Patent Application No. 2013-190735 filed on Sep. 13, 2013, the entire disclosures of which are incorporated herein by reference.

### BACKGROUND OF THE INVENTION

1. Field of the Invention

The present invention relates to a pattern formation method, a processing agent which is used for the same, and an electronic-device production method which are able to be applied to steps for manufacturing semiconductors such as IC, the manufacturing of circuit boards such as liquid crystals and thermal heads, and other photofabrication lithography steps. In particular, the present invention relates to a pattern formation method, a processing agent which is used for the same, and an electronic-device production method which are favorable for exposure in an ArF exposure apparatus which uses far ultraviolet ray light with a wavelength of 300 nm or less as a light source.

2. Description of the Related Art

For resists for use with KrF excimer lasers (248 nm) and later resists, a pattern formation method which uses chemical amplification has been used in order to compensate for decreases in sensitivity due to light absorption. For example, in a positive type chemical amplification method, firstly, a photo-acid generator which is included in an exposure section is decomposed by being irradiated with light to generate an acid. Then, in a post exposure bake (Post Exposure Bake: PEB) process or the like, an alkali-insoluble group which is included in a photosensitive composition is changed to an alkali-soluble group by a catalytic action of the generated acid. After that, for example, an alkali solution is used to perform the development. By doing this, the exposure section is removed to obtain a desired pattern.

In the method described above, various types of alkali developers have been proposed. For example, as the alkali developer, an aqueous alkali developer of a 2.38 mass % tetramethyl ammonium hydroxide aqueous solution (TMAH) is widely used.

In order to refine semiconductor elements, the wavelengths of exposure light sources are being shortened and the numerical apertures (high NA) of projection lenses are being increased and, currently, an exposure apparatus which uses an ArF excimer laser which has a wavelength of 193 nm as a light source is being developed. As a technique for further increasing resolving power, a method (that is, a liquid immersion method) in which a liquid with a high refractive index (also referred to below as an “immersion liquid”) is filled between a projection lens and a sample has been proposed. In addition, EUV lithography in which exposure is performed with ultraviolet light with an even shorter wavelength (13.5 nm) has also been proposed.

However, it is extremely difficult in practice to find an appropriate combination of a resist composition, a developer, a rinsing liquid, and the like which are necessary to form a pattern of which the performance is comprehensively favorable and there is a demand for further improvement.

In recent years, a pattern formation method in which a developer which includes an organic solvent is used has also been developed (for example, refer to WO2013/054803A and JP2008-310314A).

### SUMMARY OF THE INVENTION

However, the need to refine patterns has become much greater in more recent years and, due to this, for example, in a case of trying to form a line and space pattern which has an ultrafine space width (for example, 60 nm or less), there is room for further improvement in the methods in the prior art described above.

The present invention has been made in consideration of the problems described above and has an object of providing a pattern formation method for achieving a finer pattern by applying a processing agent to a pattern (in other words, carrying out a shrinking step), which is able to reliably form a line and space pattern which has an ultrafine space width (for example, 60 nm or less) due to the excellent pattern refinement and to form the line and space pattern in a state where the roughness performance is excellent after application of a shrinking step; a processing agent which is used for the same; and an electronic-device production method.

The present invention is configured as below and due to this, the problems of the present invention described above are solved.

[1]

A pattern formation method including:

a step (1) of forming a film using an actinic ray-sensitive or radiation-sensitive resin composition which contains a resin of which, due to a polarity being increased by an action of an acid, solubility decreases with respect to a developer which includes an organic solvent;

a step (2) of exposing the film to an actinic ray or radiation;

a step (3) of forming a target process pattern by developing the film using a developer which includes an organic solvent; and

a step (4) of obtaining a processed pattern by applying a processing agent which includes a compound (x) which has at least one of a primary amino group and a secondary amino group with respect to the target process pattern.

[2]

The pattern formation method according to [ ], in which the processing agent contains 30 mass % or more of an organic solvent with respect to a total amount of the processing agent.

[3]

The pattern formation method according to [2], in which the organic solvent contained in the processing agent is an alcohol-based solvent or an ether-based solvent.

[4]

The pattern formation method according to any one of [1] to [3], in which the compound (x) is a compound which has a partial structure which is represented by Formula (1) below as the primary amino group or the secondary amino group,

—NHR (1)

in the formula above, R represents a hydrogen atom, an aliphatic hydrocarbon group in which a hetero atom may be included, or an aromatic hydrocarbon group in which a hetero atom may be included, and - represents an atomic bond.

[5]

The pattern formation method according to any one of [1] to [4], in which the compound (x) is a resin.

[6]

The pattern formation method according to [5], in which the resin is a resin which has 30 mol % or more of a repeating unit, which has at least one of a primary amino group and a secondary amino group, with respect to all of the repeating units in the resin.

[7]

The pattern formation method according to any one of [1] to [6], further including Step (3′) of developing using an alkali developer before the step (4).

[8]

The pattern formation method according to any one of [1] to [7], further including Step (5) of bringing a removal solution which is able to dissolve the compound (x) in contact with the processed pattern after the step (4).

[9]

The pattern formation method according to [8], in which the removal solution contains an organic solvent.

[10]

The pattern formation method according to any one of [1] to [9], in which exposure in the step (2) is exposure to light with a wavelength of 250 nm or less or an electron beam.

[11]

An electronic-device production method, including the pattern formation method according to any one of [1] to [10].

[12]

A processing agent for processing a target process pattern which is obtained by a pattern formation method which has a step (1) of forming a film using an actinic ray-sensitive or radiation-sensitive resin composition which contains a resin of which, due to a polarity being increased by an action of an acid, solubility decreases with respect to a developer which includes an organic solvent, a step (2) of exposing the film to an actinic ray or radiation, and a step (3) of forming a target process pattern by developing the film using a developer which includes an organic solvent, the processing agent including a compound (x) which has at least one of a primary amino group and a secondary amino group.

[13]

The processing agent according to [12], further including 30 mass % or more of an organic solvent with respect to a total amount of the processing agent.

According to the present invention, it is possible to provide a pattern formation method for achieving a finer pattern by applying a processing agent to a pattern (in other words, carrying out a shrinking step), which is able to reliably form a line and space pattern which has an ultrafine space width (for example, 60 nm or less) due to the excellent pattern refinement and to form the line and space pattern in a state where the roughness performance is excellent after application of a shrinking step; a processing agent which is used for the same; and an electronic-device production method.

### DESCRIPTION OF THE PREFERRED EMBODIMENTS

Description will be given below of embodiments for carrying out the present invention.

Here, in the notation of the groups (atomic groups) in the present specification, notation which does not indicate whether a group is substituted or unsubstituted encompasses having a substituent group as well as not having a substituent group. For example, an “alkyl group” encompasses not only an alkyl group which does not have a substituent group (an unsubstituted alkyl group), but also an alkyl group which has a substituent group (a substituted alkyl group).

In addition, the “actinic ray” or “radiation” in the present specification has the meaning of, for example, the bright line spectrum of a mercury lamp, far ultraviolet rays which are represented by an excimer laser, extreme ultraviolet (EUV light) rays, X-rays, an electron beam, and the like. In addition, light in the present invention has the meaning of an actinic ray or radiation. Unless otherwise stated, “exposure” in the present specification includes not only exposure using a mercury lamp, far ultraviolet rays which are represented by an excimer laser, X-rays, EUV light, and the like, but also drawing using particle beams such as electron beams and ion beams.

<Pattern Formation Method>

A pattern formation method of the present invention includes:

Step (1) of forming a film using an actinic ray-sensitive or radiation-sensitive resin composition which contains a resin of which, due to a polarity being increased by an action of an acid, solubility decreases with respect to a developer which includes an organic solvent;

Step (2) of exposing the film to an actinic ray or radiation;

Step (3) of forming a target process pattern by developing the film using a developer which includes an organic solvent; and

Step (4) of obtaining a processed pattern by applying a processing agent which includes a compound (x) which has at least one of a primary amino group and a secondary amino group with respect to the target process pattern.

Due to this, in the pattern formation method for achieving a finer pattern by applying a processing agent to a pattern (in other words, carrying out a shrinking step), the pattern formation method is able to reliably form a line and space pattern having an ultrafine space width (for example, 60 nm or less) due to the excellent pattern refinement and to form the line and space pattern in a state where the roughness performance is excellent after application of a shrinking step. The reason why is not certain; however, for example, the following is presumed.

For example, in a case where the processing agent which is applied to a target process pattern is a compound which has a tertiary amino group, a polar group of a resin in the pattern (specifically, a polar group which is generated by the action of an acid) and the tertiary amino group of the compound described above react to form an ion bond.

With respect to this, the processing agent in the present invention contains, as described above, a compound (x) which has at least one of a primary amino group and a secondary amino group. Thus, it is possible to form a covalent bond which is strong compared to an ion bond by the polar group of the resin in the pattern and at least one of the primary amino group and the secondary amino group of the compound described above reacting. It is considered that, due to this, it is possible to reliably bond the processing agent in the present invention with respect to the target process pattern and, as a result, it is possible to reliably form a line and space pattern which has an ultrafine space width (for example 60 nm or less) by being excellent at refining the pattern in the step of shrinking (in other words, sufficiently thickening the pattern).

In addition, the roughness performance is also considered to be excellent after the step of shrinking is applied since it is possible to reliably bond the processing agent in the present invention with respect to the target process pattern as described above.

Detailed description will be given below of each step which is included in the pattern formation method of the present invention.

Step (1) of forming a film using an actinic ray-sensitive or radiation-sensitive resin composition which contains a resin of which, due to a polarity being increased by the action of an acid, solubility decreases with respect to a developer which includes an organic solvent

The film in Step (1) is formed of the actinic ray-sensitive or radiation-sensitive resin composition in Step (1) and, more specifically, is preferably a film which is formed by coating an actinic ray-sensitive or radiation-sensitive resin composition on a substrate. In the pattern formation method of the present invention, it is possible to perform the step of forming a film on a substrate using an actinic ray-sensitive or radiation-sensitive resin composition using commonly known methods.

The substrate on which a film is formed in the present invention is not particularly limited and it is possible to use substrates which are generally used in steps of manufacturing semiconductors such as IC, in manufacturing circuit boards such as liquid crystal or thermal heads, and in other photofabrication lithography, such as inorganic substrates of silicon, SiO₂, or SiN, or inorganic substrates coated with SOG or like. Furthermore, as necessary, an organic anti-reflection film may be formed between the film and the substrate.

A prebake (PB; Prebake) step is also preferably included after the film-forming and before the exposure step. Here, the pattern formation method of the present invention may include the preheating step a plurality of times.

In addition, a post exposure bake (PEB; Post Exposure Bake) step is also preferably included after the exposure step and before the developing step. Here, the pattern formation method of the present invention may include the post exposure bake step a plurality of times.

PB and PEB are both preferably performed at a heating temperature of 70° C. to 130° C. and more preferably performed at 80° C. to 120° C.

The heating time is preferably 30 seconds to 300 seconds, more preferably 30 seconds to 180 seconds, and even more preferably 30 seconds to 90 seconds.

The heating is able to be performed by a means which is provided in an ordinary exposing and developing apparatus and may be performed using a hot plate or the like.

The reaction of the exposure section is promoted by the baking and the sensitivity and the pattern profile are improved.

Step (2) of exposing the film to an actinic ray or radiation

The actinic ray or radiation which is used for exposure in Step (2) is not limited; however, examples thereof include infrared light, visible light, ultraviolet light, far ultraviolet light, extreme ultraviolet light, X-rays, an electron beam, and the like.

Examples of far ultraviolet light preferably include light with a wavelength of 250 nm or less, more preferably 220 nm or less, and particularly preferably 1 nm to 200 nm, specific examples thereof include a KrF excimer laser (248 nm), an ArF excimer laser (193 nm), an F₂ excimer laser (157 nm), EUV (13 nm), and the like, and a KrF excimer laser, an ArF excimer laser, and EUV are preferable, and an ArF excimer laser is more preferable.

The exposure in Step (2) is preferably exposure to light with a wavelength of 250 nm or less or an electron beam.

In addition, it is possible to apply a liquid immersion exposure method in the exposure step of the present invention. It is possible to combine the liquid immersion exposure method with a super-resolution technique such as the phase shift method and the modified lighting method.

In a case of performing liquid immersion exposure, a step of cleaning the surface of a film with an aqueous chemical liquid may be carried out before Step (1) of carrying out exposure after forming a film on a substrate and/or before Step (2) of heating the film after the step of exposing the film via an immersion liquid.

The immersion liquid is preferably a liquid which is transparent with respect to the exposure wavelength and where the temperature coefficient of the refractive index is as small as possible in order to keep deformation of an optical image which is projected on the film to a minimum; however, in particular, in a case where the exposure light source is an ArF excimer laser (wavelength; 193 nm), it is preferable to use water in terms of ease of availability and ease of handling in addition to the points of view described above.

In a case of using water, an additive agent (a liquid) which increases surface activity in addition to reducing the surface tension of the water may be added in a small ratio. The additive agent preferably does not dissolve a resist layer on a wafer and any influence with respect to an optical coating on a lower surface of a lens element is negligible.

The additive agent is preferably, for example, an aliphatic alcohol which has substantially the same refractive index as water and specific examples thereof include methyl alcohol, ethyl alcohol, isopropyl alcohol, and the like. By adding alcohol which has substantially the same refractive index as water, even when the alcohol components in the water are evaporated and the content concentration changes, it is possible to obtain an advantage in that it is possible to make changes in the refractive index throughout the entirety of the liquid extremely small.

On the other hand, distilled water is preferable as the water to be used since deformation of the optical image which is projected on the resist is caused in a case where a substance, which is opaque with respect to 193 nm light, or impurities with a refractive index greatly different from that of water are mixed therein. Furthermore, pure water filtered through an ion-exchange filter or the like may be used.

The electrical resistance of the water which is used as the immersion liquid is desirably 18.3 MΩcm or more, the TOC (total organic concentration) is desirably 20 ppb or less, and a degassing process is desirably carried out.

In addition, by increasing the refractive index of the immersion liquid, it is possible to increase the lithographic performance. From this point of view, an additive agent which increases the refractive index may be added to the water, or heavy water (D₂O) may be used instead of water.

The receding contact angle of the actinic ray-sensitive or radiation-sensitive film which is formed using the actinic ray-sensitive or radiation-sensitive resin composition in the present invention is 70° or more at a temperature of 23±3° C. and a humidity of 45±5%, which is favorable in a case of exposure via a liquid immersion medium, preferably 75° or more, and more preferably 75° to 85°.

When the receding contact angle is excessively small, it is not possible to favorably use the film in a case of exposing via the liquid immersion medium and it is not possible to sufficiently exhibit an effect of reducing residual water (water mark) defects. In order to realize a preferable receding contact angle, the hydrophobic resin (HR) which will be described below is preferably included in the actinic ray-sensitive or radiation-sensitive composition. Alternatively, the receding contact angle may be improved by forming a coating layer (a so-called “top coat”) on the actinic ray-sensitive or radiation-sensitive film using a hydrophobic resin composition. The applicable top coat is not particularly limited and it is possible to appropriately use top coats known in the present technical field. In addition, imparting an auxiliary function to adjust the pattern shape or the like by applying a top coat which includes not only a resin but also a basic compound (a quencher) may also be considered as described in JP2013-61647A, particularly the examples OC-5 to OC-11 in Table 3 thereof.

In the liquid immersion exposure step, since it is necessary for the immersion liquid to move on the wafer following the movement of an exposure head scanning on the wafer at high speed and forming an exposure pattern, the contact angle of the immersion liquid with respect to the actinic ray-sensitive or radiation-sensitive film in a dynamic state is important and a performance capable of following a high speed scan of the exposure head without liquid droplets remaining is required for the resist.

The pattern formation method of the present invention may include Step (2) a plurality of times.

Step (3) of forming a target process pattern by developing the film using a developer (also referred to below as an “organic-based developer”) which includes an organic solvent

According to Step (3) described above, a negative type pattern is formed.

It is possible to use polar solvents and hydrocarbon-based solvents such as ketone-based solvents, ester-based solvents, alcohol-based solvents, amide-based solvents, and ether-based solvents as the organic-based developer.

Examples of the ketone-based solvents include 1-octanone, 2-octanone, 1-nonanone, 2-nonanone, acetone, 2-heptanone (methyl amyl ketone), 4-heptanone, 1-hexanone, 2-hexanone, diisobutyl ketone, cyclohexanone, methyl cyclohexanone, phenyl acetone, methyl ethyl ketone, methyl isobutyl ketone, acetyl acetone, acetonyl acetone, ionone, diacetonyl alcohol, acetyl carbinol, acetophenone, methyl naphthyl ketone, isophorone, propylene carbonate, and the like.

Examples of the ester-based solvents include methyl acetate, butyl acetate, ethyl acetate, isopropyl acetate, pentyl acetate, isopentyl acetate, amyl acetate, propylene glycol monomethyl ether acetate, ethylene glycol monoethyl ether acetate, diethylene glycol monobutyl ether acetate, diethylene glycol monoethyl ether acetate, ethyl-3-ethoxypropionate, 3-methoxybutyl acetate, 3-methyl-3-methoxybutyl acetate, methyl formate, ethyl formate, butyl formate, propyl formate, ethyl lactate, butyl lactate, propyl lactate, and the like.

Examples of the alcohol-based solvents include alcohols such as methyl alcohol, ethyl alcohol, n-propyl alcohol, isopropyl alcohol, n-butyl alcohol, sec-butyl alcohol, tert-butyl alcohol, isobutyl alcohol, n-hexyl alcohol, n-heptyl alcohol, n-octyl alcohol, and n-decanol, glycol-based solvents such as ethylene glycol, diethylene glycol, and triethylene glycol, glycol ether-based solvents such as ethylene glycol monomethyl ether, propylene glycol monomethyl ether, ethylene glycol monoethyl ether, propylene glycol monoethyl ether, diethylene glycol monomethyl ether, triethylene glycol monoethyl ether, and methoxy methyl butanol, and the like.

Examples of the ether-based solvents include dioxane, tetrahydrofuran, and the like other than the glycol ether-based solvents described above.

As the amide-based solvents, it is possible to use, for example, N-methyl-2-pyrrolidone, N,N-dimethyl acetamide, N,N-dimethyl formamide, hexamethylphosphoric triamide, 1,3-dimethyl-2-imidazolidinone, and the like.

Examples of the hydrocarbon-based solvents include aromatic hydrocarbon-based solvents such as toluene and xylene and aliphatic hydrocarbon-based solvents such as pentane, hexane, octane, and decane.

In particular, the organic-based developer is preferably a developer which contains at least one type of organic solvent selected from a group consisting of ketone-based solvents and ester-based solvents, and is particularly preferably a developer which includes butyl acetate as an ester-based solvent and methylamyl ketone (2-heptanone) as a ketone-based solvent.

A plurality of solvents may be mixed or the solvents may be used in a mixture with solvents other than the solvents described above or water. However, in order to sufficiently exhibit the effects of the present invention, the moisture content for the entirety of the developer is preferably less than 10 mass % and water is more preferably substantially not contained.

That is, the usage amount of the organic solvent with respect to the organic-based developer is preferably 90 mass % to 100 mass % and more preferably 95 mass % to 100 mass % with respect to the total amount of the developer.

The vapor pressure of the organic-based developer at 20° C. is preferably 5 kPa or less, more preferably 3 kPa or less, and particularly preferably 2 kPa or less. By setting the vapor pressure of the organic-based developer to 5 kPa or less, the evaporation of the developer on the substrate or in a developing cup is suppressed, the temperature uniformity in the wafer surface is improved, and as a result, the uniformity of the dimensions in the wafer surface is improved.

It is possible to add an appropriate amount of a surfactant to the organic-based developer as necessary

The surfactant is not particularly limited; however, it is possible to use, for example, ionic or non-ionic fluorine-based and/or silicon-based surfactants or the like. Examples of the fluorine and/or silicon-based surfactants include the surfactants described in JP1987-36663A (JP-S62-36663A), JP1986-226746A (JP-S61-226746A), JP1986-226745A (JP-S61-226745A), JP1987-170950A (JP-S62-170950A), JP1988-34540A (JP-S63-34540A), JP1995-230165A (JP-H7-230165A), JP1996-62834A (JP-H8-62834A), JP1997-54432A (JP-H9-54432A), JP1997-5988A (JP-119-5988A), U.S. Pat. No. 5,405,720A, U.S. Pat. No. 5,360,692A, U.S. Pat. No. 5,529,881A, U.S. Pat. No. 5,296,330A, U.S. Pat. No. 5,436,098A, U.S. Pat. No. 5,576,143A, U.S. Pat. No. 5,294,511 A, and U.S. Pat. No. 5,824,451A and non-ionic surfactants are preferable. The non-ionic surfactants are not particularly limited; however, it is more preferable to use a fluorine-based surfactant or a silicon-based surfactant.

The usage amount of the surfactant is normally 0.001 mass % to 5 mass %, preferably 0.005 mass % to 2 mass %, and more preferably 0.01 mass % to 0.5 mass % with respect to the total amount of the developer.

In addition, the organic-based developer may contain a basic compound as necessary. Examples of the basic compound include a nitrogen-containing basic compound and examples thereof include the nitrogen-containing compounds described in JP2013-11833A, in particular, in paragraphs “0021” to “0063”. As a result of the organic-based developer containing a basic compound, it is possible to expect improvements in the contrast during the developing, suppression of film thinning, and the like.

As the developing method, it is possible to apply, for example, a method of dipping a substrate in a tank which is filled with a developer for a certain period (a dipping method), a method of developing by raising a developer onto a substrate surface using surface tension and leaving the developer to stand for a certain period (a paddle method), a method of spraying a developer onto a substrate surface (a spraying method), a method of continuing to discharge a developer onto a substrate which is rotating at a certain speed while scanning developer discharging nozzles at a certain speed (a dynamic dispensing method), and the like.

In a case where the various types of developing methods described above include a step of discharging a developer from the developing nozzles of a developing apparatus onto a film, the discharging pressure of the developer which is discharged (the flow speed per unit area of the discharged developer) is, as an example, preferably 2 mL/sec/mm² or less, more preferably 1.5 mL/sec/mm² or less, and even more preferably 1 mL/sec/mm² or less. There is no lower limit on the flow speed; however, when considering throughput, 0.2 mL/sec/mm² or more is preferable. The details thereof are described in paragraphs “0022” to “0029” in particular in JP2010-232550A and the like.

In addition, a step in which the developing is stopped while substitution with other solvents is carried out may be carried out after the step of developing using a developer which includes an organic solvent.

The pattern formation method of the present invention preferably includes a rinsing step of cleaning using a rinsing liquid after Step (3). The rinsing liquid is not particularly limited as long as the rinsing liquid does not dissolve the resist pattern and it is possible to use a solution which includes a typical organic solvent. As the rinsing liquid, it is preferable to use a rinsing liquid which contains at least one type of organic solvent selected from a group consisting of a hydrocarbon-based solvent, a ketone-based solvent, an ester-based solvent, an alcohol-based solvent, an amide-based solvent, and an ether-based solvent.

Specific examples of the hydrocarbon-based solvent, the ketone-based solvent, the ester-based solvent, the alcohol-based solvent, the amide-based solvent, and the ether-based solvent include the same solvents as described for the developer which includes an organic solvent.

In one embodiment of the present invention, after the developing step, a step of cleaning using a rinsing liquid which contains at least one type of organic solvent selected from a group consisting of a ketone-based solvent, an ester-based solvent, an alcohol-based solvent, and an amide-based solvent is performed, a step of cleaning using a rinsing liquid which contains an alcohol-based solvent or an ester-based solvent is more preferably performed, a step of cleaning using a rinsing liquid which contains a monovalent alcohol is particularly preferably performed, and a step of cleaning using a rinsing liquid which contains a monovalent alcohol with 5 or more carbon atoms is most preferably performed.

Here, examples of the monovalent alcohol which is used in the step of rinsing include straight-chain, branched, and cyclic monovalent alcohols and specifically, it is possible to use 1-hexanol, 2-hexanol, 4-methyl-2-pentanol (methyl isobutyl carbinol), l-pentanol, 3-methyl-1-butanol, and the like.

A plurality of each of the components may be mixed or each of the components may be used mixed with organic solvents other than described above.

The moisture content in the rinsing liquid is preferably 10 mass % or less, more preferably 5 mass % or less, and particularly preferably 3 mass % or less. It is possible to obtain favorable developing characteristics by setting the moisture content to 10 mass % or less.

The vapor pressure at 20° C. of the rinsing liquid which is used after the step of developing using the developer which includes an organic solvent is preferably 0.05 kPa to 5 kPa, more preferably 0.1 kPa to 5 kPa, and most preferably 0.12 kPa to 3 kPa. By setting the vapor pressure of the rinsing liquid to 0.05 kPa to 5 kPa, the temperature uniformity in the wafer surface is improved and, moreover, swelling which is caused by permeation of the rinsing liquid is suppressed and the uniformity of the dimensions in the wafer surface is improved.

It is also possible to use the rinsing liquid after adding an appropriate amount of a surfactant thereto.

In the rinsing step, a cleaning process is carried out on the wafer, on which the developing which uses the developer which includes an organic solvent was performed, using the rinsing liquid which includes the organic solvent. The method of the cleaning process is not particularly limited; however, for example, it is possible to apply a method of continuously discharging the rinsing liquid onto a substrate which is rotating at a certain speed (a rotary coating method), a method of dipping the substrate in a tank which is filled with the rinsing liquid for a certain time (a dipping method), a method of spraying the rinsing liquid onto the substrate surface (a spraying method), and the like, and it is preferable to perform the cleaning process using the rotary coating method among these, to rotate the substrate at a rotation speed of 2000 rpm to 4000 rpm after the cleaning, and to remove the rinsing liquid from on the substrate. In addition, it is also preferable to include a heating Step (Post Baking) after the rinsing step. The developer and rinsing liquid which remain between the patterns and in the pattern are removed by the baking. The heating step after the rinsing step is normally performed at 40° C. to 160° C., preferably at 70° C. to 95° C., normally for 10 seconds to 3 minutes, and preferably for 30 seconds to 90 seconds.

Step (3′) of developing using an alkali developer

In addition, the pattern formation method of the present invention may further include Step (3′) of developing using an alkali developer before Step (4) (and typically after Step (2)).

The pattern formation method of the present invention may include Step (3′) before Step (3) or may include Step (3′) after Step (3).

Due to the combination of Step (3) and Step (3′), it is possible to expect to obtain a pattern with ½ of the spatial frequency of an optical image as illustrated in FIG. 1 to FIG. 11 and the like in U.S. Pat. No. 8,227,183B.

Water is included in the alkali developer in Step (3) described above as a main component. Here, “main component” has the meaning that the content of the water exceeds 50 mass % with respect to the total amount of the developer.

In terms of the solubility of the pattern being superior, an alkali aqueous solution which includes alkali is preferably used as a developer.

The type of the alkali aqueous solution described above is not particularly limited; however, it is possible to use, an alkali aqueous solution of, for example, inorganic alkalis such as sodium hydroxide, potassium hydroxide, sodium carbonate, sodium silicate, sodium metasilicate, and ammonia water, primary amines such as ethylamine and n-propylamine, secondary amines such as diethylamine and di-n-butylamine, tertiary amines such as triethylamine and methyldiethylamine, alcohol amines such as dimethylethanolamine and triethanolamine, tetraalkyl ammonium hydroxide such as tetramethyl ammonium hydroxide, tetraethyl ammonium hydroxide, tetrapropyl ammonium hydroxide, tetrabutyl ammonium hydroxide, tetrapentyl ammonium hydroxide, tetrahexyl ammonium hydroxide, tetraoctyl ammonium hydroxide, ethyl trimethyl ammonium hydroxide, butyl trimethyl ammonium hydroxide, methyl triamyl ammonium hydroxide, and dibutyl dipentyl ammonium hydroxide, quaternary ammonium salt such as trimethyl phenyl ammonium hydroxide, trimethyl benzyl ammonium hydroxide, and triethyl benzyl ammonium hydroxide, and cyclic amines such as pyrrole and piperidine, and the like. Furthermore, it is also possible to use the alkali aqueous solution described above after adding an appropriate amount of alcohols and a surfactant thereto. An alkali concentration of the alkali developer is normally 0.1 mass % to 20 mass %. The pH of the alkali developer is normally 10.0 to 15.0. It is possible to use the alkali developer after appropriately adjusting the alkali concentration and the pH thereof.

An aqueous solution of 2.38 mass % tetramethyl ammonium hydroxide is generally used as the alkali developer.

The alkali developer may be used by adding appropriate amounts of a surfactant or an organic solvent such as alcohols.

Examples of the developing method include the developing methods described for Step (3) described above.

Rinsing may be performed after Step (3′) and it is also possible to use pure water as the rinsing liquid in the rinsing process which is performed after the alkali developing and to use the pure water after adding an appropriate amount of a surfactant thereto.

Step (4) of obtaining a processed pattern by applying a processing agent which includes a compound (x) which has at least one of a primary amino group and a secondary amino group with respect to the target process pattern

As a method for applying a processing agent with respect to a target process pattern, it is possible to apply, for example, a method of dipping a target process pattern in a tank which is filled with a processing agent for a certain period (a dipping method), a method of raising a processing agent on a surface of a target process pattern using surface tension and leaving to stand for a certain period (a paddle method), a method of spraying a processing agent onto a surface of a target process pattern (a spraying method), a method of continuing to discharge a processing agent onto a target process pattern which is rotating at a certain speed while scanning processing agent discharging nozzles at a certain speed (a dynamic dispensing method), a method of forming a processed film on a pattern by coating a processing agent onto a target process pattern, and the like, and the method of forming a processed film on a pattern by coating a processing agent onto a target process pattern is preferable.

Description will be given below of details of the processing agent which is used in Step (4) described above.

In a case where the processing agent is a solution, the usage amount is not particularly limited as long as it is possible to sufficiently carry out a reaction with a polar group of the resin after exposure; however, it is preferable to use at least an amount which is able to cover the entirety of the substrate surface. Although the specific usage amount depends on the concentration of the processing agent, the viscosity, the film thickness of the film, the size of the substrate, and the like, for example, in a case where the substrate is a wafer with a diameter of 300 mm, adjustments are appropriately carried out in a range of 1 mL to 100 mL as appropriate amounts.

By carrying out Step (4), typically, at least on a side wall of the target process pattern, a processed pattern formed by a film being formed by the processing agent is obtained. In other words, a processed pattern is formed as a pattern where a space width of the target process pattern is reduced.

Step (5) of bringing a removal solution which is able to dissolve the compound (x) into contact with the processed pattern

The pattern formation method of the present invention preferably contains Step (5) of bringing a removal solution which is able to dissolve the compound (x) into contact with the processed pattern.

By carrying out Step (5), it is possible to remove excess compound (x) which does not contribute to reaction with the resin in the pattern (in other words, does not contribute to the thickening of the pattern) and it is possible to suppress changes in the shape of regions other than the target process pattern surface.

The method of bringing the removal solution into contact is the same as the developing process in Step (3) described above. The contact time is, for example, set to 30 seconds to 120 seconds.

The removal solution preferably contains an organic solvent and specific examples and preferable examples of the organic solvent favorably include the organic solvents described above as the organic-based developer in Step (3).

The organic-based developer, the alkali developer, the rinsing liquid, and the processing liquid which are used in the present invention preferably have few impurities such as various types of fine particles or metal elements. In order to obtain a chemical liquid with few impurities, the chemical liquid is preferably produced in a clean room and moreover, impurity reduction is preferably performed by performing filtration using various types of filters such as Teflon filters, polyolefin-based filters, and ion-exchange filters, and the like. With regard to metal elements, the metal element concentrations of each of Na, K, Ca, Fe, Cu, Mg, Mn, Li, Al, Cr, Ni, and Zn is preferably 10 ppm or less, and more preferably 5 ppm or less.

In addition, the storage container for the developer, the rinsing liquid, and the processing liquid is not particularly limited and it is possible to appropriately use a container of a polyethylene resin, polypropylene resin, polyethylene-polypropylene resin, or the like used for purposes involving electronic materials; however, a container in which few components elute into the chemical liquid from inner walls of the container is also preferably selected in order to reduce impurities which elute from the container. Examples of containers include a container of which the inner wall is a perfluoro resin (for example, a FluoroPure PFA compound drum manufactured by Entegris Inc. (wetted inner surface; PFA resin lining) and a drum made of steel manufactured by JFE Corporation (wetted inner surface; tribasic zinc phosphate film)) and the like.

The pattern which is eventually obtained by the pattern formation method of the present invention is normally used as a “mask” in a so-called etching process or an ion implantation process. However, the present invention does not exclude application to other uses. Examples of the other uses include guide pattern forming in Directed Self-Assembly (DSA) (for example, refer to ACS Nano Vol. 4 No. 8 Page 4815 to 4823), use as a core material (core) of a so-called spacer process (for example, refer to JP1991-270227A (JP-H3-270227A), JP2013-164509A, and the like), and the like.

The present invention also relates to an electronic-device production method which includes the pattern formation method of the present invention described above and to an electronic device which is produced by this production method.

The electronic device of the present invention is favorably mounted on electrical and electronic devices (household electrical appliances, OA and media-related devices, optical apparatuses and instruments, telecommunication devices, and the like).

<Processing Agent>

Detailed description will be given below of the processing agent (also referred to below as a “processing agent of the present invention”) which is used in the present invention.

The processing agent includes a compound (x) which has at least one of a primary amino group and a secondary amino group.

In more detail, the processing agent is preferably a compound which has a partial structure which is represented by Formula (1) below as a primary amino group or a secondary amino group.

—NHR (1)

In the formula above, R represents a hydrogen atom, an aliphatic hydrocarbon group in which a hetero atom may be included, or an aromatic hydrocarbon group in which a hetero atom may be included, and - represents an atomic bond.

The aliphatic hydrocarbon group which is represented by R may be straight-chain, may be branched chain, or may be cyclic.

In a case where the straight-chain or branched chain aliphatic hydrocarbon group is a saturated hydrocarbon group, the number of carbon atoms of the aliphatic hydrocarbon group is preferably 1 to 50, more preferably 1 to 30, and even more preferably 1 to 20. Examples of the saturated hydrocarbon group include saturated hydrocarbon groups such as a methyl group, an ethyl group, a propyl group, a butyl group, a hexyl group, an octyl group, a decyl group, a dodecyl group, an octadecyl group, an isopropyl group, an isobutyl group, a sec-butyl group, a t-butyl group, a 1-ethylpentyl group, and a 2-ethylhexyl group.

In a case where the straight-chain or branched chain aliphatic hydrocarbon group is an unsaturated hydrocarbon group, the number of carbon atoms of the aliphatic hydrocarbon group is preferably 2 to 50, more preferably 2 to 30, and even more preferably 3 to 20. Examples of the unsaturated hydrocarbon group include alkenyl groups such as a vinyl group, an allyl group, and a styryl group.

Preferable examples of the cyclic aliphatic hydrocarbon group include a monocyclic cycloalkyl group with 3 to 8 carbon atoms such as a cyclopropyl group, a cyclopentyl group, and a cyclohexyl group, and the like.

The aromatic hydrocarbon group which is represented by R preferably has 6 to 14 carbon atoms. Examples of the group include an aryl group such as a phenyl group and a naphthyl group.

As described above, the aliphatic hydrocarbon group and the aromatic hydrocarbon group as R may include a hetero atom. Here, the type of the hetero atom is not particularly limited; however, examples thereof include a halogen atom, an oxygen atom, a nitrogen atom, a sulfur atom, a selenium atom, a tellurium atom, and the like. For example, the hetero atom is included in an aspect of —Y₁H, —Y₁—, —N(Rₐ)—, —C(═Y₂)—, —CON(R_{b})—, —C(═Y₃)Y₄—, —SOₜ—, —SO₂N(R_{c})—, a halogen atom, or a group in a combination of two or more types thereof.

Y₁ to Y₄ are each independently selected from a group consisting of an oxygen atom, a sulfur atom, a selenium atom, and a tellurium atom. Among these, in terms of easier handling, an oxygen atom and a sulfur atom are preferable.

Rₐ, R_{b}, and R_{c} described above are each independently selected from a hydrogen atom or a hydrocarbon group with 1 to 20 carbon atoms.

t represents an integer of 1 to 3.

Examples of R in a case where the cyclic aliphatic hydrocarbon group which is represented by R contains a hetero atom and R in a case where the aromatic hydrocarbon group which is represented by R contains a hetero atom preferably include a heterocyclic hydrocarbon group with 5 to 20 carbon atoms and more preferably include a heterocyclic hydrocarbon group with 6 to 15 carbon atoms.

A hetero ring which is included in the heterocyclic hydrocarbon group may be monocyclic or may be polycyclic. Examples of the hetero ring include an imidazole ring, a pyridine ring, a pyrazine ring, a pyrimidine ring, a pyridazine ring, a 2H-pyrrole ring, a 3H-indole ring, 1H-indazole ring, a purine ring, an isoquinoline ring, a 4H-quinolizine ring, a quinoline ring, a phthalazine ring, a naphthyridine ring, a quinoxaline ring, a quinazoline ring, a cinnoline ring, a pteridine ring, a phenanthridine ring, an acridine ring, a phenanthroline ring, a phenazine ring, a perimidine ring, a triazine ring, a benzisoquinoline ring, a thiazole ring, a thiadiazine ring, an azepine ring, an azocine ring, an isothiazole ring, an isooxazole ring, and a benzothiazole ring.

In addition, examples of the heterocyclic hydrocarbon group also include a group which is provided with a lactone structure which will be exemplified in the resin (A) which will be described below and the like.

In the present invention, the secondary amino group also includes cyclic secondary amino groups such as a pyrrolidino group, a piperidino group, a piperazino group, and a hexahydrotriazino group (however, cases of an N-pyrrolidino group in pyrrolidino groups and an N-piperidino group in piperidino groups are excluded).

The compound (x) may take the form of a low molecular compound or may take the form of a resin.

Detailed description will be firstly given below of a form of a low molecular compound (the compound (x) is also referred to as a low molecular compound (x) in the form below).

[Low Molecular Compound]

The low molecular compound is typically a compound with a molecular weight of 900 or less, more preferably a low molecular weight of 700 or less, and even more preferably a low molecular weight of 500 or less. Here, the low molecular compound in the present invention is not a so-called polymer or oligomer which is obtained by splitting the unsaturated bond of a compound (a so-called polymerizable monomer) which has an unsaturated bond using an initiator and making the bond grow in a chain reaction, but a compound (a compound which substantially does not have a molecular weight distribution) which has a constant molecular weight with a molecular weight of 2000 or less (more preferably 1500 or less, even more preferably 900 or less). Here, the molecular weight is normally 100 or more.

The low molecular compound (x) is preferably a compound which has 2 or more of at least one of a primary amino group and a secondary amino group, more preferably a compound which has 3 or more, and even more preferably a compound which has 4 or more.

Examples of a favorable aspect of the low molecular compound (x) include compounds which are represented by Formula (2) below in terms of the effects of the present invention being superior.

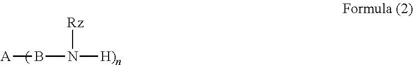

In Formula (2), A represents a single bond or an n-valent organic group.

n represents an integer of 2 or more. However, in a case where A represents a single bond, n represents 2.

B represents a single bond, an alkylene group, a cycloalkylene group, or an aromatic group.

However, A and B are not a single bond at the same time.

R_{z} represents a hydrogen atom, an aliphatic hydrocarbon group in which a hetero atom may be included, or an aromatic hydrocarbon group in which a hetero atom may be included.

A plurality of B's and a plurality of R_{z}'s may be each the same or may be different.

Examples of A as an n-valent organic group specifically include a group which is represented by Formula (1A) below, a group which is represented by Formula (1B) below,

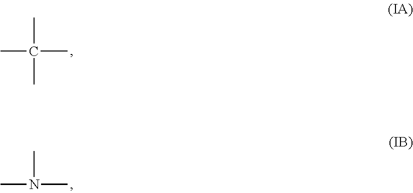

—NiH—, —NR_{W}—, —O—, —S—, a carbonyl group, an alkylene group, an alkenylene group, an alkynylene group, a cycloalkylene group, an aromatic group, a heterocyclic group, and a group formed in a combination of two or more types thereof, and the like. Here, in the formula described above, R_{W} represents an organic group and is preferably an alkyl group, an alkylcarbonyl group, and an alkylsulfonyl group. In addition, in the combination described above, the hetero atoms are not linked with each other.

Among these, A is preferably an aliphatic hydrocarbon group (an alkylene group, an alkenylene group, an alkynylene group, and a cycloalkylene group), a group which is represented by Formula (1B) described above, —NH—, or —NR_{W}—.

Here, the alkylene group, the alkenylene group, and the alkynylene group are preferably with 1 to 40 carbon atoms, more preferably with 1 to 20 carbon atoms, and even more preferably with 2 to 12 carbon atoms. The alkylene group may be straight-chain or branched and may have a substituent group. Here, the cycloalkylene group is preferably with 3 to 40 carbon atoms, more preferably with 3 to 20 carbon atoms, and even more preferably with 5 to 12 carbon atoms. The cycloalkylene group may be monocyclic or polycyclic and may have a substituent group on a ring.

The aromatic group may be monocyclic or polycyclic and a non-benzenoid aromatic group is also included. Examples of the monocyclic aromatic group include a benzene residue, a pyrrole residue, a furan residue, a thiophene residue, an indole residue, and the like, and examples of the polycyclic aromatic group include a naphthalene residue, an anthracene residue, a tetracene residue, a benzofuran residue, a benzothiophene residue, and the like. The aromatic groups may have a substituent group.

The n-valent organic group may have a substituent group and the type thereof is not particularly limited; however, examples thereof include an alkyl group, an alkoxy group, an alkylcarbonyl group, an alkylcarbonyloxy group, an alkyloxycarbonyl group, an alkenyl group, an alkenyloxy group, an alkenylcarbonyl group, an alkenylcarbonyloxy group, an alkenyloxycarbonyl group, an alkynyl group, an alkynyleneoxy group, an alkynylenecarbonyl group, an alkynylenecarbonyloxy group, an alkynyleneoxycarbonyl group, an aralkyl group, an aralkyloxy group, an aralkylcarbonyl group, an aralkylcarbonyloxy group, an aralkyloxycarbonyl group, a hydroxyl group, an amide group, a carboxyl group, a cyano group, a fluorine atom, and the like.

B represents a single bond, an alkylene group, a cycloalkylene group, or an aromatic group, and the alkylene group, the cycloalkylene group, and the aromatic group may have a substituent group. Here, description of the alkylene group, the cycloalkylene group, and the aromatic group is the same as described above.

However, A and B are not a single bond at the same time.

R_{z} represents a hydrogen atom, an aliphatic hydrocarbon group in which a hetero atom may be included, or an aromatic hydrocarbon group in which a hetero atom may be included.

Examples of the aliphatic hydrocarbon group include an alkyl group, an alkenyl group, an alkynyl group, and the like. The number of carbon atoms which are included in the aliphatic hydrocarbon atoms is not particularly limited; however, in terms of the effects of the present invention being superior, 1 to 20 is preferable, and 1 to 10 is more preferable.

Examples of the aromatic hydrocarbon group include a phenyl group, a naphthyl group, and the like.

A hetero atom may be included in the aliphatic hydrocarbon group and the aromatic hydrocarbon group. The definition and favorable aspects of the hetero atom are the same as the definition of the hetero atom described in Formula (1) described above.

In addition, a substituent group (for example, a hydroxyl group, a cyano group, an amino group, a pyrrolidino group, a piperidino group, a morpholino group, a functional group such as an oxo group, an alkoxy group, and a halogen atom) may be included in the aliphatic hydrocarbon group and the aromatic hydrocarbon group.

n preferably represents an integer of 2 to 8 and more preferably represents an integer of 3 to 8.

Here, the compound which is represented by Formula (2) described above preferably has 3 or more nitrogen atoms. In this aspect, in a case where n is 2, at least one nitrogen atom is included in A. A nitrogen atom being included in A means that, for example, A includes at least one selected from a group consisting of a group which is represented by Formula (18B) described above, —NH—, and —NR_{W}—.

Compounds which are represented by Formula (2) will be exemplified below.

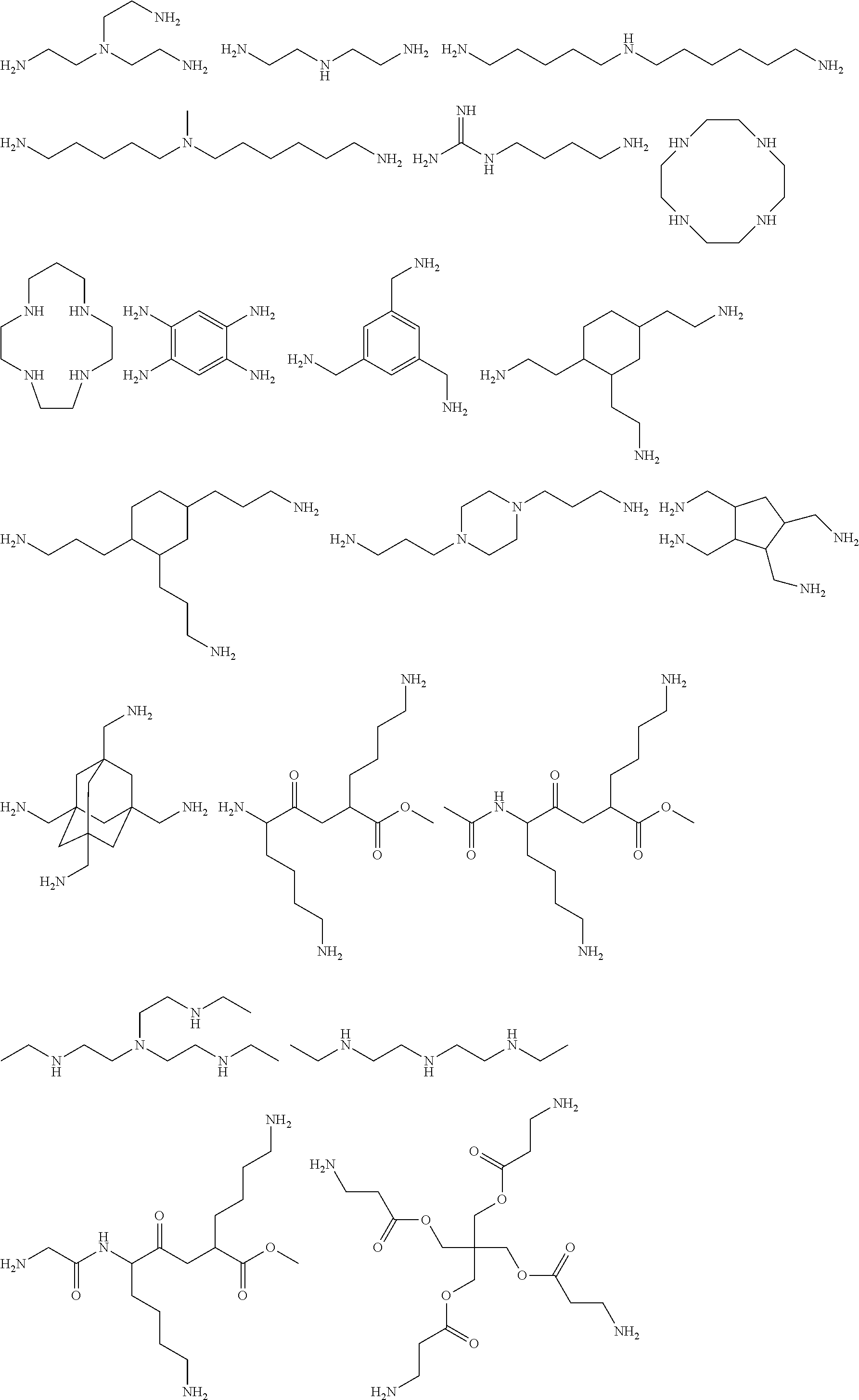

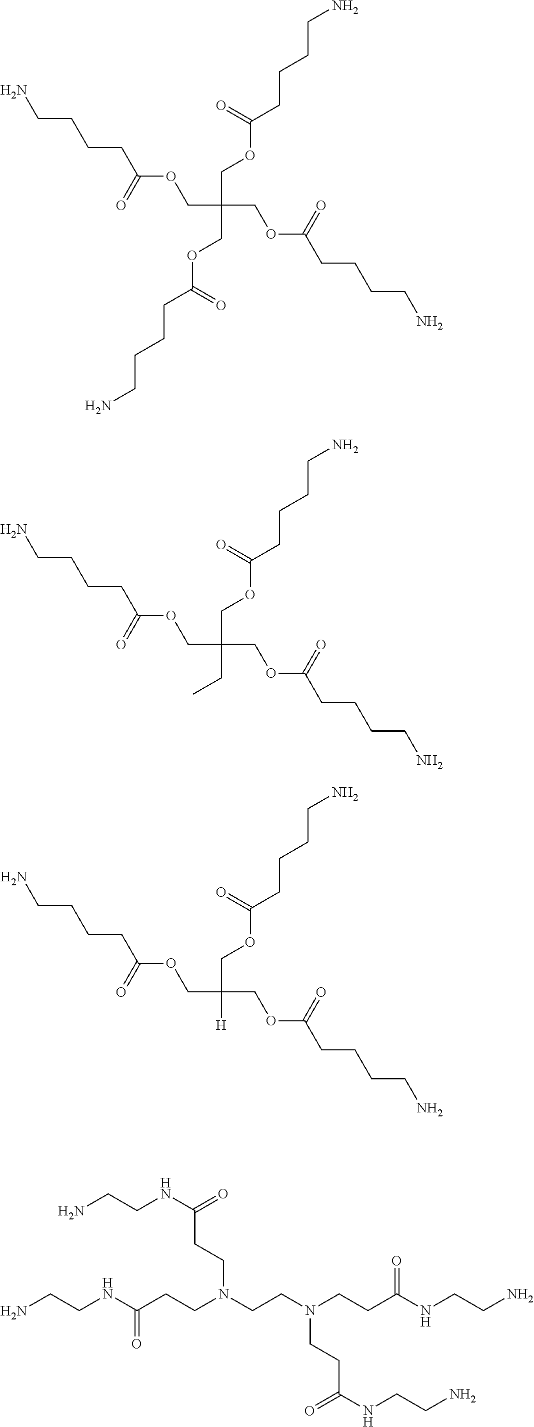 [SMILES: NCCCCC(=O)OCC(COC(=O)CCCCN)(COC(=O)CCCCN)COC(=O)CCCCN ; CCC(COC(=O)CCCCN)(COC(=O)CCCCN)COC(=O)CCCCN ; NCCCCC(=O)OCC(COC(=O)CCCCN)COC(=O)CCCCN ; NCCNC(=O)CCN(CCC(=O)NCCN)CCN(CCC(=O)NCCN)CCC(=O)NCCN]

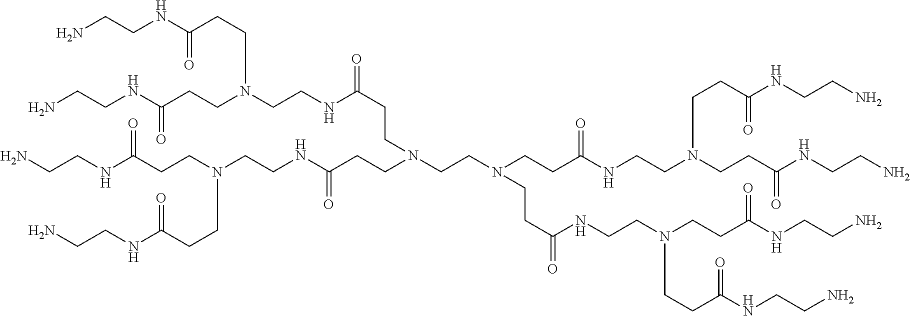 [SMILES: NCCNC(=O)CCN(CCNC(=O)CCN(CCC(=O)NCCN(CCC(=O)NCCN)CCC(=O)NCCN)CCN(CCC(=O)NCCN(CCC(=O)NCCN)CCC(=O)NCCN)CCC(=O)NCCN(CCC(=O)NCCN)CCC(=O)NCCN)CCC(=O)NCCN]

As described above, the compound (A) may take the form of a low molecular compound or may take the form of a resin; however, the form of a resin is preferable from the point of view of being able to carry out a reaction with a polar group of the resin in a pattern at a greater number of points and the like.

Detailed description will be given below of the form of a resin (compound (x) in this form is also referred to below as resin (x)).

The resin (x) is a resin which has at least one of a primary amino group and a secondary amino group (also collectively referred to below simply as an “amino group”) and an amino group may be included in either of the main chain or side chain of the resin.

Specific examples of a side chain in a case where an amino group is included in a part of the side chain will be given below. Here, * represents an atomic bond which is bonded with the main chain of a resin.

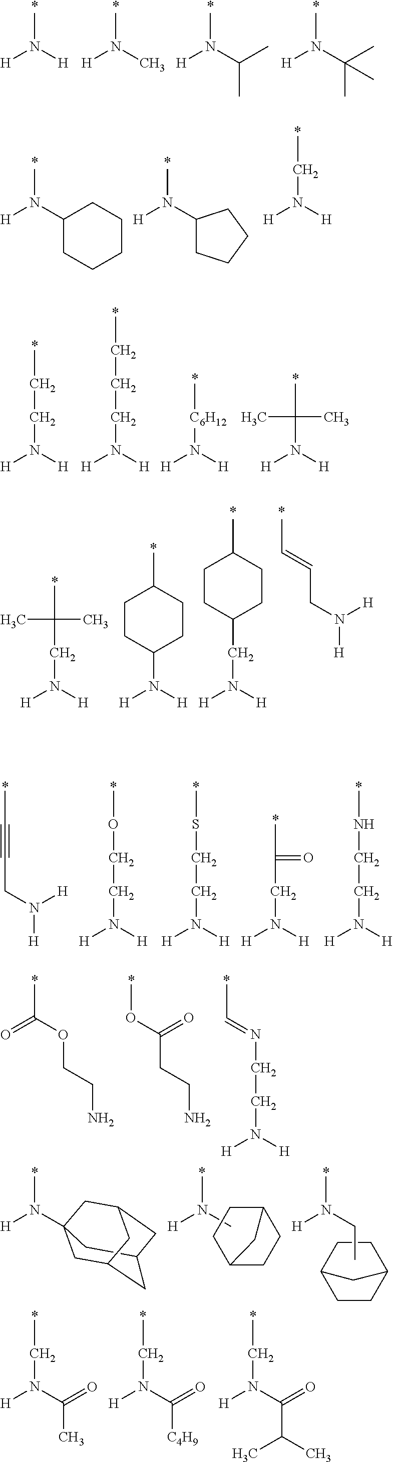

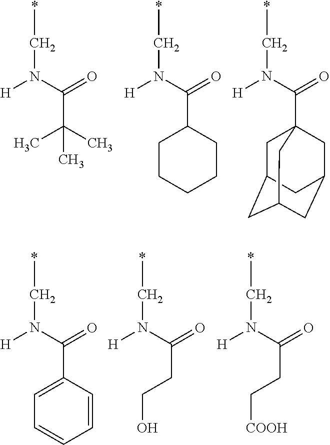

Examples of a polymer which has the amino group described above include polyallylamine, polyethyleneimine, polyvinylimidazole, polytriazole, polyindole, polypurine, polybenzimidazole, and the like.

The resin (x) is preferably a repeating unit which has at least one of a primary amino group and a secondary amino group.

Examples of the repeating unit which has at least one of a primary amino group and a secondary amino group favorably include a repeating unit which is represented by Formula (3) below.

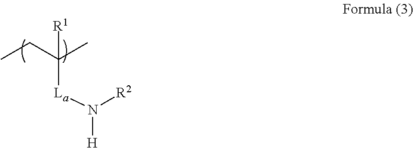

In Formula (3), R¹ represents a hydrogen atom or an alkyl group.

R² represents a hydrogen atom, an alkyl group which may include a hetero atom, a cycloalkyl group which may include a hetero atom, or an aromatic group which may include a hetero atom.

Lₐ represents a divalent linking group.

The number of carbon atoms which are included in an alkyl group as R¹ is not particularly limited; however, in terms of the effects of the present invention being superior, 1 to 4 is preferable, and 1 or 2 is more preferable.

The number of carbon atoms which are included in an alkyl group and a cycloalkyl group as R² is not particularly limited; however, 1 to 20 is preferable, and 1 to 10 is more preferable.

Examples of an aromatic group as R² include an aromatic hydrocarbon, an aromatic heterocyclic group, and the like.

A hetero atom may be included in the alkyl group, the cycloalkyl group, and the aromatic group described above.

The definition and favorable aspects of the hetero atom are the same as the definition of the hetero atom described in Formula (1) described above.

In addition, a substituent group (for example, a hydroxyl group, a cyano group, an amino group, a pyrrolidino group, a piperidino group, a morpholino group, a functional group such as an oxo group, an alkoxy group, and a halogen atom) may be included in the alkyl group, the cycloalkyl group, and the aromatic group described above.

Examples of the divalent linking group which represents Lₐ include a substituted or unsubstituted divalent aliphatic hydrocarbon group (preferably with 1 to 8 carbon atoms, for example, an alkylene group such as a methylene group, an ethylene group, and a propylene group), a substituted or unsubstituted divalent aromatic hydrocarbon group (preferably with 6 to 12 carbon atoms, for example, a phenylene group), —O—, —S—, —SO₂—, —N(R)— (R: an alkyl group), —CO—, —NH—, —COO—, —CONH—, or a group in a combination of two or more types thereof (for example, an alkyleneoxy group, an alkyleneoxycarbonyl group, an alkylenecarbonyloxy group, and the like), and the like.

Among these, in terms of the effects of the present invention being superior, La is preferably an alkylene group, an arylene group, —COO—, or a group combing two or more types thereof (-arylene group-alkylene group-, —COO-alkylene group-, or the like), and more preferably an alkylene group.

Here, a substituent group (for example, a hydroxyl group or the like) may be further substituted for the group which is represented by R¹ and R² described above and the divalent linking group which is represented by LI.

Specific examples of the repeating unit which is represented by Formula (3) will be given below.

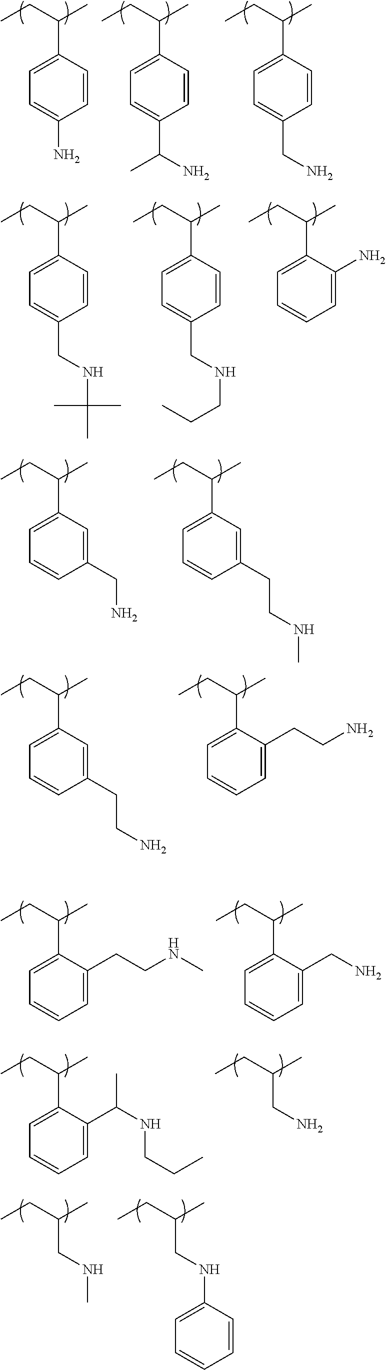

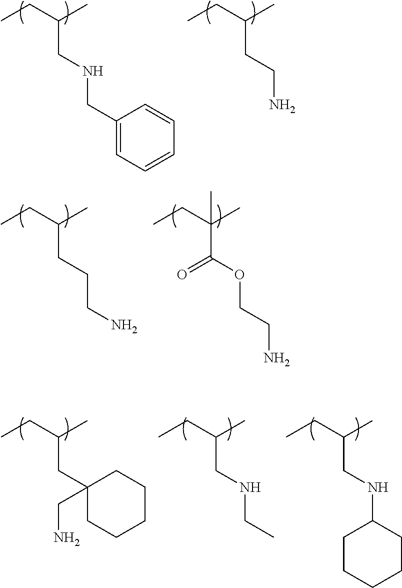

The content of the repeating units which have at least one of a primary amino group and a secondary amino group is not particularly limited; however, in terms of the effects of the present invention being superior, 30 mol % or more is preferable with respect to all of the repeating units in the resin (x), 40 mol % to 100 mol % is more preferable, and 70 mol % to 100 mol % is even more preferable.

Here, the resin (x) may contain repeating units other than the repeating unit which has at least one of a primary amino group and a secondary amino group and examples of the other repeating units include the repeating unit which the resin (A) which will be described below may have.

The weight average molecular weight of the resin (x) is preferably 1000 or more as a polystyrene converted value by a GPC method, more preferably 5000 or more, even more preferably 10000 or more, and particularly preferably 50000 or more in terms of the effects of the present invention being superior.

The weight average molecular weight of the resin (x) is normally 100000 or less as a polystyrene converted value by a GPC method.

The resin (x) of which the dispersity (molecular weight distribution) is generally in a range of 1.0 to 3.0, preferably 1.0 to 2.6, more preferably 1.0 to 2.0, and particularly preferably 1.4 to 2.0 is used.

Here, in the present specification, it is possible to obtain the weight average molecular weight (Mw) and the dispersity of the resin (including the resins to be described below) using, for example, HLC-8120 (manufactured by Tosoh Corporation), using TSK gel Multipore HXL-M (manufactured by Tosoh Corporation, 7.8 mm HD×30.0 cm) as a column, and using tetrahydrofuran (THF) as an eluent.

The processing agent of the present invention may contain one type of the compound (x) or may contain two or more types.

The content of the compounds (x) is preferably 85 mass % to 100 mass %, more preferably 90 mass % to 100 mass %, and even more preferably 95 mass % to 100 mass % with respect to the entirety of the solid content of the processing agent of the present invention.

In addition, the processing agent of the present invention preferably contains an organic solvent. Specific examples and preferable examples of the organic solvent are substantially the same as the examples in the rinsing liquid described above; however, a solvent in which the film dissolving speed at 23° C. when contacting the non-exposed coating film of the actinic ray-sensitive or radiation-sensitive film is 0.1 nm/s or less is particularly preferably used as the organic solvent.

In detail, the organic solvent contained in the processing agent is preferably an alcohol-based solvent or an ether-based solvent. In detail, examples thereof include alcohol, dialkyl ether, and the like which have at least one of an alkyl group with 3 or more carbon atoms (more preferably with 5 to 10 carbon atoms), a cycloalkyl group (preferably with 5 to 10 carbon atoms), and an aralkyl group (preferably with 7 to 10 carbon atoms). In addition, it is also possible to apply water as the solvent.

The film dissolving speed represents the amount of reduction in the film thickness per unit of time when bringing the solution into contact with the actinic ray-sensitive or radiation-sensitive film. The film dissolving speed is the average dissolving speed (the speed at which the film thickness is reduced) when the film is dipped for 1000 seconds into a developer at room temperature (23° C.) and is measured using a quartz crystal microbalance (QCM) sensor or the like after forming an actinic ray-sensitive or radiation-sensitive film on a substrate.

The processing agent of the present invention may contain a plurality of types of organic solvents or may contain water.

However, in order to sufficiently exhibit the effects of the present invention, the processing agent of the present invention preferably contains 30 mass % or more of the organic solvent with respect to the total amount of the processing agent, more preferably contains 50 mass % or more, even more preferably 90 mass % to 100 mass %, and particularly preferably 95 mass % to 100 mass %.

The moisture content of the entirety of the processing agent is preferably less than 10 mass % and water is more preferably substantially not contained.

The processing agent of the present invention may further include an acid. For specific examples of the acid, it is possible to refer to the description in the paragraph “0026” in WO2013/054803A and the contents thereof are included in the present specification.

The processing agent of the present invention may contain other additive agents as necessary. Examples of the other additive agents include surfactants and the like. Examples of the surfactants include the surfactants described as the surfactants which the actinic ray-sensitive or radiation-sensitive resin composition which will be described below may contain.

In a case where the processing agent of the present invention contains other additive agents, the content is preferably 0.001 mass % to 1 mass % and more preferably 0.001 mass % to 0.1 mass % with respect to the total amount of the processing agent.

The present invention also relates to a processing agent which processes the target process pattern which is obtained by a pattern formation method which has Step (1) of forming a film using an actinic ray-sensitive or radiation-sensitive resin composition which contains a resin of which, due to the polarity being increased by the action of an acid, solubility decreases with respect to a developer which includes an organic solvent, Step (2) of exposing the film to an actinic ray or radiation, and Step (3) of forming a target process pattern by developing the film using a developer which includes an organic solvent, the processing agent including a compound (x) which has at least one of a primary amino group and a secondary amino group.

Here, examples of preferable forms of the processing agent include a processing agent which contains an organic solvent at 30 mass % or more with respect to the total amount of the processing agent.

<Actinic Ray-Sensitive or Radiation-Sensitive Resin Composition>

Next, description will be given of an actinic ray-sensitive or radiation-sensitive resin composition which is used in the pattern formation method of the present invention.

The actinic ray-sensitive or radiation-sensitive resin composition according to the present invention is used for negative type development (development by which, when exposed, the solubility decreases with respect to the developer, the exposed section remains as a pattern, and the unexposed section is removed). That is, it is possible to set the actinic ray-sensitive or radiation-sensitive resin composition according to the present invention as an actinic ray-sensitive or radiation-sensitive resin composition for organic solvent development which is used for development using a developer which includes an organic solvent. Here, for organic solvent development has at least the meaning of use for the step of developing using a developer which includes an organic solvent.

In this manner, the present invention also relates to an actinic ray-sensitive or radiation-sensitive resin composition used for the pattern formation method of the present invention described above.

The actinic ray-sensitive or radiation-sensitive resin composition of the present invention is typically a resist composition and is preferably a negative type resist composition (that is, a resist composition for organic solvent development) in terms of being able to obtain particularly high-level effects. In addition, the composition according to the present invention is typically a chemical amplification type resist composition.

The actinic ray-sensitive or radiation-sensitive resin composition contains a resin of which, due to the polarity being increased by the action of an acid, the solubility decreases with respect to a developer which includes an organic solvent.

In addition, in one aspect, the composition of the present invention may further contain a compound which generates an acid when irradiated with an actinic ray or radiation, a hydrophobic resin, a basic compound, a surfactant, and the like.

Description will be given below of each of these components.

[Resin of which, Due to the Polarity being Increased by the Action of an Acid, the Solubility Decreases with Respect to a Developer which Includes an Organic Solvent]

Examples of the resin (also referred to below as a “resin (A)”) of which, due to the polarity being increased by the action of an acid, the solubility decreases with respect to a developer which includes an organic solvent include a resin which has a group (also referred to below as an “acid-decomposable group”) which generates a polar group by being decomposed by the action of an acid in the main chain or a side chain of the resin or both the main chain and a side chain. Here, the resin (A) is also a resin of which, due to the polarity being increased by the action of an acid, the solubility increases with respect to an alkali developer.

The acid-decomposable group preferably has a structure which is protected by a group which decomposes and desorbs a polar group due to the action of an acid.

The polar group is not particularly limited as long as the polar group is a group which is hardly soluble or insoluble in a developer which includes an organic solvent; however, examples thereof include acidic groups (groups which dissociate in a 2.38 mass % tetramethyl ammonium hydroxide aqueous solution which is used as a developer of a resist in the prior art) such as a phenolic hydroxyl group, a carboxyl group, a fluorinated alcohol group (preferably a hexafluoroisopropanol group), a sulfonic acid group, a sulfonamide group, a sulfonylimide group, an (alkylsulfonyl) (alkylcarbonyl) methylene group, an (alkylsulfonyl) (alkylcarbonyl) imide group, a bis(alkylcarbonyl) methylene group, a bis(alkylcarbonyl) imide group, a bis(alkylsulfonyl) methylene group, a bis(alkylsulfonyl) imide group, a tris(alkylcarbonyl) methylene group, and a tris(alkylsulfonyl) methylene group, an alcoholic hydroxyl group, or the like.

Here, the alcoholic hydroxyl group is a hydroxyl group which is bonded with a hydrocarbon group and a hydroxyl group other than a hydroxyl group (a phenolic hydroxyl group) which is directly bonded on an aromatic ring, while aliphatic alcohol groups (for example, fluorinated alcohol groups (a hexafluoroisopropanol group and the like)) in which the α-position is substituted with an electron-withdrawing group such as a fluorine atom as a hydroxyl group is excluded. The alcoholic hydroxyl group is preferably a hydroxyl group of which the pKa is 12 or more and 20 or less.

Examples of preferable polar groups include a carboxyl group, a fluorinated alcohol group (preferably, a hexafluoroisopropanol group), and a sulfonic acid group.

A preferable group as an acid-decomposable group is a group in which the hydrogen atoms of the groups are substituted with groups which are desorbed by an acid.

Examples of groups which are desorbed by an acid include —C(R₃₆)(R₃₇)(R₃₈), —C(R₃₆)(R₃₇)(OR₃₉), —C(R₀₁)(R₀₂)(R₃₉), and the like.

In the formula, R₃₆ to R₃₉ each independently represent an alkyl group, a cycloalkyl group, an aryl group, an aralkyl group, or an alkenyl group. R₃₆ and R₃₇ may bond with each other to form a ring.

R₀₁ and R₀₂ each independently represent a hydrogen atom, an alkyl group, a cycloalkyl group, an aryl group, an aralkyl group, or an alkenyl group.

The alkyl group of R₃₆ to R₃₉, R₀₁, and R₀₂ is preferably an alkyl group with 1 to 8 carbon atoms.

A cycloalkyl group of group of R₃₆ to R₃₉ and R₀₁, and R₀₂ may be a monocyclic type or may be a polycyclic type. The number of carbon atoms of the cycloalkyl group is preferably 3 to 20.

The aryl group of R₃₆ to R₃₉, R₀₁, and R₀₂ is preferably an aryl group with 6 to 10 carbon atoms.

An aralkyl group of R₃₆ to R₃₉, R₀₁, and R₀₂ is preferably an aralkyl group with 7 to 12 carbon atoms.

An alkenyl group of R₃₆ to R₃₉, R₀₁, and R₀₂ is preferably an alkenyl group with 2 to 8 carbon atoms.

A ring which is formed by R₃₆ and R₃₇ bonding with each other is preferably a cycloalkyl group (monocyclic or polycyclic). The cycloalkyl group is preferably a monocyclic cycloalkyl group such as a cyclopentyl group and a cyclohexyl group, or a polycyclic cycloalkyl group such as a norbornyl group, a tetracyclodecanyl group, a tetracyclododecanyl group, and an adamantyl group. A monocyclic cycloalkyl group with 5 or 6 carbon atoms is more preferable, and a monocyclic cycloalkyl group with 5 carbon atoms is particularly preferable.

An acid-decomposable group is preferably a cumyl ester group, an enol ester group, an acetal ester group, a tertiary alkyl ester group, and the like. The tertiary alkyl ester group is more preferable.

[Repeating Unit which has an Acid-Decomposable Group]

The resin (A) preferably has a repeating unit which has an acid-decomposable group.

In one aspect, the resin (A) preferably contains a repeating unit (AI) (also referred to below as a “repeating unit (AI)”) which generates a carboxyl group by being decomposed by an acid and more preferably has a repeating unit which is represented by General Formula (aI) or (aI′) below.

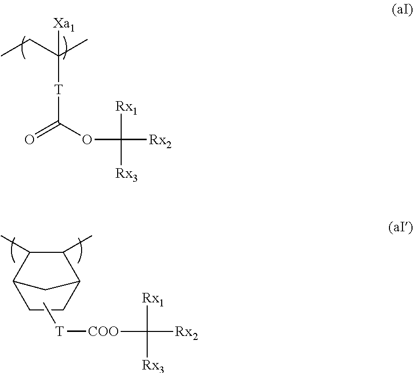

In General Formulas (aI) and (aI′),

Xa₁ represents a hydrogen atom, an alkyl group, a cyano group, or a halogen atom.

T represents a single bond or a divalent linking group.

Rx₁ to Rx₃ each independently represent an alkyl group or a cycloalkyl group. Two of Rx₁ to Rx₃ may bond with each other to form a ring structure. In addition, the ring structure may contain a hetero atom such as an oxygen atom in a ring.

Examples of a divalent linking group of T include an alkylene group, a —COO-Rt- group, a —O-Rt- group, a phenylene group, and the like. In the formula, Rt represents an alkylene group or a cycloalkylene group.

From the point of view of the resist being insoluble with respect to an organic solvent-based developer, T in General Formula (aI) is preferably a single bond or a —COO-Rt- group and more preferably a —COO-Rt group. Rt is preferably an alkylene group with 1 to 5 carbon atoms and more preferably a —CH₂— group, a —(CH₂)₂— group, and a —(CH₂)₃— group.

T in General Formula (aI′) is preferably a single bond.

An alkyl group of Xa₁ may have a substituent group and examples of the substituent group include a hydroxyl group and a halogen atom (preferably a fluorine atom).

An alkyl group of Xa₁ preferably has 1 to 4 carbon atoms and is preferably a methyl group.

Xa₁ is preferably a hydrogen atom or a methyl group.

An alkyl group of Rx₁, Rx₂, and Rx₃ may be straight-chain or may be branched.

A cycloalkyl group of Rx₁, Rx₂, and Rx₃ is preferably a monocyclic cycloalkyl group such as a cyclopentyl group and a cyclohexyl group, or a polycyclic cycloalkyl group such as a norbornyl group, a tetracyclodecanyl group, a tetracyclododecanyl group, and an adamantyl group.

A ring structure which two of Rx₁, Rx₂, and Rx₃ form by bonding with each other is preferably a monocyclic cycloalkane ring such as a cyclopentyl ring and a cyclohexyl ring or a polycyclic cycloalkyl group such as a norbornane ring, a tetracyclodecane ring, a tetracyclododecane ring, and an adamantane ring. A monocyclic cycloalkane ring with 5 or 6 carbon atoms is particularly preferable.

Rx₁, Rx₂, and Rx₃ are each independently preferably an alkyl group and more preferably a straight-chain or branched alkyl group with 1 to 4 carbon atoms.

Each of the groups described above may have a substituent group and examples of the substituent group include an alkyl group (with 1 to 4 carbon atoms), a cycloalkyl group (with 3 to 8 carbon atoms), a halogen atom, an alkoxy group (with 1 to 4 carbon atoms), a carboxyl group, an alkoxycarbonyl group (with 2 to 6 carbon atoms), and the like and the number of carbon atoms is preferably 8 or less. Among these, from the point of view of further improving the dissolution contrast with respect to a developer which contains an organic solvent before and after being decomposed by an acid, a substituent group which does not have a hetero atom such as an oxygen atom, a nitrogen atom, and a sulfur atom is more preferable (for example, more preferably not an alkyl group or the like which is substituted with a hydroxyl group), a group which is only formed of hydrogen atoms and carbon atoms is even more preferable, and a straight-chain or branched alkyl group and a cycloalkyl group are particularly preferable.

Specific examples of the repeating unit which is represented by General Formula (aI) or (aI′) will be given below; however, the present invention is not limited to the specific examples.

In the specific examples, Rx represents a hydrogen atom, CH₃, CF₃, or CH₂OH. Rxa and Rxb each represent an alkyl group with 1 to 4 carbon atoms. Xa₁ represents a hydrogen atom, CH₃, CF₃, or CH₂OH. Z represents a substituent group and in a case where a plurality of Z's are present, the plurality of Z's may be the same as or may be different from each other. p represents 0 or a positive integer. Specific examples and preferable examples of Z are the same as the specific examples and the preferable examples of the substituent group which each group of Rx₁ to Rx₃ or the like may have.

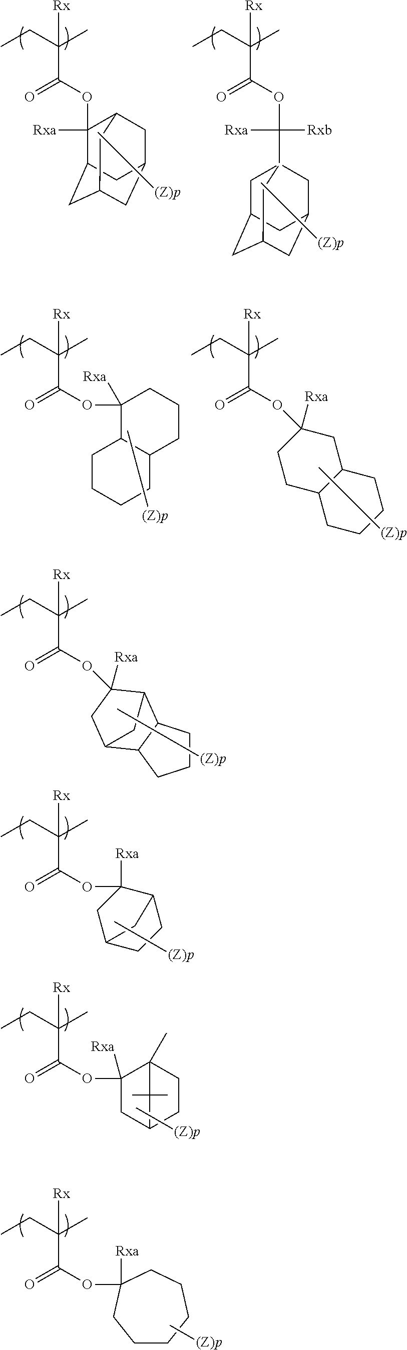

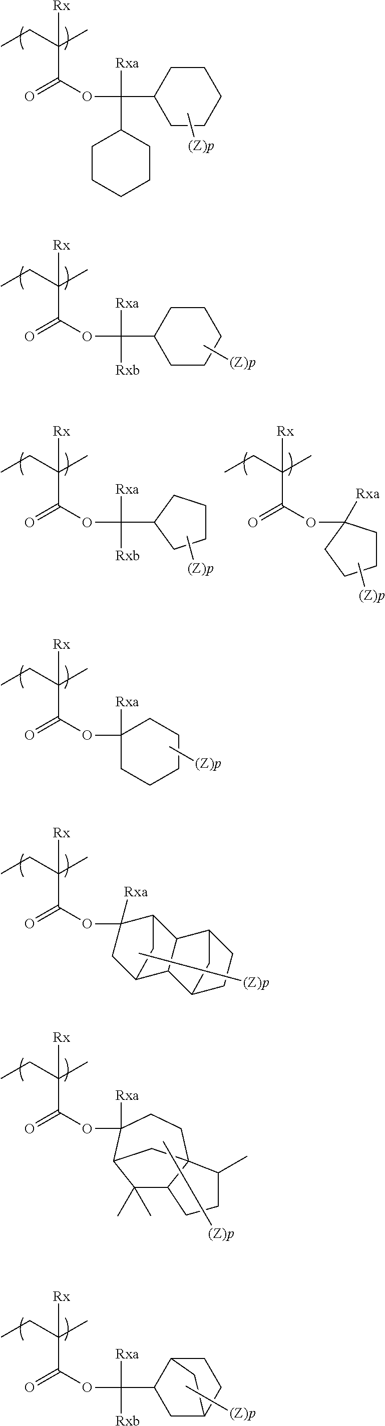

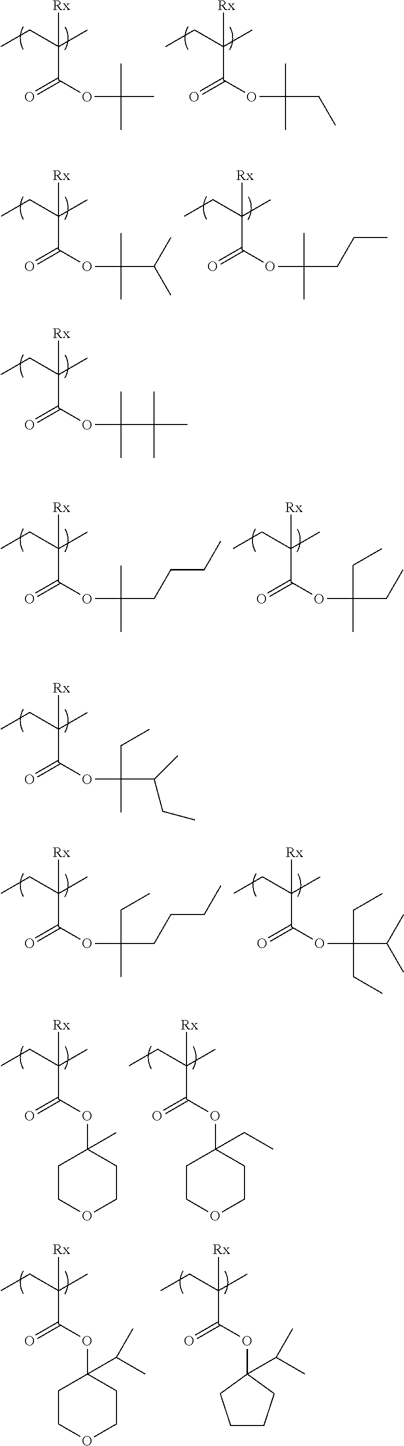

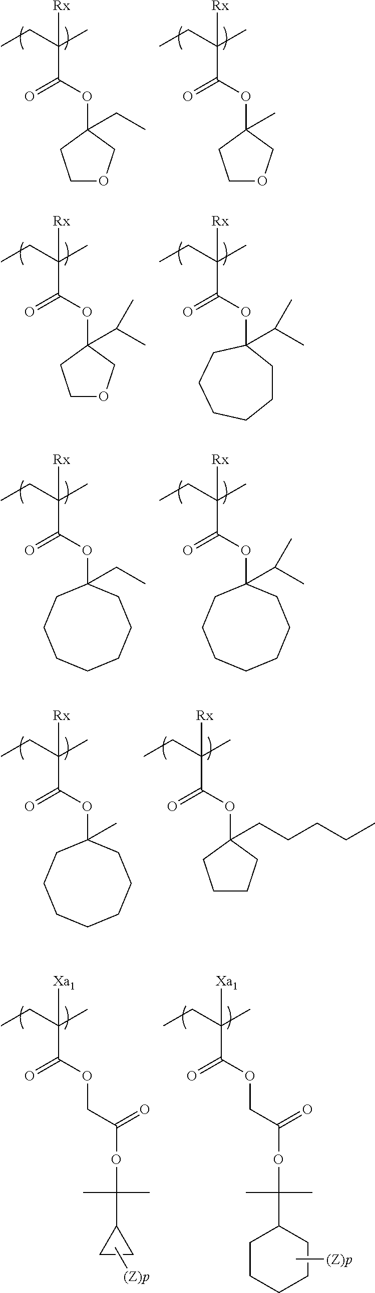

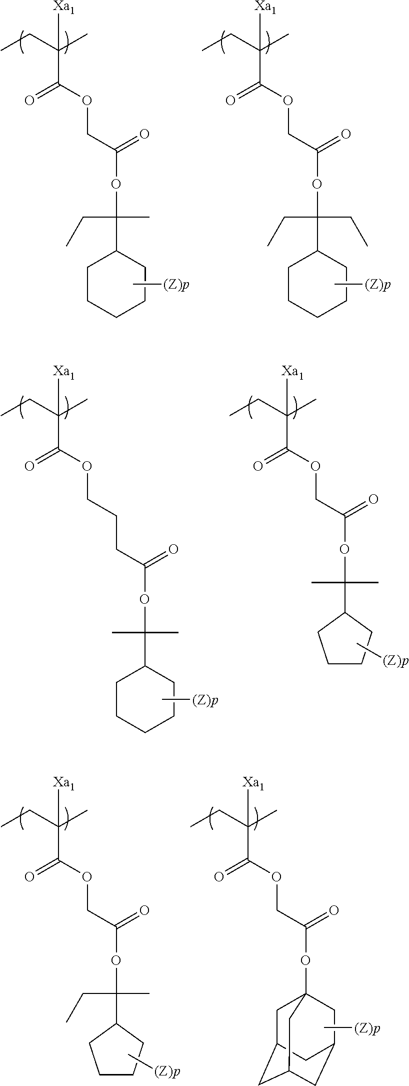

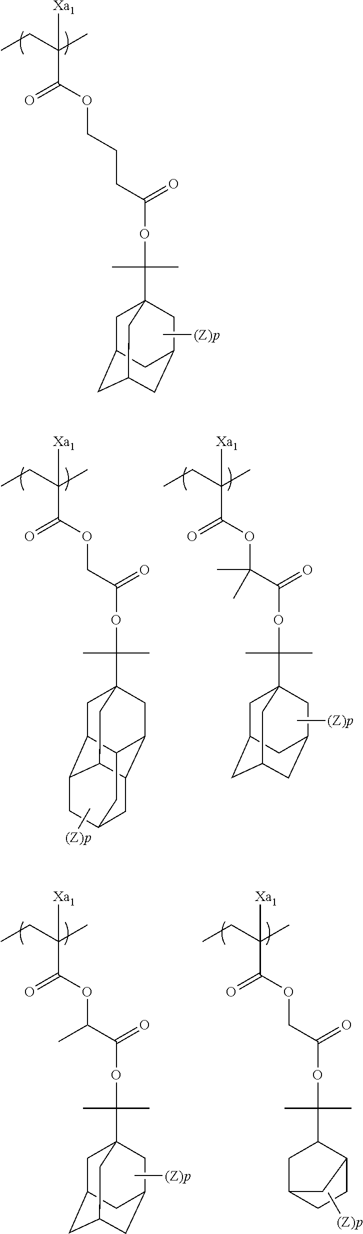

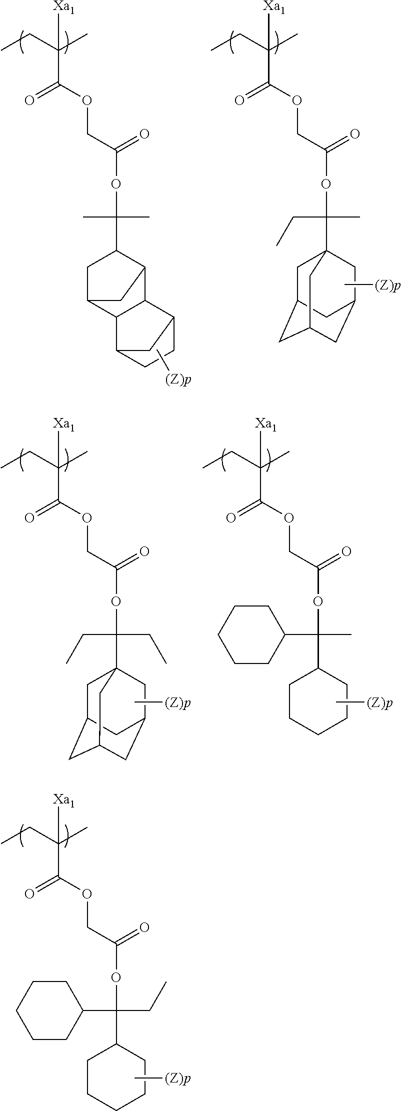

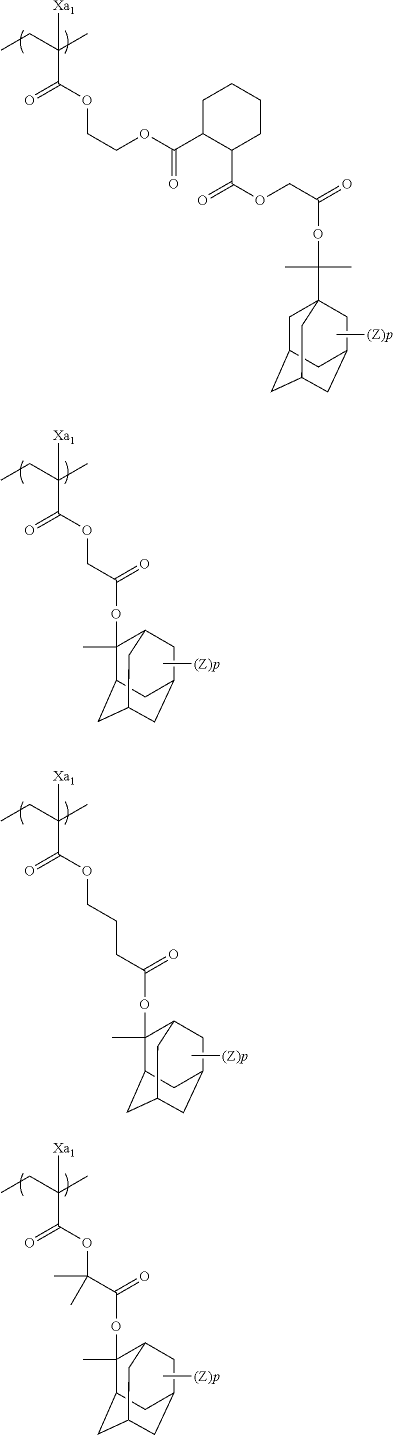

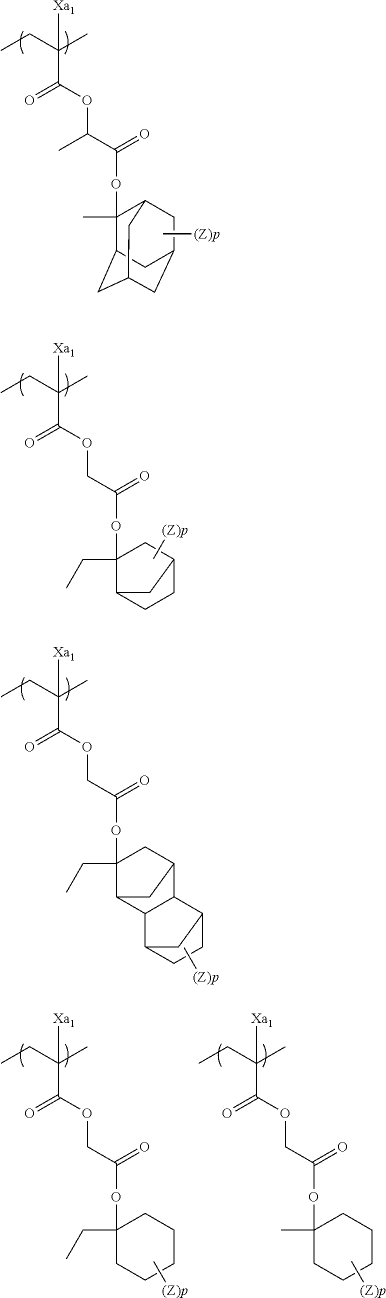

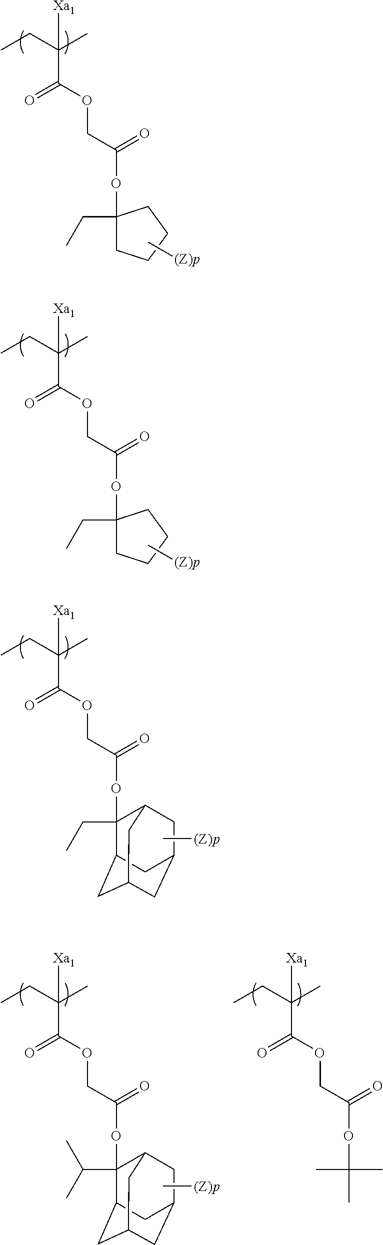

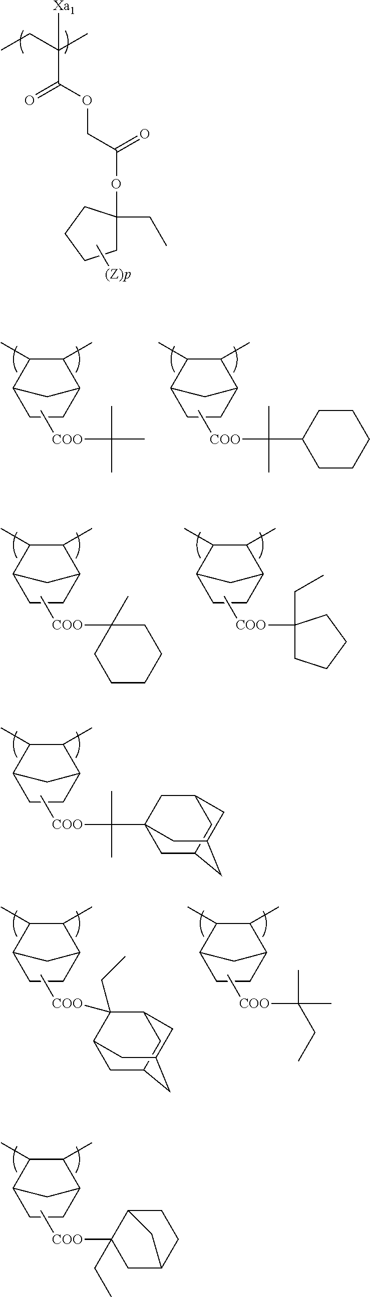

In the specific examples below, Xa represents a hydrogen atom, an alkyl group, a cyano group, or a halogen atom.

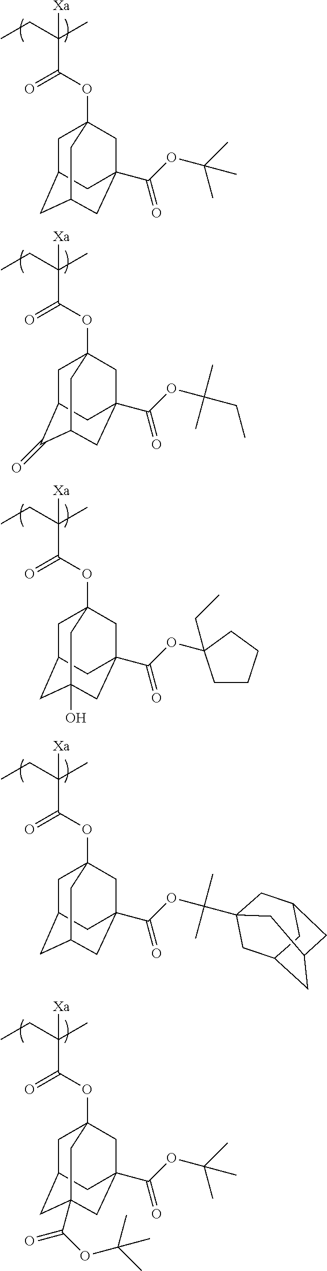

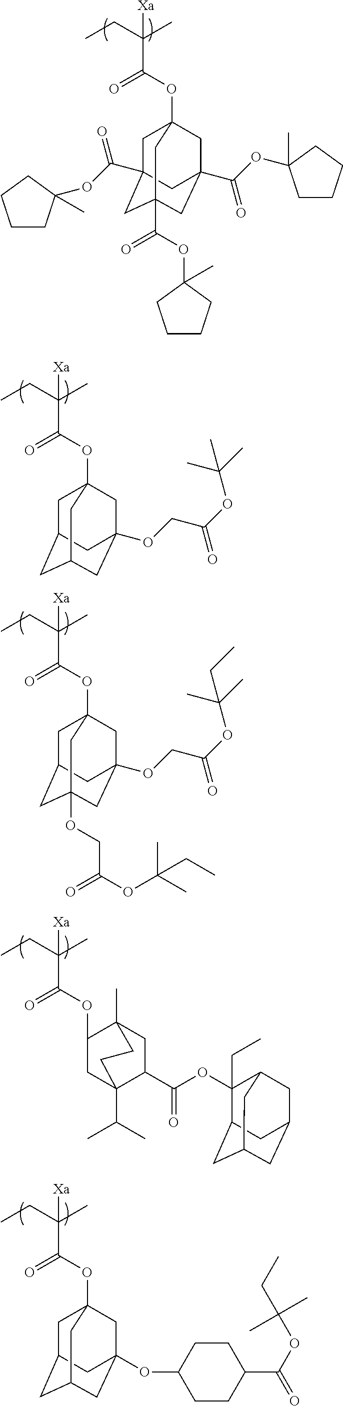

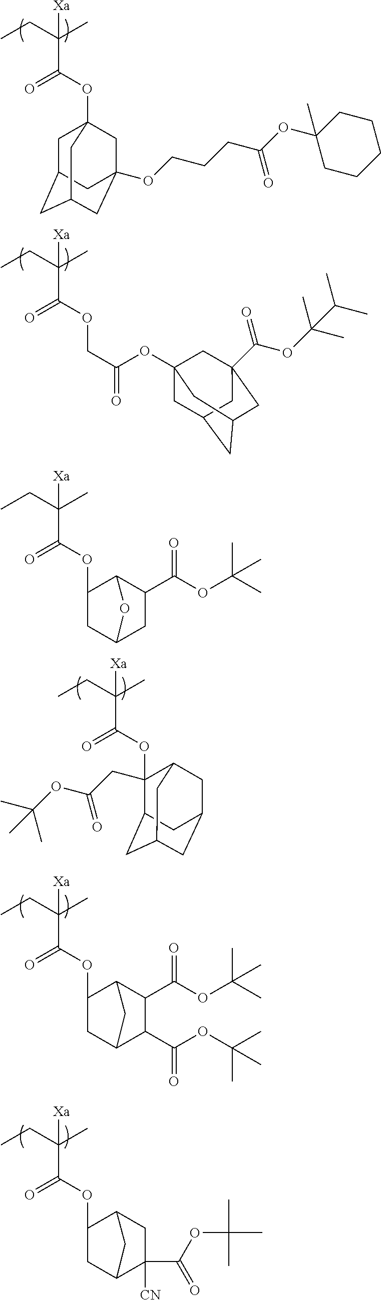

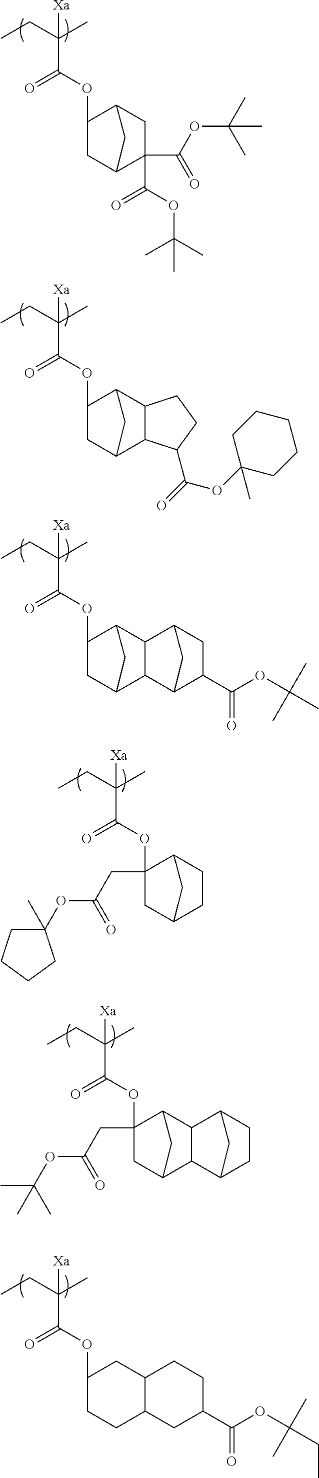

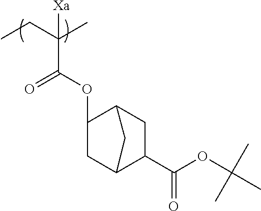

The following are examples of a repeating unit which has an acid-decomposable group in a case where a group which is desorbed by an acid has a structure which is represented by —C(R₀₁)(R₀₂)(OR₃₉) described above.

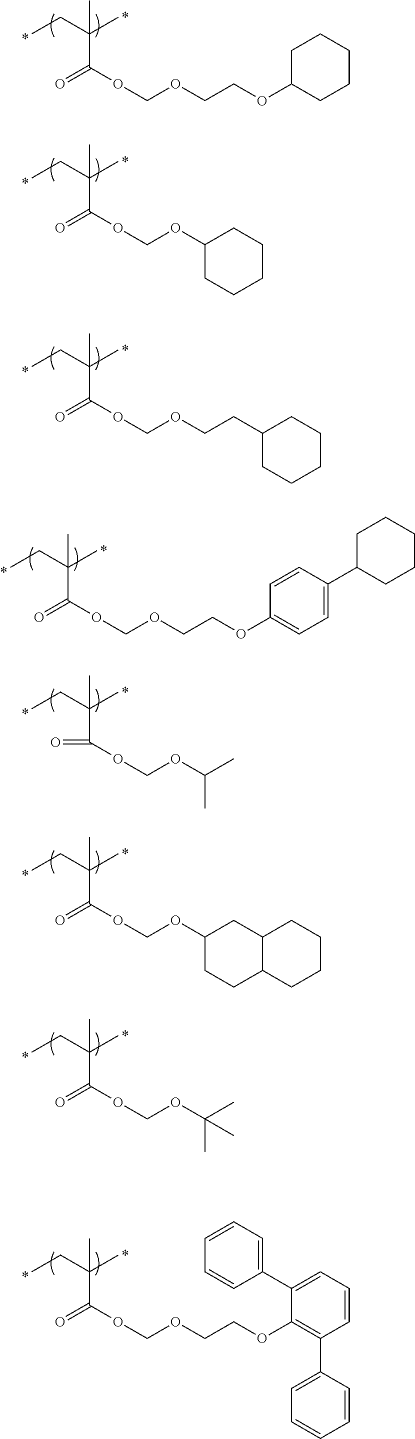

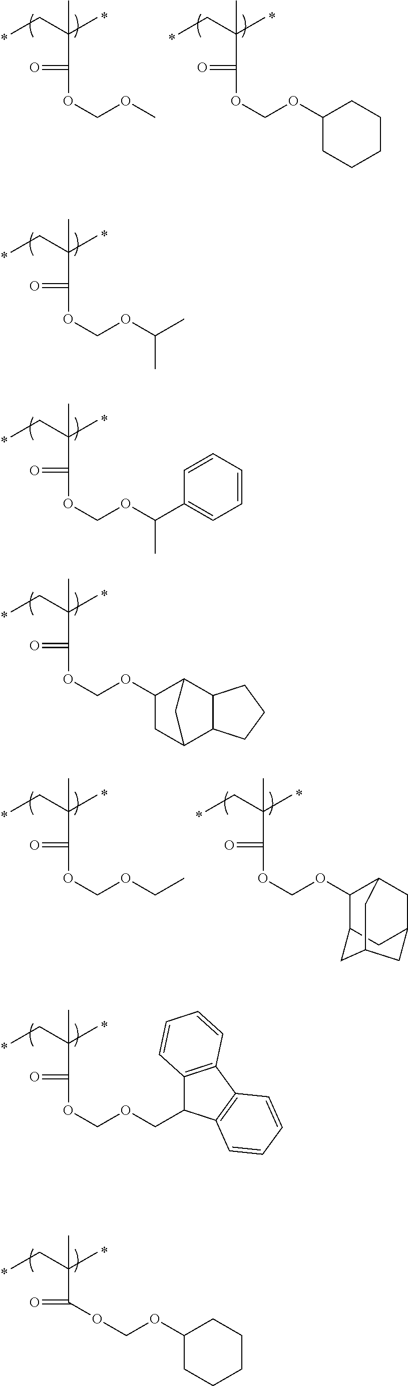

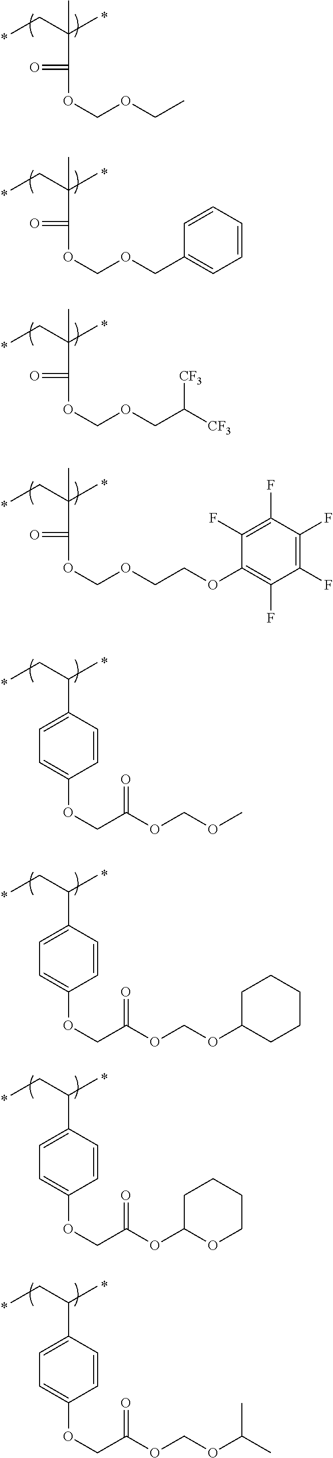

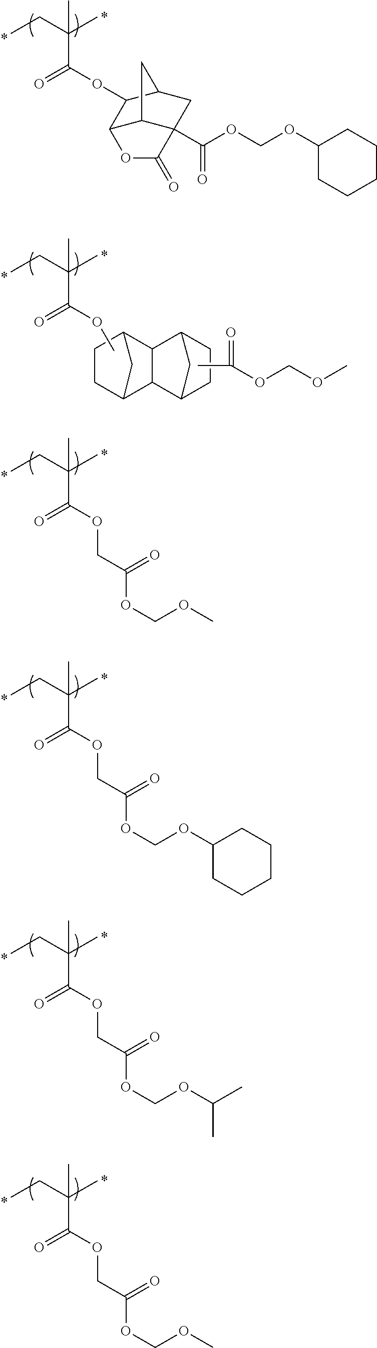

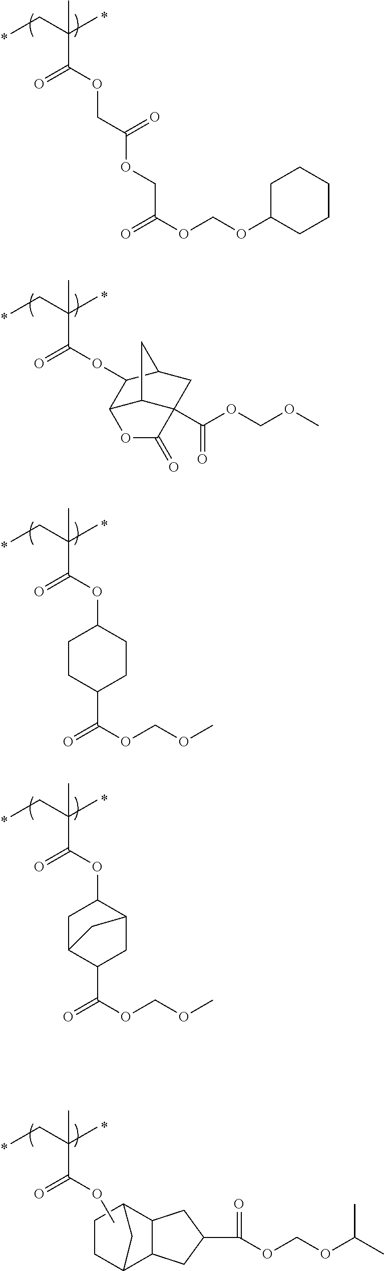

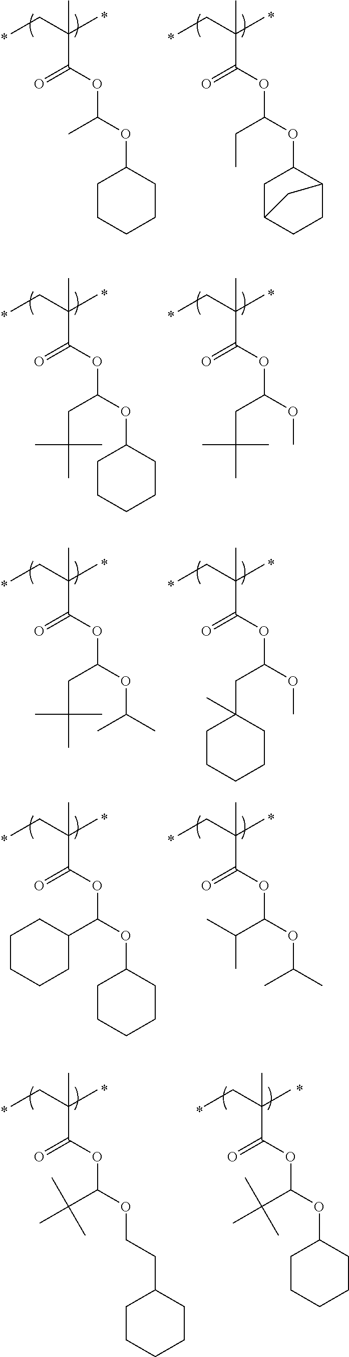

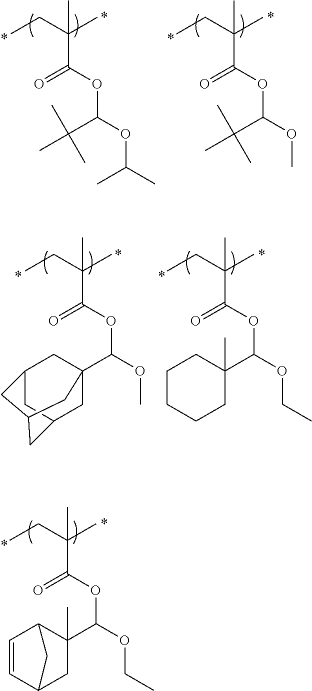

In one aspect, the resin (A) preferably contains a repeating unit of which the total number of carbon atoms of a site which is decomposed by an acid is 4 to 9 as a repeating unit which has an acid-decomposable group. An aspect where the number of carbon atoms of the —C(Rx₁)(Rx₂)(Rx₃) portion in General Formula (aI) described above is 4 to 9 is more preferable.

An aspect where all of Rx₁, Rx₂, and Rx₃ in General Formula (aI) are methyl groups or ethyl groups or an aspect which is represented by General Formula (aII) below is even more preferable.

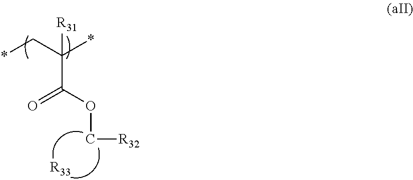

In General Formula (aII),

R₃₁ represents a hydrogen atom or an alkyl group.

R₃₂ represents a methyl group, an ethyl group, an n-propyl group, an isopropyl group, an n-butyl group, an isobutyl group, or a sec-butyl group.

R₃₃ represents an atomic group which is necessary to form a monocyclic alicyclic hydrocarbon structure with a carbon atom with which R₃₂ is bonded. Regarding the alicyclic hydrocarbon structure, some carbon atoms which form a ring may be substituted with hetero atoms or groups which have hetero atoms.

Here, the total number of carbon atoms of R₃₂ and R₃₃ is 8 or less.

An alkyl group of R₃₁ may have a substituent group and examples of the substituent group include a fluorine atom, a hydroxyl group, and the like.

R₃₁ preferably represents a hydrogen atom, a methyl group, a trifluoromethyl group, or a hydroxymethyl group.

R₃₂ is preferably a methyl group, an ethyl group, an n-propyl group, or an isopropyl group, and more preferably a methyl group or an ethyl group.

A monocyclic alicyclic hydrocarbon structure which R₃₃ forms with carbon atoms is preferably a 3-membered to 8-membered ring and more preferably a 5-membered or 6-membered ring.

In the monocyclic alicyclic hydrocarbon structure which R₃₃ forms with carbon atoms, examples of hetero rings which may form a ring include an oxygen atom, a sulfur atom, and the like and examples of groups which have a hetero atom include a carbonyl group and the like. However, the group which has a hetero atom is preferably not an ester group (an ester bond).

The monocyclic alicyclic hydrocarbon structure which R₃₃ forms with carbon atoms is preferably only formed by carbon atoms and hydrogen atoms.

In addition, in another aspect, as a repeating unit which has an acid-decomposable group, the resin (A) may include a repeating unit (aIII) of which the number of carbon atoms of a site which is decomposed by an acid is 10 to 20 and which has an acid-decomposable site which includes a polycyclic structure.

The repeating unit (aIII) of which the number of carbon atoms of the acid-decomposable site is 10 to 20 and which includes a polycyclic structure in the acid-decomposable site preferably has an aspect where, in General Formula (aI) described above, one of Rx₁, Rx₂, and Rx₃ is a group which has an adamantane skeleton and the remaining two are a straight-chain or branched alkyl group, or an aspect where, in General Formula (aI), two out of Rx₁, Rx₂, and Rx₃ bond with each other to form an adamantane structure and the remaining one is a straight-chain or branched alkyl group.

In addition, the resin (A) may have a repeating unit, which generates an alcoholic hydroxyl group by being decomposed by the action of an acid as represented below, as a repeating unit which has an acid-decomposable group.

In the specific examples below, Xa₁ represents a hydrogen atom, CH₃, CF₃, or CH₂OH.

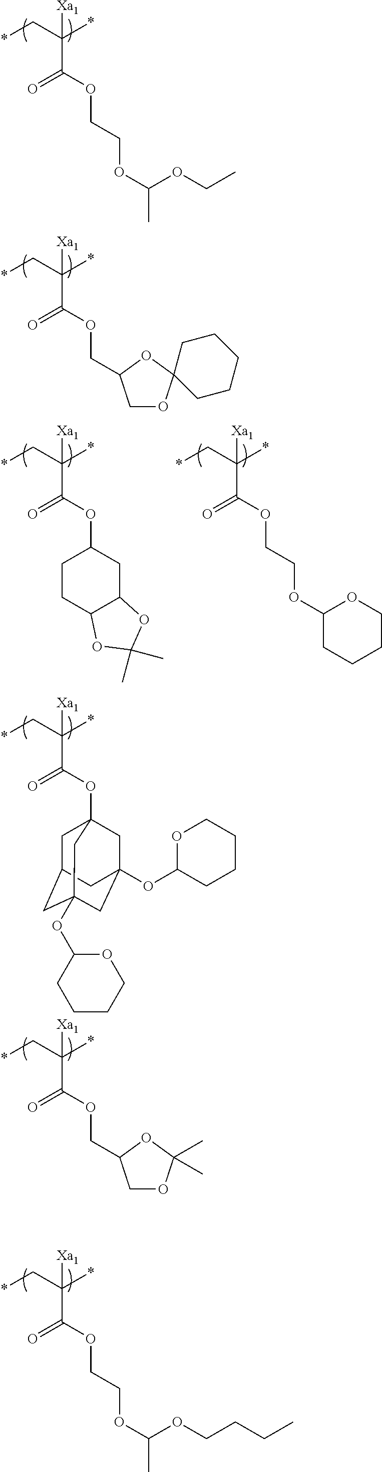

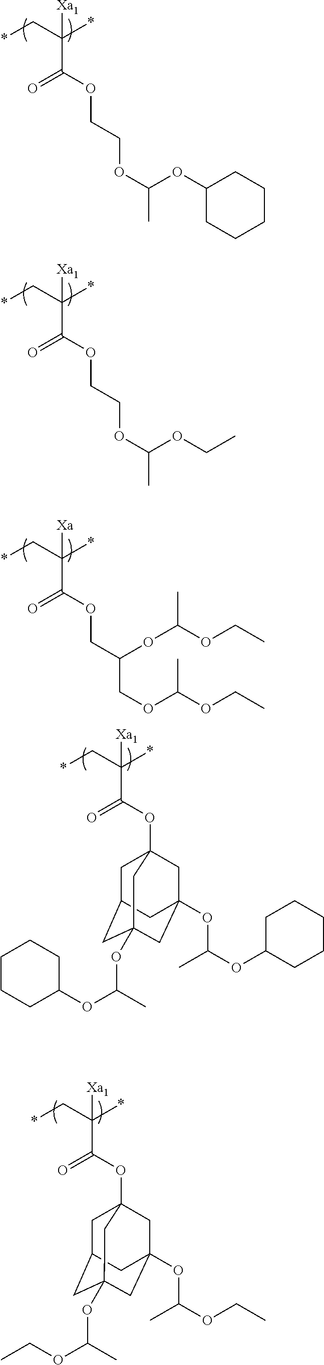

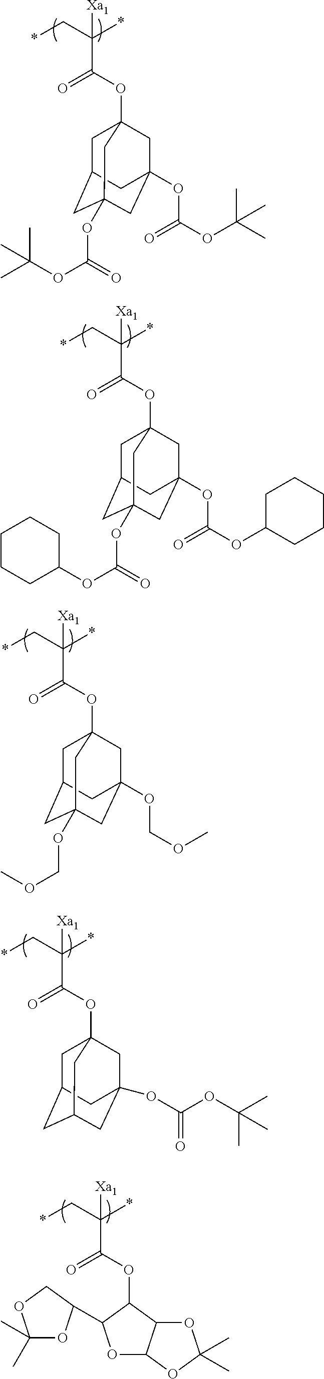

The repeating unit which has an acid-decomposable group which may be contained in the resin (A) may be one type or two or more types may be used together.

In a case where the resin (A) contains two or more types of the repeating units which have an acid-decomposable group, for example, a combination of a repeating unit of an aspect where Rx₁, Rx₂, and Rx₃ in General Formula (aI) described above are all methyl groups or ethyl groups or an aspect which is represented by General Formula (aII) described above and a repeating unit of which the number of carbon atoms of the acid-decomposable site described above is 10 to 20 and which is represented by the repeating unit (aIII) which includes a polycyclic structure in the acid-decomposable site is preferable.

Examples of the combination in a case where the resin (A) includes two types of repeating units which have an acid-decomposable group specifically include the following. In the formula below, R's each independently represent a hydrogen atom or a methyl group.

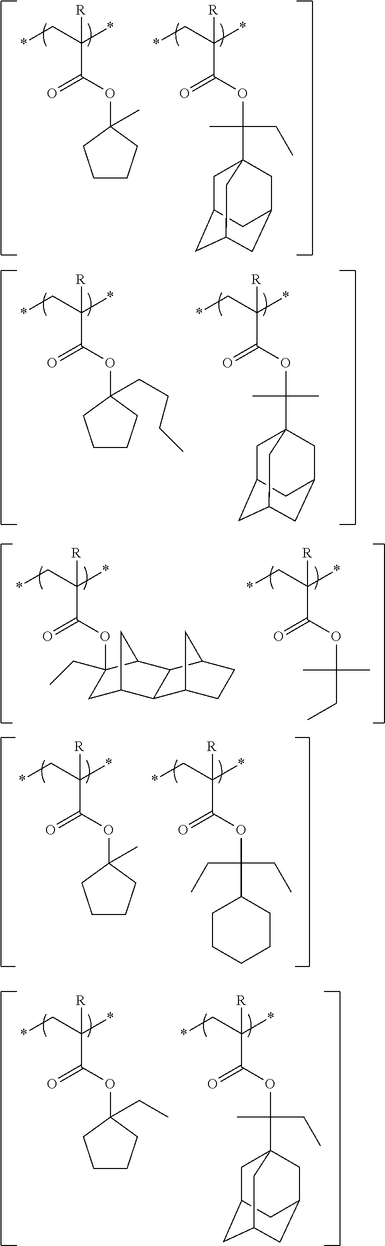

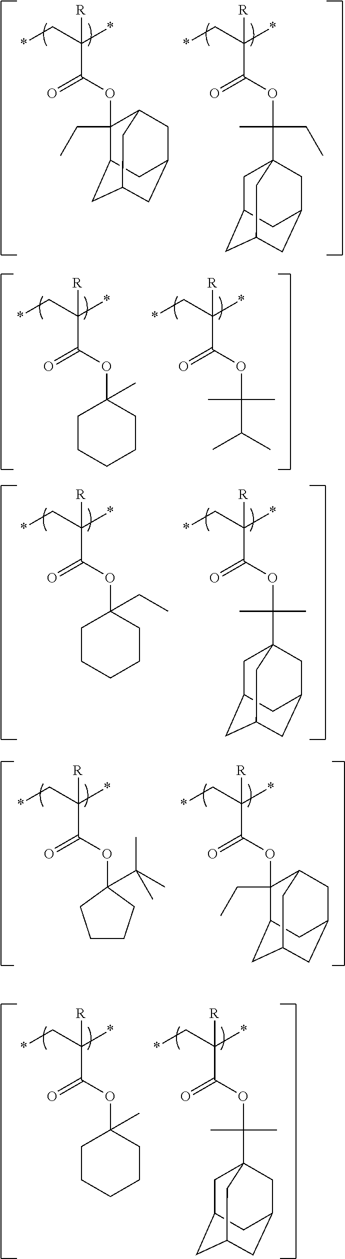

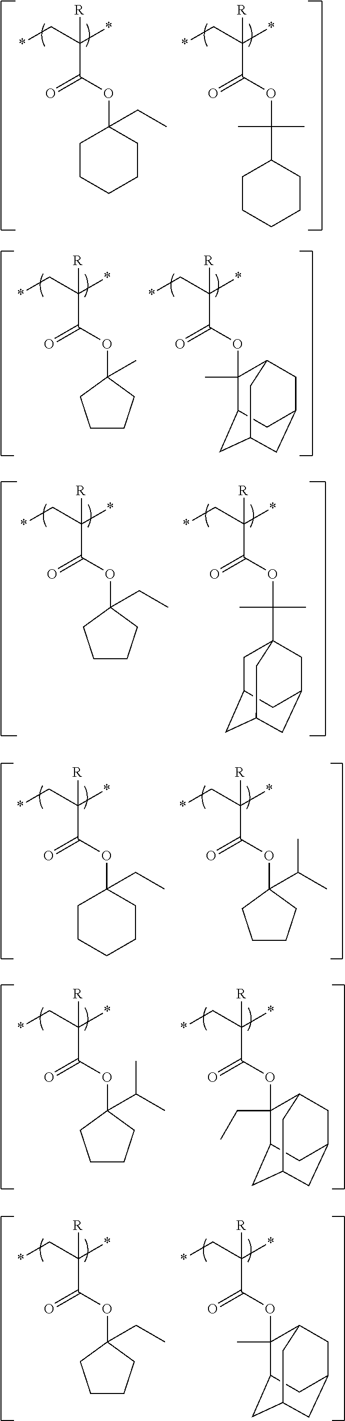

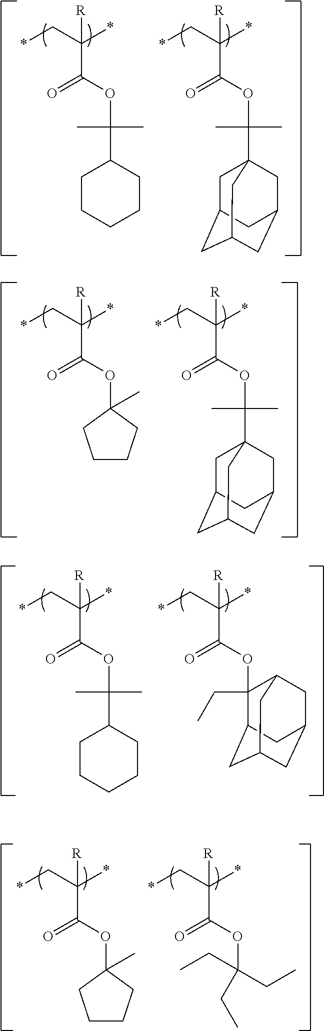

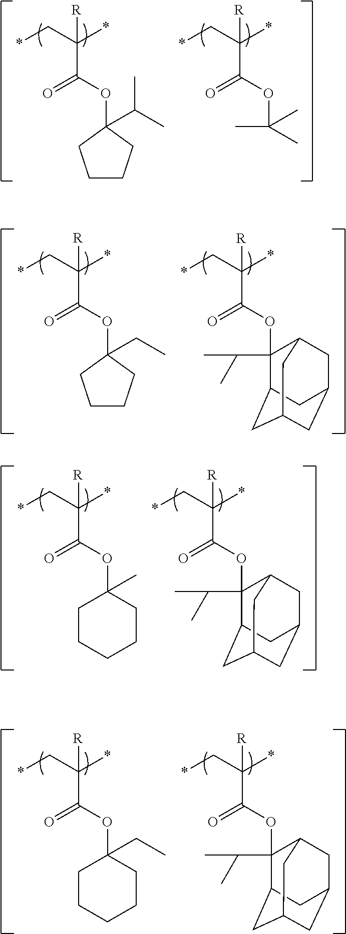

All of the repeating units which has an acid-decomposable group is preferably 30 mol % to 80 mol %, more preferably 40 mol % to 75 mol/o, particularly preferably 45 mol % to 70 mol %, and most preferably 50 mol % to 70 mol % with respect to all of the repeating units which form the resin (A).

The content ratio of the repeating units which are represented by General Formula (aI) is preferably 30 mol % to 80 mol %, more preferably 40 mol % to 75 mol %, particularly preferably 45 mol % to 70 mol %, and most preferably 50 mol % to 70 mol % with respect to all of the repeating units which form the resin (A).

In addition, the ratio of the repeating units (aIII) in all of the repeating units which have an acid-decomposable group is preferably 3 mol % to 50 mol/%, more preferably 5 mol % to 40 mol %, and most preferably 5 mol % to 30 mol % or less.

[Repeating Unit which has a Lactone Structure or a Sultone Structure]

The resin (A) may contain a repeating unit which has a lactone structure or a sultone structure.

As a lactone structure or a sultone structure, it is possible to use any structure as long as the structure is a lactone structure or a sultone structure; however, a 5-membered to 7-membered cyclic lactone structure or a 5-membered to 7-membered cyclic sultone structure is preferable, and a repeating unit in which another ring structure is condensed in a form of forming a bicyclo structure and a spiro structure in a 5-membered to 7-membered cyclic lactone structure or a repeating unit in which another ring structure is condensed in a form of forming a bicyclo structure and a spiro structure in a 5-membered to 7-membered cyclic sultone structure is more preferable. It is more preferable to have a repeating unit which has a lactone structure which is represented by any of General Formulas (LC1-1) to (LC1-21) below or a sultone structure which is represented by any of General Formulas (SL1-1) to (SL1-3) below. In addition, the lactone structure or the sultone structure may be directly bonded with the main chain. Preferable lactone structures are (LC1-1), (LC1-4), (LC1-5), (LC1-6), (LC1-13), (LC1-14), and (LC1-17) and a particularly preferable structure is (LC1-4). The LER and developing defects are favorable as a result of using the specific lactone structure.

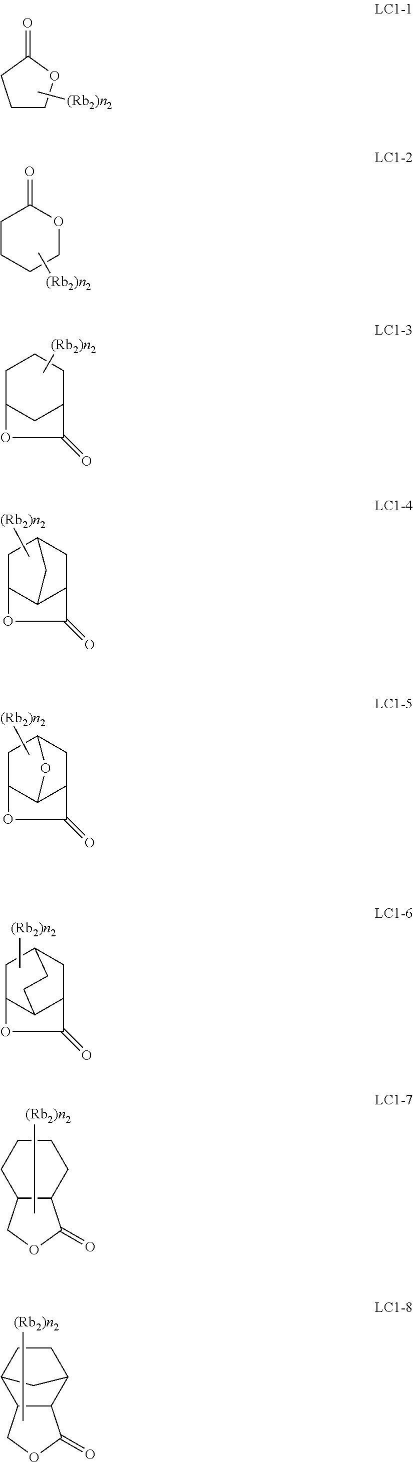

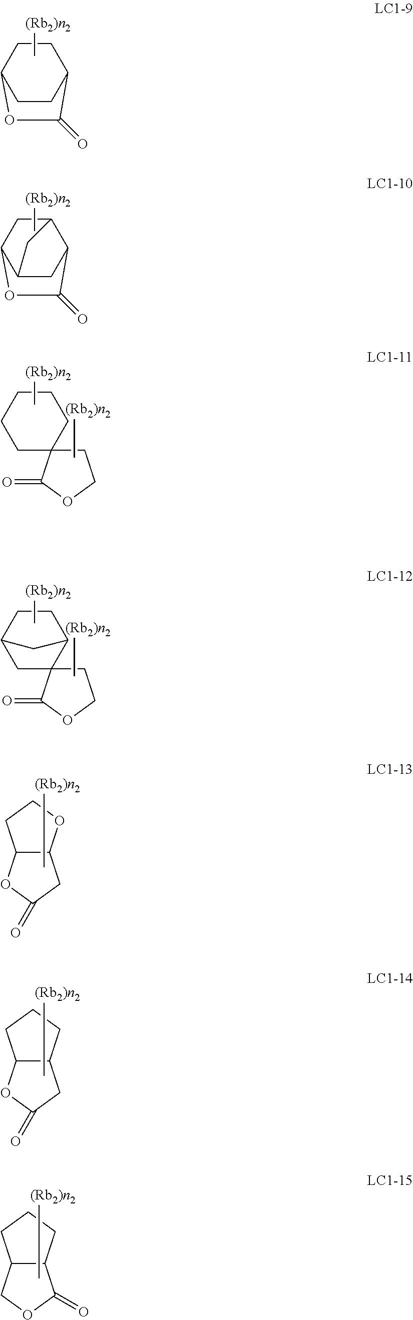

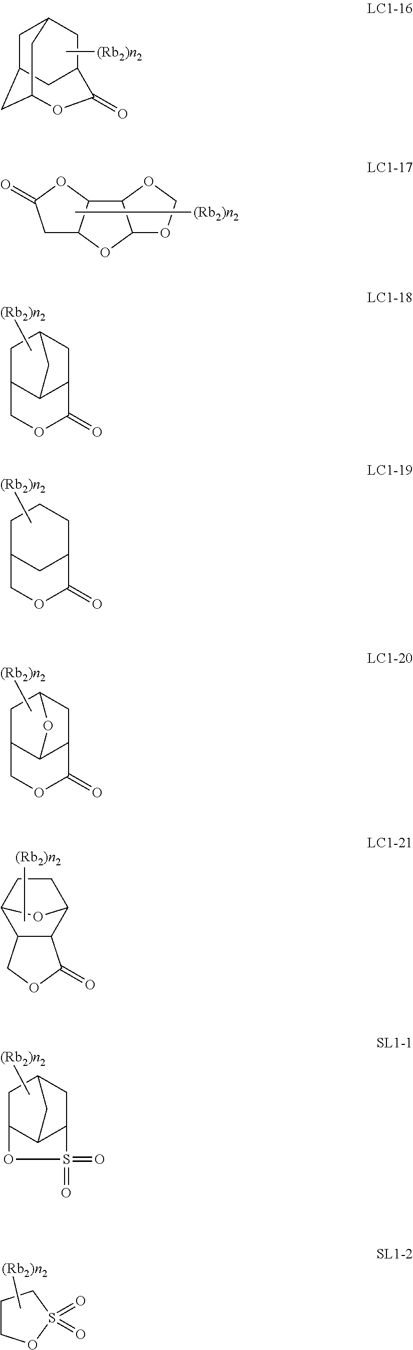

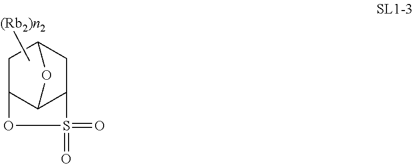

The lactone structure portion or the sultone structure portion may or may not have a substituent group (Rb₂). Examples of a preferable substituent group (Rb₂) include an alkyl group with 1 to 8 carbon atoms, a cycloalkyl group with 4 to 7 carbon atoms, an alkoxy group with 1 to 8 carbon atoms, an alkoxycarbonyl group with 2 to 8 carbon atoms, a carboxyl group, a halogen atom, a hydroxyl group, a cyano group, an acid-decomposable group, and the like. An alkyl group with 1 to 4 carbon atoms, a cyano group, and an acid-decomposable group are more preferable. n₂ represents an integer of 0 to 4. When n₂ is 2 or more, a plurality of substituent groups (Rb₂) may be the same as or different from each other. In addition, the plurality of substituent groups (Rb₂) may bond with each other to form a ring.

In a repeating unit which has a lactone structure or a sultone structure, an optical isomer is normally present; however, any optical isomer may be used. In addition, one type of optical isomer may be used individually or a plurality of optical isomers may be used in a mixture. In a case of mainly using one type of optical isomer, the optical purity (ee) thereof is preferably 90% or more and more preferably 95% or more.

The repeating unit which has a lactone structure or a sultone structure is preferably a repeating unit which is represented by General Formula (III) below.

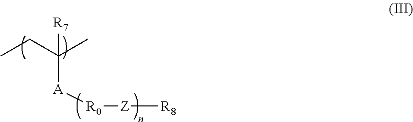

In General Formula (III) described above,

A represents an ester bond (a group which is represented by —COO—) or an amide bond (a group which is represented by —CONH—).

R₀'s each independently represent an alkylene group, a cycloalkylene group, or the combination thereof in a case where there are a plurality thereof.

Z's each independently represent a single bond, an ether bond, an ester bond, an amide bond, or a urethane bond

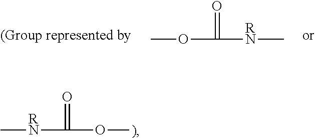

or a urea bond in a case where there are a plurality thereof.

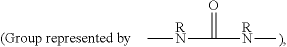

Here, R's each independently represent a hydrogen atom, an alkyl group, a cycloalkyl group, or an aryl group.

R₈ represents a monovalent organic group which has a lactone structure or a sultone structure.

n is the number of repetitions of the structures which are represented by —R₀—Z— and represents an integer of 0 to 5, is preferably 0 or 1, and more preferably 0. In a case where n is 0, —R₀—Z— is not present and n is a single bond.

R₇ represents a hydrogen atom, a halogen atom, or an alkyl group.

An alkylene group and a cycloalkylene group of R₀ may have a substituent group.

Z is preferably an ether bond and an ester bond and particularly preferably an ester bond.

An alkyl group of R₇ is preferably an alkyl group with 1 to 4 carbon atoms and particularly preferably a methyl group.

The alkylene group and the cycloalkylene group of R₀ and the alkyl group in R₇ may be each substituted and examples of the substituent group include a halogen atom such as a fluorine atom, a chlorine atom, or a bromine atom, a mercapto group, a hydroxyl group, and an alkoxy group.

R₇ is preferably a hydrogen atom, a methyl group, a trifluoromethyl group, or a hydroxymethyl group.

A preferable chain alkylene group in R₀ is preferably a chain alkylene group with 1 to 10 carbon atoms and examples thereof include a methylene group, an ethylene group, a propylene group, and the like. A preferable cycloalkylene group is a cycloalkylene group with 3 to 20 carbon atoms and examples thereof include a cyclohexylene group, a cyclopentylene group, a norbornylene group, an adamantylene group, and the like. In order to exhibit the effects of the present invention, a chain alkylene group is more preferable, and a methylene group is particularly preferable.

A monovalent organic group which has a lactone structure or a sultone structure which is represented by R₈ is not limited as long as the monovalent organic group has a lactone structure or a sultone structure, specific examples include a lactone structure or a sultone structure which is represented by any out of General Formulas (LC1-1) to (LC1-21) and (SL1-1) to (SL1-3), and a structure which is represented by (LC1-4) out of these is particularly preferable. In addition, n₂ in (LC1-1) to (LC1-21) is more preferably 2 or less.

In addition, R₈ is preferably a monovalent organic group which has an unsubstituted lactone structure or sultone structure or a monovalent organic group which has a lactone structure or a sultone structure which has a methyl group, a cyano group, or an alkoxycarbonyl group as a substituent group, and more preferably a monovalent organic group which has a lactone structure (cyanolactone) which has a cyano group as a substituent group.

Specific examples of the repeating unit which has a lactone structure or a sultone structure will be given below; however, the present invention is not limited thereto.

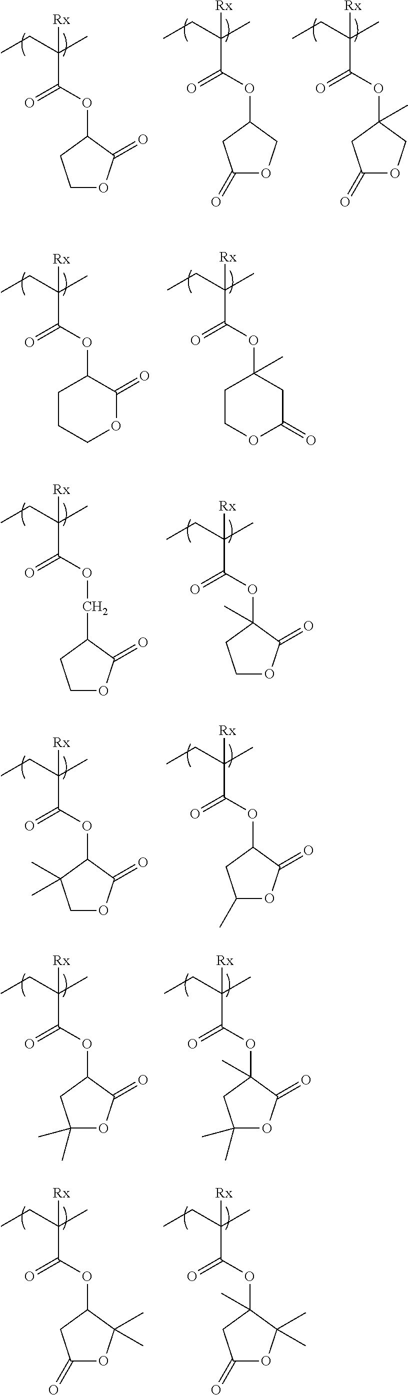

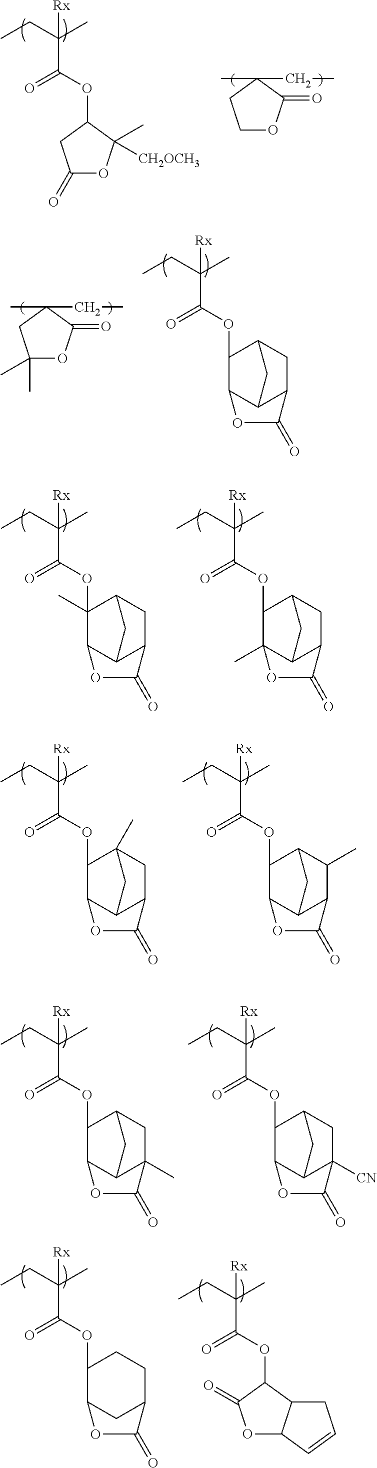

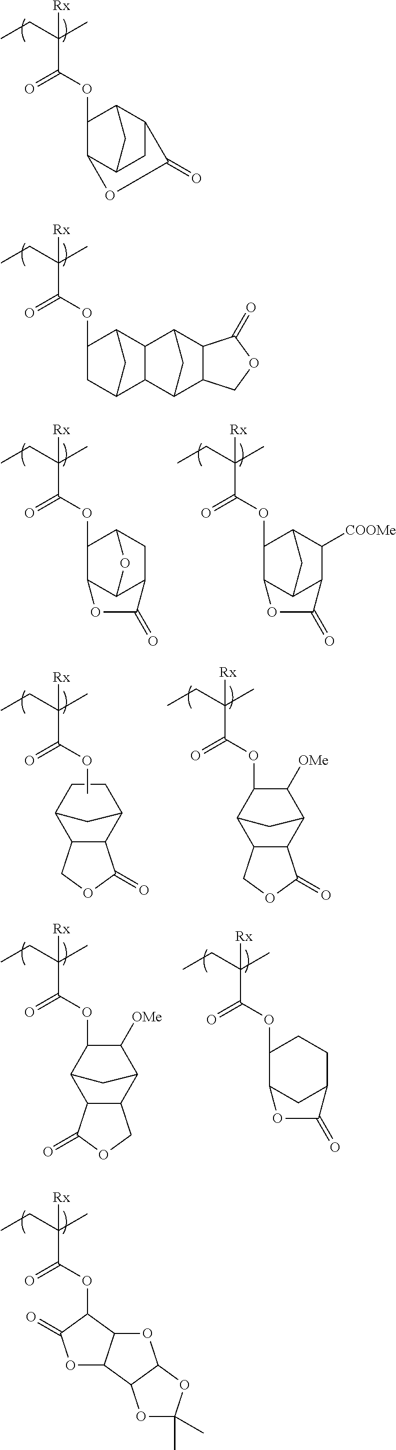

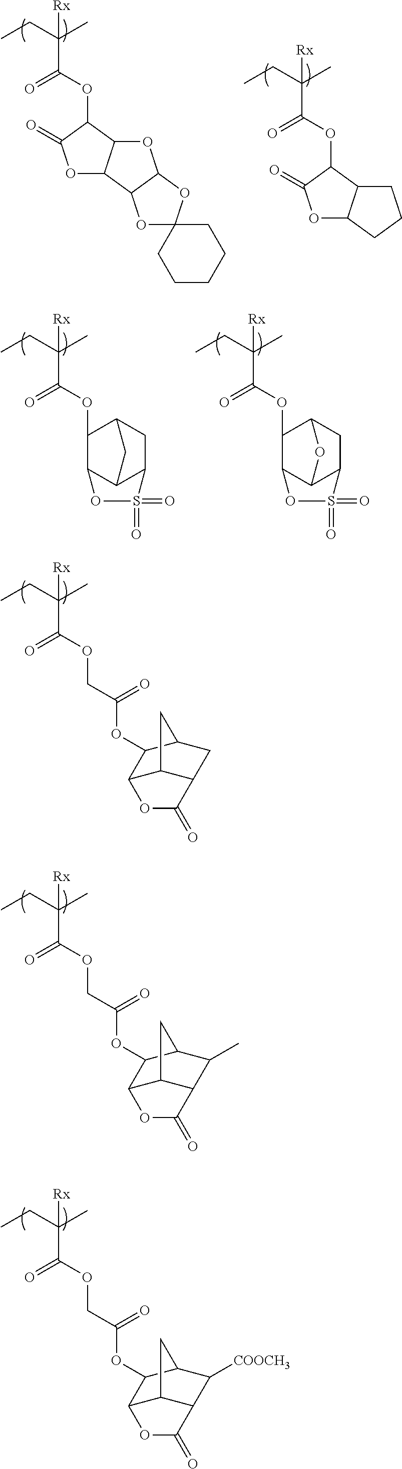

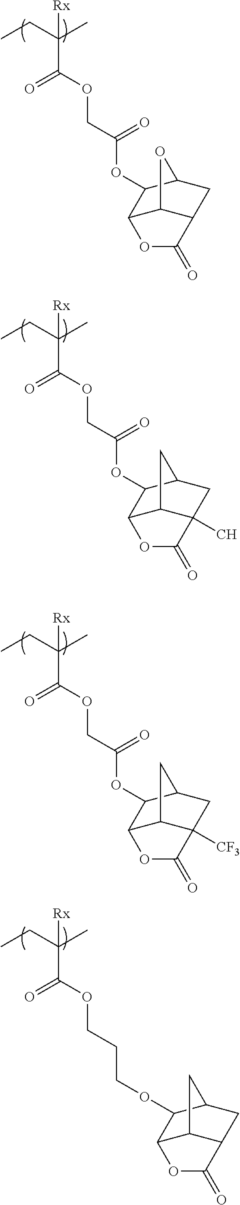

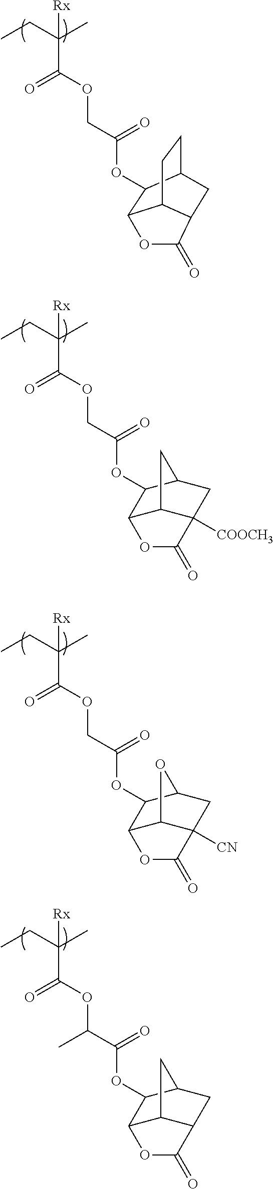

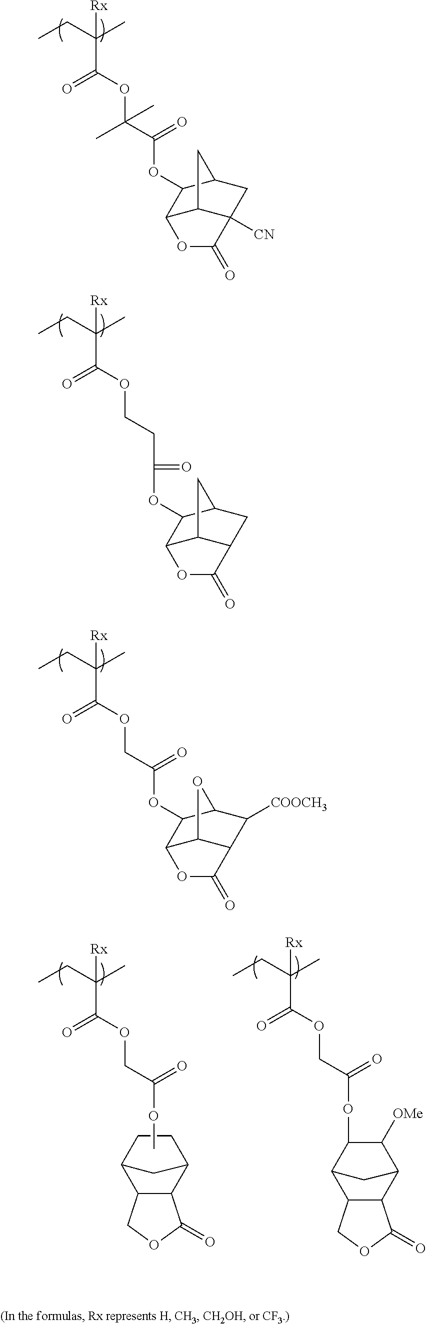

In order to increase the effects of the present invention, it is also possible to use two or more types of repeating units which have a lactone structure or a sultone structure.

In a case where the resin (A) contains a repeating unit which has a lactone structure or a sultone structure, the content of the repeating units which have a lactone structure or a sultone structure is preferably 5 mol % to 60 mol %, more preferably 5 mol % to 55 mol %, and even more preferably 10 mol % to 50 mol % with respect to all of the repeating units in the resin (A).

[Repeating Unit which has a Cyclic Carbonic Ester Structure]

In addition, the resin (A) may have a repeating unit which has a cyclic carbonic ester structure.

The repeating unit which has a cyclic carbonic ester structure is preferably a repeating unit which is represented by General Formula (A-1) below.

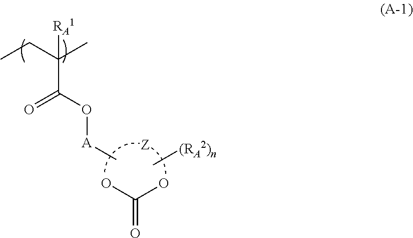

In General Formula (A-1),

R_{A}¹ represents a hydrogen atom or an alkyl group.

R_{A}²'s each independently represent a substituent group in a case where n is 2 or more.

A represents a single bond or a divalent linking group.

Z represents an atomic group which forms a monocyclic or polycyclic structure with a group which is represented by —O—C(═O)—O— in the formula.

n represents an integer of 0 or more.

Detailed description will be given of General Formula (A-1). An alkyl group which is represented by R_{A}¹ may have a substituent group such as a fluorine atom. R_{A}¹ preferably represents a hydrogen atom, a methyl group, or a trifluoromethyl group, and more preferably represents a methyl group.

A substituent group which is represented by R_{A}² is, for example, an alkyl group, a cycloalkyl group, a hydroxyl group, an alkoxy group, an amino group, and an alkoxycarbonylamino group. An alkyl group with 1 to 5 carbon atoms is preferable, and examples thereof include a straight-chain alkyl group with 1 to 5 carbon atoms, a branched alkyl group with 3 to 5 carbon atoms, and the like. The alkyl group may have a substituent group such as a hydroxyl group.

n is an integer of 0 or more which represents the number of substituent groups. n is, for example, preferably 0 to 4 and more preferably 0.

Examples of a divalent linking group which is represented by A include an alkylene group, a cycloalkylene group, an ester bond, an amide bond, an ether bond, a urethane bond, a urea bond, or the combination thereof, and the like. The alkylene group is preferably an alkylene group with 1 to 10 carbon atoms, and more preferably an alkylene group with 1 to 5 carbon atoms.

In one aspect of the present invention, A is preferably a single bond or an alkylene group.

Examples of a monocycle which is represented by Z and which includes —O—C(═O)—O include a 5-membered to 7-membered ring where n_{A}=2 to 4 in a cyclic carbonic ester which is represented by General Formula (a) below and a 5-membered ring or a 6-membered ring (n_{A}=2 or 3) is preferable, and a 5-membered ring (n_{A}=2) is more preferable.

Examples of a polycycle which is represented by Z and which includes —O—C(═O)—O— include a structure where a cyclic carbonic ester which is represented by General Formula (a) below forms a condensed ring with one or two or more of other ring structures, or a structure which forms a spiro ring. The “other ring structures” which may form a condensed ring or a spiro ring may be an alicyclic hydrocarbon group, may be an aromatic hydrocarbon group, or may be a hetero ring.

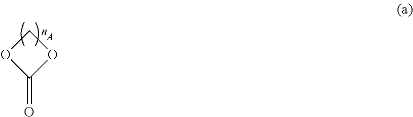

One type out of repeating units which are represented by General Formula (A-1) may be included individually in the resin (A) or two or more types may be included.

In the resin (A), the content ratio of the repeating units which have a cyclic carbonic ester structure (preferably repeating units which are represented by General Formula (A-1)) is preferably 3 mol % to 80 mol %, more preferably 3 mol % to 60 mol %, and particularly preferably 10 mol % to 50 mol % with respect to all of the repeating units which form the resin (A). By setting the content ratio as above, it is possible to improve the developing characteristics as a resist, lower defects, lower LWR, lower PEB temperature dependency, improve the profile, and the like.

Specific examples of repeating units which are represented by General Formula (A-1) will be given below; however, the present invention is not limited thereto.

Here, R_{A}¹ in the specific examples below has the same meaning as R_{A}¹ in General Formula (A-1).

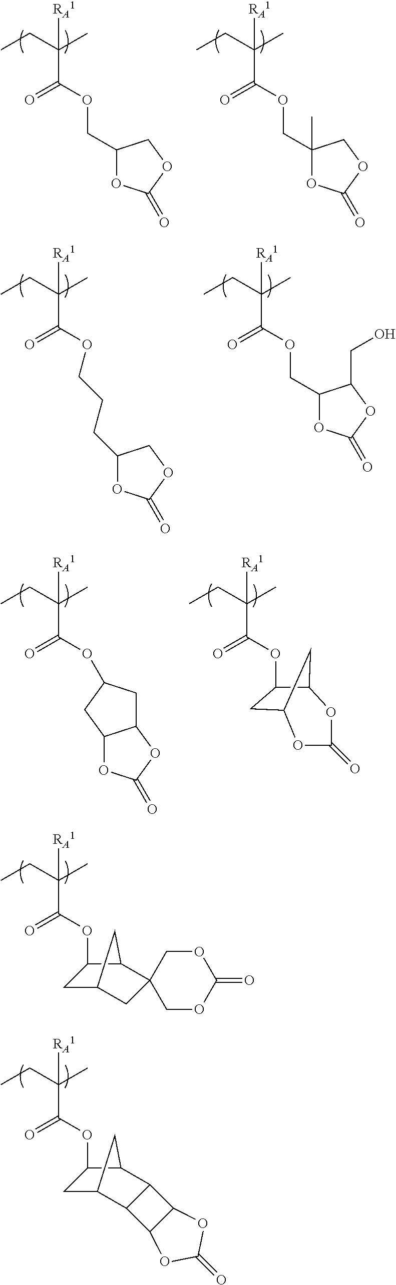

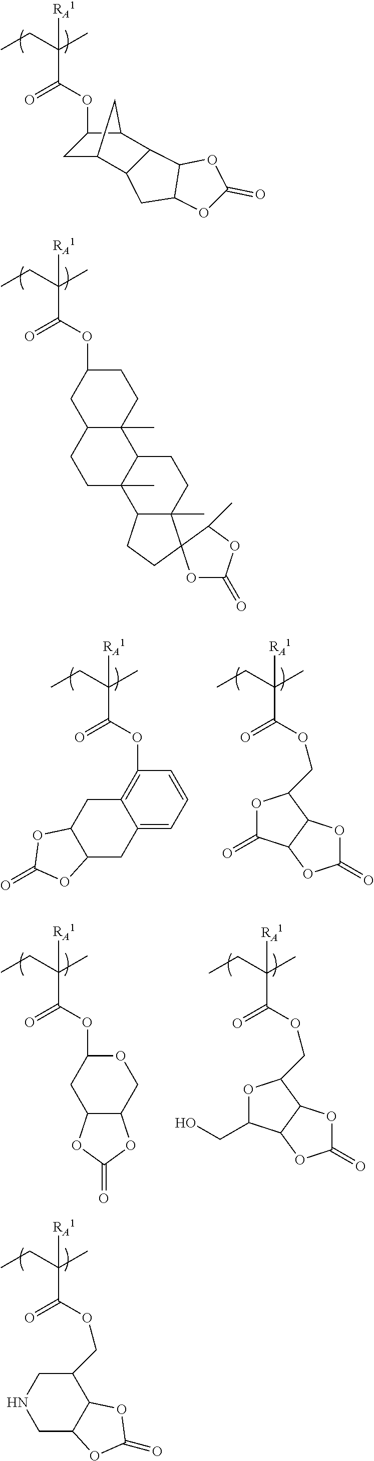

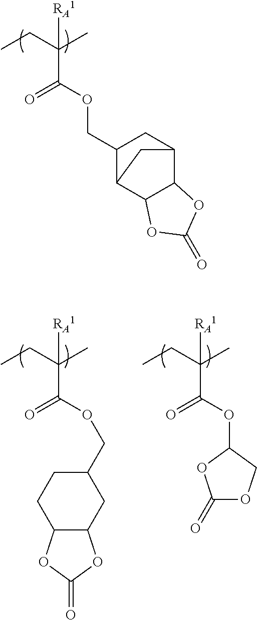

[Repeating Unit which has a Hydroxyl Group, a Cyano Group, or a Carbonyl Group]

The resin (A) may have a repeating unit which has a hydroxyl group, a cyano group, or a carbonyl group. Due to this, the substrate adhesion and developer compatibility are improved.

The repeating unit which has a hydroxyl group, a cyano group, or a carbonyl group is preferably a repeating unit which has an alicyclic hydrocarbon structure which is substituted with a hydroxyl group, a cyano group, or a carbonyl group, and preferably does not have an acid-decomposable group.

In addition, the repeating unit which has an alicyclic hydrocarbon structure which is substituted with a hydroxyl group, a cyano group, or a carbonyl group is preferably different from a repeating unit which has an acid-decomposable group (that is, preferably a repeating unit which is stable with respect to an acid).

An alicyclic hydrocarbon structure in the alicyclic hydrocarbon structure which is substituted with a hydroxyl group, a cyano group, or a carbonyl group is preferably an adamantyl group, diadamantyl group, and a norbornane group.

More preferable examples thereof include a repeating unit which is represented by any of General Formulas (AIIa) to (AIIe) below.

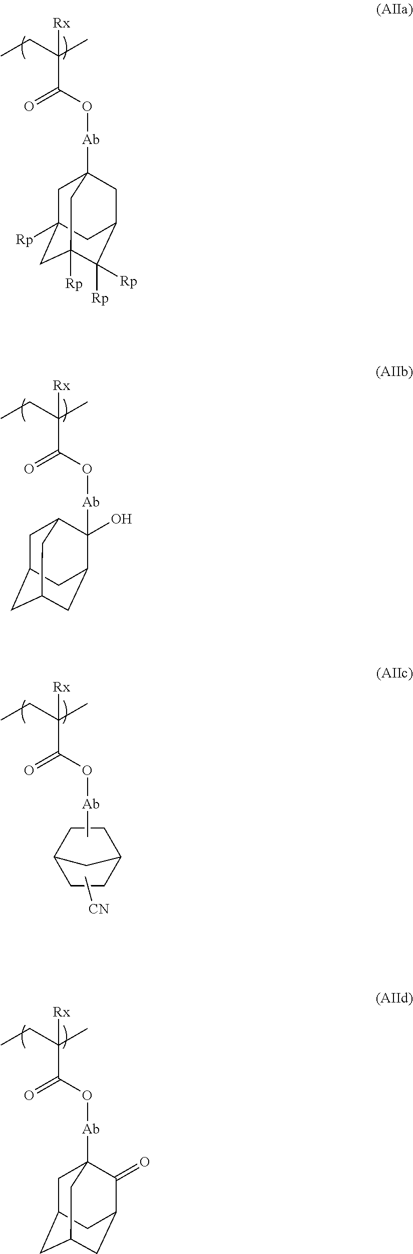

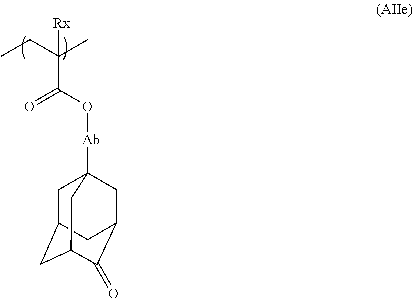

In the formula, Rx represents a hydrogen atom, a methyl group, a hydroxymethyl group, or a trifluoromethyl group.

Ab represents a single bond or a divalent linking group.

Examples of the divalent linking group which is represented by Ab include an alkylene group, a cycloalkylene group, an ester bond, an amide bond, an ether bond, a urethane bond, a urea bond, or the combination thereof, and the like. The alkylene group is preferably an alkylene group with 1 to 10 carbon atoms and more preferably an alkylene group with 1 to 5 carbon atoms and examples thereof include a methylene group, an ethylene group, a propylene group, and the like.

In one form of the present invention, Ab is preferably a single bond or an alkylene group.

Rp represents a hydrogen atom, a hydroxyl group, or a hydroxyalkyl group. A plurality of Rp's may be the same as or different from each other, however, at least one out of the plurality of Rp's represents a hydroxyl group or a hydroxyalkyl group.

The resin (A) may or may not contain a repeating unit which has a hydroxyl group, a cyano group, or a carbonyl group; however, in a case where the resin (A) contains a repeating unit which has a hydroxyl group, a cyano group, or a carbonyl group, the content ratio of the repeating units which have a hydroxyl group, a cyano group, or a carbonyl group is preferably 1 mol % to 40 mol %, more preferably 3 mol % to 30 mol %, and even more preferably 5 mol % to 25 mol % with respect to all of the repeating units of the resin (A).

Specific examples of a repeating unit which has a hydroxyl group, a cyano group, or a carbonyl group will be given below; however, the present invention is not limited thereto.

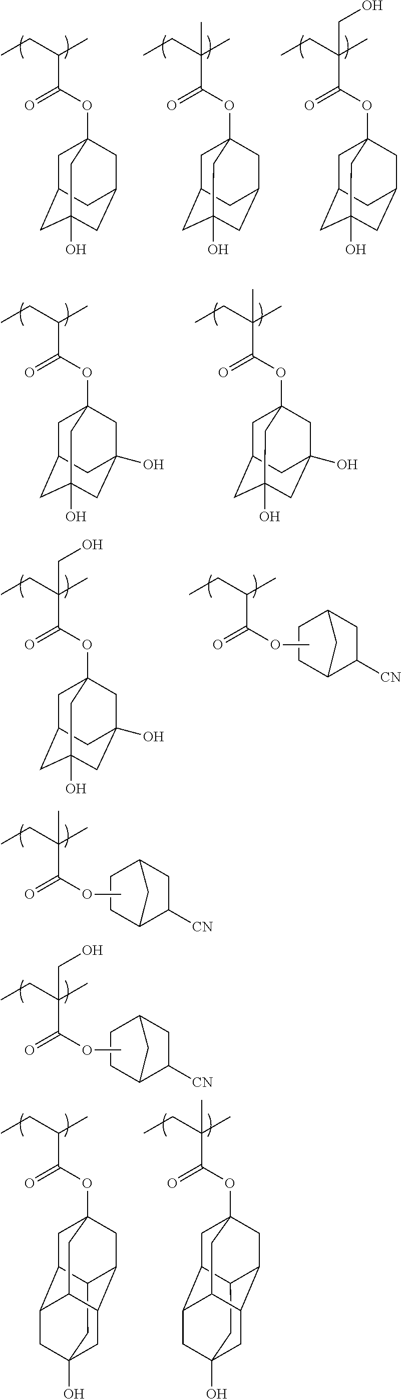

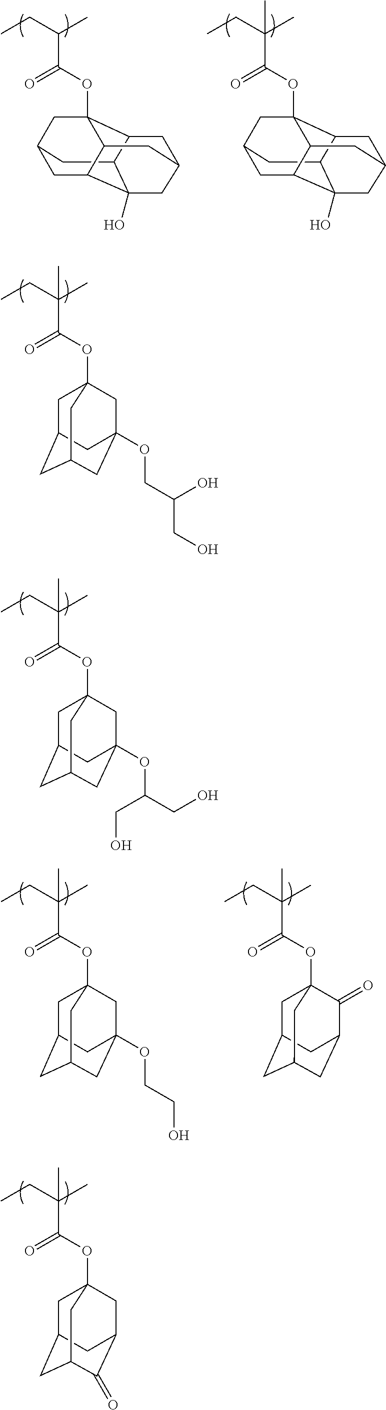

Other than the above, it is also possible to appropriately use the monomers described in “0011” and after in WO2011/122336A or repeating units or the like which correspond thereto.

[Repeating Unit which has an Acid Group]

The resin (A) may have a repeating unit which has an acid group. Examples of the acid group include a carboxyl group, a sulfonamide group, a sulfonyl imide group, a bissulfonyl imide group, a naphthol structure, an aliphatic alcohol group in which the α-position is substituted with an electron-withdrawing group (for example, a hexafluoroisopropanol group), and it is more preferable to have a repeating unit which has a carboxyl group. The developing characteristics are improved in contact hole applications as a result of containing a repeating unit which has an acid group. The repeating unit which has an acid group is preferably any of a repeating unit in which an acid group is directly bonded with the main chain of a resin such as a repeating unit using acrylic acid or methacrylic acid, or a repeating unit in which an acid group is bonded with the main chain of a resin via a linking group, and using a polymerization initiator or a chain transfer agent which has an acid group during the polymerization and introducing the polymerization initiator or the chain transfer agent to the end of a polymer chain, and the linking group may have a monocyclic or polycyclic cyclic hydrocarbon structure. A repeating unit using acrylic acid or methacrylic acid is particularly preferable.

The resin (A) may or may not contain a repeating unit which has an acid group; however, in a case of being contained, the content of the repeating units which have an acid group is preferably 25 mol % or less with respect to all of the repeating units in the resin (A), and more preferably 20 mol % or less. In a case where the resin (A) contains repeating units which have an acid group, the content of the repeating units which have an acid group in the resin (A) is normally 1 mol % or more.

Specific examples of the repeating unit which has an acid group will be given below; however, the present invention is not limited thereto.

In the specific examples, Rx represents H, CH₃, CH₂OH, or CF₃.

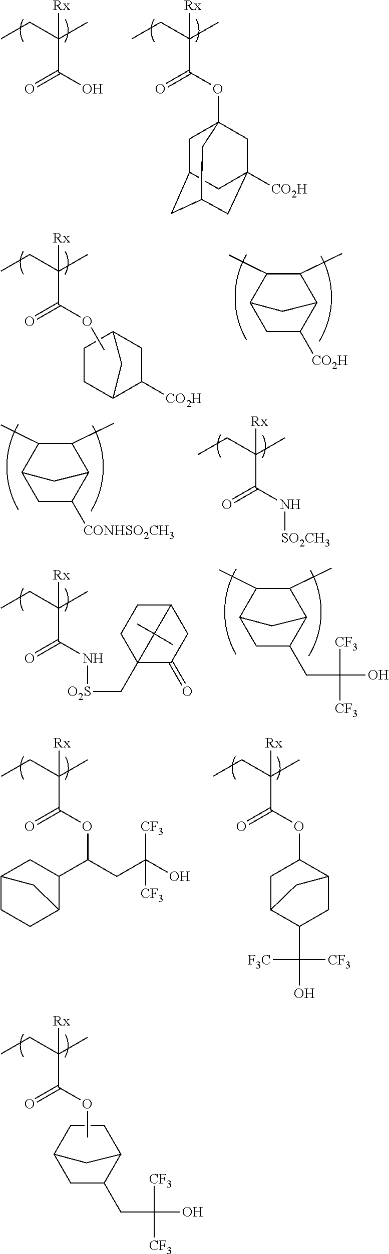

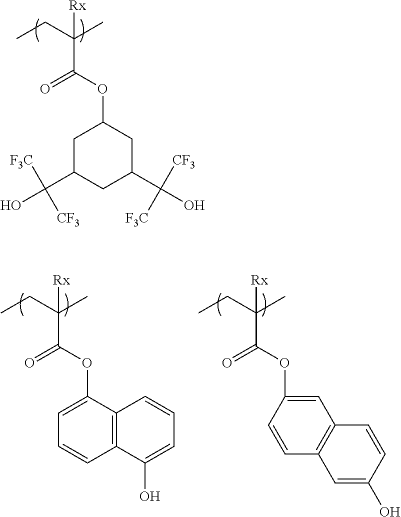

[Repeating Unit which has an Alicyclic Hydrocarbon Structure which does not have a Polar Group and which does not Exhibit Acid Decomposability]

The resin (A) in the present invention is able to further have a repeating unit which has an alicyclic hydrocarbon structure which does not have a polar group (for example, the acid group, the hydroxyl group, or the cyano group) and which does not exhibit acid decomposability. Due to this, it is possible to appropriately adjust the solubility of the resin during development in which a developer which includes an organic solvent is used in addition to it being possible to reduce the elution of low molecular components from a resist film to an immersion liquid during liquid immersion exposure. Examples of the repeating unit include the repeating unit which is represented by General Formula (IV).

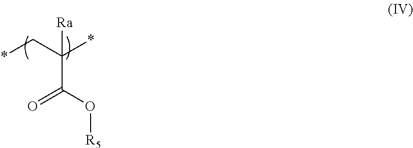

In General Formula (V), R₅ represents a hydrocarbon group which has at least one cyclic structure and which does not have a polar group.

Ra represents a hydrogen atom, an alkyl group, or a —CH₂—O—Ra₂ group. In the formula, Ra₂ represents a hydrogen atom, an alkyl group, or an acyl group. Ra is preferably a hydrogen atom, a methyl group, a hydroxymethyl group, and a trifluoromethyl group, and particularly preferably a hydrogen atom and a methyl group.

A monocyclic hydrocarbon group and a polycyclic hydrocarbon group are included in the cyclic structure of R₅. Examples of the monocyclic hydrocarbon group include cycloalkyl groups with 3 to 12 carbon atoms such as a cyclopentyl group, a cyclohexyl group, a cycloheptyl group, and a cyclooctyl group, and cycloalkenyl groups with 3 to 12 carbon atoms such as a cyclohexenyl group. A preferable monocyclic hydrocarbon group is a monocyclic hydrocarbon group with 3 to 7 carbon atoms and more preferable examples thereof include a cyclopentyl group and a cyclohexyl group.

A ring-aggregated hydrocarbon group and a cross-linked cyclic hydrocarbon group are included in the polycyclic hydrocarbon group and examples of the ring-aggregated hydrocarbon group include a bicyclohexyl group, a perhydronaphthalenyl group, and the like. Examples of a cross-linked cyclic hydrocarbon ring include a 2-cyclic hydrocarbon ring such as pinane, bornane, norpinane, norbornane, or a bicyclooctane ring (a bicyclo[2.2.2]octane ring, a bicyclo[3.2.1]octane ring, and the like), a 3-cyclic hydrocarbon ring such as homobredane, adamantane, tricyclo[5.2.1.0^{2,6}]decane, or a tricyclo[4.3.1.1^{2,5}]undecane ring, and a 4-cyclic hydrocarbon ring such as tetracyclo[4.4.0.1^{2,5}.1^{7,10}]dodecane and a perhydro-1,4-methano-5,8-methanonaphthalene ring, and the like. In addition, a condensed cyclic hydrocarbon ring, for example, a condensed ring where a plurality of 5-membered to 8-membered cycloalkane rings are condensed such as perhydronaphthalene (decaline), perhydroanthracene, perhydrophenanthrene, perhydroacenaphthene, perhydrofuluorene, perhydroindene, and perhydrophenalene rings are also included in the cross-linked cyclic hydrocarbon group.

Examples of a preferable cross-linked cyclic hydrocarbon group include a norbornyl group, an adamantyl group, a bicyclooctanyl group, a tricyclo[5,2,1,0^{2,6}]decanyl group, and the like. Examples of a more preferable cross-linked cyclic hydrocarbon group include a norbornyl group and an adamantyl group.

The alicyclic hydrocarbon groups may have a substituent group and examples of a preferable substituent group include a halogen atom, an alkyl group, a hydroxyl group in which a hydrogen atom is substituted, an amino group in which a hydrogen atom is substituted, and the like.

The resin (A) may or may not contain a repeating unit which has an alicyclic hydrocarbon structure which does not have a polar group and which does not exhibit acid decomposability; however, in a case of being contained, the content of the repeating units is preferably 1 mol % to 50 mol % and more preferably 5 mol % to 50 mol % with respect to all of the repeating units in the resin (A).

Specific examples of a repeating unit which has an alicyclic hydrocarbon structure which does not have a polar group and which does not indicate acid decomposability will be given below; however, the present invention is not limited thereto. In the formulas, Ra represents H, CH₃, CH₂OH, or CF₃.

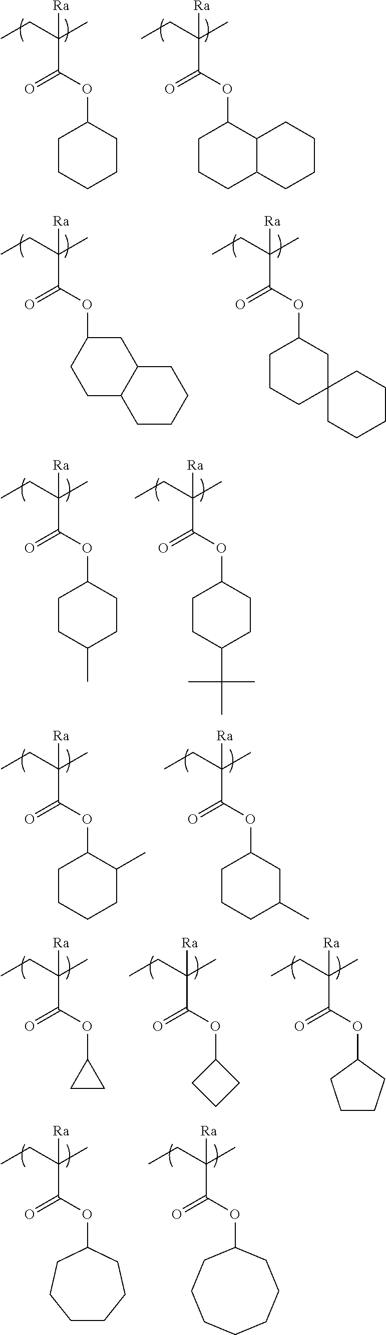

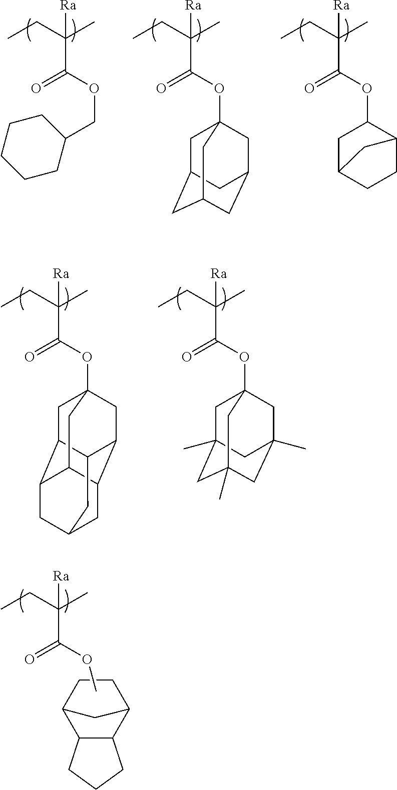

[Repeating Unit which has an Aromatic Ring]

In a case of irradiating the composition of the present invention with KrF excimer laser light, electron beams, X-rays, and high energy rays (EUV and the like) with a wavelength of 50 nm or less, the resin (A) may have a repeating unit which has an aromatic ring. The repeating unit which has an aromatic ring is not particularly limited and, moreover, although examples are given in the description regarding each of the repeating units described above, examples thereof include a styrene unit, a hydroxystyrene unit, a phenyl(meth)acrylate unit, a hydroxyphenyl(meth)acrylate unit, a benzyl(meth)acrylate unit, and the like. In more detail, examples of the resin (A) include a resin which has a repeating unit, which has a phenolic hydroxyl group, and a hydroxystyrene-based repeating unit which is protected by an acid-decomposable group, a resin which has a repeating unit which has the aromatic ring described above and a repeating unit in which a carbonic acid site of (meth)acrylic acid is protected by an acid-decomposable group, and the like.

In a case where the resin (A) has a repeating unit which has an aromatic ring, the copolymerization unit is not particularly limited and it is possible to appropriately select various types of the repeating units described above (for example, lactone-containing repeating units) and also other repeating units known in the art. For example, regarding a repeating unit which has an acid-decomposable group, as well as the repeating unit which has an acid-decomposable group described above, it is possible to apply a repeating unit which has a structure which protects a phenolic hydroxyl group using an acid-decomposable group such as acetal as described in paragraphs “0086” to paragraph “0107” in JP2013-160947A (this document is incorporated the present specification), an acid-decomposable repeating unit which has an aralkyl site as described in paragraphs “0108” to “0136” in the same document, a repeating unit which has a structure where an alcoholic hydroxyl group is protected by an acid-decomposable group as described in paragraphs “0127” to paragraph “0147” in the same document, and the like.

In one aspect, the resin (A) may be an aspect where a structure which corresponds to an acid generating agent which will be described below is supported. Specific examples of this aspect include the structures described in JP2011-248019A (in particular, the structures described in paragraphs “0164” to “0191” and the structures which are included in the resins described in the examples in paragraph “0555”), the repeating units (R) described in paragraph “0023” to “0210” in JP2013-80002A, and the like and the contents thereof are included in the present specification. Even in the aspect where the resin (A) supports the structure which corresponds to an acid generating agent, the composition of the present invention may further include an acid generating agent (that is, a compound (B) which will be described below) which is not supported by the resin (A).

Examples of the repeating unit which has a structure which corresponds to an acid generating agent include the repeating units below; however, the present invention is not limited thereto.

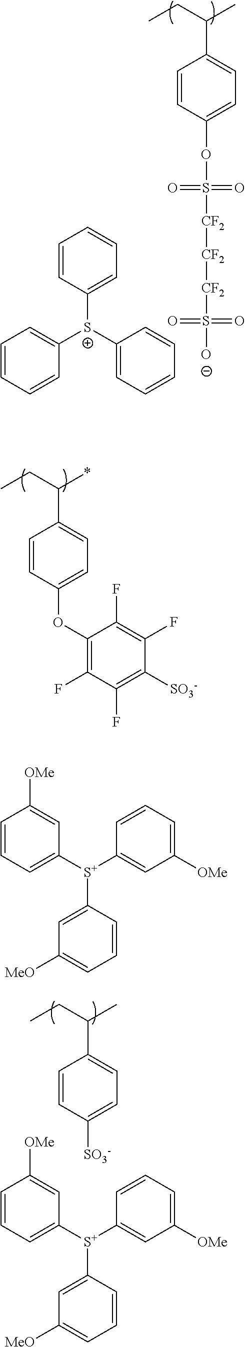

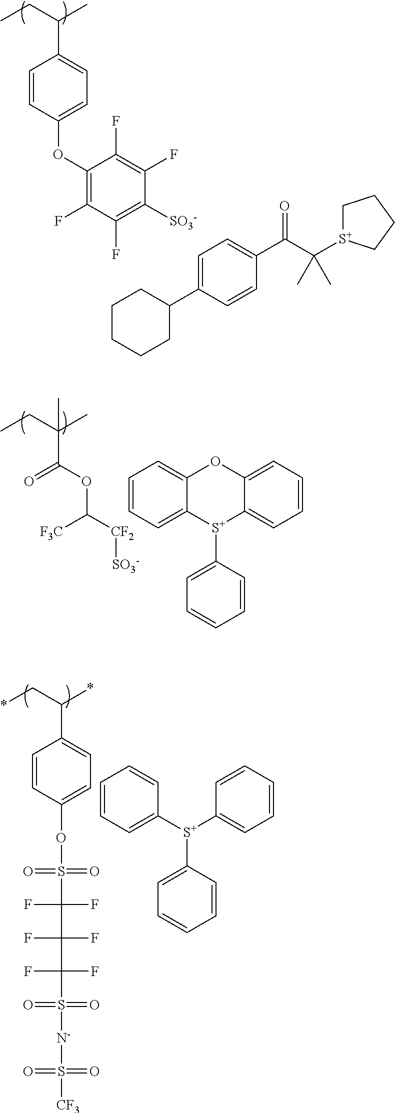

The resin (A) which is used for the composition of the present invention is able to have various types of repeating structure units other than the repeating structure units described above for the purpose of adjusting the dry etching resistance or standard developer aptitude, the substrate adhesion, the resist profile, and moreover, resolving power, heat resistance, sensitivity, and the like which are typical necessary characteristics for the actinic ray-sensitive or radiation-sensitive resin composition.

Examples of the repeating structure units include the repeating structure units which are equivalent to the monomers below; however, the present invention is not limited thereto.

Due to this, it is possible to carry out fine adjustment of the performances which are demanded for a resin which is used for the composition of the present invention, in particular,

(1) solubility with respect to a coating solvent,
(2) film-forming property (glass transition point),
(3) alkali developing characteristics,
(4) film thinning (selecting hydrophilic-hydrophobic and alkali-soluble groups),
(5) adhesion of an unexposed section to a substrate,
(6) dry etching resistance, and the like.

Examples of the monomer include a compound and the like which have one addition polymerizable unsaturated bond which is selected from, for example, acrylic acid esters, methacrylic acid esters, acrylamides, methacrylamides, allyl compounds, vinyl ethers, vinyl esters, and the like.

Apart from the above, copolymerization may be carried out with an addition polymerizable unsaturated compound which is able to be copolymerized with monomers which are equivalent to the various types of repeating structure units described above.

In the resin (A) which is used for the composition of the present invention, the content molar ratio of each of the repeating structure units is appropriately set in order to adjust the dry etching resistance or standard developer aptitude of the actinic ray-sensitive or radiation-sensitive resin composition, the substrate adhesion, the resist profile, and, moreover, the resolving power, the heat resistance, the sensitivity, and the like which are typical necessary characteristics for the actinic ray-sensitive or radiation-sensitive resin composition.

When the composition of the present invention is used for ArF exposure, in terms of the transparency to ArF light, the resin (A) which is used for the composition of the present invention preferably substantially does not have an aromatic ring (in detail, in the resin, the ratio of the repeating units which have an aromatic group is preferably 5 mol % or less, more preferably 3 mol % or less, and ideally 0 mol %, that is, the resin does not have an aromatic group) and the resin (A) preferably has a monocyclic or polycyclic alicyclic hydrocarbon structure.

The form of the resin (A) in the present invention may take any form of a random shape, a block shape, a comb shape, or a star shape. It is possible to synthesize the resin (A), for example, by radical, cation, or anion polymerization of the unsaturated monomers which correspond to each structure. In addition, it is also possible to obtain a desired resin by performing a polymer reaction after carrying out polymerization using unsaturated monomers which are equivalent to the precursor bodies of each structure.

In a case where the composition of the present invention includes a hydrophobic resin (HR) which will be described below, from the point of view of the compatibility with the hydrophobic resin (HR), the resin (A) preferably does not contain a fluorine atom and a silicon atom (in detail, in the resin, the ratio of the repeating units which have a fluorine atom or a silicon atom is preferably 5 mol % or less, more preferably 3 mol % or less, and ideally 0 mol %).

The resin (A) which is used for the composition of the present invention preferably has a configuration where all of the repeating units are (meth)acrylate-based repeating units. In this case, it is possible to use any of a resin where all of the repeating units are methacrylate-based repeating units, a resin where all of the repeating units are acrylate-based methacrylate-based repeating units, a resin where all of the repeating units are acrylate-based repeating units, and a resin where all of the repeating units are methacrylate-based repeating units and acrylate-based repeating units; however, acrylate-based repeating units are preferably 50 mol % or less of all of the repeating units.

It is possible to synthesize the resin (A) in the present invention according to a typical method (for example, by a method which is generally used in the field of polymer synthesis such as radical polymerization, living radical polymerization, anion polymerization, and cation polymerization). Examples of general synthesis methods include a collective polymerization method for performing polymerization by dissolving monomers and an initiator in a solvent and heating the result, a dripping polymerization method for adding a solution of monomers and an initiator to a heated solvent by dripping over 1 hour to 10 hours, and the like, and the dripping polymerization method is preferable. Examples of a reaction solvent include ethers such as tetrahydrofuran, 1,4-dioxane, and diisopropylether, ketones such as methyl ethyl ketone and methyl isobutyl ketone, ester solvents such as ethyl acetate, amide solvents such as dimethylformamide and dimethylacetamide, and, moreover, solvents which dissolve the composition of the present invention such as propylene glycol monomethyl ether acetate, propylene glycol monomethyl ether, and cyclohexanone which will be described below. It is more preferable to carry out the polymerization using the same solvent as the solvent which is used for the photosensitive composition of the present invention. Due to this, it is possible to suppress particles from being generated during storage.

The polymerization reaction is preferably carried out in an inert gas atmosphere such as nitrogen or argon. Polymerization is initiated using a commercially available radical initiator (an azo-based initiator, peroxide, and the like) as a polymerization initiator. The radical initiator is preferably an azo-based initiator and preferably an azo-based initiator which has an ester group, a cyano group, and a carboxyl group. Examples of a preferable initiator include azobisisobutyronitrile, azobisdimethylvaleronitrile, dimethyl 2,2′-azobis(2-methylpropionate), and the like. As desired, an initiator is added all at once or added in several parts and, after the reaction ends, the result is introduced into a solvent to collect a desired polymer by a method such as powder or solid collection. The concentration in the reaction liquid is 5 mass % to 50 mass % and preferably 10 mass % to 30 mass %. The reaction temperature is normally 10° C. to 150° C., preferably 30° C. to 120° C., and more preferably 60° C. to 100° C.

After the reaction ends, the result is left to cool and purified. With regard to the purification, it is possible to apply general methods such as a liquid extraction method which removes residual monomers or oligomer components by washing with water or combining appropriate solvents, a purifying method for a dissolved state such as ultrafiltration which only extracts and removes substances with a specific molecular weight or less, a re-precipitation method in which residual monomers and the like are removed by solidifying resins in a weak solvent by dripping a resin solution in the weak solvent, and a purifying method for a solid state such as cleaning a filtered and separated resin slurry using a weak solvent.

For example, the resin is precipitated as a solid matter by being brought into contact with a solvent (a weak solvent) in which the resin described above hardly dissolves or does not dissolve at a volume amount of 10 times or less that of the reaction solution, preferably at a volume amount of 10 times to 5 times.

It is sufficient if the solvent (a precipitation or re-precipitation solvent) which is used during precipitation or re-precipitation operation from a polymer solution is a weak solvent for the polymer and it is possible to use a solvent by appropriately selecting from among hydrocarbons, halogenated hydrocarbons, nitro compounds, ethers, ketones, esters, carbonates, alcohols, carboxylic acids, water, a mixed solvent which includes these solvents, and the like according to the type of the polymer. Among these, a solvent which includes at least alcohol (in particular, methanol and the like) or water is preferable as a precipitation or re-precipitation solvent.

It is possible to select the usage amount of the precipitation or re-precipitation solvent in consideration of the efficiency, yield, and the like; however, the usage amount is generally 100 parts by mass to 10000 parts by mass with respect to 100 parts by mass of a polymer solution, preferably 200 parts by mass to 2000 parts by mass, and even more preferably 300 parts by mass to 1000 parts by mass.

It is possible to appropriately select the temperature during precipitation or re-precipitation in consideration of the efficiency or handleability; however, the temperature is normally approximately 0° C. to 50° C. and preferably approximately room temperature (for example, approximately 20° C. to 35° C.). It is possible to perform the precipitation or re-precipitation operation using methods known in the art such as a batch type method and a continuous type method using a common mixture container such as a stirring tank.

The polymer which is precipitated or re-precipitated is provided for use by applying a typical solid-liquid separation method such as filtration or centrifugal separation and being dried. Filtration is preferably performed under pressure using a filter material with solvent resistance. Drying is performed under normal pressure or reduced pressure (preferably under reduced pressure), at a temperature of approximately 30° C. to 100° C., preferably 30° C. to 50° C.

Here, the resin may be precipitated once, dissolved in the solvent again after being separated, and brought into contact with a solvent in which the resin hardly dissolves or does not dissolve. That is, the method may be a method which includes precipitating a resin through contact with a solvent in which the polymer hardly dissolves or does not dissolve after the radical polymerization reaction described above finishes (step a), separating the resin from the solution (step b), preparing a resin solution A by carrying out dissolving in a solvent again (step c), subsequently precipitating resin solid matter through contact with a solvent in which the resin hardly dissolves or does not dissolve with the resin solution A at a volume amount of less than 10 times that of the resin solution A (preferably at a volume amount of 5 times or less) (step d), and separating the precipitated resin (step e).

In addition, in order to suppress resins from aggregating and the like after the preparation of the composition, for example, as described in JP2009-037108A, a step of making a solution by dissolving the synthesized resins in a solvent and heating the solution at approximately 30° C. to 90° C. for approximately 30 minutes to 4 hours may be added.

It is preferable to reduce the non-reacted low molecular compounds (monomers and oligomers) as much as possible by these purification steps.

The weight average molecular weight of the resin (A) in the present invention is preferably 6000 to 50000 as a polystyrene converted value by a GPC method, more preferably 8000 to 30000, and most preferably 10000 to 25000. By setting the molecular weight to these ranges, it is possible to expect the solubility with respect to an organic-based developer to be an appropriate numeric value.

The resin (A) of which the dispersity (molecular weight distribution) is normally in a range of 1.0 to 3.0, preferably 1.0 to 2.6, more preferably 1.0 to 2.0, and particularly preferably 1.4 to 2.0 is used. A resin (A) with a smaller molecular weight distribution is excellent in terms of the resolution and the resist shape, additionally, the side walls of the resist pattern are smooth and the roughness is excellent.

The content of the resin (A) is preferably 30 mass % to 99 mass % and more preferably 60 mass % to 95 mass % with respect to the entirety of the solid content of the actinic ray-sensitive or radiation-sensitive resin composition of the present invention.

In addition, the resin (A) in the present invention may be used as one type or a plurality thereof may be used together.

Specific examples of the resin (A) will be given below (the composition ratio of the repeating units is the molar ratio); however, the present invention is not limited thereto.

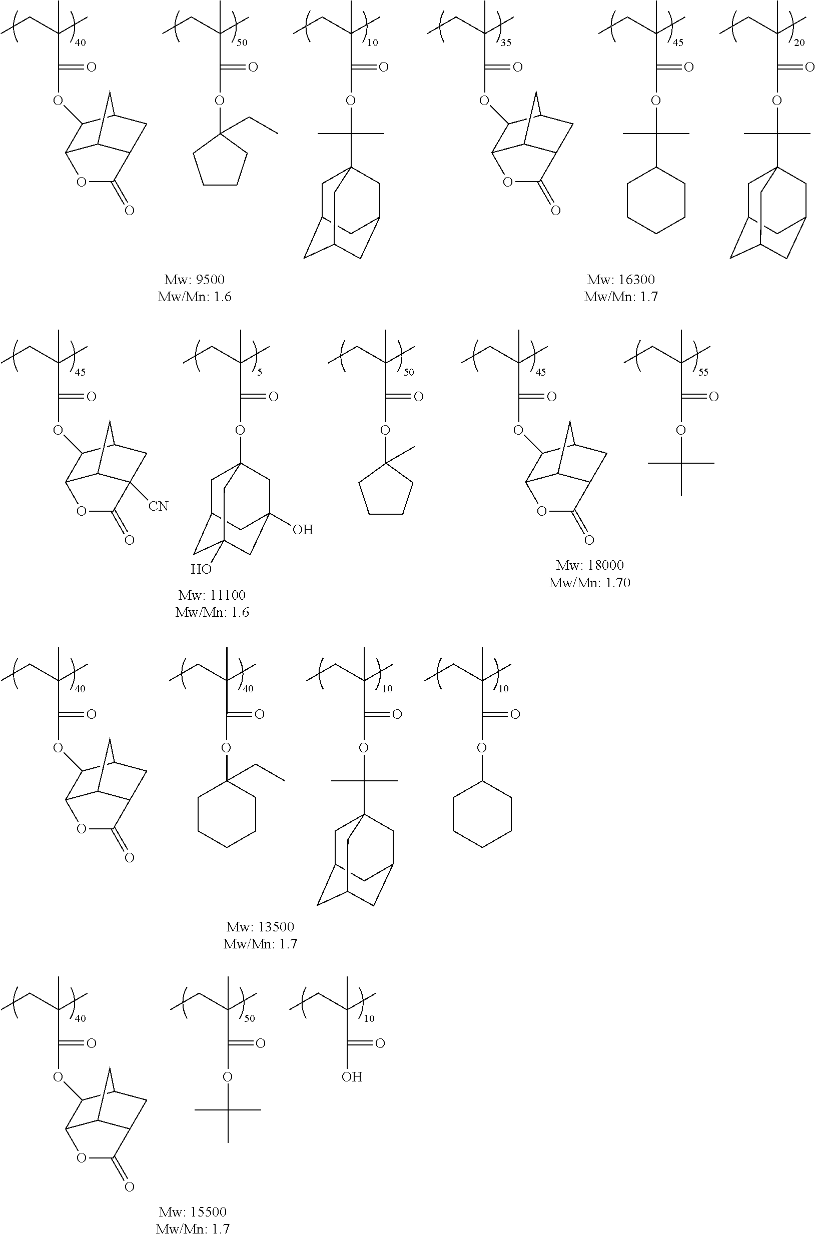

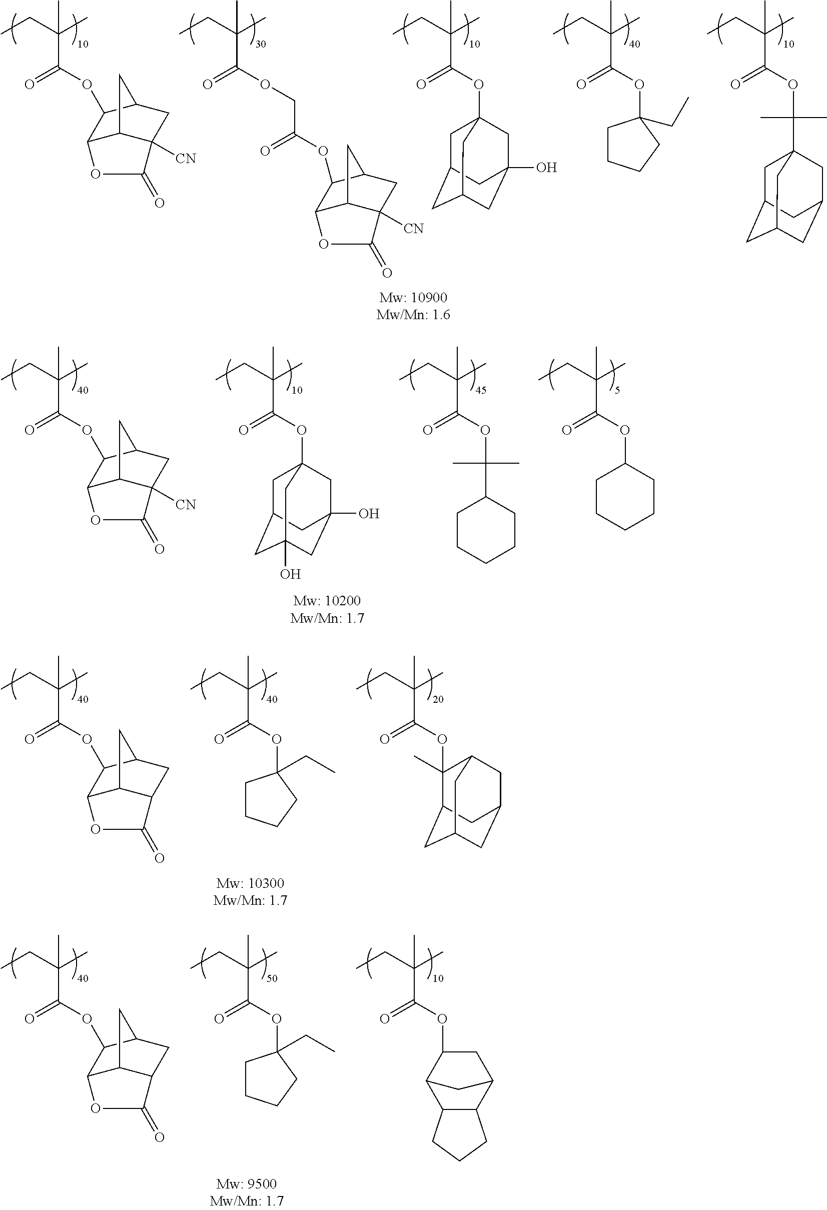

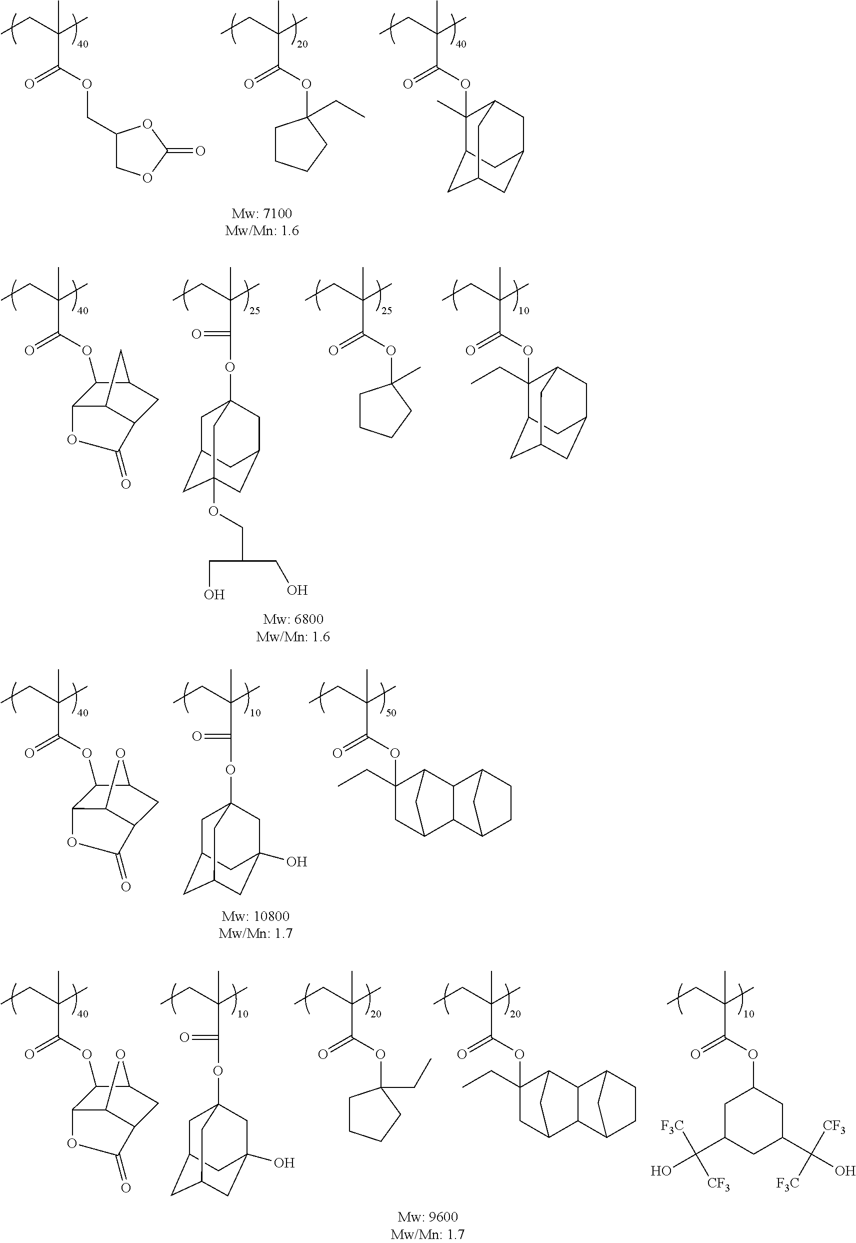

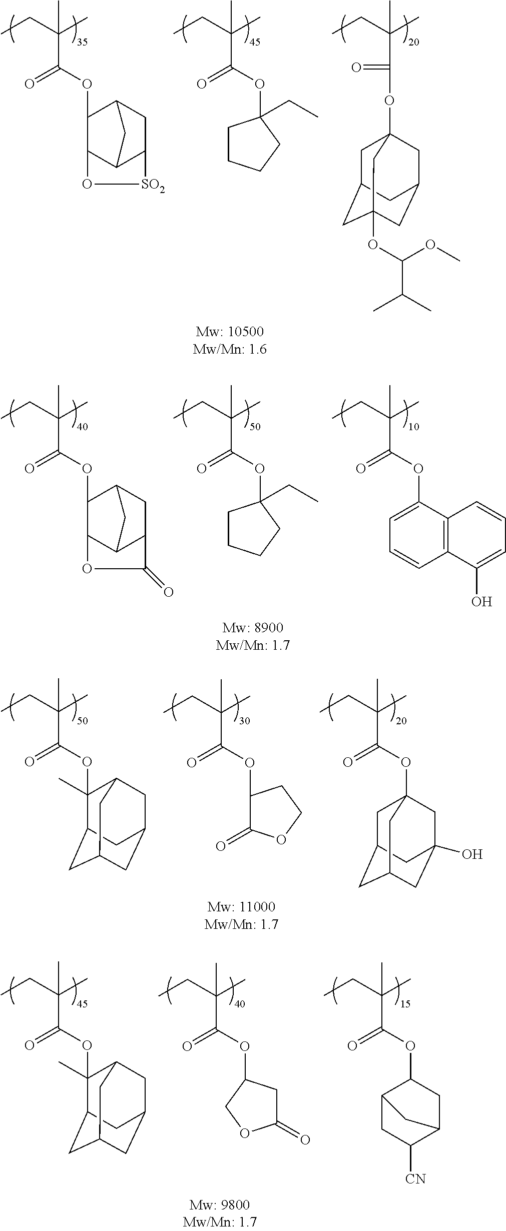

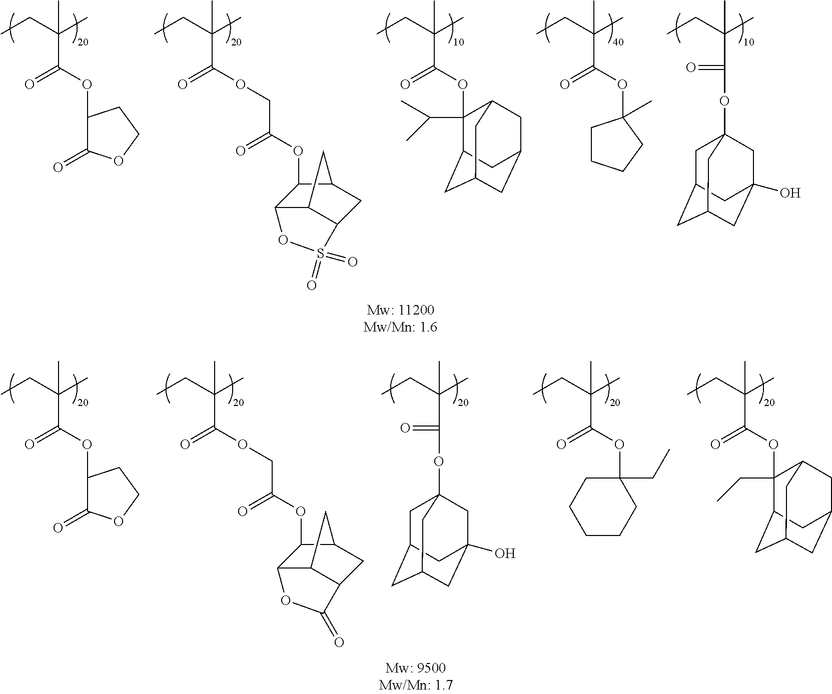

Favorable resins (A) in a case where the exposure is exposure by EUV light or an electron beam will be given below (the composition ratio of the repeating units is the molar ratio).

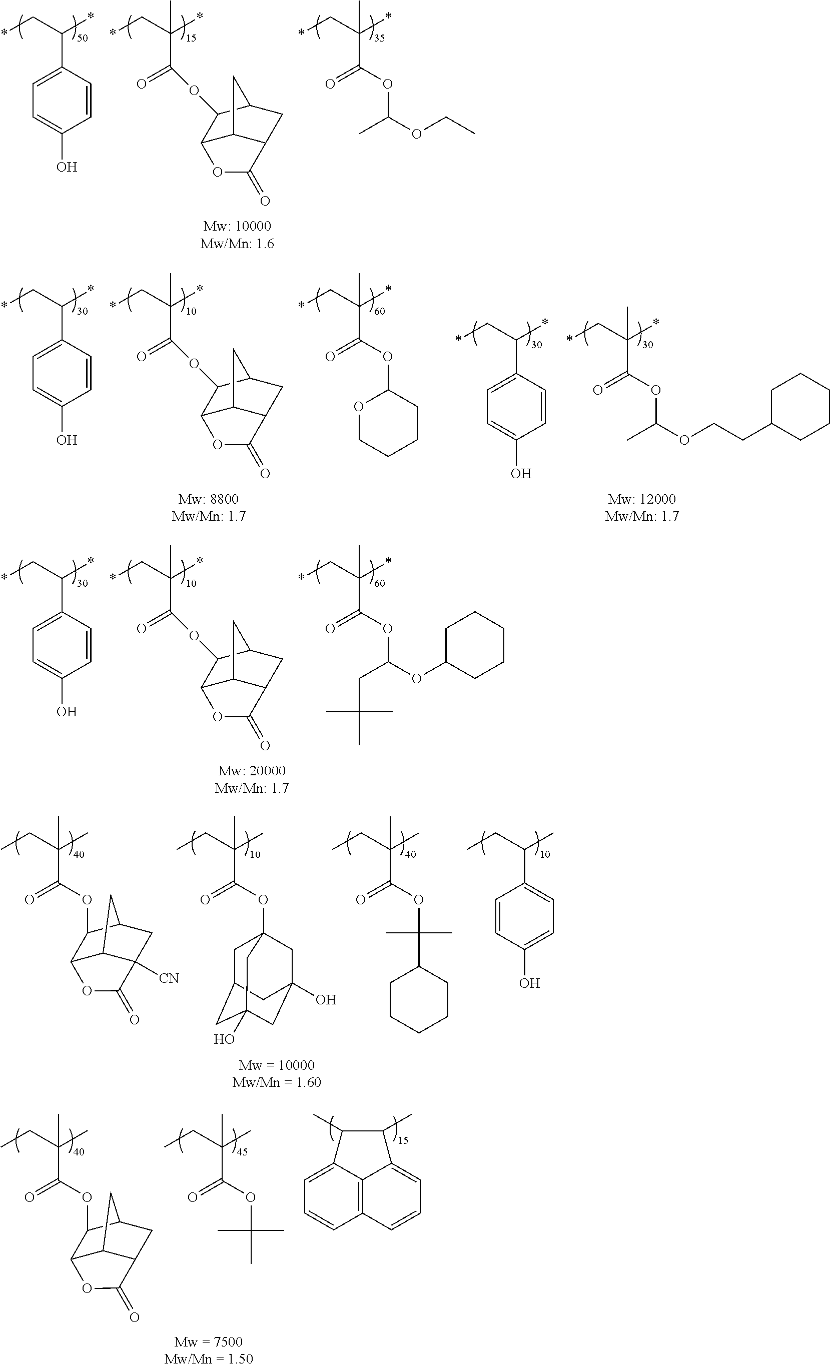

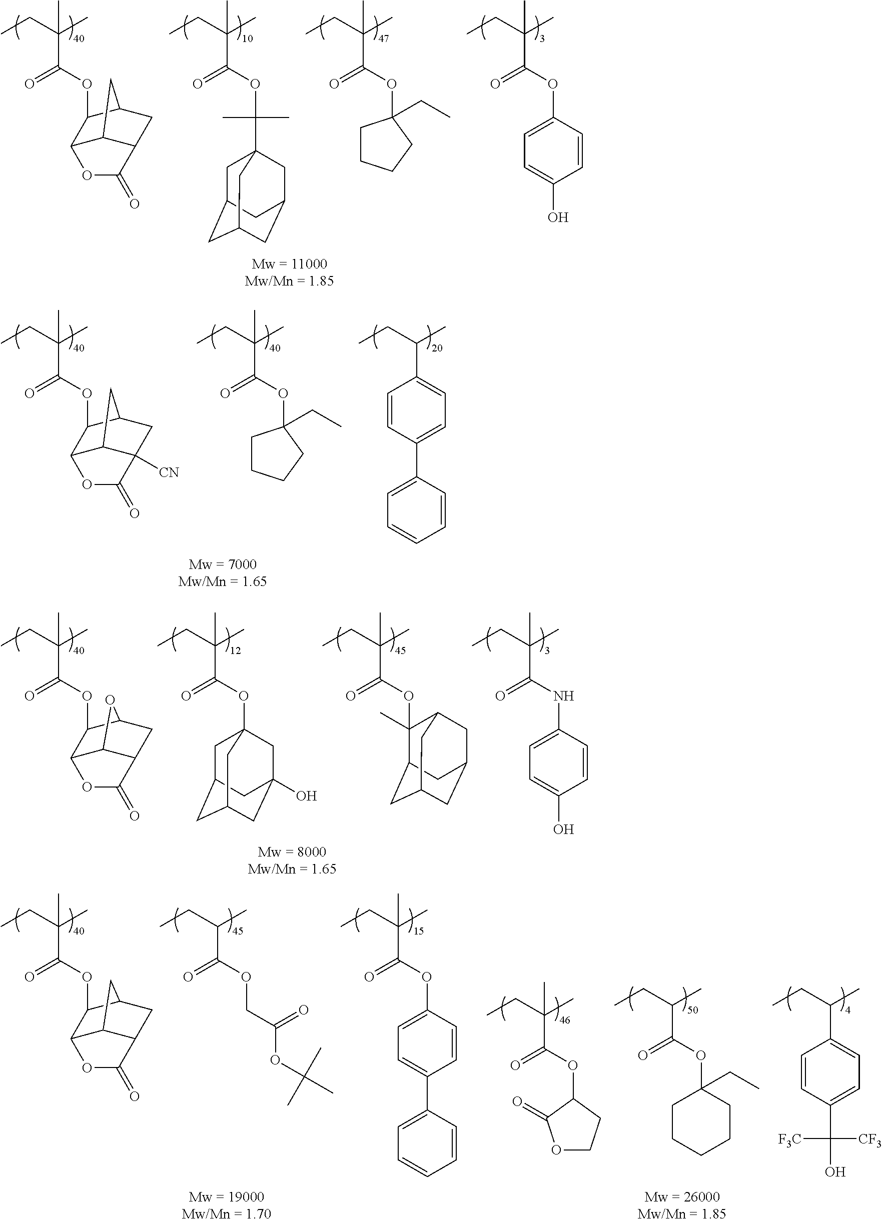

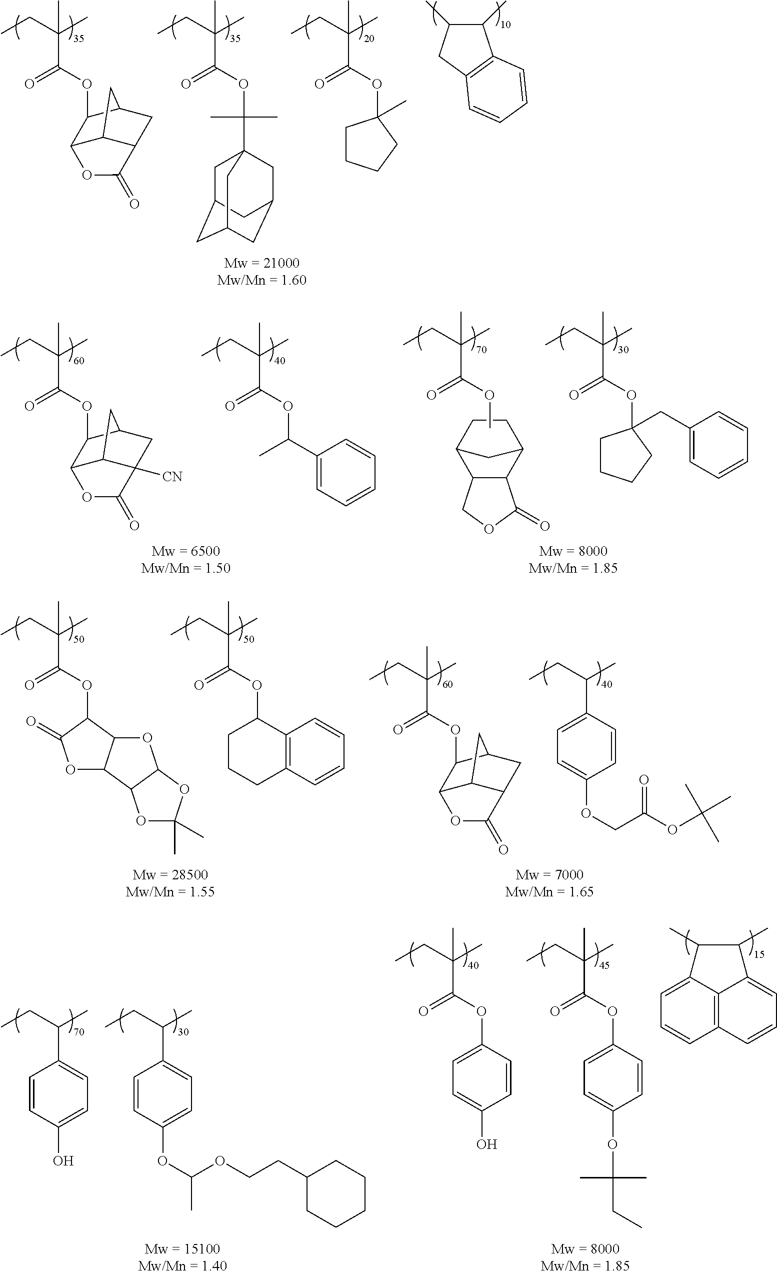

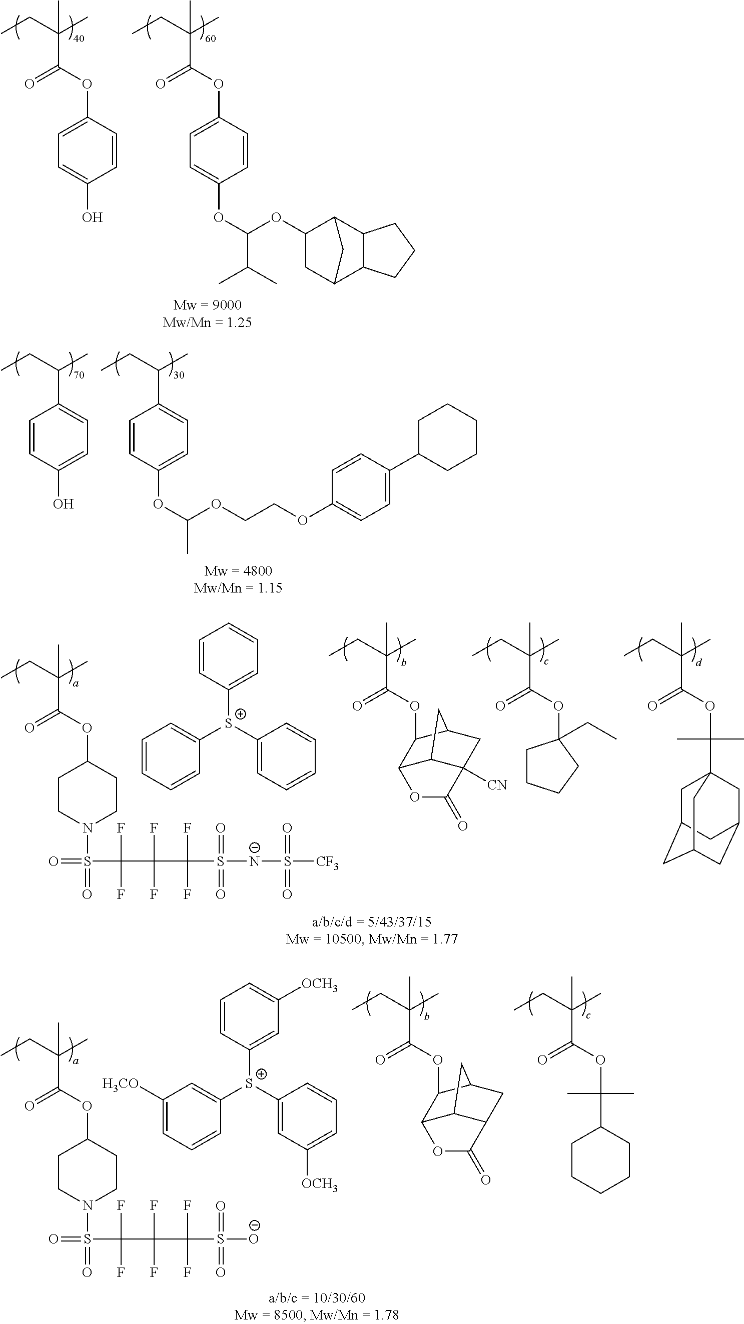

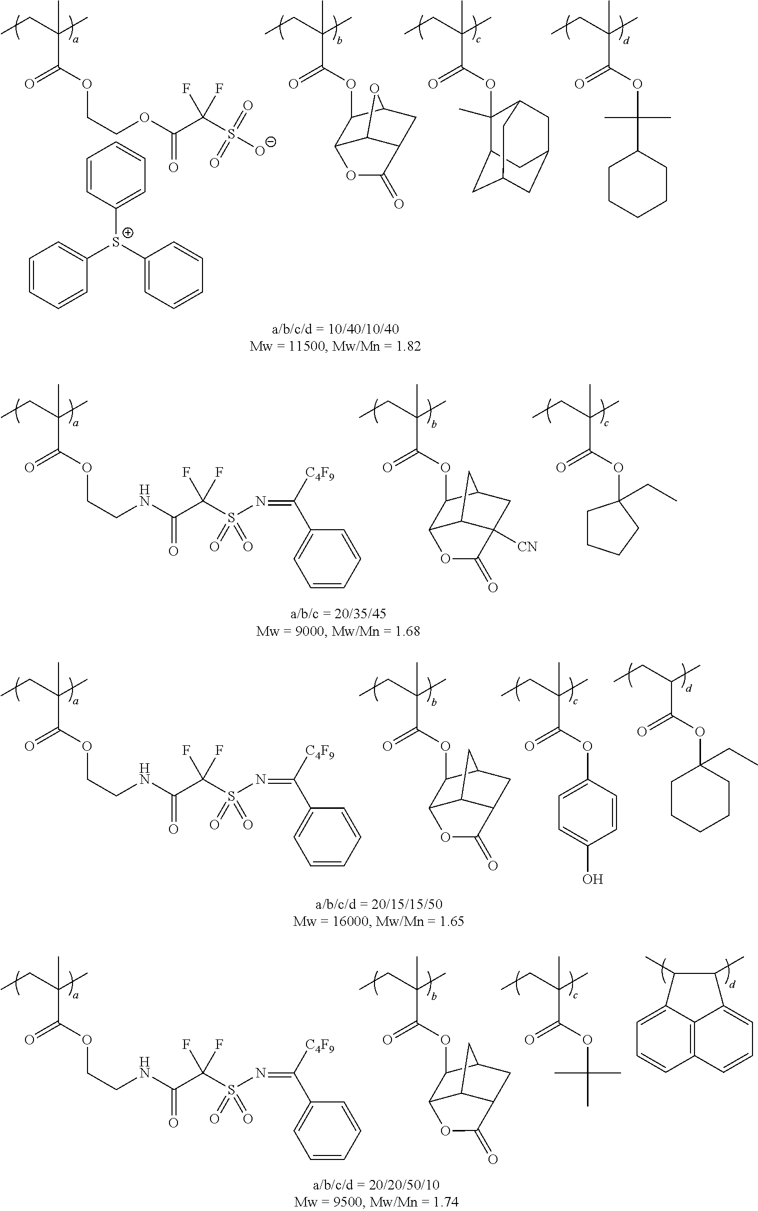

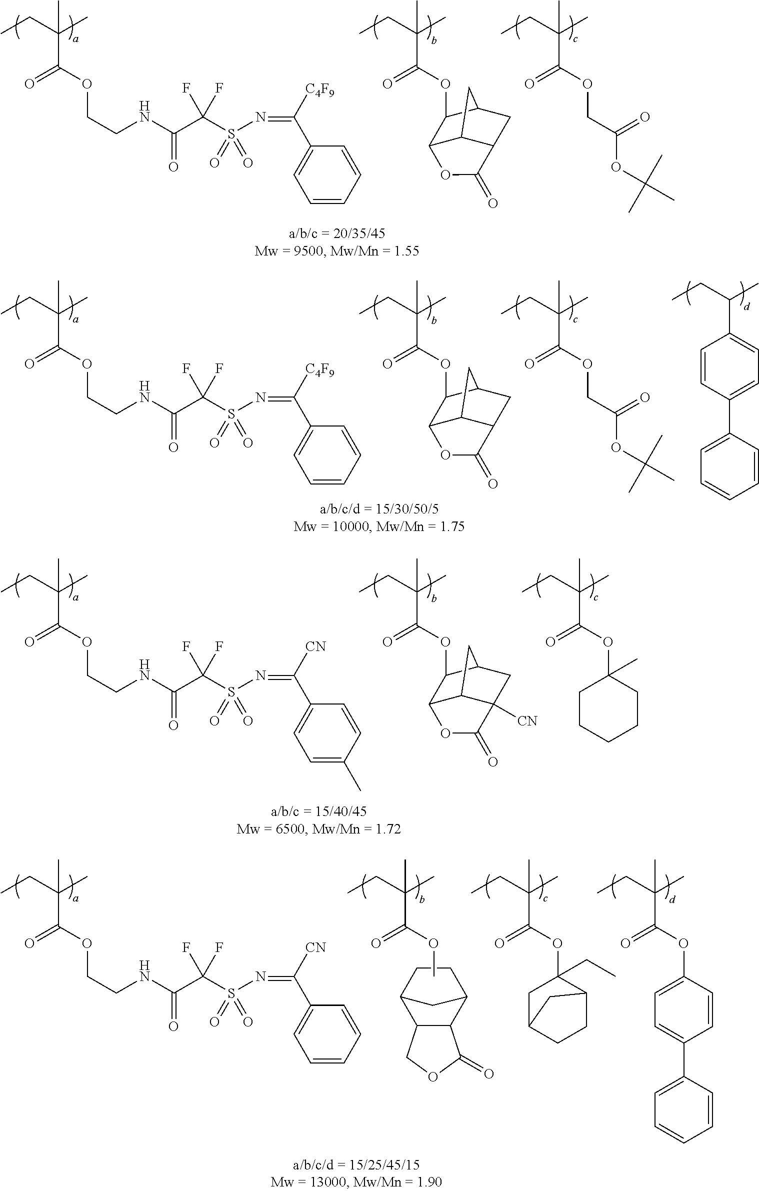

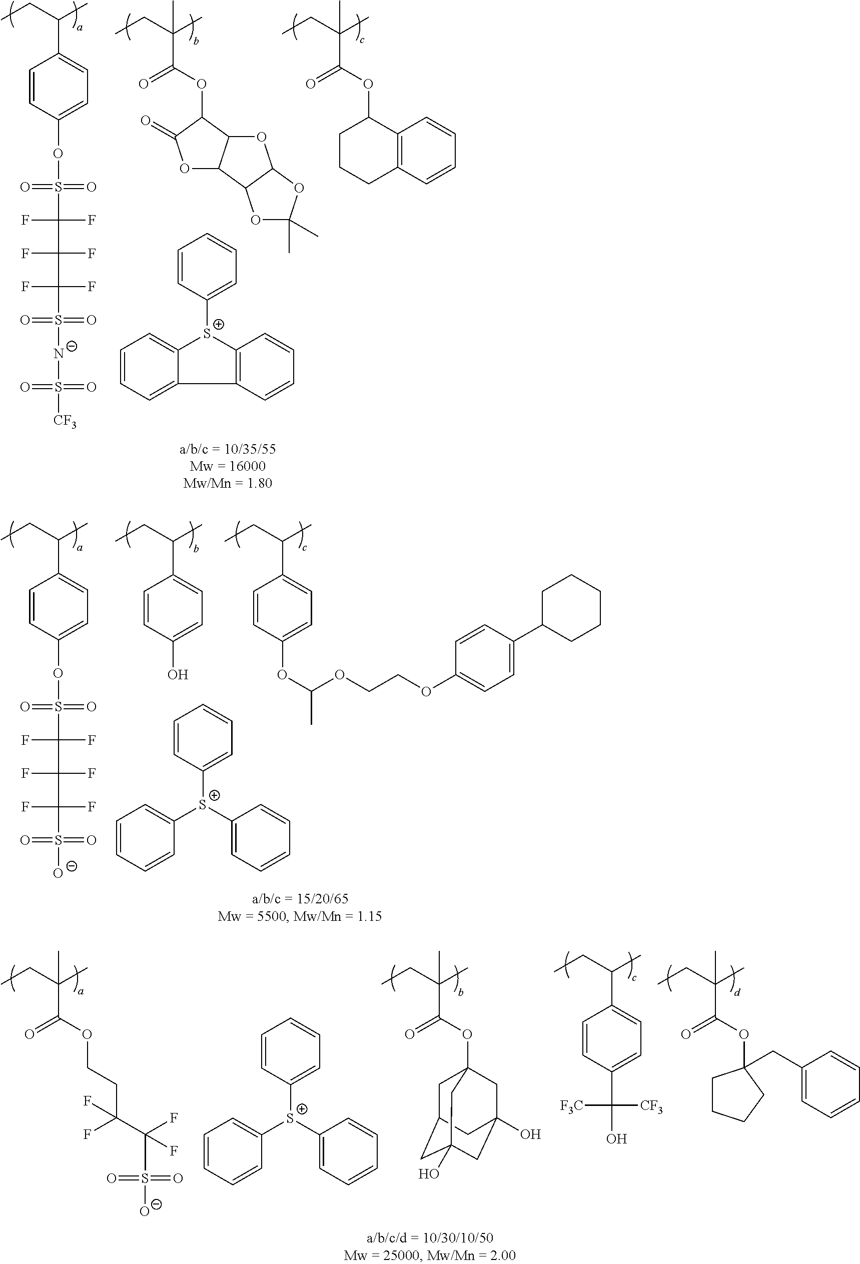

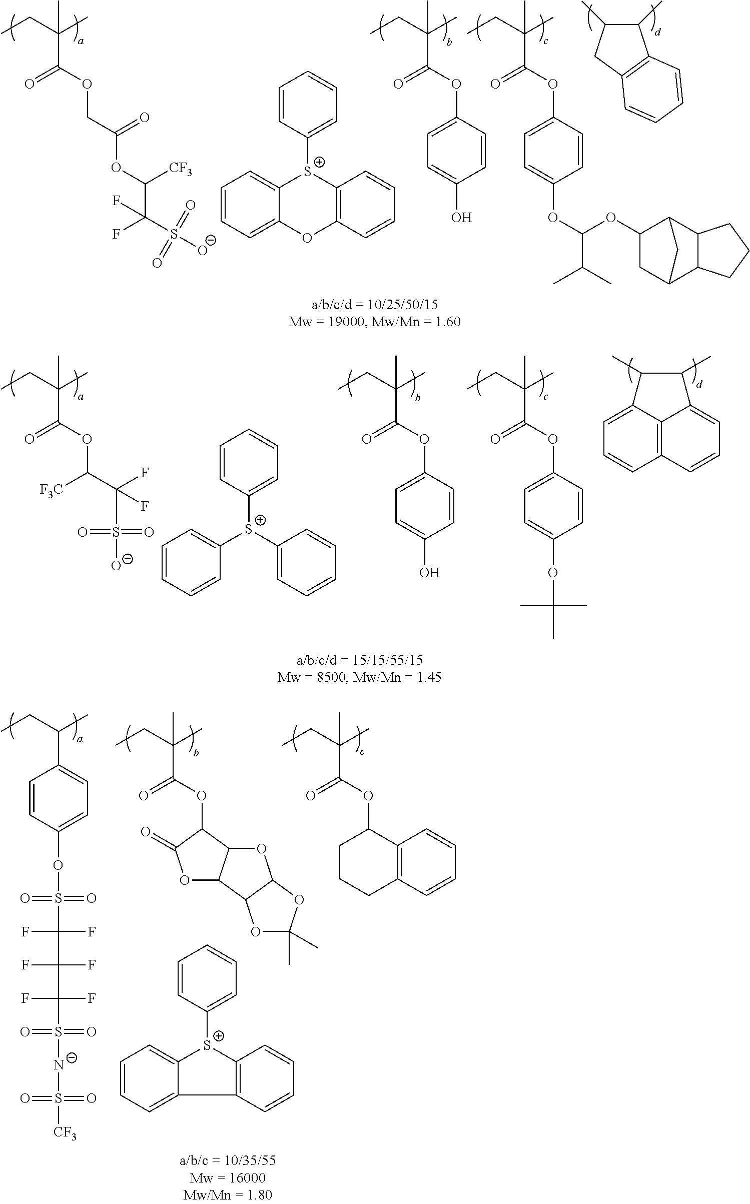

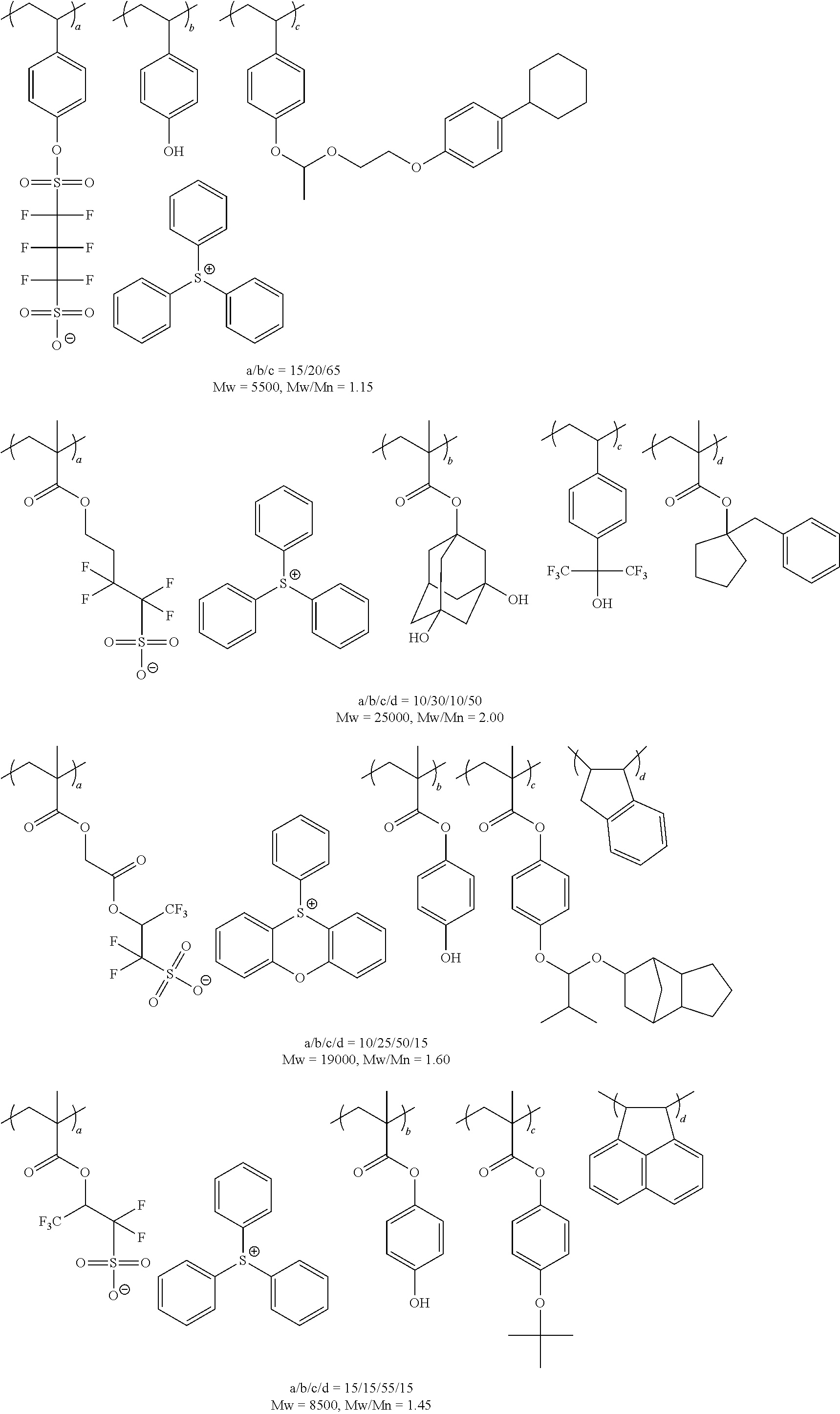

[Compound which Generates an Acid when Irradiated with an Actinic Ray or Radiation]

The composition of the present invention may contain a compound (also referred to below as a “compound (B)” or an “acid generating agent”) which generates an acid when irradiated with an actinic ray or radiation.

The compound which generates an acid when irradiated with an actinic ray or radiation may take the form of a low molecular compound or may take the form of being incorporated in a part of a polymer. In addition, a form of a low molecular compound and a form of being incorporated in a part of a polymer may be used together.

In a case where the compound which generates an acid when irradiated with an actinic ray or radiation takes the form of a low molecular compound, the molecular weight is preferably 3000 or less, more preferably 2000 or less, and even more preferably 1000 or less.

In a case where the compound which generates an acid when irradiated with an actinic ray or radiation takes the form of being incorporated in a part of a polymer, the compound may be incorporated in a part of the resin (A) described above or may be incorporated in a resin which is different from the resin (A).

In the present invention, the compound which generates an acid when irradiated with an actinic ray or radiation preferably takes the form of a low molecular compound.

As the acid generating agent, it is possible to appropriately select and use a photo-cationic polymerization photoinitiator, a photo-radical polymerization photoinitiator, a light decolorant for dyes, a photodiscoloration agent, a compound known in the art which generates an acid when irradiated with an actinic ray or radiation which is used for microresists and the like, or mixtures thereof.

Examples thereof include diazonium salt, phosphonium salt, sulfonium salt, iodonium salt, imide sulfonate, oxime sulfonate, diazo disulfone, disulfone, and o-nitrobenzyl sulfonate.

In one aspect of the present invention, examples of the acid generating agent include the compound which are represented by General Formula (ZI), (ZII), or (ZIII) below.

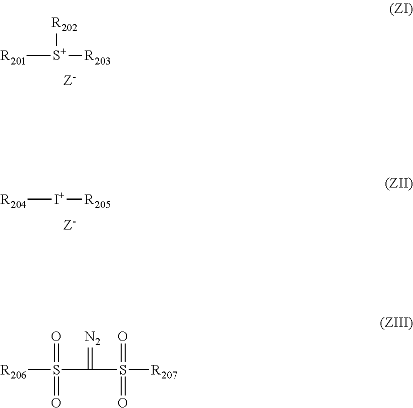

In General Formula (ZI) described above,

R₂₀₁, R₂₀₂, and R₂₀₃ each independently represent an organic group.

The number of carbon atoms of the organic group as R₂₀₁, R₂₀₂, and R₂₀₃ is generally 1 to 30 and preferably 1 to 20.

In addition, two out of R₂₀₁ to R₂₀₃ may bond with each other to form a ring structure and an oxygen atom, a sulfur atom, an ester bond, an amide bond, and a carbonyl group may be included in the ring. Examples of a group which two out of R₂₀₁ to R₂₀₃ bond with each other to form include an alkylene group (for example, a butylene group and a pentylene group).

Here, the compound may have a plurality of structures which are represented by General Formula (ZI). For example, the compound may have a structure where at least one of R₂₀₁ to R₂₀₃ of the compounds which are represented by General Formula (ZI) is bonded with at least one of R₂₀₁ to R₂₀₃ of another compound which is represented by General Formula (ZI) via a single bond or a linking group.

Z⁻ represents a non-nucleophilic anion (an anion which has a remarkably low ability to cause a nucleophilic reaction).

Examples of Z⁻ include sulfonic acid anions (aliphatic sulfonic acid anions, aromatic sulfonic acid anions, camphor sulfonic acid anions, and the like), carboxylic acid anions (aliphatic carboxylic acid anions, aromatic carboxylic acid anions, aralkyl carboxylic acid anions, and the like), sulfonylimide anions, bis(alkylsulfonyl) imide anions, tris(alkylsulfonyl) methide anions, and the like.

An aliphatic site in the aliphatic sulfonic acid anion and the aliphatic carboxylic acid anion may be an alkyl group or a cycloalkyl group and preferable examples thereof include a straight-chain or branched alkyl group with 1 to 30 carbon atoms or a cycloalkyl group with 3 to 30 carbon atoms.

An aromatic group in the aromatic sulfonic acid anion and the aromatic carboxylic acid anion is preferably an aryl group with 6 to 14 carbon atoms and examples thereof include a phenyl group, a tolyl group, a naphthyl group, and the like.

The alkyl group, the cycloalkyl group, and the aryl group described above may have a substituent group. Specific examples thereof include a nitro group, a halogen atom such as a fluorine atom, a carboxyl group, a hydroxyl group, an amino group, a cyano group, an alkoxy group (preferably with 1 to 15 carbon atoms), a cycloalkyl group (preferably with 3 to 15 carbon atoms), an aryl group (preferably with 6 to 14 carbon atoms), an alkoxycarbonyl group (preferably with 2 to 7 carbon atoms), an acyl group (preferably with 2 to 12 carbon atoms), an alkoxycarbonyloxy group (preferably with 2 to 7 carbon atoms), an alkylthio group (preferably with 1 to 15 carbon atoms), an alkylsulfonyl group (preferably with 1 to 15 carbon atoms), an alkyliminosulfonyl group (preferably with 2 to 15 carbon atoms), an aryloxysulfonyl group (preferably with 6 to 20 carbon atoms), an alkylaryloxysulfonyl group (preferably with 7 to 20 carbon atoms), a cycloalkylaryloxysulfonyl group (preferably with 10 to 20 carbon atoms), an alkyloxyalkyloxy group (preferably with 5 to 20 carbon atoms), a cycloalkylalkyloxyalkyloxy group (preferably with 8 to 20 carbon atoms), and the like. The aryl group and a ring structure which each group have may further have an alkyl group (preferably with 1 to 15 carbon atoms) as a substituent group.

An aralkyl group in an aralkyl carboxylic acid anion is preferably an aralkyl group with 7 to 12 carbon atoms and examples thereof include a benzyl group, a phenethyl group, a naphthylmethyl group, a naphthylethyl group, a naphthylbutyl group, and the like.

Examples of sulfonylimide anions include saccharin anions.

An alkyl group in a bis(alkylsulfonyl) imide anion and a tris(alkylsulfonyl) methide anion is preferably an alkyl group with 1 to 5 carbon atoms. Examples of a substituent group of the alkyl groups include a halogen atom, an alkyl group which is substituted with a halogen atom, an alkoxy group, an alkylthio group, an alkyloxysulfonyl group, an aryloxysulfonyl group, a cycloalkylaryloxysulfonyl group, and the like and a fluorine atom or an alkyl group which is substituted with a fluorine atom is preferable.

Other examples of Z⁻ include fluorinated phosphorus (for example, PF₆⁻), fluorinated boron (for example, BF₄⁻), fluorinated antimony (for example, SbF₆⁻), and the like.

Z⁻ is preferably an aliphatic sulfonic acid anion where at least α-position of sulfonic acid is substituted with a fluorine atom, an aromatic sulfonic acid anion which is substituted with a fluorine atom or a group which has a fluorine atom, a bis(alkylsulfonyl) imide anion where an alkyl group is substituted with a fluorine atom, and a tris(alkylsulfonyl) methide anion where an alkyl group is substituted with a fluorine atom.

In one aspect of the present invention, the number of fluorine atoms which are included in an anion as Z⁻ is preferably 2 or 3.

From the view point of the acid strength, the pKa of the generated acid is preferably −1 or less in order to improve the sensitivity.

Examples of the organic group of R₂₀₁, R₂₀₂, and R₂₀₃ include an aryl group (preferably with 6 to 15 carbon atoms), a straight-chain or branched alkyl group (preferably with 1 to 10 carbon atoms), a cycloalkyl group (preferably with 3 to 15 carbon atoms), and the like.

Out of R₂₀₁, R₂₀₂, and R₂₀₃, at least one is preferably an aryl group and all three are more preferably aryl groups. Apart from a phenyl group, a naphthyl group, and the like, a hetero aryl group such as an indole residue and a pyrrole residue is also possible as the aryl group.

The aryl group, the alkyl group, and the cycloalkyl group as R₂₀₁, R₂₀₂, and R₂₀₃ may further have a substituent group. Examples of the substituent group include a nitro group, a halogen atom such as a fluorine atom, a carboxyl group, a hydroxyl group, an amino group, a cyano group, an alkoxy group (preferably with 1 to 15 carbon atoms), a cycloalkyl group (preferably with 3 to 15 carbon atoms), an aryl group (preferably with 6 to 14 carbon atoms), an alkoxycarbonyl group (preferably with 2 to 7 carbon atoms), an acyl group (preferably with 2 to 12 carbon atoms), an alkoxycarbonyloxy group (preferably with 2 to 7 carbon atoms), and the like; however, the present invention is not limited thereto.

In addition, two selected from R₂₀₁, R₂₀₂, and R₂₀₃ may be bonded with each other via a single bond or a linking group. Examples of the linking group include an alkylene group (preferably with 1 to 3 carbon atoms), —O—, —S—, —CO—, —SO₂—, and the like; however, the present invention is not limited thereto.

Examples of a preferable structure in a case where at least one out of R₂₀₁, R₂₀₂, and R₂₀₃ is not an aryl group include cation structures such as the compounds which are exemplified as Formulas (I-1) to (I-70) in paragraphs “0046” and “0047” in JP2004-233661A, paragraphs “0040” to “0046” in JP2003-35948A, and in US2003/0224288A1 and the compounds which are exemplified as Formulas (IA-1) to (IA-54) and Formulas (IB-1) to (IB-24) in US2003/0077540A.

More preferable examples of the compound which is represented by General Formula (ZI) include a compound which is represented by General Formula (ZI-3) or (ZI-4) which will be described below. Firstly, description will be given of the compound which is represented by General Formula (ZI-3).

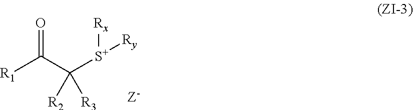

In General Formula (ZI-3) described above,

R₁ represents an alkyl group, a cycloalkyl group, an alkoxy group, a cycloalkoxy group, an aryl group, or an alkenyl group,

R₂ and R₃ each independently represent a hydrogen atom, an alkyl group, a cycloalkyl group, or an aryl group, R₂ and R₃ may link with each other to form a ring,

R₁ and R₂ may link with each other to form a ring,

R_{X} and R_{y} each independently represent an alkyl group, a cycloalkyl group, an alkenyl group, an aryl group, a 2-oxoalkyl group, a 2-oxocycloalkyl group, an alkoxycarbonylalkyl group, and an alkoxycarbonylcycloalkyl group, R_{X} and R_{y} may link with each other to form a ring, and the ring structure may include an oxygen atom, a nitrogen atom, a sulfur atom, a ketone group, an ether bond, an ester bond, and an amide bond.

Z⁻ represents a non-nucleophilic anion.

The alkyl group as R₁ is preferably a straight-chain or branched alkyl group with 1 to 20 carbon atoms and may have an oxygen atom, a sulfur atom, and a nitrogen atom in the alkyl chain. Examples thereof specifically include a branched alkyl group. The alkyl group of R₁ may have a substituent group.

The cycloalkyl group as R₁ is preferably a cycloalkyl group with 3 to 20 carbon atoms and may have an oxygen atom or a sulfur atom in the ring. The cycloalkyl group of R₁ may have a substituent group.

The alkoxy group as R₁ is preferably an alkoxy group with 1 to 20 carbon atoms. The alkoxy group of R₁ may have a substituent group.

The cycloalkoxy group as R₁ is preferably a cycloalkoxy group with 3 to 20 carbon atoms. The cycloalkyl group of R₁ may have a substituent group.

The aryl group as R₁ is preferably an aryl group with 6 to 14 carbon atoms. The aryl group of R₁ may have a substituent group.

Examples of the alkenyl group as R₁ include a vinyl group and an allyl group.

R₂ and R₃ represent a hydrogen atom, an alkyl group, a cycloalkyl group, or an aryl group and R₂ and R₃ may link with each other to form a ring. However, at least one out of R₂ and R₃ represents an alkyl group, a cycloalkyl group, or an aryl group. Specific examples and preferable examples of the alkyl group, the cycloalkyl group, and the aryl group regarding R₂ and R₃ include the same specific examples and the preferable examples described above regarding R₁. In a case where R₂ and R₃ link with each other to form a ring, the total number of carbon atoms which contribute to forming the ring which are included in R₂ and R₃ is preferably 4 to 7 and particularly preferably 4 or 5.

R₁ and R₂ may link with each other to form a ring. In a case where R₁ and R₂ link with each other to form a ring, it is preferable that R₁ is an aryl group (preferably a phenyl group or a naphthyl group which may have a substituent group) and that R₂ is an alkylene group with 1 to 4 carbon atoms (preferably a methylene group or an ethylene group) and examples of preferable substituent groups include the same substituent groups described above which the aryl group as R₁ may have. As another form in a case where R₁ and R₂ link with each other to form a ring, it is also preferable that R₁ is a vinyl group and that R₂ is an alkylene group with 1 to 4 carbon atoms.

The alkyl group which is represented by R_{X} and R_{y} is preferably an alkyl group with 1 to 15 carbon atoms.

The cycloalkyl group which is represented by R_{X} and R_{y} is preferably a cycloalkyl group with 3 to 20 carbon atoms.

The alkenyl group which is represented by R_{X} and R_{y} is preferably an alkenyl group with 2 to 30 carbon atoms and examples thereof include a vinyl group, an allyl group, and a styryl group.

The aryl group which is represented by R_{X} and R_{y} is, for example, an aryl group with 6 to 20 carbon atoms, preferably a phenyl group and a naphthyl group, and more preferably a phenyl group.

Examples of the alkyl group portion of the 2-oxoalkyl group and the alkoxycarbonylalkyl group which are represented by R_{X} and R_{y} include the examples previously given as R_{X} and R_{y}.

Examples of the cycloalkyl group portion of the 2-oxocycloalkyl group and the alkoxycarbonylcycloalkyl group which are represented by R_{X} and R_{y} include the examples previously given as R_{X} and R_{y}.

Examples of Z⁻ include the examples given as Z⁻ in General Formula (ZI) described above.

Specific examples of a cation portion of the compound which is represented by General Formula (ZI-3) will be given below.

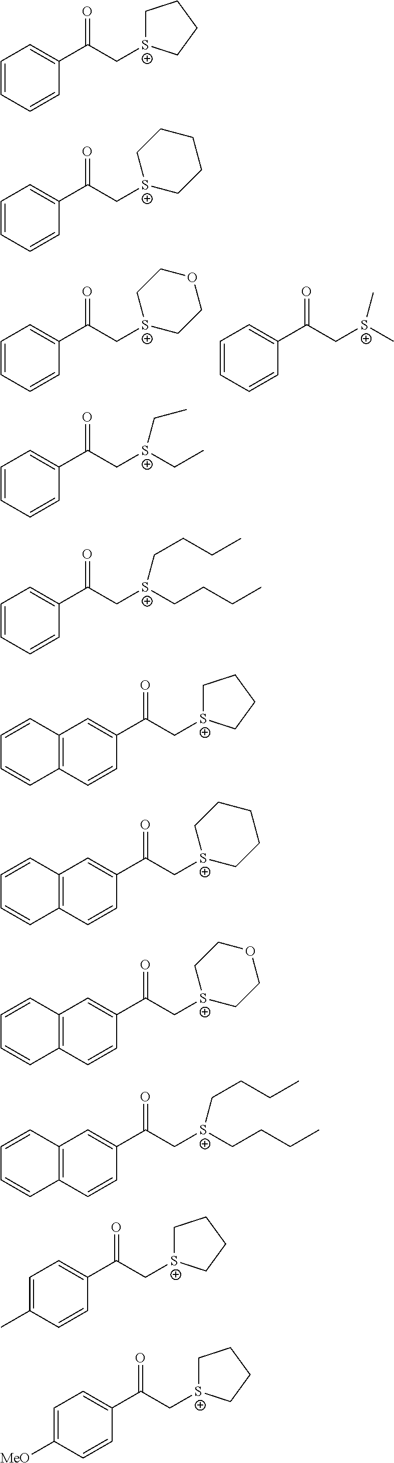

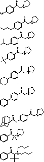

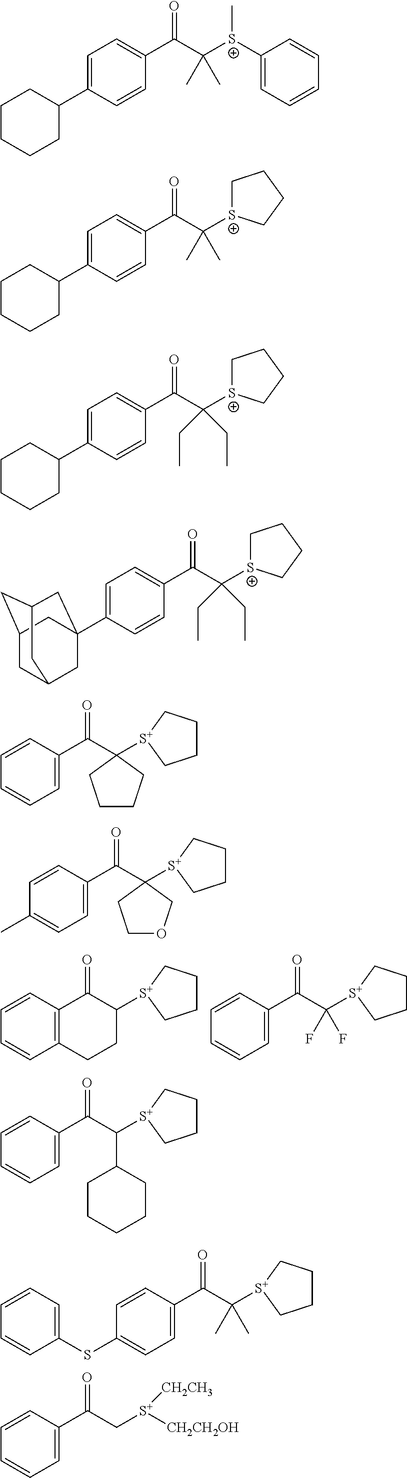

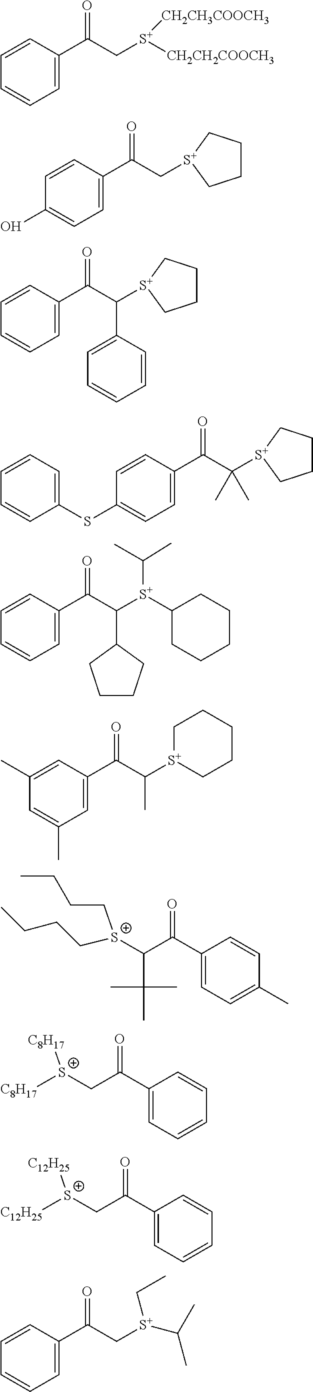

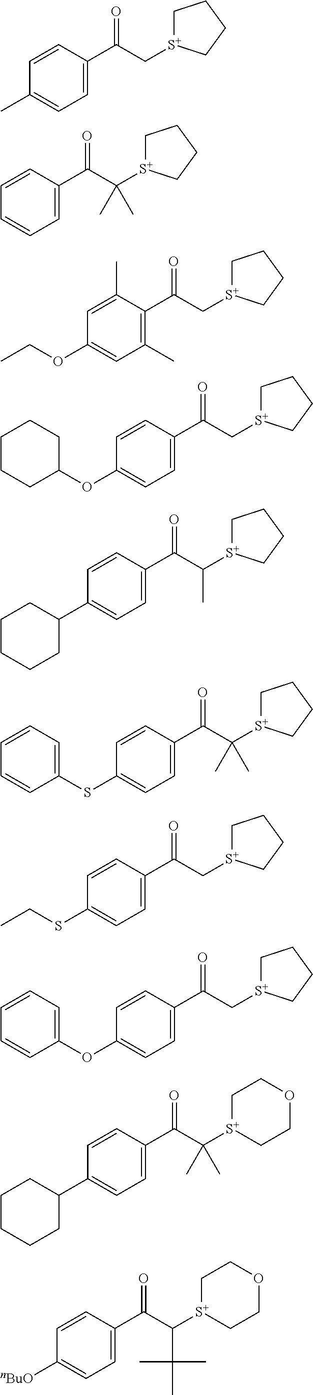

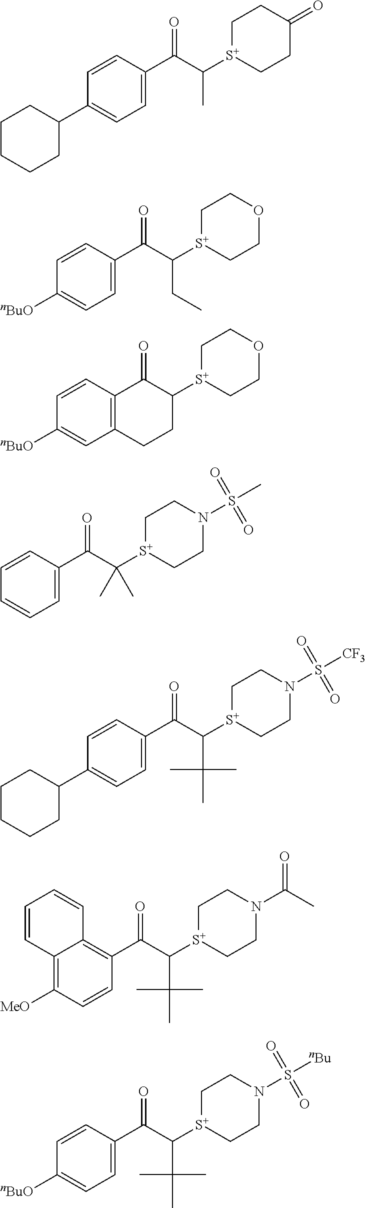

Next, description will be given of the compound which is represented by General Formula (ZI-4).

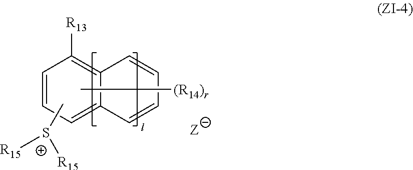

In General Formula (ZI-4),

R₁₃ represents a hydrogen atom, a fluorine atom, a hydroxyl group, an alkyl group, a cycloalkyl group, an alkoxy group, an alkoxycarbonyl group, or a group which has a cycloalkyl group. These groups may have a substituent group.

In a case where a plurality of R₁₄'s are present, R₁₄'s each independently represent a hydroxyl group, an alkyl group, a cycloalkyl group, an alkoxy group, an alkoxycarbonyl group, an alkylcarbonyl group, an alkylsulfonyl group, a cycloalkylsulfonyl group, or a group which has a cycloalkyl group. These groups may have a substituent group.

R₁₅'s each independently represent an alkyl group, a cycloalkyl group, or a naphthyl group. Two R₁₅s's may bond with each other to form a ring and may include a hetero atom such as an oxygen atom, a sulfur atom, and a nitrogen atom as atoms which form the ring. These groups may have a substituent group.

l represents an integer of 0 to 2.

r represents an integer of 0 to 8.

Z⁻ represents a non-nucleophilic anion and examples thereof include the same non-nucleophilic anions as Z⁻ in General Formula (ZI).

In General Formula (ZI-4), the alkyl group of R₁₃, R₁₄, and R₁₅ takes a straight-chain form or a branched form, preferably an alkyl group with 1 to 10 carbon atoms.

Examples of the cycloalkyl group of R₁₃, R₁₄, and R₁₅ include a monocyclic or polycyclic cycloalkyl group.

The alkoxy group of R₁₃ and R₁₄ is in a straight-chain form or a branched form and preferably an alkoxy group with 1 to 10 carbon atoms.

The alkoxycarbonyl group of R₁₃ and R₁₄ takes a straight-chain form or a branched form and preferably an alkoxycarbonyl group with 2 to 11 carbon atoms.

Examples of the group which has the cycloalkyl group of R₁₃ and R₁₄ include a group which has a monocyclic or polycyclic cycloalkyl group. These groups may further have a substituent group.

Examples of the alkyl group of the alkylcarbonyl group of R₁₄ include the same specific examples as the alkyl group as R₁₃ to R₁₅ described above.

The alkylsulfonyl group and the cycloalkylsulfonyl group of R₁₄ take a straight-chain form, a branched form, or a cyclic form and are preferably an alkylsulfonyl group or a cycloalkylsulfonyl group with 1 to 10 carbon atoms.

Examples of the substituent group which each of the groups described above may have include a halogen atom (for example, a fluorine atom), a hydroxyl group, a carboxyl group, a cyano group, a nitro group, an alkoxy group, an alkoxyalkyl group, an alkoxycarbonyl group, an alkoxycarbonyloxy group, and the like.

Examples of the ring structure which two R₁₅'s may form by bonding with each other include a 5-membered or 6-membered ring which two R₁₅'s form with a sulfur atom in General Formula (ZI-4), and particularly preferably include a 5-membered ring (that is, a tetrahydrothiophene ring or a 2,5-dihydrothiophene ring) and the ring structure may be condensed with an aryl group or a cycloalkyl group. Two R₁₅s's may have a substituent group and examples of the substituent group include a hydroxyl group, a carboxyl group, a cyano group, a nitro group, an alkyl group, a cycloalkyl group, an alkoxy group, an alkoxyalkyl group, an alkoxycarbonyl group, an alkoxycarbonyloxy group, and the like. A plurality of the substituent groups may be present in the ring structure and, moreover, may bond with each other to form a ring.

R₁₅ in General Formula (ZI-4) is preferably a methyl group, an ethyl group, a naphthyl group, a divalent group in which two R₁₅'s bond with each other to form a tetrahydrothiophene ring structure with a sulfur atom, and the like, and particularly preferably a divalent group in which two R₁₅s's bond with each other to form a tetrahydrothiophene ring structure with a sulfur atom.

The substituent group which R₁₃ and R₁₄ may have is preferably a hydroxyl group, an alkoxy group, an alkoxycarbonyl group, and a halogen atom (in particular, a fluorine atom).

l is preferably 0 or 1 and more preferably 1.

r is preferably 0 to 2.

Other than the cation structures of the compounds and the like which are exemplified in JP2004-233661A, JP2003-35948A, US2003/0224288A1, and US2003/0077540A1 described above, specific examples of the cation structure of the compound which is represented by General Formula (ZI-3) or (ZI-4) described above include the cation structures in the chemical structures and the like which are exemplified in paragraphs “0046”, “0047”, “0072” to “0077”, and “0107” to “0110” in JP2011-53360A, the cation structures in the chemical structures and the like which are exemplified in paragraphs “0135” to “0137”, “0151”, and “0196” to “0199” in JP2011-53430A, and the like.

In General Formulas (ZII) and (ZIII),

R₂₀₄ to R₂₀₇ each independently represent an aryl group, an alkyl group, or a cycloalkyl group.

The aryl group, the alkyl group, and the cycloalkyl group of R₂₀₄ to R₂₀₇ are the same as the aryl group, the alkyl group, and the cycloalkyl group of R₂₀₁ to R₂₀₃ in the compound (ZI) described above.

The aryl group, the alkyl group, and the cycloalkyl group of R₂₀₄ to R₂₀₇ may have a substituent group. Examples of the substituent group include the substituent groups which the aryl group, the alkyl group, and the cycloalkyl group of R₂₀₁ to R₂₀₃ in the compound (ZI) described above may have.

Examples of Z⁻ include the examples given as Z⁻ in General Formula (ZI) described above.

Next, description will be given of a preferable structure of a non-nucleophilic anion Z⁻.

The non-nucleophilic anion Z⁻ is preferably a sulfonic acid anion which is represented by General Formula (2).

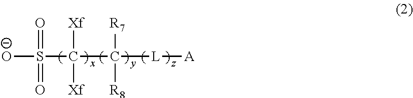

In General Formula (2),

Xf's each independently represent a fluorine atom or an alkyl group which is substituted with at least one fluorine atom.

R₇ and R₈ each independently represent a hydrogen atom, a fluorine atom, an alkyl group, or an alkyl group which is substituted with at least one fluorine atom, and R₇ and R₈ may be the same as or different from each other in a case where a plurality thereof are present.

L represents a divalent linking group and L may be the same as or different from each other in a case where a plurality thereof are present.

A represents an organic group which includes a cyclic structure.

x represents an integer of 1 to 20. y represents an integer of 0 to 10. z represents an integer of 0 to 10.

More detailed description will be given of the anion of General Formula (2).

Xf is a fluorine atom or an alkyl group which is substituted with at least one fluorine atom as described above and the alkyl group in the alkyl group which is substituted with a fluorine atom is preferably an alkyl group with 1 to 10 carbon atoms, and more preferably an alkyl group with 1 to 4 carbon atoms. In addition, the alkyl group which is substituted with a fluorine atom of Xf is preferably a perfluoroalkyl group.

Xf is preferably a fluorine atom or a perfluoroalkyl group with 1 to 4 carbon atoms. In detail, a fluorine atom or CF₃ is preferable. In particular, both Xf's are preferably fluorine atoms.

R₇ and R₈ represent a hydrogen atom, a fluorine atom, an alkyl group, or an alkyl group which is substituted with at least one fluorine atom as described above and the alkyl group preferably has 1 to 4 carbon atoms. A perfluoroalkyl group with 1 to 4 carbon atoms is more preferable. As a specific example of the alkyl group which is substituted with at least one fluorine atom of R₇ and R₈, CF₃ is preferable.

L represents a divalent linking group and examples thereof include —COO—, —OCO—, —CO—, —O—, —S—, —SO—, —SO₂—, —N(Ri)- (in the formula, Ri represents a hydrogen atom or alkyl), an alkylene group (preferably with 1 to 6 carbon atoms), a cycloalkylene group (preferably with 3 to 10 carbon atoms), an alkenylene group (preferably with 2 to 6 carbon atoms), or a divalent linking group in which a plurality of the above are combined, and the like, —COO—, —OCO—, —CO—, —SO₂—, —CON(Ri)-, —SO₂N(Ri)-, —CON(Ri)-alkylene group-, —N(Ri)CO-alkylene group-, —COO-alkylene group-, or —OCO-alkylene group- is preferable, and —COO—, —OCO—, —SO₂—, —CON(Ri)-, or —SO₂N(Ri)- is more preferable. L may be the same as or different from each other in a case where a plurality thereof are present.

The alkyl group as Ri is preferably a straight-chain or branched alkyl group with 1 to 20 carbon atoms and may have an oxygen atom, a sulfur atom, and a nitrogen atom in the alkyl chain. Specific examples thereof include a straight-chain alkyl group and a branched alkyl group. Examples of the alkyl group which has a substituent group include a cyanomethyl group, a 2,2,2-trifluoroethyl group, a methoxycarbonylmethyl group, an ethoxycarbonylmethyl group, and the like.

The organic group which includes the cyclic structure of A is not particularly limited as long as the organic group has a cyclic structure and examples thereof include an alicyclic group, an aryl group, a heterocyclic group (not only heterocyclic groups which have an aromaticity but also heterocyclic groups which do not have aromaticity are included, for example, a tetrahydropyran ring and a lactone ring structure are also included), and the like.

The alicyclic group may be monocyclic or may be polycyclic. In addition, a nitrogen atom-containing alicyclic group such as a piperidine group, a decahydroquinoline group, and a decahydroisoquinoline group is preferable. Among these, from the point of view of being able to suppress the diffusion in a film in the PEB (post exposure bake) step and improving the exposure latitude, an alicyclic group which has a bulky structure with 7 or more carbon atoms such as a norbornyl group, a tricyclodecanyl group, a tetracyclodecanyl group, a tetracyclododecanyl group, an adamantyl group, a decahydroquinoline group, and a decahydroisoquinoline group is preferable.

Examples of the aryl group include a benzene ring, a naphthalene ring, a phenanthrene ring, and an anthracene ring. Among these, naphthalene with low light absorbance is preferable from the point of view of the light absorbance at 193 nm.

Examples of the heterocyclic group include a furan ring, a thiophene ring, a benzofuran ring, a benzothiophene ring, a dibenzofuran ring, a dibenzothiophene ring, and a pyridine ring. Among these, a furan ring, a thiophene ring, and a pyridine ring are preferable.

The cyclic organic groups described above may have a substituent group and examples of the substituent group include alkyl groups (any of straight-chain, branched, or cyclic, preferably with 1 to 12 carbon atoms), an aryl group (preferably with 6 to 14 carbon atoms), a hydroxy group, an alkoxy group, an ester group, an amide group, a urethane group, a ureide group, a thioether group, a sulfonamide group, a sulfonic acid ester group, a cyano group, and the like.

Here, the carbon (carbon which contributes to forming a ring) which forms an organic group which includes a cyclic structure may be carbonyl carbon.

x is preferably 1 to 8, more preferably 1 to 4, and particularly preferably 1. y is preferably 0 to 4, more preferably 0 or 1, and even more preferably 0. z is preferably 0 to 8, more preferably 0 to 4, and even more preferably 1.

In addition, in one aspect of the present invention, the number of fluorine atoms which are included in the anion which is represented by General Formula (2) is preferably 2 or 3. Due to this, it is possible to further improve the effects of the present invention.

Specific examples of a sulfonic acid anion structure which is represented by General Formula (2) will be given below; however, the present invention is not limited thereto.

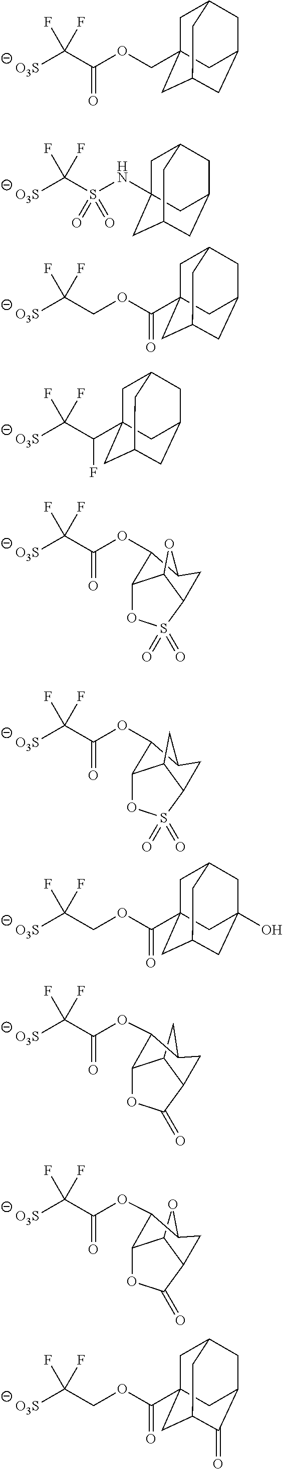

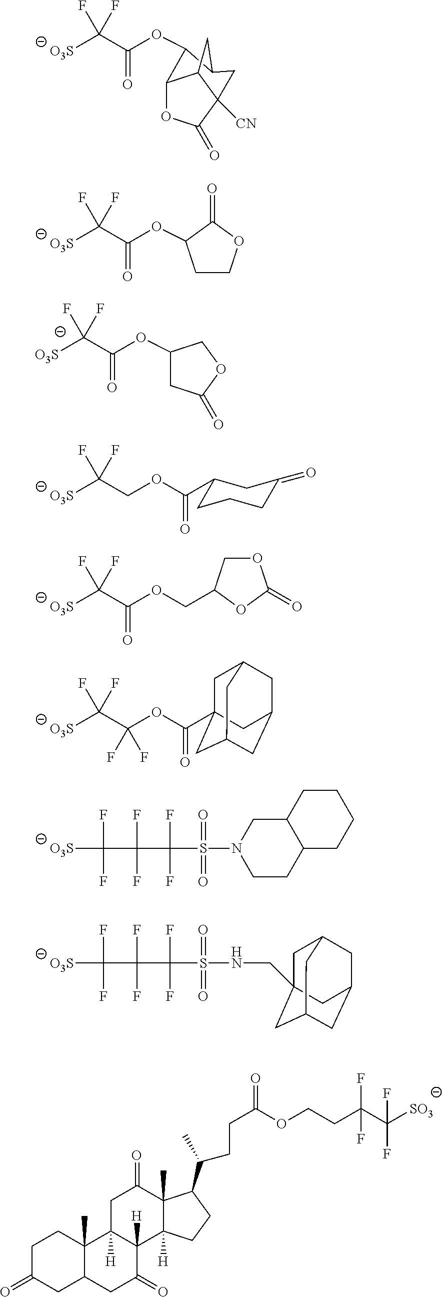

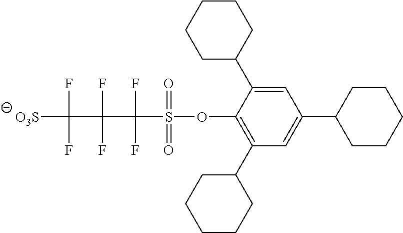

Z⁻ is also preferably a sulfonic acid anion which is represented by General Formula (B-1) below.

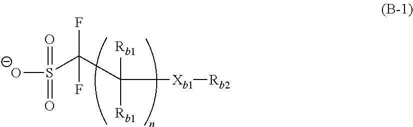

In General Formula (B-1) described above,

R_{b1}'s each independently represent a hydrogen atom, a fluorine atom, or a trifluoromethyl group (CF₃).

n represents an integer of 0 to 4.

n is preferably an integer of 0 to 3 and more preferably 0 or 1.

X_{b1} represents a single bond, an alkylene group, an ether bond, an ester bond (—OCO— or —COO—), a sulfonic acid ester bond (—OSO₂— or —SO₃—), or a combination thereof.

X_{b1} is preferably an ester bond (—OCO— or —COO—) or a sulfonic acid ester bond (—OSO₂— or —SO₃—), and more preferably an ester bond (—OCO— or —COO—).

R_{b2} represents an organic group with 6 or more carbon atoms.

The organic group with 6 or more carbon atoms regarding R_{b2} is preferably a bulky group and examples thereof include an alkyl group, an alicyclic group, an aryl group, a heterocyclic group, and the like, with 6 or more carbon atoms.

The alkyl group with 6 or more carbon atoms regarding R_{b2} may be straight-chain or branched, and is preferably a straight-chain or branched alkyl group with 6 to 20 carbon atoms. and examples thereof include a straight-chain or branched hexyl group, a straight-chain or branched heptyl group, a straight-chain or branched octyl group, and the like. From the point of view of bulkiness, a branched alkyl group is preferable.

The alicyclic group with 6 or more carbon atoms regarding R_{b2} may be monocyclic or may be polycyclic. Among these, from the point of view of suppressing the diffusion in a film in the PEB (post exposure bake) step and improving the mask error enhancement factor (MEEF), an alicyclic group which has a bulky structure with 7 or more carbon atoms such as a norbornyl group, a tricyclodecanyl group, a tetracyclodecanyl group, a tetracyclododecanyl group, and an adamantyl group is preferable.

The aryl group with 6 or more carbon atoms regarding R_{b2} may be monocyclic or may be polycyclic. Examples of the aryl group include a phenyl group, a naphthyl group, a phenanthryl group, and an anthryl group. Among these, a naphthyl group with relatively low light absorbance at 193 nm is preferable.

The heterocyclic group with 6 or more carbon atoms regarding R_{b2} may be monocyclic or may be polycyclic; however, the polycyclic is able to further suppress the acid diffusion. In addition, the heterocyclic group may have aromaticity or may not have aromaticity. Examples of the hetero ring which has aromaticity include a benzofuran ring, a benzothiophene ring, a dibenzofuran ring, and a dibenzothiophene ring. Examples of the hetero ring which does not have aromaticity include a tetrahydropyran ring, a lactone ring, a sultone ring, and a decahydroisoquinoline ring.

The substituent group with 6 or more carbon atoms regarding R_{b2} described above may further have a substituent group. Examples of further substituent groups include an alkyl group (may be either straight-chain or branched, preferably with 1 to 12 carbon atoms), a cycloalkyl group (may be any of monocyclic, polycyclic, and a spiro ring, preferably with 3 to 20 carbon atoms), an aryl group (preferably with 6 to 14 carbon atoms), a hydroxy group, an alkoxy group, an ester group, an amide group, a urethane group, a ureide group, a thioether group, a sulfonamide group, and a sulfonic acid ester group. Here, the carbon (carbon which contributes to forming a ring) which forms the alicyclic group, the aryl group, or the heterocyclic group described above may be carbonyl carbon.

Specific examples of the sulfonic acid anion structure which is represented by General Formula (B-1) will be given below; however, the present invention is not limited thereto. Here, an anion which corresponds to the sulfonic acid anion which is represented by General Formula (2) described above is also included in the specific examples below.

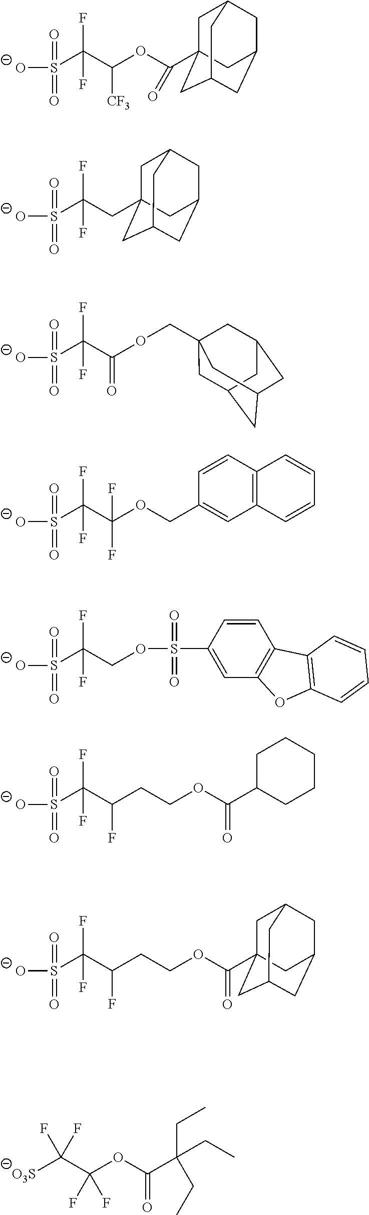

Z⁻ is also preferably a sulfonic acid anion which is represented by General Formula (A-1) below.

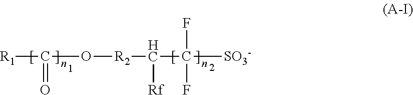

In General Formula (A-I),

R₁ is an alkyl group, a monovalent alicyclic hydrocarbon group, an aryl group, or a hetero aryl group.

R₂ is a divalent linking group.

Rf is a fluorine atom or an alkyl group which is substituted with at least one fluorine atom.

n₁ and n₂ are each independently 0 or 1.

The alkyl group which is represented by R₁ described above is preferably an alkyl group with 1 to 20 carbon atoms, more preferably an alkyl group with 1 to 10 carbon atoms, even more preferably an alkyl group with 1 to 5 carbon atoms, and particularly preferably an alkyl group with 1 to 4 carbon atoms.

In addition, the alkyl group described above may have a substituent group (preferably a fluorine atom) and the alkyl group which has a substituent group is preferably an alkyl group with 1 to 5 carbon atoms which is substituted with at least one fluorine atom and preferably a perfluoroalkyl group with 1 to 5 carbon atoms.

The alkyl group which is represented by R₁ described above is preferably a methyl group, an ethyl group, or a trifluoromethyl group and more preferably a methyl group or an ethyl group.

The number of carbon atoms of the monovalent alicyclic hydrocarbon group which is represented by R₁ described above is preferably 5 or more. In addition, the number of carbon atoms of the monovalent alicyclic hydrocarbon group is preferably 20 or less and more preferably 15 or less. The monovalent alicyclic hydrocarbon group described above may be a monocyclic alicyclic hydrocarbon group or may be a polycyclic alicyclic hydrocarbon group. A part of —CH₂— of the alicyclic hydrocarbon group may be substituted with —O— or —C(═O)—.

The monocyclic alicyclic hydrocarbon group preferably has 5 to 12 carbon atoms and is preferably a cyclopentyl group, a cyclohexyl group, and a cyclooctyl group.

The polycyclic alicyclic hydrocarbon group preferably has 10 to 20 carbon atoms and is preferably a norbornyl group, an adamantyl group, and a noradamantyl group.

The number of carbon atoms of the aryl group which is represented by R₁ described above is preferably 6 or more. In addition, the number of carbon atoms of the aryl group is preferably 20 or less and more preferably 15 or less.

The number of carbon atoms of the hetero aryl group which is represented by R₁ described above is preferably 2 or more. In addition, the number of carbon atoms of the hetero aryl group is preferably 20 or less and more preferably 15 or less.

The aryl group and the hetero aryl group described above may be a monocyclic aryl group or a monocyclic hetero aryl group or may be a polycyclic aryl group or a polycyclic hetero aryl group.

Examples of the monocyclic aryl group include a phenyl group and the like.

Examples of the polycyclic aryl group include a naphthyl group, an anthracenyl group, and the like.

Examples of the monocyclic hetero aryl group include a pyridine group, a thienyl group, a furanyl group, and the like.

Examples of the polycyclic hetero aryl group include a quinolyl group, an isoquinolyl group, and the like.

The monovalent alicyclic hydrocarbon group, the aryl group, and the hetero aryl group as R₁ described above may further have a substituent group and examples of the further substituent group include a hydroxyl group, a halogen atom (a fluorine atom, a chlorine atom, a bromine atom, an iodine atom, and the like), a nitro group, a cyano group, an amide group, a sulfonamide group, an alkyl group, an alkoxy group, an alkoxycarbonyl group, an acyl group, an acyloxy group, and a carboxy group.

R₁ is particularly preferably a cyclohexyl group or an adamantyl group.

The divalent linking group which is represented by R₂ described above is not particularly limited; however, examples thereof include —COO—, —OCO—, —CO—, —O—, —S—, —SO—, —SO₂—. an alkylene group (preferably an alkylene group with 1 to 30 carbon atoms), a cycloalkyl group (preferably a cycloalkyl group with 3 to 30 carbon atoms), an alkenylene group (preferably an alkenylene group with 2 to 30 carbon atoms), an arylene group (preferably an arylene group with 6 to 30 carbon atoms), a hetero arylene group (preferably a hetero arylene group with 2 to 30 carbon atoms), and a group in which two or more types thereof are combined. The alkylene group, the cycloalkylene group, the alkenylene group, the arylene group, and the hetero arylene group described above may further have a substituent group and specific examples of the substituent group are the same as the examples described for the substituent group which the monovalent alicyclic hydrocarbon group, the aryl group, and the hetero aryl group as R₁ may further have.

The divalent linking group which is represented by R₂ described above is preferably an alkylene group, a cycloalkylene group, an alkenylene group, an arylene group, and a hetero arylene group, more preferably an alkylene group, even more preferably an alkylene group with 1 to 10 carbon atoms, and particularly preferably an alkylene group with 1 to 5 carbon atoms.

Rf is a fluorine atom or an alkyl group which is substituted with at least one fluorine atom. The number of carbon atoms of the alkyl group is preferably 1 to 30, more preferably 1 to 10, and even more preferably 1 to 4. In addition, the alkyl group which is substituted with at least one fluorine atom is preferably a perfluoroalkyl group.

Rf is preferably a fluorine atom or a perfluoroalkyl group with 1 to 4 carbon atoms.

In more detail, Rf is preferably a fluorine atom or CF₃.

n₁ is preferably 1.

n₂ is preferably 1.

Preferable specific examples of the sulfonic acid anion which is represented by General Formula (A-I) described above will be given below; however, the present invention is not limited thereto. Here, an anion which corresponds to the sulfonic acid anion which is represented by General Formula (2) described above is also included in the specific examples below.

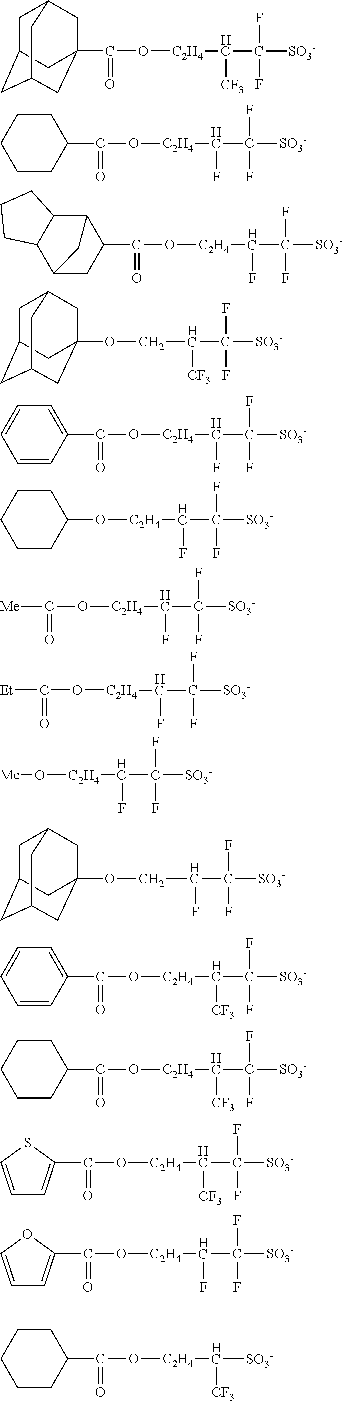

The non-nucleophilic anion Z may be a disulfonylimide acid anion which is represented by General Formula (2′).

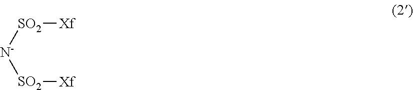

In General Formula (2′),

Xf is as defined in General Formula (2) described above and the preferable examples thereof are also the same. In General Formula (2′), two Xf's may link with each other to form a ring structure.

The disulfonylimide acid anion regarding Z⁻ is preferably a bis(alkylsulfonyl) imide anion.

The alkyl group in the bis(alkylsulfonyl) imide anion is preferably an alkyl group with 1 to 5 carbon atoms.

Two the alkyl groups in the bis(alkylsulfonyl) imide anion may link with each other to form an alkylene group (preferably with 2 to 4 carbon atoms) and form a ring with an imide group and two sulfonyl groups. The ring structure described above which the bis(alkylsulfonyl) imide anion may form is preferably a 5-membered to 7-membered ring and more preferably a 6-membered ring.

Examples of the substituent group which the alkyl groups and the alkylene group which two alkyl groups form by linking with each other may have include a halogen atom, an alkyl group which is substituted with a halogen atom, an alkoxy group, an alkylthio group, an alkyloxysulfonyl group, an aryloxysulfonyl group, a cycloalkylaryloxysulfonyl group, and the like, and a fluorine atom or an alkyl group which is substituted with a fluorine atom is preferable.

Examples of the acid generating agent will be given below. However, the present invention is not limited thereto.

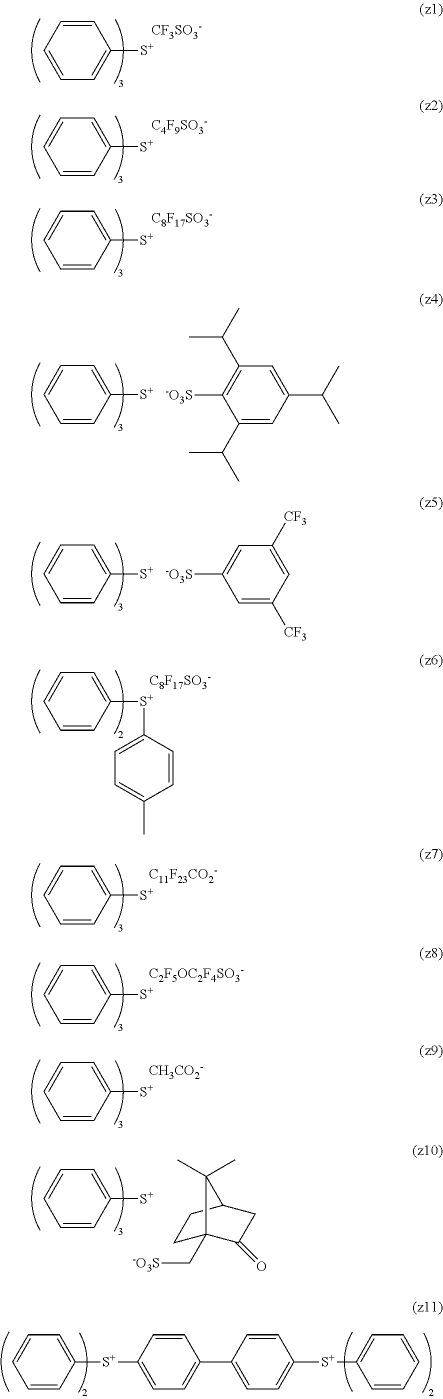

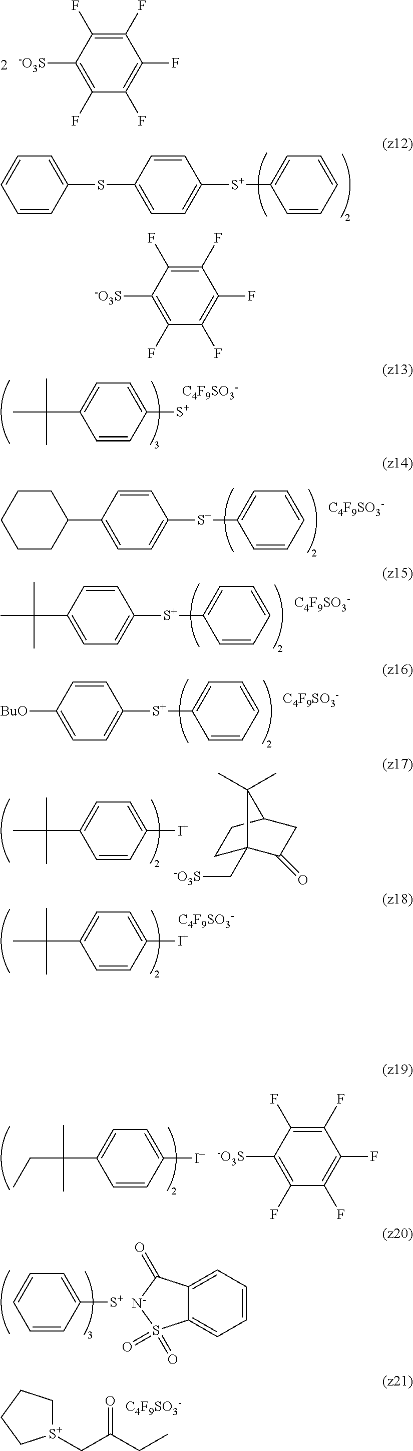

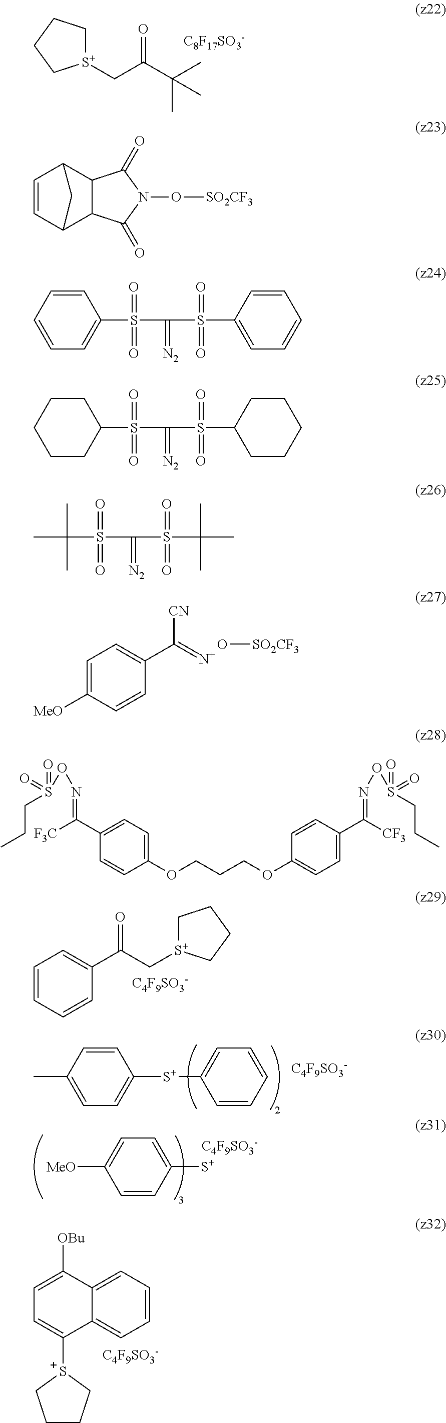

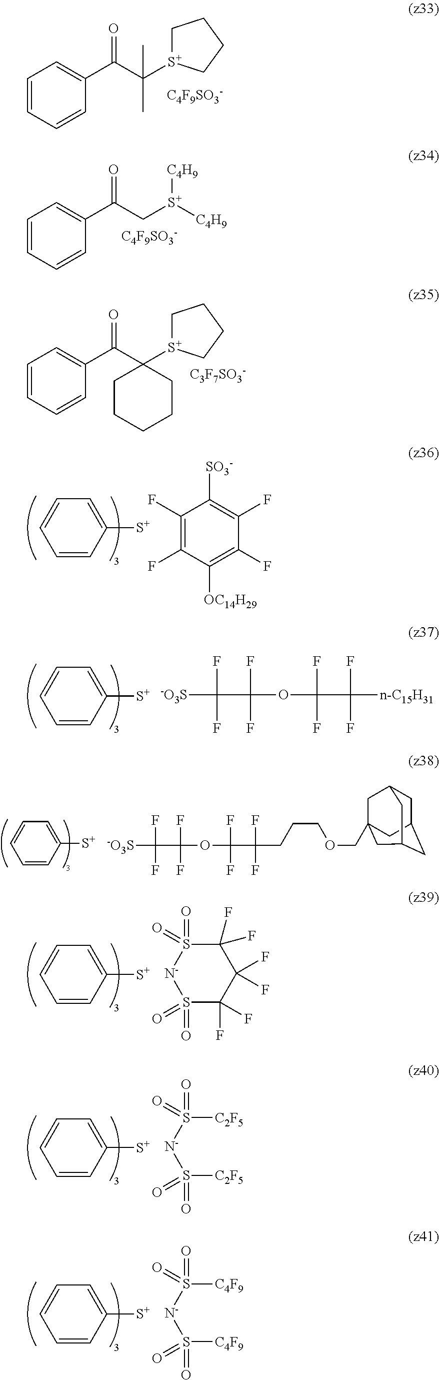

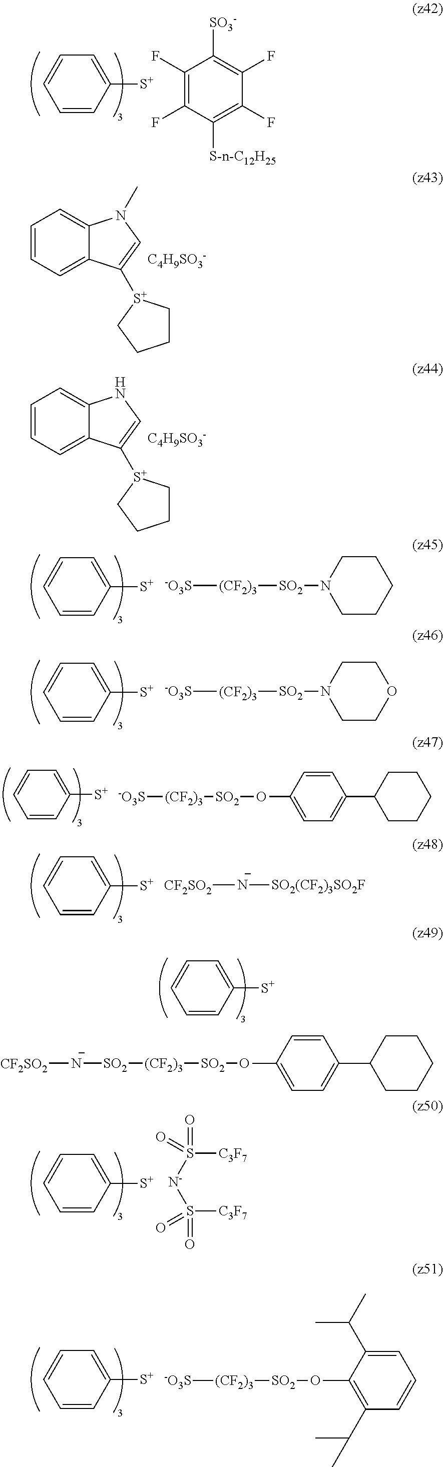

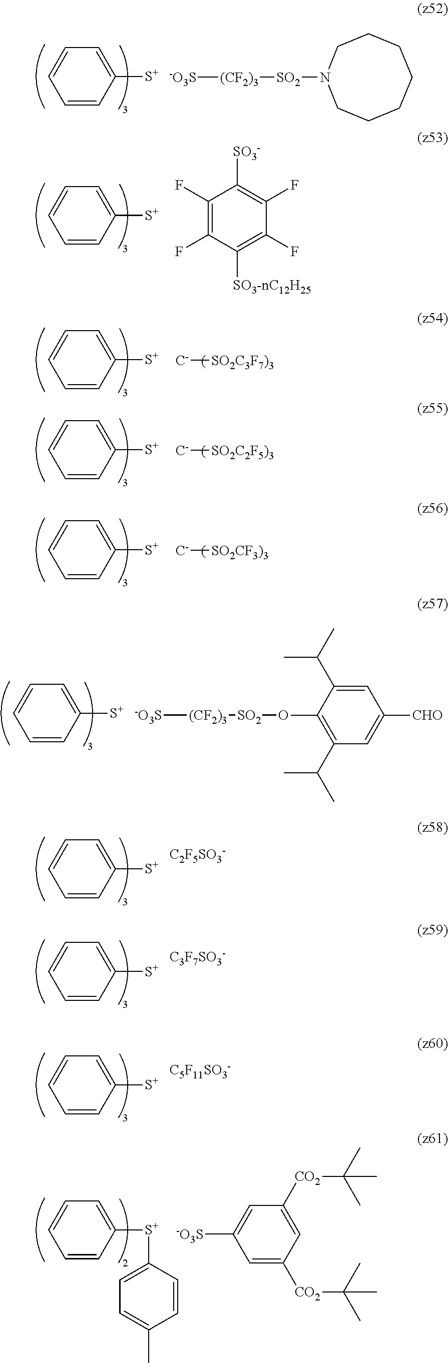

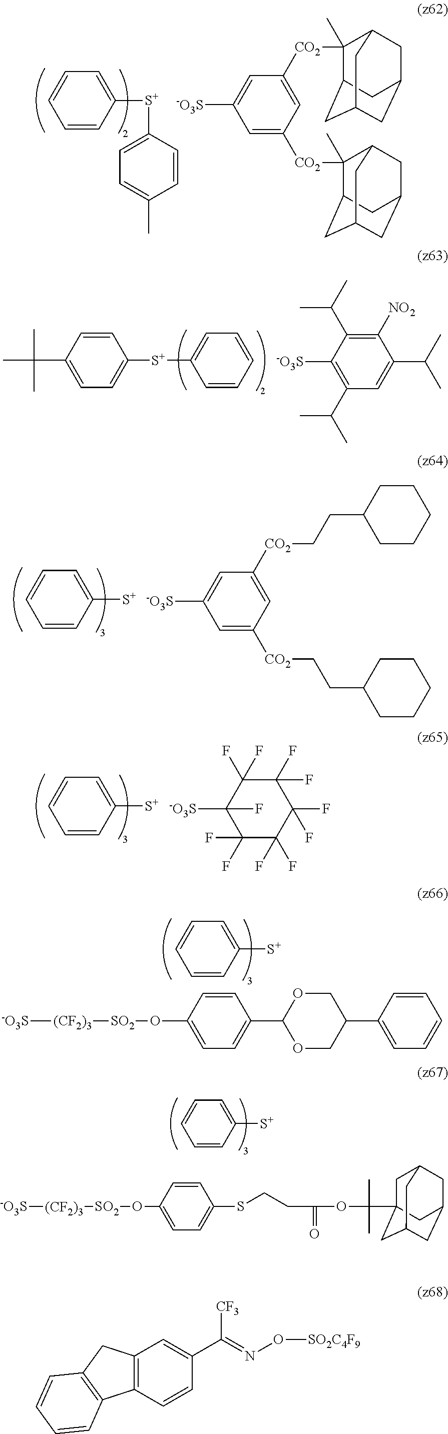

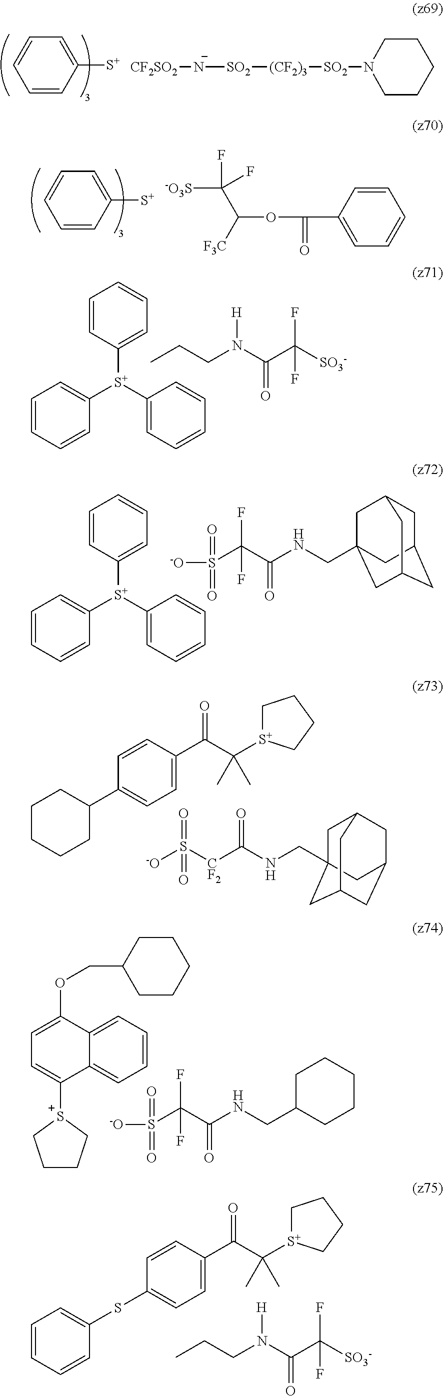

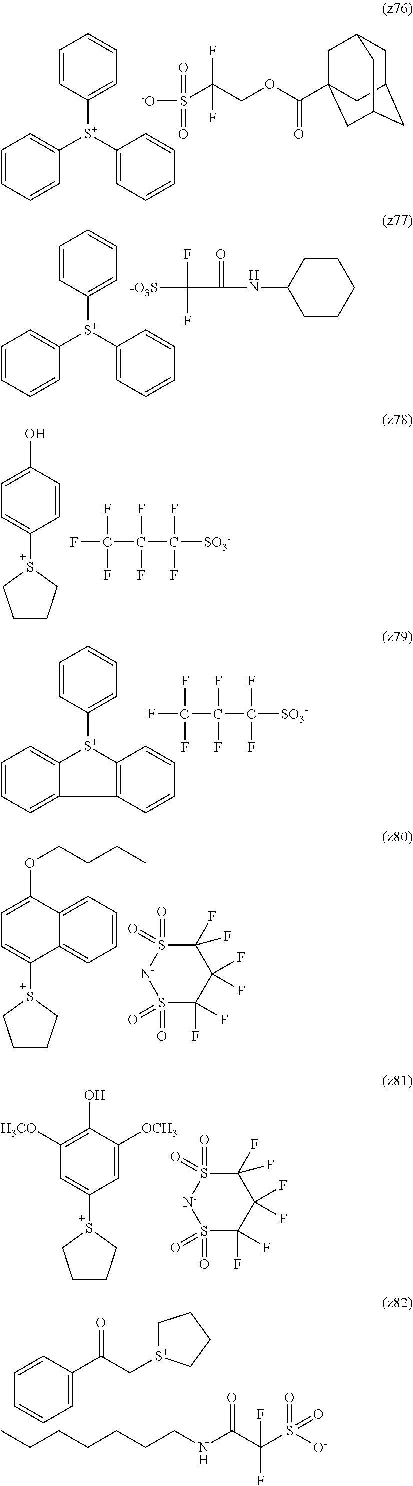

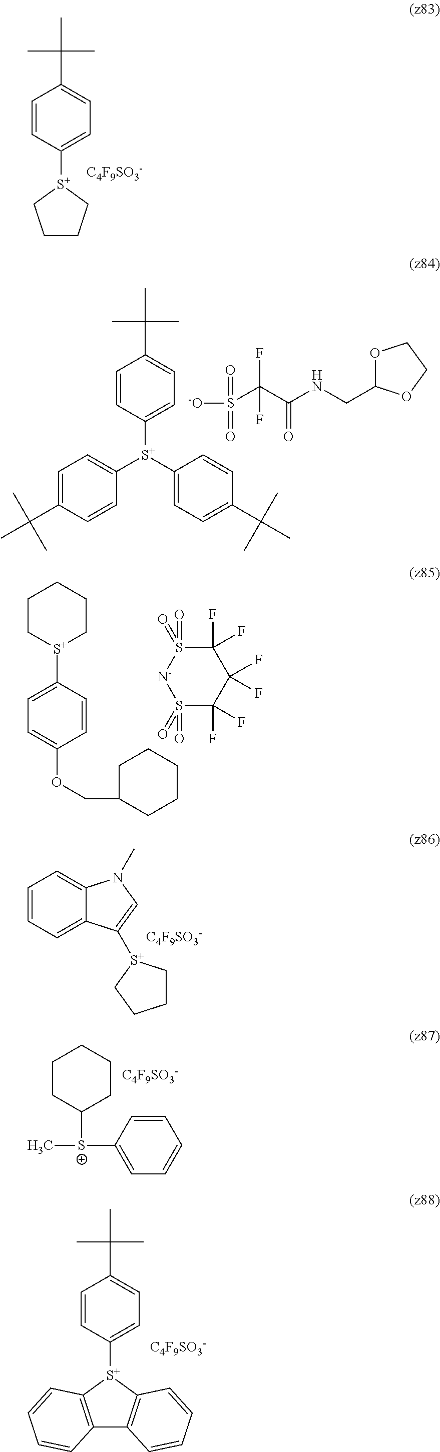

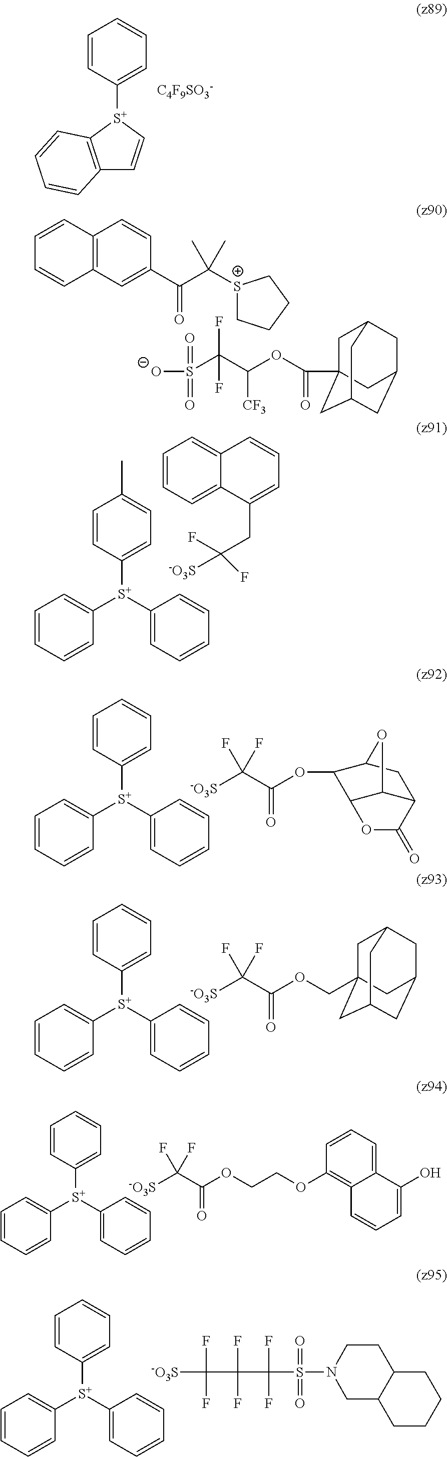

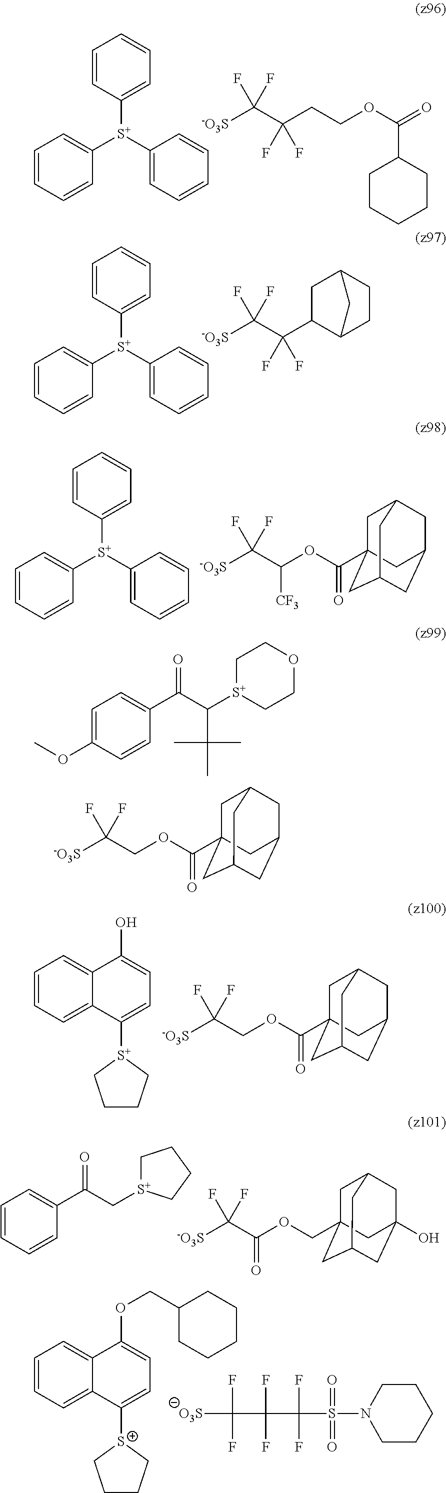

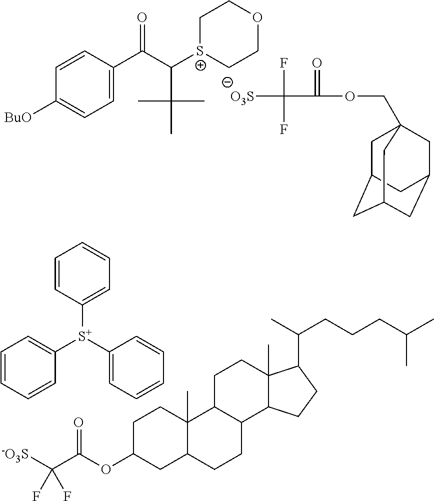

The acid generating agent is able to be used as one type individually or in a combination of two or more types.

The content ratio of the acid generating agent in the composition is preferably 0.1 mass % to 30 mass %/o, more preferably 1 mass % to 28 mass %, and even more preferably 3 mass % to 25 mass % on the basis of the entirety of the solid content of the composition.

[Hydrophobic Resin]

The actinic ray-sensitive or radiation-sensitive resin composition of the present invention may contain a hydrophobic resin (also referred to below as a “hydrophobic resin (HR)” or simply a “resin (HR)”) particularly when applied to liquid immersion exposure. Here, the hydrophobic resin (HR) and the resin (A) are preferably different.

Due to this, the hydrophobic resin (HR) is unevenly distributed on a film surface layer and, in a case where the liquid immersion medium is water, it is possible to improve static/dynamic contact angle of the resist film surface with respect to the water and improve the immersion liquid conformance.

In addition, particularly in a case where the exposure in the present invention is performed using EUV light, the immersion liquid conformance is basically not necessary; however, a hydrophobic resin is preferably added in expectation of effects such as adjustment of the solubility of the film and suppression of out gassing.

The hydrophobic resin (HR) is preferably designed so as to be unevenly distributed on an interface as described above; however, unlike a surfactant, it is not necessary to have a hydrophilic group in the molecule and it may not contribute to the even mixing of polar/non-polar substances.

The hydrophobic resin (HR) preferably has any one or more types of a “fluorine atom”, a “silicon atom”, and a “CH₃ partial structure which is contained in a side chain portion of a resin” from the point of view of being unevenly distributed on the film surface layer, and more preferably has two or more types.

In a case where the hydrophobic resin (HR) contains a fluorine atom and/or a silicon atom, the fluorine atom and/or the silicon atom described above in the hydrophobic resin (HR) may be included in the main chain of the resin or may be included in a side chain.

In a case where the hydrophobic resin (HR) includes a fluorine atom, a resin which has an alkyl group which has a fluorine atom, a cycloalkyl group which has a fluorine atom, or an aryl group which has a fluorine atom as the partial structure which has a fluorine atom is preferable.

The alkyl group (preferably with 1 to 10 carbon atoms and more preferably with 1 to 4 carbon atoms) which has a fluorine atom is a straight-chain or branched alkyl group in which at least one hydrogen atom is substituted with a fluorine atom and may further have a substituent group other than a fluorine atom.

The cycloalkyl group which has a fluorine atom is a monocyclic or polycyclic cycloalkyl group in which at least one hydrogen atom is substituted with a fluorine atom and may further have a substituent group other than a fluorine atom.

Examples of the aryl group which has a fluorine atom include an aryl group such as a phenyl group and a naphthyl group in which at least one hydrogen atom is substituted with a fluorine atom, and the aryl group may further have a substituent group other than a fluorine atom.

Examples of the alkyl group which has a fluorine atom, the cycloalkyl group which has a fluorine atom, and the aryl group which has a fluorine atom preferably include groups which are represented by General Formulas (F2) to (F4) below; however, the present invention is not limited thereto.

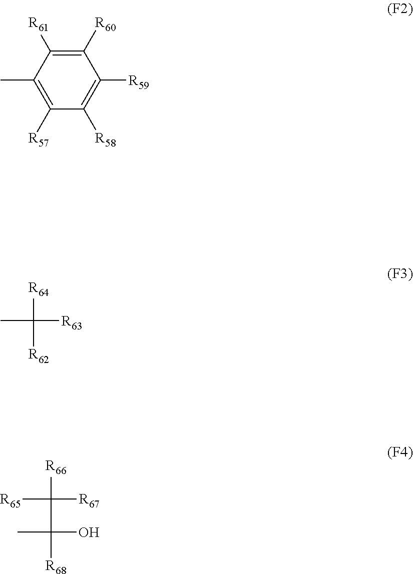

In General Formulas (F2) to (F4),

R₅₇ to R₆₈ each independently represent a hydrogen atom, a fluorine atom, or an alkyl group (straight-chain or branched). Here, at least one of R₅₇ to R₆₁ at least one of R₆₂ to R₆₄, and at least one of R₆₅ to R₆₈ each independently represent a fluorine atom or an alkyl group (preferably with 1 to 4 carbon atoms) where at least one hydrogen atom is substituted with a fluorine atom.

R₅₇ to R₆₁ and R₆₅ to R₆₇ are preferably all fluorine atoms. R₆₂, R₆₃, and R₆₈ are preferably an alkyl group (preferably with 1 to 4 carbon atoms) where at least one hydrogen atom is substituted with a fluorine atom and more preferably a perfluoroalkyl group with 1 to 4 carbon atoms. R₆₂ and R₆₃ may link with each other to form a ring.

Specific examples of the group which is represented by General Formula (F2) include a p-fluorophenyl group, a pentafluorophenyl group, a 3,5-di(trifluoromethyl)phenyl group, and the like.

Specific examples of the group which is represented by General Formula (F3) include a trifluoromethyl group, a pentafluoropropyl group, a pentafluoroethyl group, a heptafluorobutyl group, a hexafluoroisopropyl group, a heptafluoroisopropyl group, a hexafluoro(2-methyl)isopropyl group, a nonafluorobutyl group, an octafluoroisobutyl group, a nonafluorohexyl group, a nonafluoro-t-butyl group, a perfluoroisopentyl group, a perfluorooctyl group, a perfluoro(trimethyl)hexyl group, a 2,2,3,3-tetrafluorocyclobutyl group, a perfluorocyclohexyl group, and the like. A hexafluoroisopropyl group, a heptafluoroisopropyl group, a hexafluoro(2-methyl)isopropyl group, an octafluoroisobutyl group, a nonafluoro-t-butyl group, and a perfluoroisopentyl are preferable, and a hexafluoroisopropyl group and a heptafluoroisopropyl group are more preferable.

Specific examples of a group which is represented by General Formula (F4) include —C(CF₃)₂OH, —C(C₂F₅)₂OH, —C(CF₃)(CH₃)OH, —CH(CF₃)OH, and the like, and —C(CF₃)₂OH is preferable.

A partial structure which includes a fluorine atom may be directly bonded with the main chain and may be further bonded with the main chain via a group selected from a group consisting of an alkylene group, a phenylene group, an ether bond, a thioether bond, a carbonyl group, an ester bond, an amide bond, a urethane bond, and a ureylene bond, or a group in which two or more of the above are combined.

Specific examples of a repeating unit which has a fluorine atom will be given below; however, the present invention is not limited thereto.

In the specific examples, X₁ represents a hydrogen atom, —CH₃, —F, or —CF₃. X₂ represents —F or —CF₃.

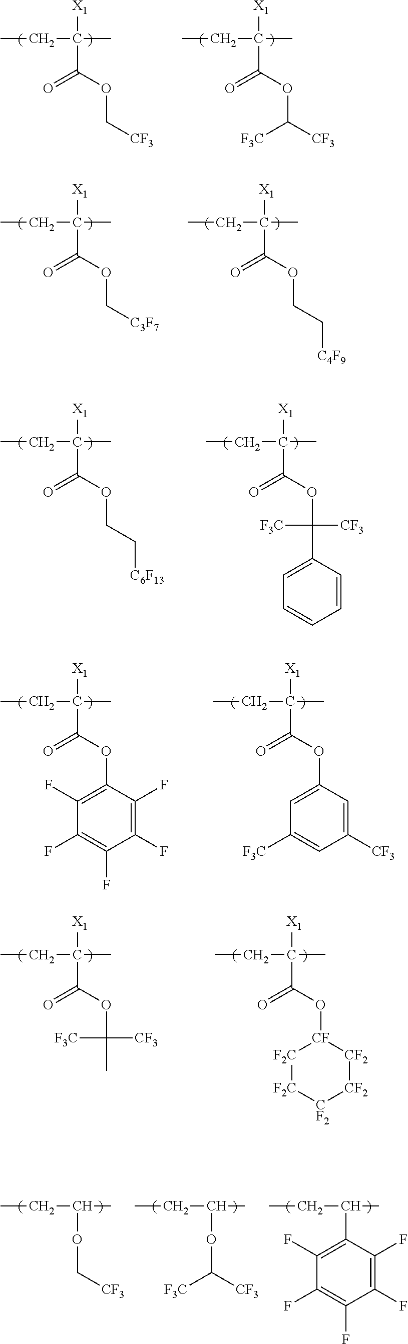

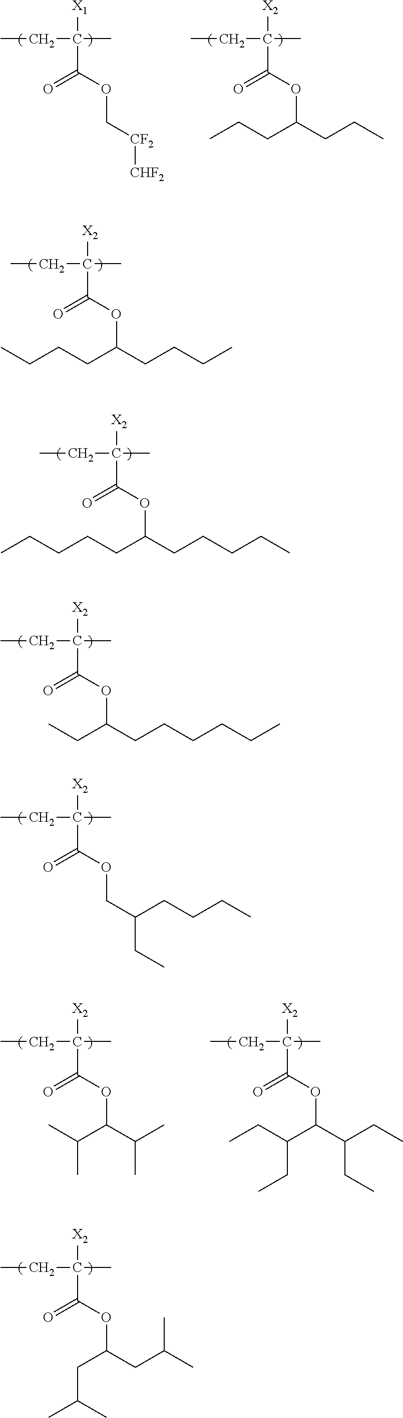

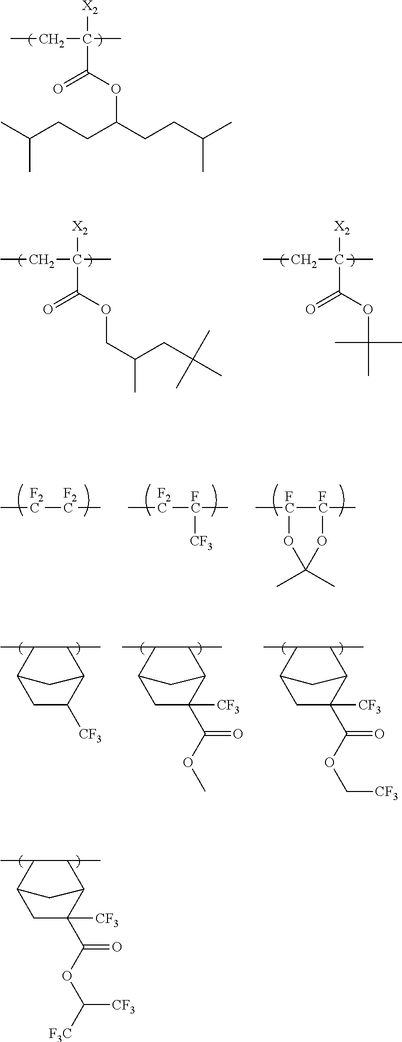

The hydrophobic resin (HR) may contain a silicon atom. A resin which has an alkylsilyl structure (preferably a trialkylsilyl group) or a cyclic siloxane structure as a partial structure which has a silicon atom is preferable.

Specific examples of the alkylsilyl structure or the cyclic siloxane structure include groups which are represented by General Formulas (CS-1) to (CS-3) below and the like.

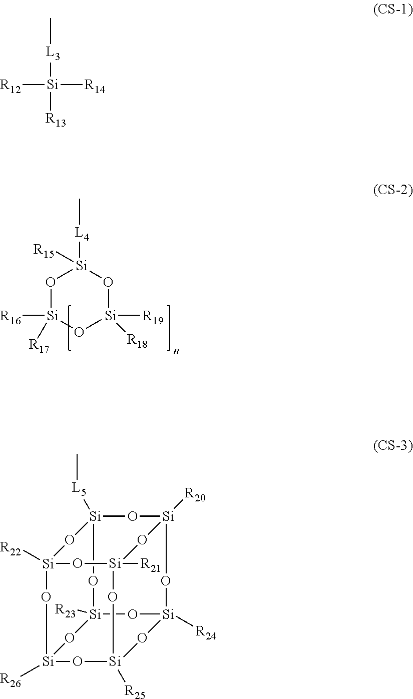

In General Formulas (CS-1) to (CS-3),

R₁₂ to R₂₆ each independently represent a straight-chain or branched alkyl group (preferably 1 to 20 carbon atoms) or a cycloalkyl group (preferably 3 to 20 carbon atoms).

L₃ to L₅ represent a single bond or a divalent linking group. Examples of a divalent linking group include one or a combination (the total number of carbon atoms is preferably 12 or less) of two or more, selected from a group consisting of an alkylene group, a phenylene group, an ether bond, a thioether bond, a carbonyl group, an ester bond, an amide bond, a urethane bond, and a urea bond.

n represents an integer of 1 to 5. n is preferably an integer of 2 to 4.

Specific examples of a repeating unit which has a group which is represented by General Formulas (CS-1) to (CS-3) will be given below; however, the present invention is not limited thereto. Here, in the specific examples, X₁ represents a hydrogen atom, —CH₃, —F, or —CF₃.

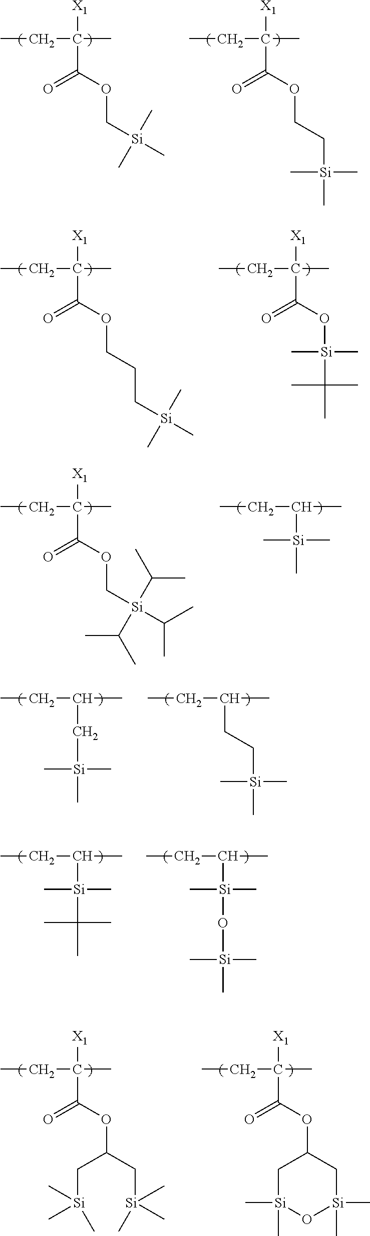

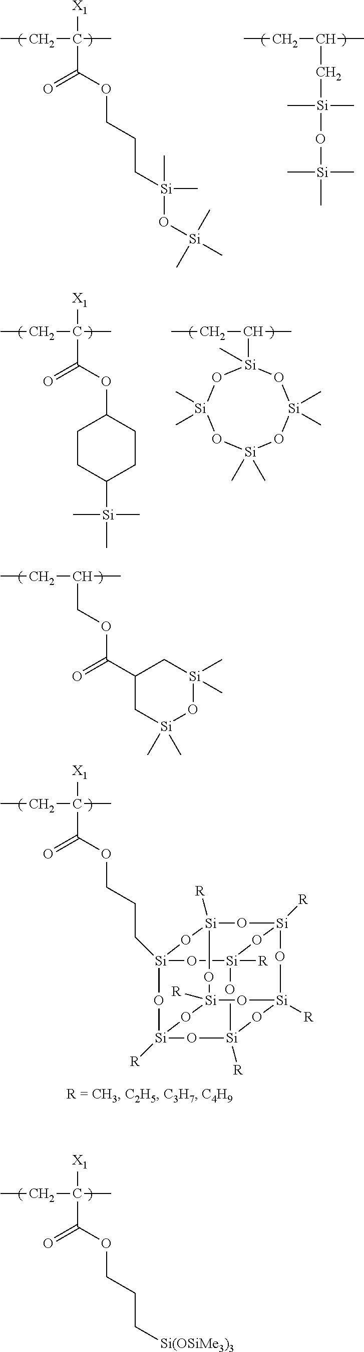

In addition, as described above, the hydrophobic resin (HR) also preferably includes a CH₃ partial structure in a side chain portion.

Here, a CH₃ partial structure of an ethyl group, a propyl group, and the like is encompassed in the CH₃ partial structure (also simply referred to below as a “side chain CH₃ partial structure”) of the side chain portion in the resin (HR).

On the other hand, a methyl group which is directly bonded with the main chain of the resin (HR) (for example, an α-methyl group of a repeating unit which has a methacrylic acid structure) is not encompassed in the CH₃ partial structure in the present invention since the contribution to the surface uneven distribution of the resin (HR) is small due to the influence of the main chain.

In more detail, for example, in a case where R₁₁ to R₁₄ are CH₃ “itself”, which is a case where the resin (HR) includes a repeating unit which is derived from a monomer which has a polymerizable site which has a carbon-carbon double bond such as the repeating unit which is represented by General Formula (M) below, the CH₃ is not encompassed in the CH₃ partial structure of the side chain portion in the present invention.

On the other hand, a CH₃ partial structure which is present via a certain atom from a C—C main chain corresponds to the CH₃ partial structure in the present invention. For example, in a case where R₁₁ is an ethyl group (CH₂CH₃), the resin (HR) has “one” CH₃ partial structure in the present invention.

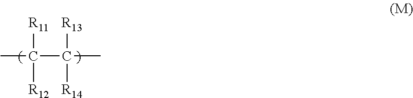

In General Formula (M) described above,

R₁₁ to R₁₄ each independently represent a side chain portion.

Examples of R₁₁ to R₁₄ of the side chain portion include a hydrogen atom, a monovalent organic group, and the like.

Examples of the monovalent organic group regarding R₁₁ to R₁₄ include an alkyl group, a cycloalkyl group, an aryl group, an alkyloxycarbonyl group, a cycloalkyloxycarbonyl group, an aryloxycarbonyl group, an alkylaminocarbonyl group, a cycloalkylaminocarbonyl group, an arylaminocarbonyl group, and the like, and the groups may further have a substituent group.

The hydrophobic resin (HR) is preferably a resin which has a repeating unit which has a CH₃ partial structure in a side chain portion and more preferably has at least one type of repeating unit (x) out of a repeating unit which is represented by General Formula (II) below and a repeating unit which is represented by General Formula (V) below as the repeating unit.

Detailed description will be given below of the repeating unit which is represented by General Formula (II).

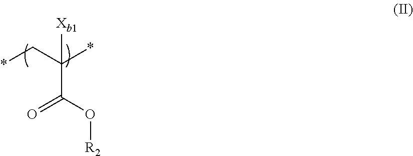

In General Formula (11) described above, X_{b1} represents a hydrogen atom, an alkyl group, a cyano group, and a halogen atom and R₂ represents an organic group which has one or more CH₃ partial structures and which is stable with respect to an acid. Here, in more detail, the organic group which is stable with respect to an acid is preferably an organic group which does not have the “group which generates a polar group by being decomposed by the action of an acid” described in the resin (A).

The alkyl group of X_{b1} is preferably with 1 to 4 carbon atoms and examples thereof include a methyl group, an ethyl group, a propyl group, a hydroxymethyl group, a trifluoromethyl group, and the like; however, a methyl group is preferable.

X_{b1} is preferably a hydrogen atom or a methyl group.

Examples of R₂ include an alkyl group, a cycloalkyl group, an alkenyl group, a cycloalkenyl group, an aryl group, and an aralkyl group which have one or more CH₃ partial structures. The cycloalkyl group, the alkenyl group, the cycloalkenyl group, the aryl group, and the aralkyl group described above may further have an alkyl group as a substituent group.

R₂ is preferably an alkyl group or an alkyl-substituted cycloalkyl group which has one or more CH₃ partial structures.

The organic group as R₂ which has one or more CH₃ partial structure and which is stable in an acid preferably has 2 to 10 CH₃ partial structures and more preferably has 2 to 8 CH₃ partial structures.

An alkyl group in R₂ which has one or more CH₃ partial structures is preferably a branched alkyl group with 3 to 20 carbon atoms.

A cycloalkyl group in R₂ which has one or more CH₃ partial structures may be monocyclic or may be polycyclic. In detail, examples thereof include a group with 5 or more carbon atoms which has a monocyclo, bicyclo, tricyclo, or tetracyclo structure, and the like. The number of carbon atoms thereof is preferably 6 to 30 and the number of carbon atoms is particularly preferably 7 to 25. A norbornyl group, a cyclopentyl group, and a cyclohexyl group are preferable.

An alkenyl group in R₂ which has one or more CH₃ partial structures is preferably a straight-chain or branched alkenyl group with 1 to 20 carbon atoms and more preferably a branched alkenyl group.

An aryl group in R₂ which has one or more CH₃ partial structures is preferably an aryl group with 6 to 20 carbon atoms and examples thereof include a phenyl group and a naphthyl group, and a phenyl group is preferable.

An aralkyl group in R₂ which has one or more CH₃ partial structures is preferably an aralkyl group with 7 to 12 carbon atoms and examples thereof include a benzyl group, a phenethyl group, a naphthylmethyl group, and the like.

Specific examples of a hydrocarbon group which has two or more CH₃ partial structures in R₂ include an isobutyl group, a t-butyl group, a 2-methyl-3-butyl group, a 2,3-dimethyl-2-butyl group, a 2-methyl-3-pentyl group, a 3-methyl-4-hexyl group, a 3,5-dimethyl-4-pentyl group, 2,4,4-trimethylpentyl group, a 2-ethylhexyl group, 2,6-dimethylheptyl group, a 1,5-dimethyl-3-heptyl group, a 2,3,5,7-tetramethyl-4-heptyl group, a 3,5-dimethylcyclohexyl group, a 3,5-ditert-butylcyclohexyl group, a 4-isopropylcyclohexyl group, a 4-t-butylcyclohexyl group, and an isobornyl group.

Preferable specific examples of the repeating unit which is represented by General Formula (II) will be given below. Here, the present invention is not limited to the following.

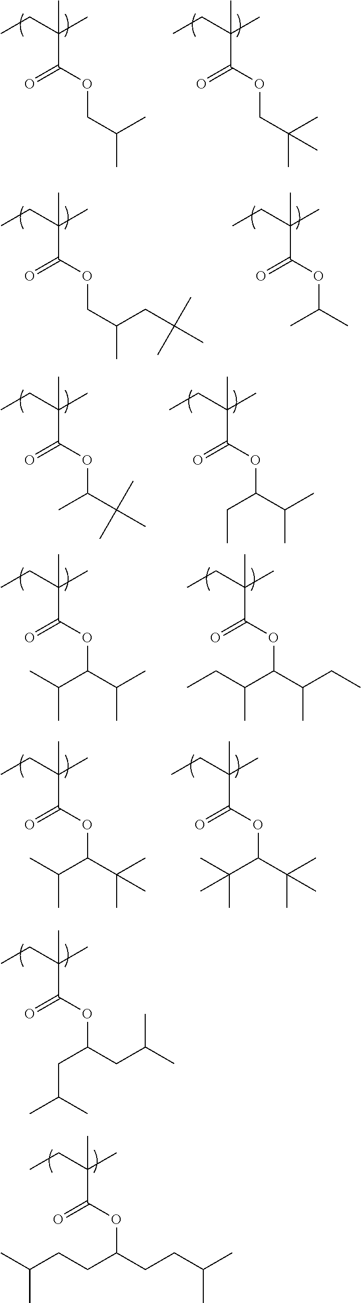

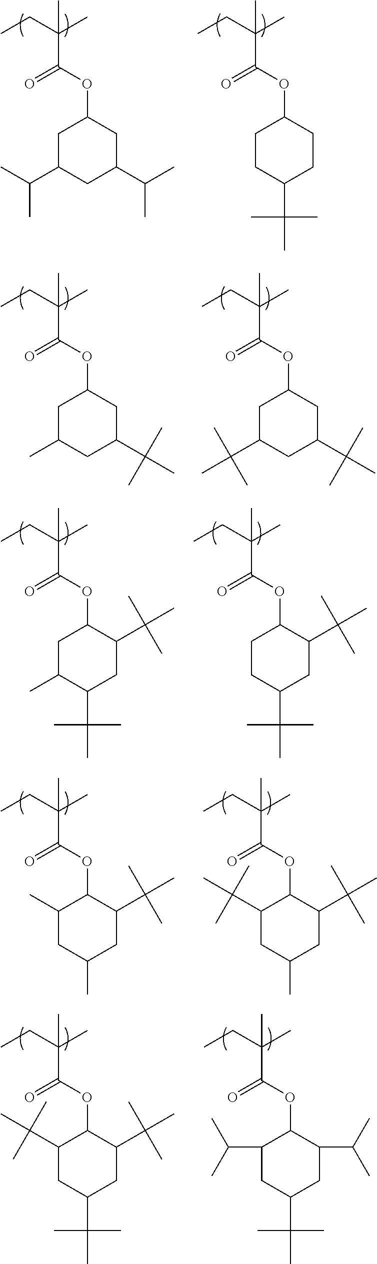

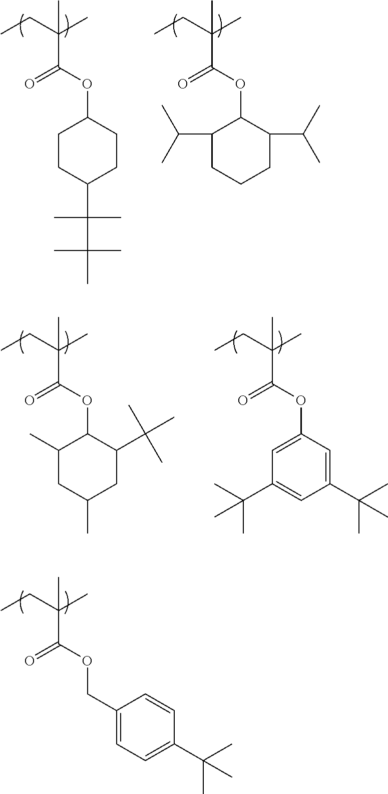

The repeating unit which is represented by General Formula (II) is preferably an (acid non-decomposable) repeating unit which is stable in an acid and specifically preferably a repeating unit which does not have a group which generates a polar group by being decomposed by the action of an acid.

Detailed description will be given below of the repeating unit which is represented by General Formula (V).

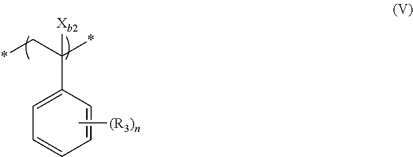

In General Formula (V) described above, X_{b2} represents a hydrogen atom, an alkyl group, a cyano group, or a halogen atom, R₃ represents an organic group which has one or more CH₃ partial structures and is stable with respect to an acid, and n represents an integer of 1 to 5.

An alkyl group of X_{b2} preferably has 1 to 4 carbon atoms and examples thereof include a methyl group, an ethyl group, a propyl group, a hydroxymethyl group, or a trifluoromethyl group; however, a hydrogen atom is preferable.

X_{b2} is preferably a hydrogen atom.

Since R₃ is an organic group which is stable with respect to an acid and, in more detail, an organic group which does not have the “group which generates a polar group by being decomposed by the action of an acid” described in the resin (A) is preferable.

Examples of R₃ include an alkyl group which has one or more CH₃ partial structures.

The organic group which has one or more CH₃ partial structures and which is stable in an acid as R₃ preferably has 1 to 10 CH₃ partial structures, more preferably 1 to 8 CH₃ partial structures, and even more preferably 1 to 4 CH₃ partial structures.

The alkyl group which has one or more CH₃ partial structures in R₃ is preferably a branched alkyl group with 3 to 20 carbon atoms.

The alkyl group which has two or more CH₃ partial structures in R₃ is specifically an isopropyl group, a t-butyl group, a 2-methyl-3-butyl group, a 2-methyl-3-pentyl group, a 3-methyl-4-hexyl group, a 3,5-dimethyl-4-pentyl group, a 2,4,4-trimethylpentyl group, a 2-ethylhexyl group, a 2,6-dimethylheptyl group, a 1,5-dimethyl-3-heptyl group, a 2,3,5,7-tetramethyl-4-heptyl group, and a 2,6-dimethylheptyl group.

n represents an integer of 1 to 5, more preferably represents an integer of 1 to 3, and even more preferably represents 1 or 2.

Preferable specific examples of the repeating unit which is represented by General Formula (V) will be given below. Here, the present invention is not limited to the following.

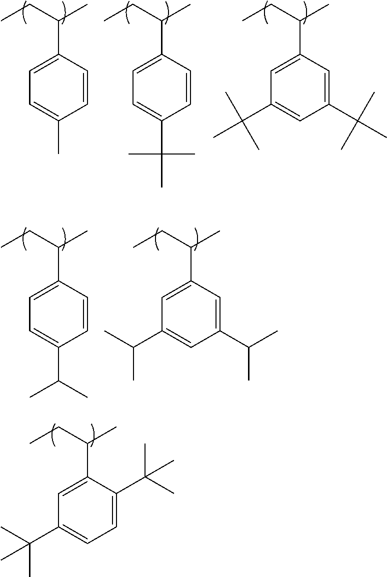

The repeating unit which is represented by General Formula (V) is preferably an (acid non-decomposable) repeating unit which is stable in an acid and specifically preferably a repeating unit which does not have a group which generates a polar group by being decomposed by the action of an acid.

In a case where the resin (HR) includes a CH₃ partial structure in the side chain portion and, particularly in a case of not having a fluorine atom or a silicon atom, the content of at least one type of repeating unit (x) out of the repeating unit which is represented by General Formula (II) and a repeating unit which is represented by General Formula (V) is preferably 90 mol % or more with respect to all of the repeating units of the resin (C), and more preferably 95 mol % or more. The content is normally 100 mol % or less with respect to all of the repeating units of the resin (C).

Due to the resin (HR) containing at least one type of repeating units (x) out of the repeating unit which is represented by General Formula (II) and the repeating unit which is represented by General Formula (V) in a proportion of 90 mol % or more with respect to all of the repeating units of the resin (HR), the surface free energy of the resin (C) increases. As a result, it is difficult for the resin (HR) to be unevenly distributed on the surface of the resist film and it is possible to reliably improve the static/dynamic contact angle of the resist film with respect to water and improve the immersion liquid conformance.

In addition, (i) even in a case of including a fluorine atom and/or a silicon atom or (ii) even in a case of including a CH₃ partial structure in a side chain portion, the hydrophobic resin (HR) may have at least one group selected from a group of (x) to (z) below:

(x) acid group;

(y) group which has a lactone structure, an acid anhydride group, or an acid imide group; and

(z) group which is decomposed by the action of an acid.

Examples of the acid group (x) include a phenolic hydroxyl group, a carboxylic acid group, a fluorinated alcohol group, a sulfonic acid group, a sulfonamide group, a sulfonylimide group, an (alkylsulfonyl) (alkylcarbonyl) methylene group, an (alkylsulfonyl) (alkylcarbonyl) imide group, a bis(alkylcarbonyl) methylene group, a bis(alkylcarbonyl) imide group, a bis(alkylsulfonyl) methylene group, a bis(alkylsulfonyl) imide group, a tris(alkylcarbonyl) methylene group, a tris(alkylsulfonyl) methylene group, and the like.

Examples of a preferable acid group include a fluorinated alcohol group (preferably hexafluoroisopropanol), a sulfonimide group, and a bis(alkylcarbonyl) methylene group.

Examples of a repeating unit which has an acid group (x) include a repeating unit in which an acid group is directly bonded with the main chain of a resin such as a repeating unit using an acrylic acid and a methacrylic acid, or a repeating unit in which an acid group is bonded with the main chain of a resin via a linking group and, it is also possible to use a polymerization initiator or a chain transfer agent which has an acid group during the polymerization to introduce the repeating unit to the end of a polymer chain, and either case is preferable. A repeating unit which has an acid group (x) may have at least one of a fluorine atom and a silicon atom.

The content of the repeating units which have an acid group (x) is preferably 1 mol % to 50 mol %, more preferably 3 mol % to 35 mol %, and even more preferably 5 mol % to 20 mol % with respect to all of the repeating units in the hydrophobic resin (HR).

Specific examples of the repeating unit which has an acid group (x) will be given below; however, the present invention is not limited thereto. In the formulas, Rx represents a hydrogen atom, CH₃, CF₃, or CH₂OH.

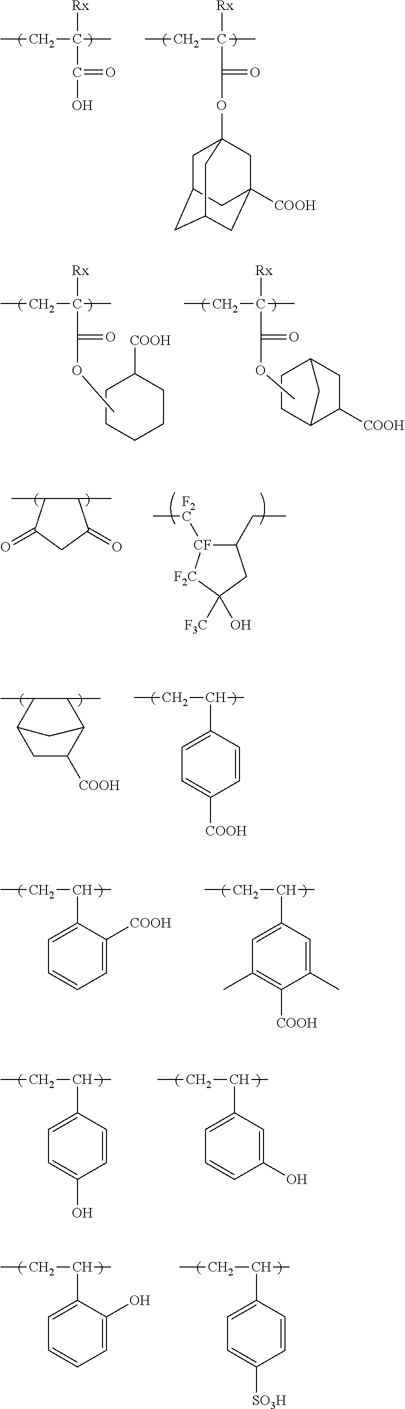

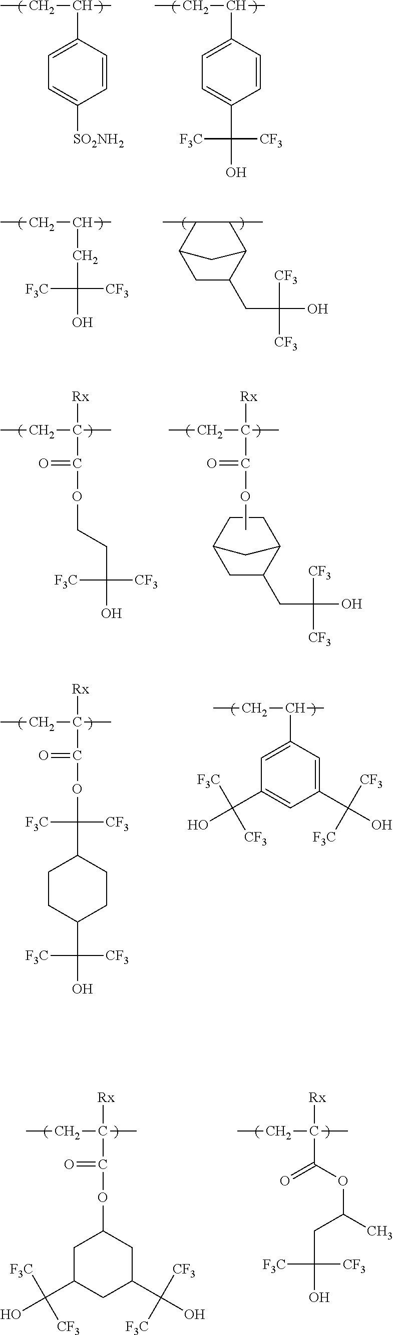

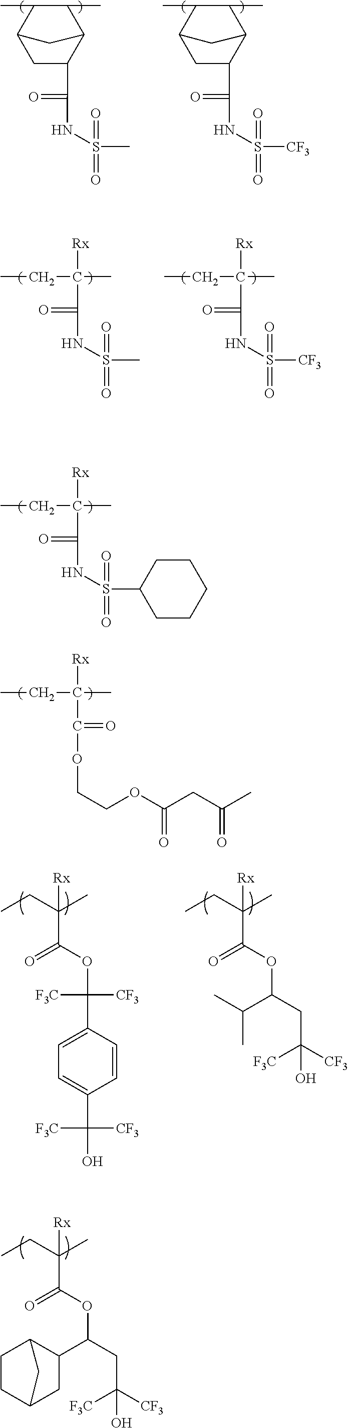

As a group which has a lactone structure, an acid anhydride group, or an acid imide group (y), a group which has a lactone structure is particularly preferable.

The repeating unit which includes these groups is, for example, a repeating unit in which the groups are directly bonded with the main chain of a resin such as a repeating unit using acrylic acid ester and methacrylic acid ester. Alternatively, the repeating unit may be a repeating unit in which the groups are bonded with the main chain of a resin via a linking group. Alternatively, the repeating unit may be introduced to the end of the resin using a polymerization initiator or a chain transfer agent which has these groups during polymerization.

Examples of a repeating unit which has a group which has a lactone structure include the same examples as for the repeating unit which has the lactone structure which was previously described in the section of the acid-decomposable resin (A).

The content of the repeating units which have a group which has a lactone structure, an acid anhydride group, or an acid imide group is preferably 1 mol % to 100 mol %, more preferably 3 mol % to 98 mol %, and even more preferably 5 mol % to 95 mol % on the basis of all of the repeating units in the hydrophobic resin (HR).

Examples of a repeating unit which has a group (z) which is decomposed by the action of an acid in the hydrophobic resin (HR) include the same examples as for the repeating units which have an acid-decomposable group which were exemplified for the resin (A). The repeating unit which has a group (z) which is decomposed by the action of an acid may have at least one of a fluorine atom and a silicon atom. The content of the repeating units which have a group (z) which is decomposed by the action of an acid in the hydrophobic resin (HR) is preferably 1 mol % to 80 mol %, more preferably 10 mol % to 80 mol %, and even more preferably 20 mol % to 60 mol % with respect to all of the repeating units in the resin (HR).

The hydrophobic resin (HR) may further have a repeating unit which is represented by General Formula (VI) below.

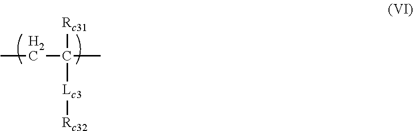

In General Formula (VI),

R_{c31} represents a hydrogen atom, an alkyl group (which may be substituted with a fluorine atom and the like), a cyano group, or a —CH₂—O-Rac₂ group. In the formula, Rac₂ represents a hydrogen atom, an alkyl group, or an acyl group. R_{c31} is preferably a hydrogen atom, a methyl group, a hydroxymethyl group, or a trifluoromethyl group, and particularly preferably a hydrogen atom or a methyl group.

R_{c32} represents an alkyl group, a cycloalkyl group, an alkenyl group, a cycloalkenyl group, or a group which has an aryl group. These groups may be substituted with a group which has a fluorine atom or a silicon atom.

L_{c3} represents a single bond or a divalent linking group.

The alkyl group of R_{c32} in General Formula (VI) is preferably a straight-chain or branched alkyl group with 3 to 20 carbon atoms.

The cycloalkyl group is preferably a cycloalkyl group with 3 to 20 carbon atoms.

The alkenyl group is preferably an alkenyl group with 3 to 20 carbon atoms.

The cycloalkenyl group is preferably a cycloalkenyl group with 3 to 20 carbon atoms.

The aryl group is preferably an aryl group with 6 to 20 carbon atoms and more preferably a phenyl group or a naphthyl group and these groups may have a substituent group.

R_{c32} is preferably an unsubstituted alkyl group or an alkyl group which is substituted with a fluorine atom.

The divalent linking group of L_{c3} is preferably an alkylene group (preferably with 1 to 5 carbon atoms), an ether bond, a phenylene group, and an ester bond (a group which is represented by —COO—).

The content of the repeating units which are represented by General Formula (VI) is preferably 1 mol % to 100 mol %, more preferably 10 mol % to 90 mol %, and even more preferably 30 mol % to 70 mol % on the basis of all of the repeating units in the hydrophobic resin.

The hydrophobic resin (HR) also preferably further has a repeating unit which is represented by General Formula (CII-AB) below.

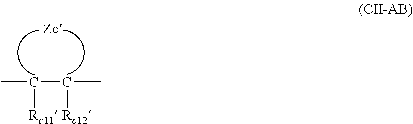

In Formula (CII-AB),

R_{c11}′ and R_{c12}′ each independently represent a hydrogen atom, a cyano group, a halogen atom, or an alkyl group.

Zc′ includes two bonded carbon atoms (C—C) and represents an atomic group for forming an alicyclic structure.

The content of the repeating units which are represented by General Formula (CII-AB) is preferably 1 mol % to 100 mol %, more preferably 10 mol % to 90 mol %, and even more preferably 30 mol % to 70 mol % on the basis of all of the repeating units in the hydrophobic resin.

Specific examples of the repeating units which are represented by General Formulas (VI) and (CII-AB) will be given below; however, the present invention is not limited thereto. In the formulas, Ra represents H, CH₃, CH₂OH, CF₃, or CN.

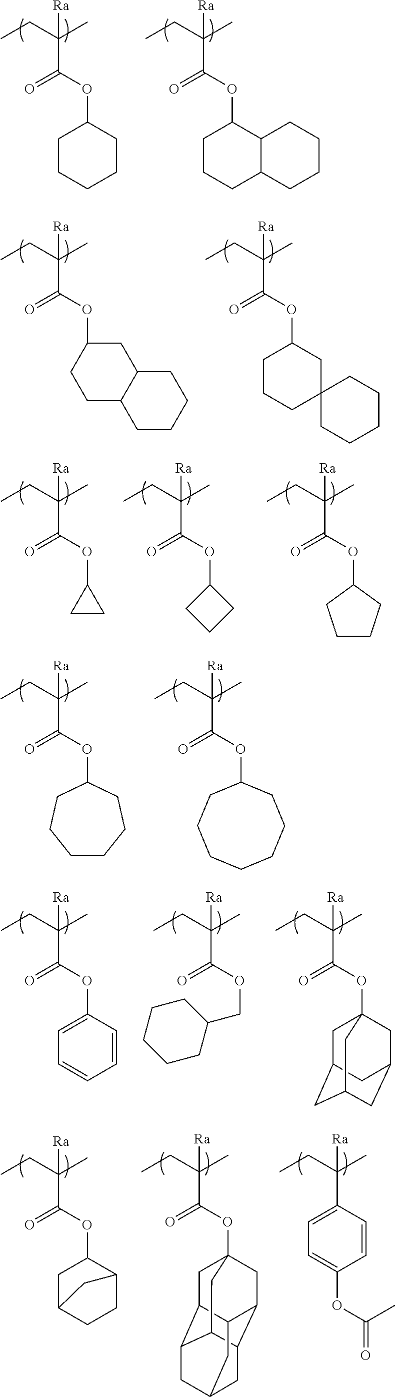

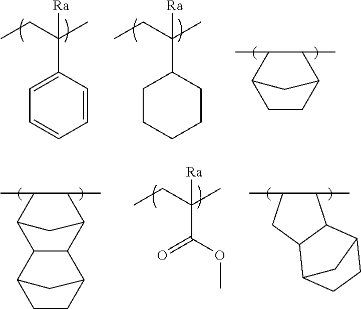

In a case where the hydrophobic resin (HR) has a fluorine atom, the content of the fluorine atoms is preferably 5 mass % to 80 mass % and more preferably 10 mass % to 80 mass % with respect to the weight average molecular weight of the hydrophobic resin (HR). In addition, the repeating units which include a fluorine atom are preferably 10 mol % to 100 mol % and more preferably 30 mol % to 100 mol % in all of the repeating units which are included in the hydrophobic resin (HR).

In a case where the hydrophobic resin (HR) has a silicon atom, the content of the silicon atoms is preferably 2 mass % to 50 mass % and more preferably 2 mass % to 30 mass % with respect to the weight average molecular weight of the hydrophobic resin (HR). In addition, the repeating units which include a silicon atom are preferably 10 mol % to 100 mol %, and more preferably 20 mol % to 100 mol % in all of the repeating units which are included in the hydrophobic resin (HR).

On the other hand, particularly in a case where the resin (HR) includes a CH₃ partial structure in a side chain portion, a form where the resin (HR) substantially does not contain a fluorine atom and a silicon atom is also preferable and, in this case, specifically, the content of the repeating units which have a fluorine atom or a silicon atom is preferably 5 mol % or less, more preferably 3 mol % or less, even more preferably 1 mol % or less, and ideally 0 mol %, that is, a fluorine atom and a silicon atom are not contained with respect to all of the repeating units in the resin (HR). In addition, the resin (HR) is preferably substantially only formed by repeating units which are only formed by atoms selected from a carbon atom, an oxygen atom, a hydrogen atom, a nitrogen atom, and a sulfur atom. In more detail, repeating units which are only formed by atoms selected from a carbon atom, an oxygen atom, a hydrogen atom, a nitrogen atom, and a sulfur atom are preferably 95 mol % or more, more preferably 97 mol % or more, even more preferably 99 mol % or more, and ideally 100 mol % in all of the repeating units of the resin (HR).

The weight average molecular weight of the hydrophobic resin (HR) in standard polystyrene conversion is preferably 1000 to 100000, more preferably 1000 to 50000, and even more preferably 2000 to 15000.

In addition, the hydrophobic resin (HR) may be used as one type or a plurality thereof may be used together.

The content of the hydrophobic resin (HR) in the composition is preferably 0.01 mass % to 10 mass %, more preferably 0.05 mass % to 8 mass %, and even more preferably 0.1 mass % to 7 mass % with respect to the total solid content in the composition of the present invention.

While the hydrophobic resin (HR) naturally has few impurities such as metals in the same manner as the resin (A), the content of the residual monomers or oligomer components are preferably 0.01 mass % to 5 mass %, more preferably 0.01 mass % to 3 mass %, and even more preferably 0.05 mass % to 1 mass %. Due to this, it is possible to obtain an actinic ray-sensitive or radiation-sensitive resin composition where there is no foreign matter in the liquid and there is no change over time in the sensitivity or the like. In addition, from the point of view of the resolution, the resist shape, the side wall of the resist pattern, the roughness, and the like, the molecular weight distribution (Mw/Mn, also referred to as the dispersity) is preferably in a range of 1 to 5, more preferably 1 to 3, and even more preferably in a range of 1 to 2.

It is also possible to use various commercially available products as the hydrophobic resin (HR) or to synthesize the hydrophobic resin (HR) according to typical methods (for example, radical polymerization). Examples of general synthesis methods include a collective polymerization method for performing polymerization by dissolving monomers and an initiator in a solvent and heating the result, a dripping polymerization method for adding dropwise a solution of monomers and an initiator to a heated solvent over 1 hour to 10 hours, and the like, and the dripping polymerization method is preferable.

The reaction solvent, the polymerization initiator, the reaction conditions (temperature, concentration, and the like), and the purifying method after reaction are the same as in the content described for the resin (A); however, in the synthesis of the hydrophobic resin (HR), the reaction concentration is preferably 30 mass % to 50 mass %.

Specific examples of the hydrophobic resin (HR) will be given below. In addition, the molar ratio of repeating units in each resin (corresponding to each repeating unit in order from the left), the weight average molecular weight, and the dispersity will be shown in the table below.

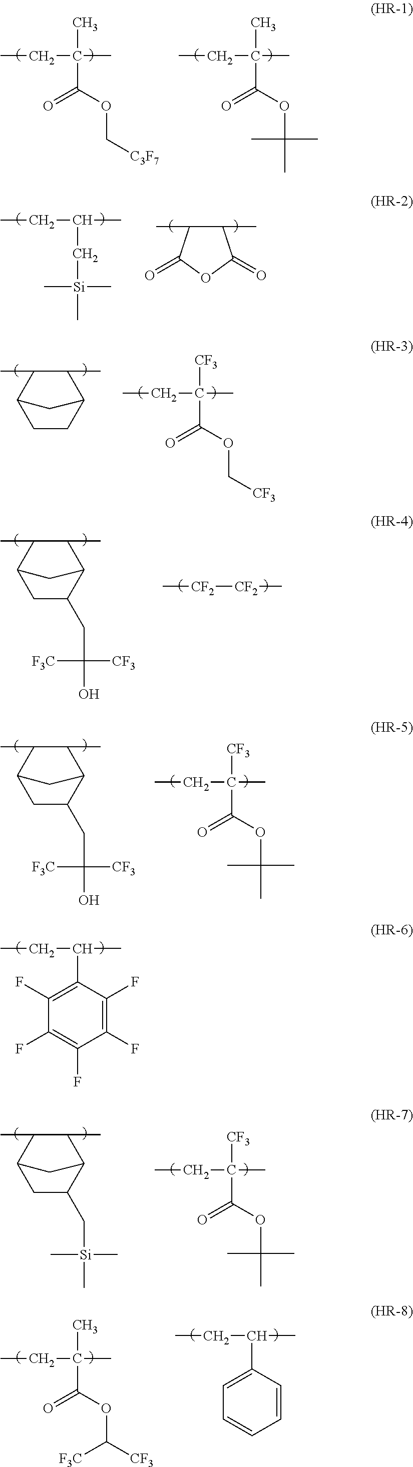

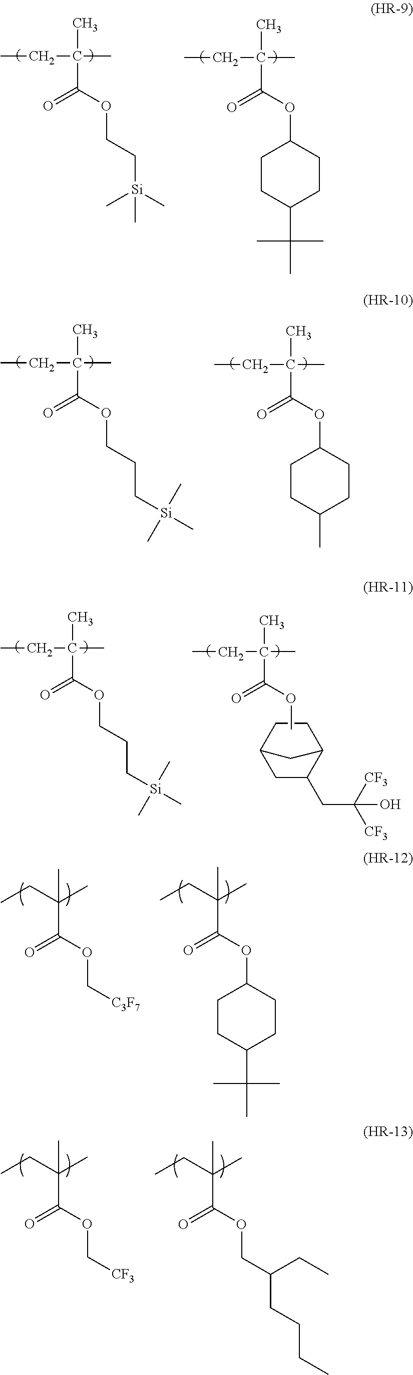

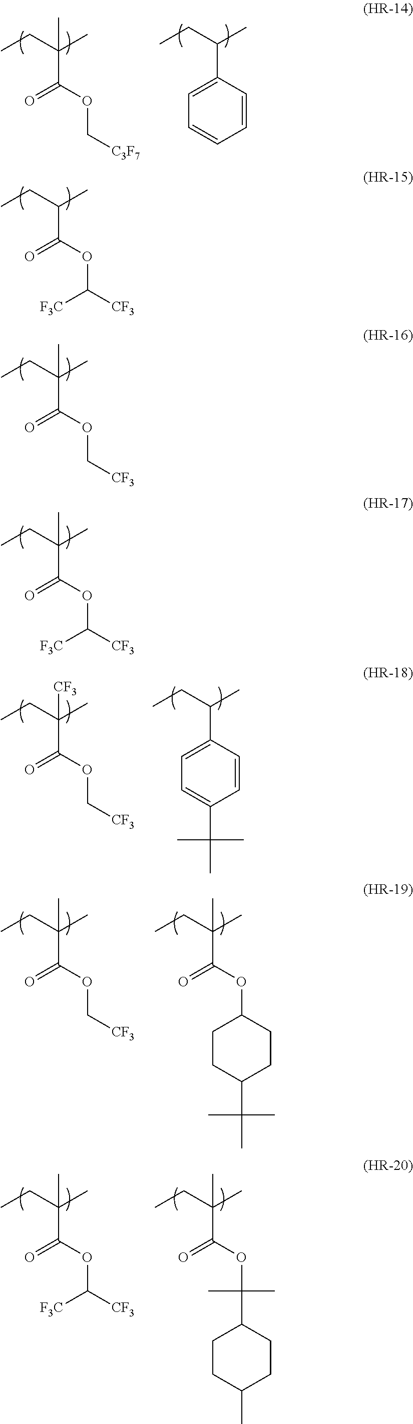

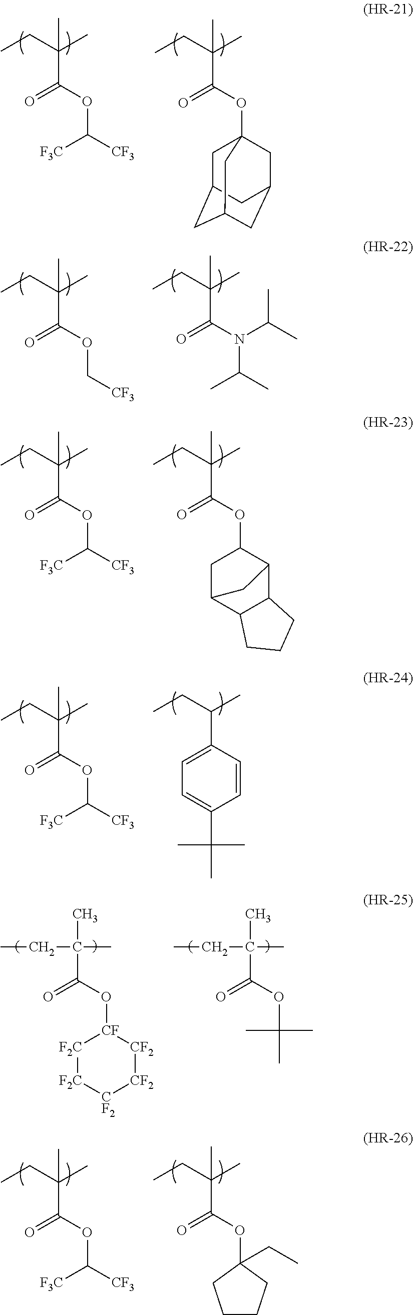

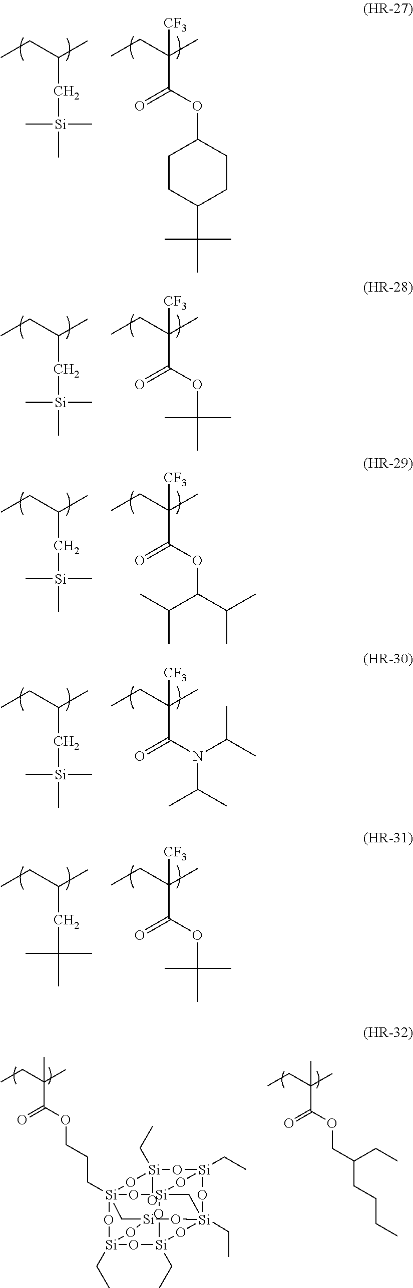

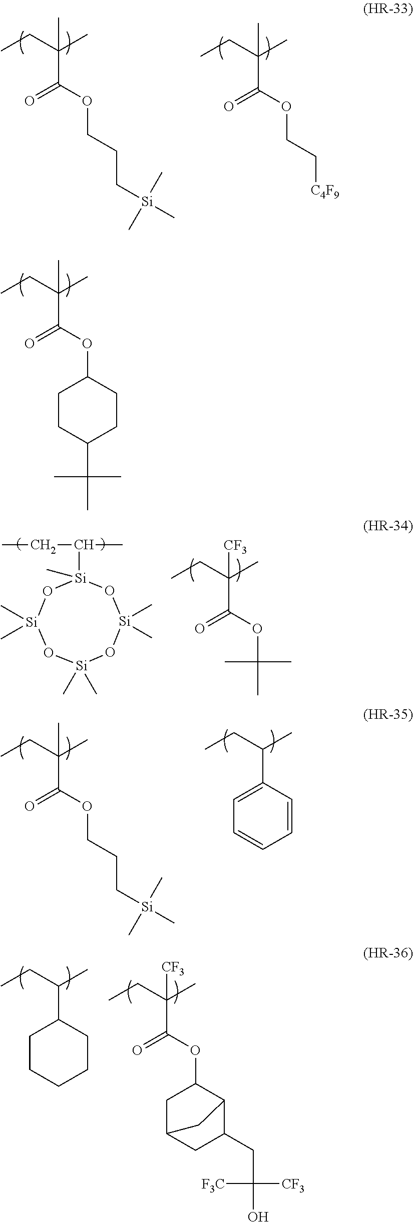

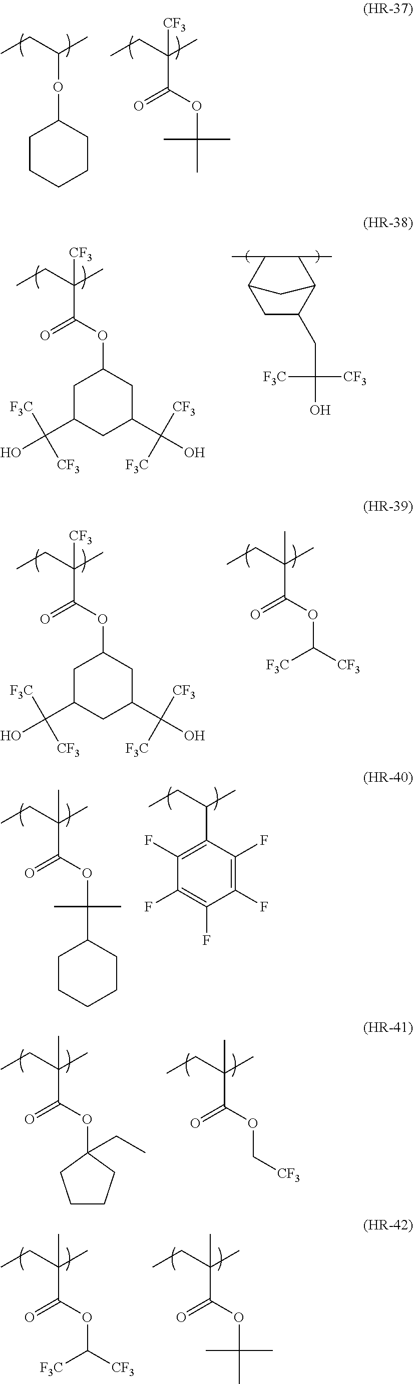

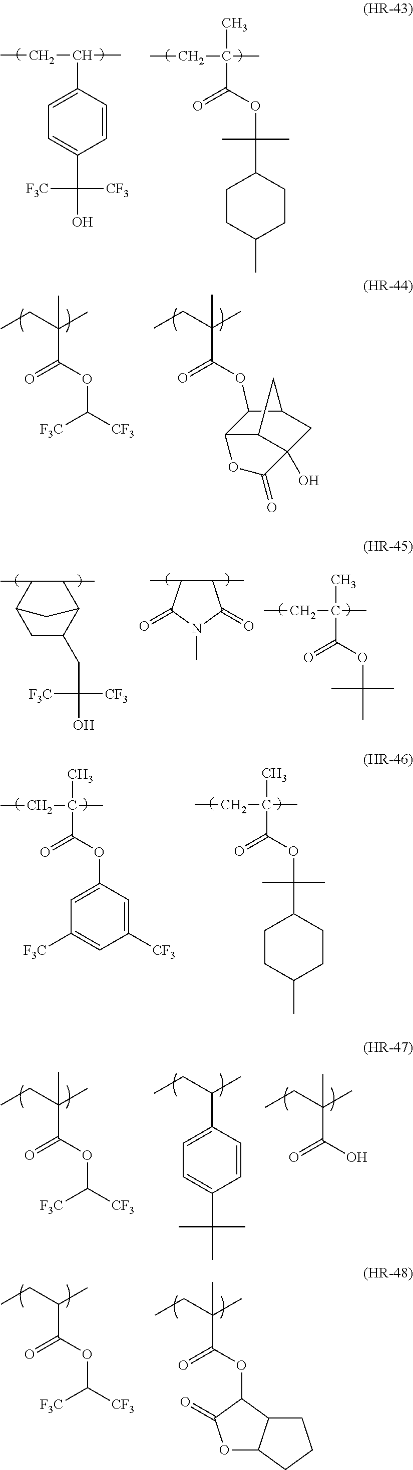

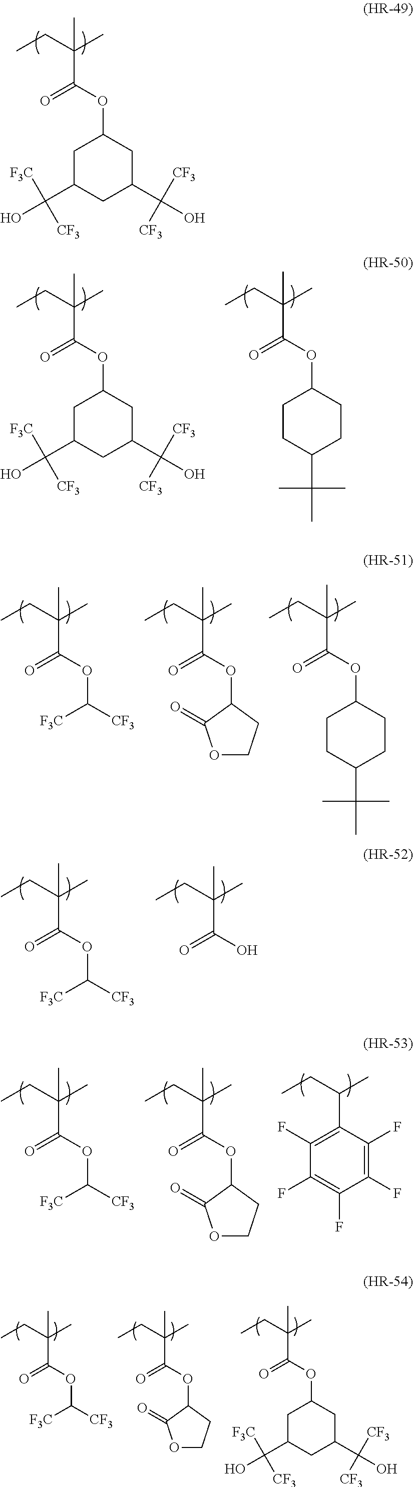

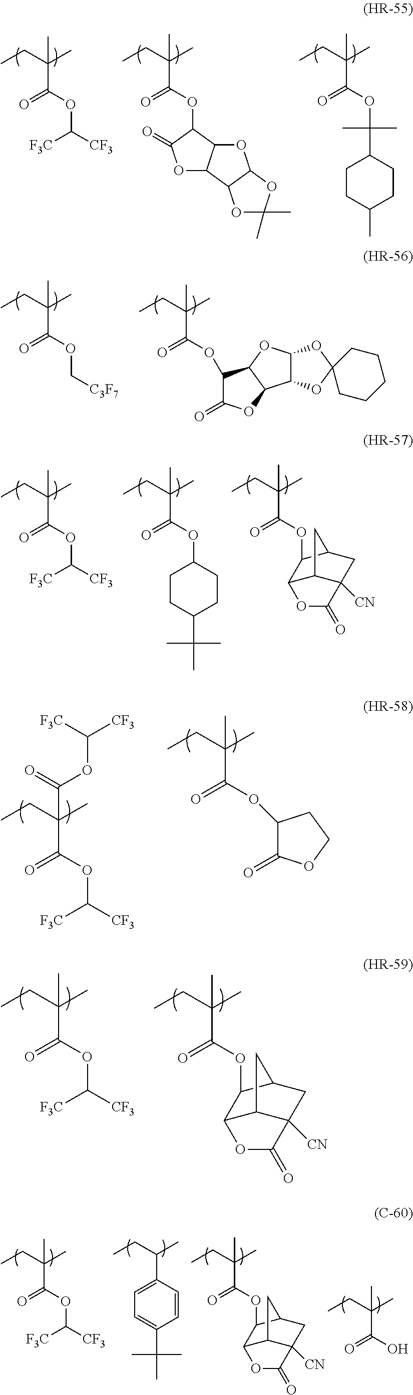

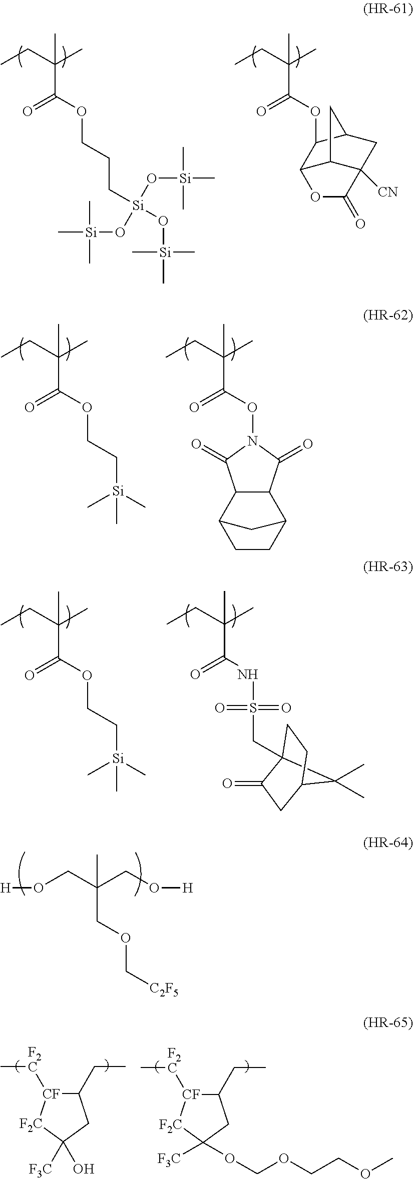

TABLE 1

| Resin | Composition | Mw | Mw/Mn |
|---|---|---|---|
| HR-1 | 50/50 | 4900 | 1.4 |
| HR-2 | 50/50 | 5100 | 1.6 |
| HR-3 | 50/50 | 4800 | 1.5 |
| HR-4 | 50/50 | 5300 | 1.6 |
| HR-5 | 50/50 | 4500 | 1.4 |
| HR-6 | 100 | 5500 | 1.6 |
| HR-7 | 50/50 | 5800 | 1.9 |
| HR-8 | 50/50 | 4200 | 1.3 |
| HR-9 | 50/50 | 5500 | 1.8 |
| HR-10 | 40/60 | 7500 | 1.6 |
| HR-11 | 70/30 | 6600 | 1.8 |
| HR-12 | 40/60 | 3900 | 1.3 |
| HR-13 | 50/50 | 9500 | 1.8 |
| HR-14 | 50/50 | 5300 | 1.6 |
| HR-15 | 100 | 6200 | 1.2 |
| HR-16 | 100 | 5600 | 1.6 |
| HR-17 | 100 | 4400 | 1.3 |
| HR-18 | 50/50 | 4300 | 1.3 |
| HR-19 | 50/50 | 6500 | 1.6 |
| HR-20 | 30/70 | 6500 | 1.5 |
| HR-21 | 50/50 | 6000 | 1.6 |
| HR-22 | 50/50 | 3000 | 1.2 |
| HR-23 | 50/50 | 5000 | 1.5 |
| HR-24 | 50/50 | 4500 | 1.4 |
| HR-25 | 30/70 | 5000 | 1.4 |
| HR-26 | 50/50 | 5500 | 1.6 |
| HR-27 | 50/50 | 3500 | 1.3 |
| HR-28 | 50/50 | 6200 | 1.4 |
| HR-29 | 50/50 | 6500 | 1.6 |
| HR-30 | 50/50 | 6500 | 1.6 |
| HR-31 | 50/50 | 4500 | 1.4 |
| HR-32 | 30/70 | 5000 | 1.6 |
| HR-33 | 30/30/40 | 6500 | 1.8 |
| HR-34 | 50/50 | 4000 | 1.3 |
| HR-35 | 50/50 | 6500 | 1.7 |
| HR-36 | 50/50 | 6000 | 1.5 |
| HR-37 | 50/50 | 5000 | 1.6 |
| HR-38 | 50/50 | 4000 | 1.4 |
| HR-39 | 20/80 | 6000 | 1.4 |
| HR-40 | 50/50 | 7000 | 1.4 |
| HR-41 | 50/50 | 6500 | 1.6 |
| HR-42 | 50/50 | 5200 | 1.6 |
| HR-43 | 50/50 | 6000 | 1.4 |
| HR-44 | 70/30 | 5500 | 1.6 |
| HR-45 | 50/20/30 | 4200 | 1.4 |
| HR-46 | 30/70 | 7500 | 1.6 |
| HR-47 | 40/58/2 | 4300 | 1.4 |
| HR-48 | 50/50 | 6800 | 1.6 |
| HR-49 | 100 | 6500 | 1.5 |
| HR-50 | 50/50 | 6600 | 1.6 |
| HR-51 | 30/20/50 | 6800 | 1.7 |
| HR-52 | 95/5 | 5900 | 1.6 |
| HR-53 | 40/30/30 | 4500 | 1.3 |
| HR-54 | 50/30/20 | 6500 | 1.8 |
| HR-55 | 30/40/30 | 7000 | 1.5 |
| HR-56 | 60/40 | 5500 | 1.7 |
| HR-57 | 40/40/20 | 4000 | 1.3 |
| HR-58 | 60/40 | 3800 | 1.4 |
| HR-59 | 80/20 | 7400 | 1.6 |
| HR-60 | 40/40/15/5 | 4800 | 1.5 |
| HR-61 | 60/40 | 5600 | 1.5 |
| HR-62 | 50/50 | 5900 | 2.1 |
| HR-63 | 80/20 | 7000 | 1.7 |
| HR-64 | 100 | 5500 | 1.8 |
| HR-65 | 50/50 | 9500 | 1.9 |

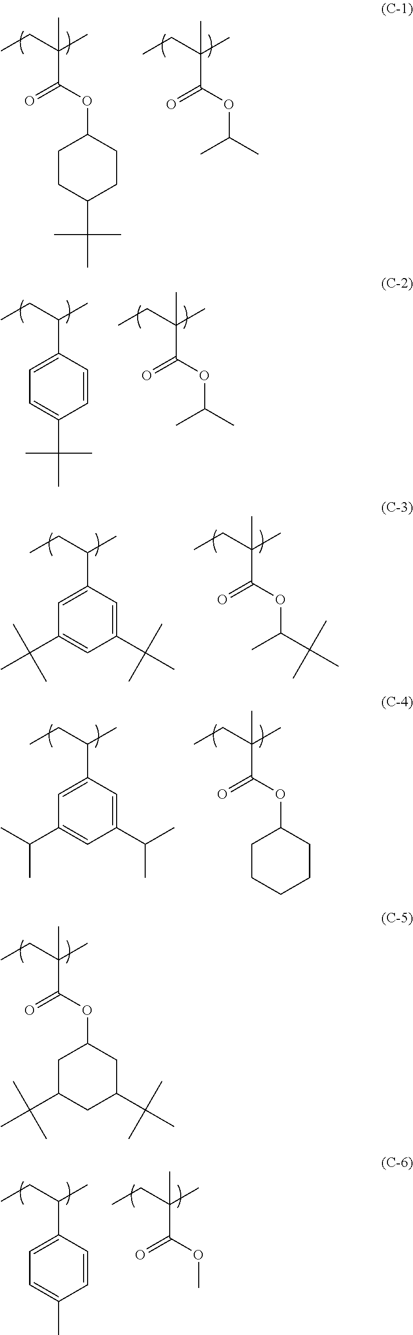

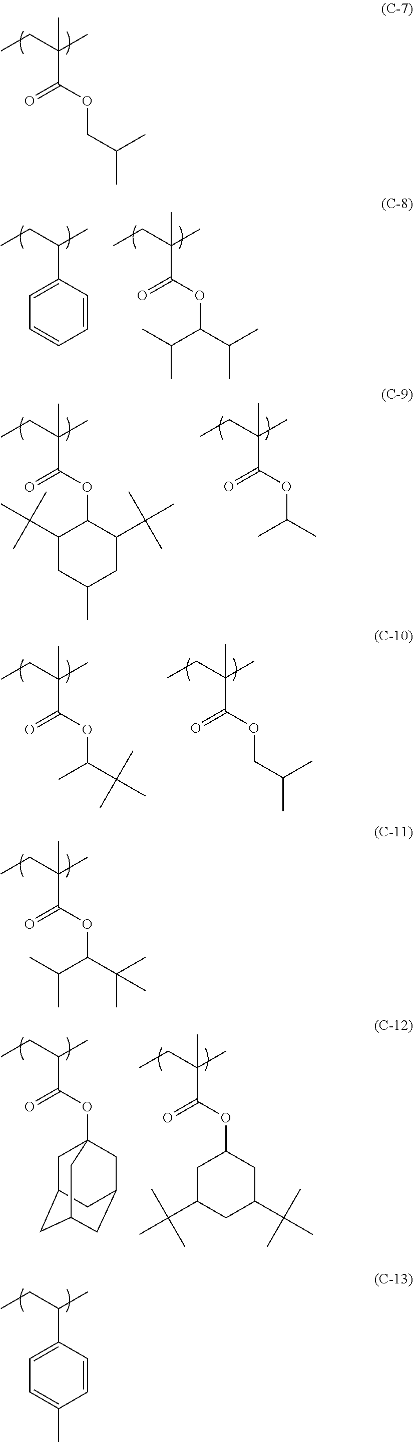

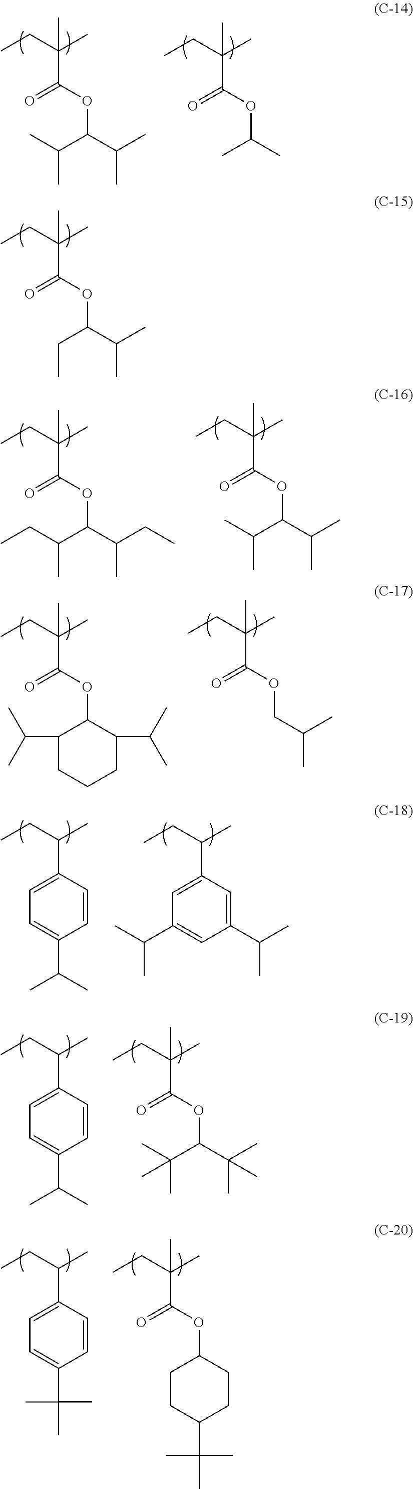

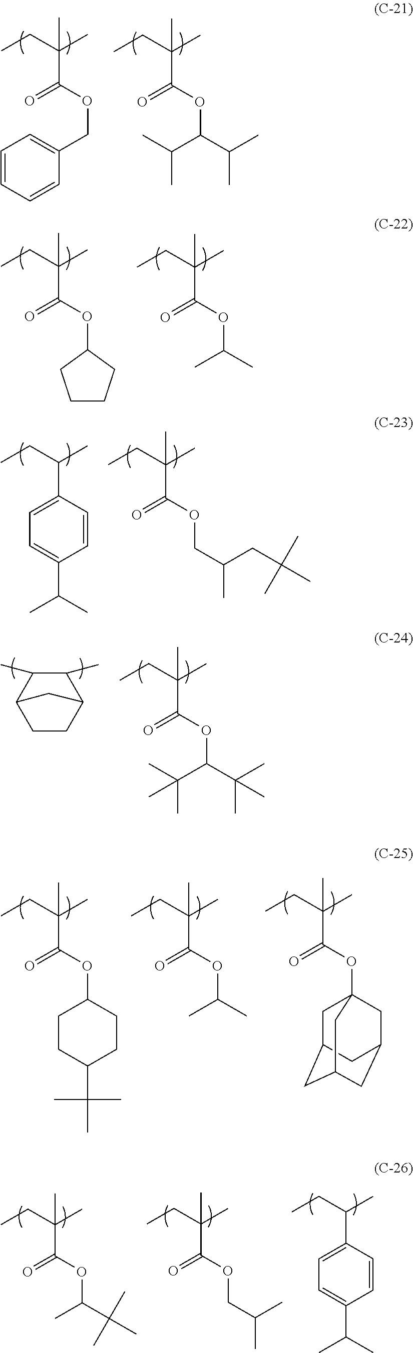

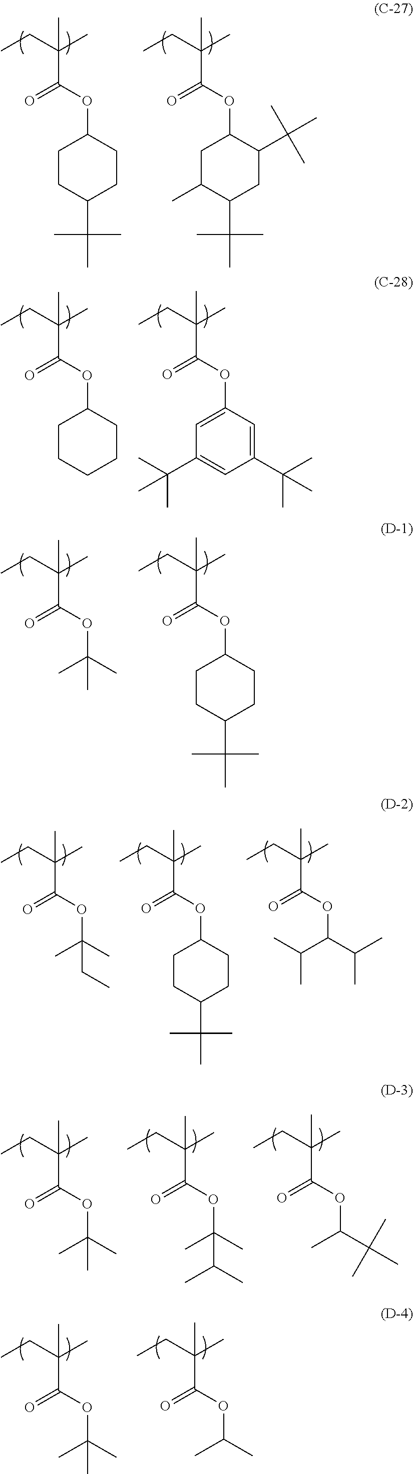

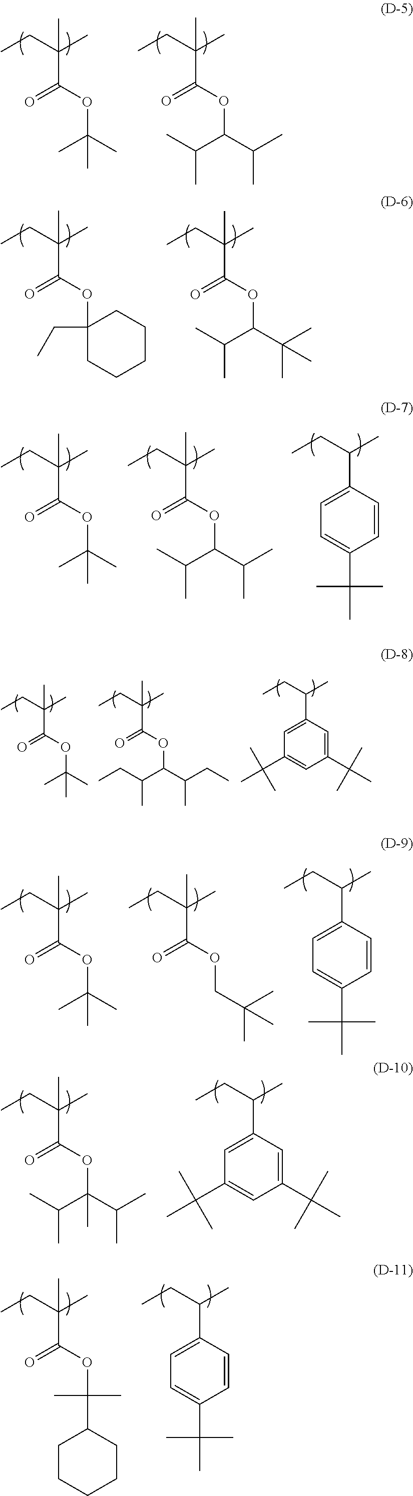

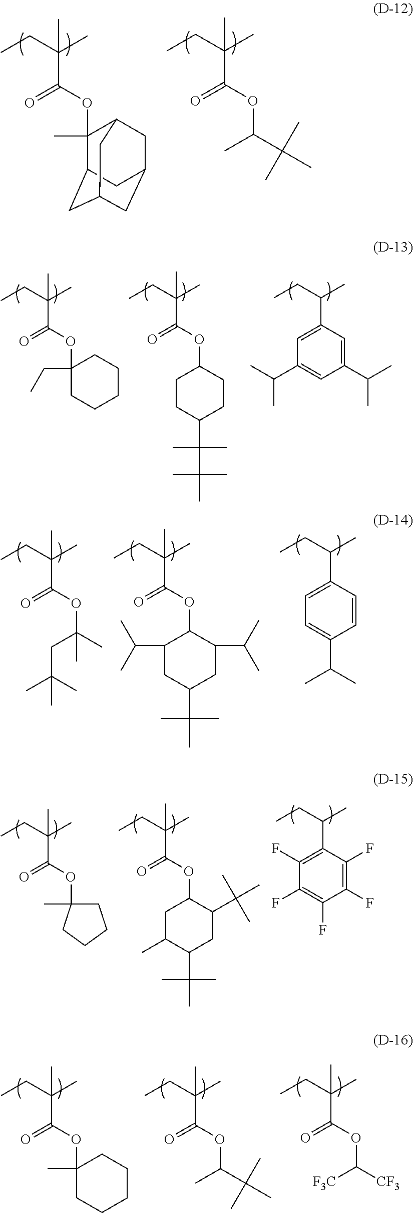

TABLE 2

| Resin | Composition | Mw | Mw/Mn |
|---|---|---|---|
| C-1 | 50/50 | 9600 | 1.74 |
| C-2 | 60/40 | 34500 | 1.43 |
| C-3 | 30/70 | 19300 | 1.69 |
| C-4 | 90/10 | 26400 | 1.41 |
| C-5 | 100 | 27600 | 1.87 |
| C-6 | 80/20 | 4400 | 1.96 |
| C-7 | 100 | 16300 | 1.83 |
| C-8 | 5/95 | 24500 | 1.79 |
| C-9 | 20/80 | 15400 | 1.68 |
| C-10 | 50/50 | 23800 | 1.46 |
| C-11 | 100 | 22400 | 1.57 |
| C-12 | 10/90 | 21600 | 1.52 |
| C-13 | 100 | 28400 | 1.58 |
| C-14 | 50/50 | 16700 | 1.82 |
| C-15 | 100 | 23400 | 1.73 |
| C-16 | 60/40 | 18600 | 1.44 |
| C-17 | 80/20 | 12300 | 1.78 |
| C-18 | 40/60 | 18400 | 1.58 |
| C-19 | 70/30 | 12400 | 1.49 |
| C-20 | 50/50 | 23500 | 1.94 |
| C-21 | 10/90 | 7600 | 1.75 |
| C-22 | 5/95 | 14100 | 1.39 |
| C-23 | 50/50 | 17900 | 1.61 |
| C-24 | 10/90 | 24600 | 1.72 |
| C-25 | 50/40/10 | 23500 | 1.65 |
| C-26 | 60/30/10 | 13100 | 1.51 |
| C-27 | 50/50 | 21200 | 1.84 |
| C-28 | 10/90 | 19500 | 1.66 |

TABLE 3

| Resin | Composition | Mw | Mw/Mn |
|---|---|---|---|
| D-1 | 50/50 | 16500 | 1.72 |
| D-2 | 10/50/40 | 18000 | 1.77 |
| D-3 | 5/50/45 | 27100 | 1.69 |
| D-4 | 20/80 | 26500 | 1.79 |
| D-5 | 10/90 | 24700 | 1.83 |
| D-6 | 10/90 | 15700 | 1.99 |
| D-7 | 5/90/5 | 21500 | 1.92 |
| D-8 | 5/60/35 | 17700 | 2.10 |
| D-9 | 35/35/30 | 25100 | 2.02 |
| D-10 | 70/30 | 19700 | 1.85 |
| D-11 | 75/25 | 23700 | 1.80 |
| D-12 | 10/90 | 20100 | 2.02 |
| D-13 | 5/35/60 | 30100 | 2.17 |
| D-14 | 5/45/50 | 22900 | 2.02 |
| D-15 | 15/75/10 | 28600 | 1.81 |
| D-16 | 25/55/20 | 27400 | 1.87 |

[Basic Compound]

The actinic ray-sensitive or radiation-sensitive resin composition of the present invention preferably contains a basic compound in order to reduce changes in performance over time from the exposure to the heating. The usable basic compounds are not particularly limited; however, for example, it is possible to use compounds which are classified according to (1) to (6) below.

(1) Basic Compound (N)

Examples of a basic compound preferably include a compound (N) which has a structure which is indicated by Formulas (A) to (E) below.

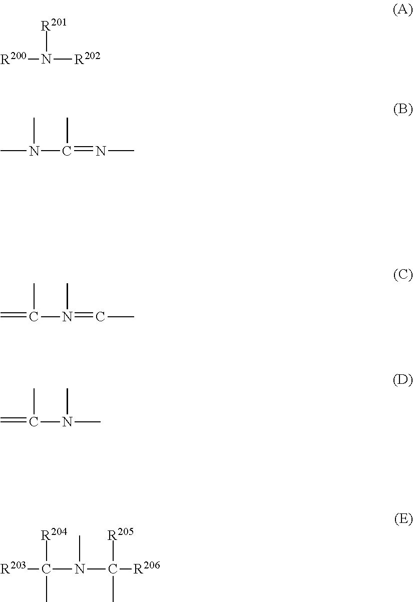

In General Formulas (A) and (E),

R²⁰⁰, R²⁰¹, and R²⁰² may be the same as or different from each other and represent a hydrogen atom, an alkyl group (preferably with 1 to 20 carbon atoms), a cycloalkyl group (preferably with 3 to 20 carbon atoms), or an aryl group (with 6 to 20 carbon atoms) and, here, R²⁰¹ and R²⁰² may bond with each other to form a ring.

R²⁰³, R²⁰⁴, R²⁰⁵, and R²⁰⁶ may be the same as or different from each other and represent an alkyl group with 1 to 20 carbon atoms.

Regarding the alkyl groups described above, the alkyl group which has a substituent group is preferably an aminoalkyl group with 1 to 20 carbon atoms, a hydroxyalkyl group with 1 to 20 carbon atoms, or a cyanoalkyl group with 1 to 20 carbon atoms.

The alkyl groups in General Formulas (A) and (E) are more preferably unsubstituted.

Examples of a preferable compound (N) include guanidine, aminopyrrolidine, pyrazole, pyrazoline, piperazine, aminomorpholine, aminoalkyl morpholine, piperidine, and the like, and examples of more preferable compounds (N) include a compound (N) which has an imidazole structure, a diazabicyclo structure, an onium hydroxide structure, an onium carboxylate structure, a trialkylamine structure, an aniline structure, or a pyridine structure, an alkylamine derivative which has a hydroxyl group and/or an ether bond, an aniline derivative which has a hydroxyl group and/or an ether bond, and the like.

Examples of a compound (N) which has an imidazole structure include imidazole, 2,4,5-triphenylimidazole, benzimidazole, 2-phenylbenzimidazole, and the like. Examples of a compound (N) which has a diazabicyclo structure include 1,4-diazabicyclo[2,2,2]octane, 1,5-diazabicyclo[4,3,0]nona-5-en, 1,8-diazabicyclo[5,4,0]undeca-7-en, and the like. Examples of a compound (N) which has an onium hydroxide structure include tetrabutyl ammonium hydroxide, triarylsulfonium hydroxide, phenacylsulfonium hydroxide, sulfonium hydroxide which has a 2-oxoalkyl group, specifically, triphenylsulfonium hydroxide, tris(t-butylphenyl) sulfonium hydroxide, bis(t-butylphenyl) iodonium hydroxide, phenacyl thiophenium hydroxide, 2-oxopropylthiophenium hydroxide, and the like. A compound (N) which has an onium carboxylate structure is a compound (N) which has an onium hydroxide structure of which an anion part is carboxylate and examples thereof include acetate, adamantane-1-carboxylate, perfluoroalkyl carboxylate, and the like. Examples of a compound (N) which has a trialkylamine structure include tri(n-butyl) amine, tri(n-octyl) amine, and the like. Examples of an aniline compound (N) include 2,6-diisopropylaniline, N,N-dimethylaniline, N,N-dibutylaniline, N,N-dihexylaniline, and the like. Examples of an alkylamine derivative which has a hydroxyl group and/or an ether bond include ethanolamine, diethanolamine, triethanolamine, N-phenyldiethanolamine, tris(methoxyethoxyethyl) amine, and the like. Examples of an aniline derivative which has a hydroxyl group and/or an ether bond include N,N-bis(hydroxyethyl) aniline, and the like.

Examples of a preferable basic compound (N) further include an amine compound which has a phenoxy group, an ammonium salt compound which has a phenoxy group, an amine compound which has a sulfonic acid ester group, and an ammonium salt compound which has a sulfonic acid ester group. Examples of the compounds include the compounds (C1-1) to (C3-3) which are exemplified in paragraph “0066” in US2007/0224539A1 and the like.

In addition, the compounds below are also preferable as the basic compound (N).

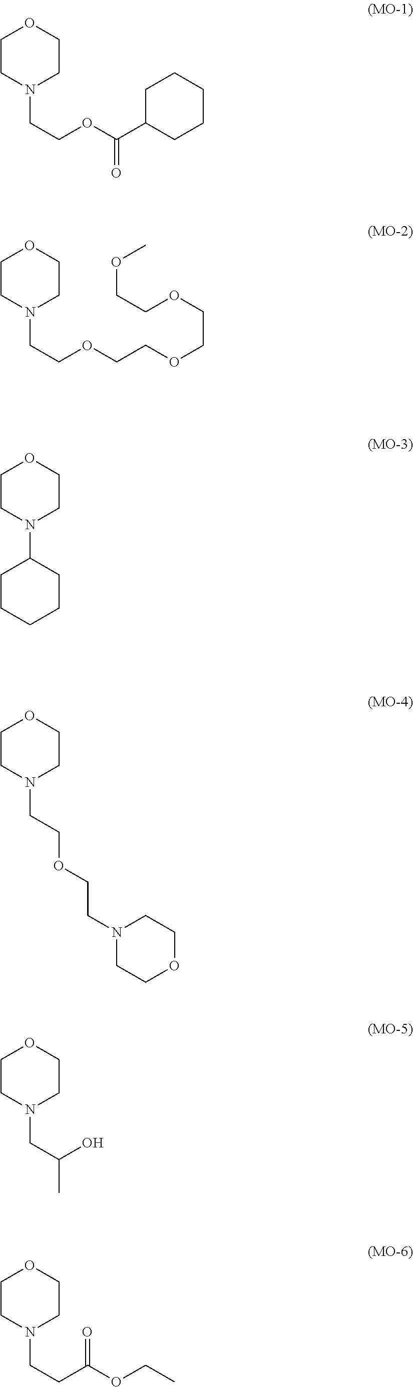

As the basic compound (N), it is also possible to use the compounds described in paragraphs “0180” to “0225” in JP2011-22560A, paragraphs “0218” to “0219” in JP2012-137735A, and paragraphs “0416” to “0438” in WO2011/158687A1 and the like other than the compounds described above. The basic compound (N) may be a basic compound or an ammonium salt compound of which the basicity decreases when irradiated with an actinic ray or radiation.

The basic compound (N) may be used as one type individually or may be used in a combination of two or more types.

The composition of the present invention may or may not contain the basic compound (N); however, in a case of being contained, the content ratio of the basic compounds (N) is normally 0.001 mass % to 10 mass % and preferably 0.01 mass % to 5 mass % on the basis of the solid content of the actinic ray-sensitive or radiation-sensitive resin composition.

The usage ratio of the acid generating agent and the basic compounds (N) in the composition is preferably acid generating agent/basic compounds (molar ratio)=2.5 to 300. That is, the molar ratio is preferably 2.5 or more in terms of the sensitivity and resolution and preferably 300 or less in terms of suppressing decreases in the resolution due to the resist pattern thickening over time until the post exposure baking. The acid generating agent/basic compounds (N) (molar ratio) is more preferably 5.0 to 200 and even more preferably 7.0 to 150.

(2) Basic Compound or Ammonium Salt Compound (F) of which the Basicity Decreases when Irradiated with an Actinic Ray or Radiation

The actinic ray-sensitive or radiation-sensitive resin composition in the present invention preferably contains a basic compound or an ammonium salt compound (also referred to below as a “compound (F)”) of which the basicity decreases when irradiated with an actinic ray or radiation.

The compound (F) is preferably a compound (F-1) which has a basic functional group or an ammonium group and a group which generates an acidic functional group when irradiated with an actinic ray or radiation. That is, the compound (F) is preferably a basic compound which has a basic functional group and a group which generates an acidic functional group when irradiated with an actinic ray or radiation or an ammonium salt compound which has an ammonium group and a group which generates an acidic functional group when irradiated with an actinic ray or radiation.

Examples of compounds which the compound (F) or (F-1) generates by being decomposed when irradiated with an actinic ray or radiation and of which the basicity is decreased include a compound which is represented by General Formula (PA-I), (PA-II), or (PA-III) below and a compound which is represented by General Formula (PA-II) or (PA-III) is particularly preferable from the point of view that it is possible to achieve excellent effects regarding LWR, local uniformity of pattern dimensions, and DOF at a high level.

Firstly, description will be given of the compound which is represented by General Formula (PA-I).

Q-A₁-(X)ₙ—B—R (PA-I)

In General Formula (PA-I),

A₁ represents a single bond or a divalent linking group.

Q represents —SO₃H or —CO₂H. Q is equivalent to an acidic functional group which is generated when irradiated with an actinic ray or radiation.

X represents —SO₂— or —CO—.

n represents 0 or 1.

B represents a single bond, an oxygen atom, or —N(Rx)-.

Rx represents a hydrogen atom or a monovalent organic group.

R represents a monovalent organic group which has a basic functional group or a monovalent organic group which has an ammonium group.

Next, description will be given of the compound which is represented by General Formula (PA-II).

Q₁-X₁—NH—X₂-Q₂ (PA-II)

In General Formula (PA-II),

Q₁ and Q₂ each independently represent a monovalent organic group. Here, one of Q₁ and Q₂ has a basic functional group. Q₁ and Q₂ bond with each other to form a ring and the formed ring may have a basic functional group.

X₁ and X₂ each independently represent —CO— or —SO₂—.

Here, —NH— is equivalent to an acidic functional group which is generated when irradiated with an actinic ray or radiation.

Next, description will be given of the compound which is represented by General Formula (PA-III).

Q₁-X₁—NH—X₂-A₂-(X₃)ₘ—B-Q₃ (PA-III)

In General Formula (PA-III),

Q₁ and Q₃ each independently represent a monovalent organic group. Here, one of Q₁ and Q₃ has a basic functional group. Q₁ and Q₃ bond with each other to form a ring and the formed ring may have a basic functional group.

X₁, X₂, and X₃ each independently represent —CO— or —SO₂—.

A₂ represents a divalent linking group.

B represents a single bond, an oxygen atom, or —N(Qx)-.

Qx represents a hydrogen atom or a monovalent organic group.

When B is —N(Qx)-, Q and Qx may bond with each other to form a ring.

m represents 0 or 1.

Here, —NH— is equivalent to an acidic functional group which is generated when irradiated with an actinic ray or radiation.

Specific examples of the compound (F) will be given below; however, the present invention is not limited thereto. In addition, preferable specific examples of a compound (E) include the compounds (A-1) to (A-44) in US2010/0233629A, (A-1) to (A-23) in US2012/0156617A, and the like other than the exemplified compounds.

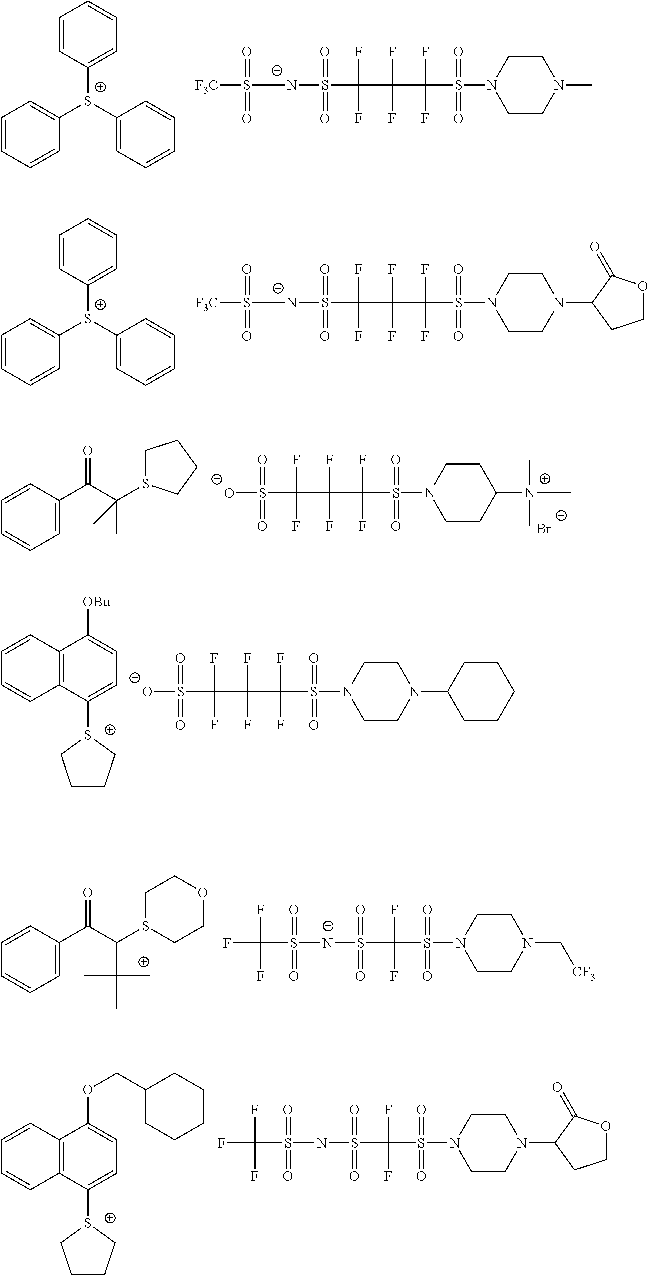

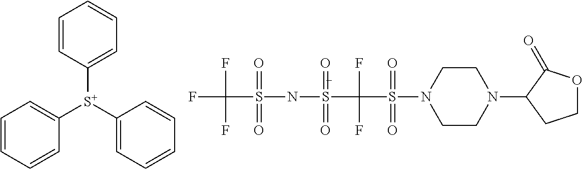 [SMILES: c1ccc([S+](c2ccccc2)c2ccccc2)cc1 ; O=C1OCCC1N1CCN(S(=O)(=O)C(F)(F)S(=O)(=O)NS(=O)(=O)C(F)(F)F)CC1]

The molecular weight of the compound (F) is preferably 500 to 1000.

The actinic ray-sensitive or radiation-sensitive resin composition in the present invention may or may not contain the compound (F); however, in a case of being contained, the content of the compounds (F) is preferably 0.1 mass % to 20 mass % and more preferably 0.1 mass % to 10 mass % on the basis of the solid content of the actinic ray-sensitive or radiation-sensitive resin composition.

(3) Low Molecular Compound (G) which has a Nitrogen Atom and a Group which is Desorbed by the Action of an Acid

The composition of the present invention may contain a compound (also referred to below a “compound (G)”) which has a nitrogen atom and a group which is desorbed by the action of an acid.

The group which is desorbed by the action of an acid is not particularly limited; however, an acetal group, a carbonate group, a carbamate group, a tertiary ester group, a tertiary hydroxyl group, and a hemiaminal ether group are preferable, and a carbamate group and a hemiaminal ether group are particularly preferable.

The molecular weight of the compound (N″) which has a group which is desorbed by the action of an acid is preferably 100 to 1000, more preferably 100 to 700, and particularly preferably 100 to 500.

The compound (G) is preferably an amine derivative which has a group which is desorbed by the action of an acid on a nitrogen atom.

The compound (G) may have a carbamate group which has a protective group on a nitrogen atom. The protective group which forms a carbamate group is able to be represented by General Formula (d-1) below.

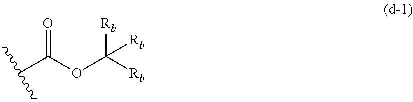

In General Formula (d-1),

R_{b}'s each independently represent a hydrogen atom, an alkyl group (preferably with 1 to 10 carbon atoms), a cycloalkyl group (preferably with 3 to 30 carbon atoms), an aryl group (preferably with 3 to 30 carbon atoms), an aralkyl group (preferably with 1 to 10 carbon atoms), or an alkoxyalkyl group (preferably 1 to 10 carbon atoms). R_{b} may link with each other to form a ring.

An alkyl group, a cycloalkyl group, an aryl group, and an aralkyl group indicated by R_{b} may be substituted with a hydroxyl group, a cyano group, an amino group, a pyrrolidino group, a piperidino group, a morpholino group, and a functional group such as an oxo group, an alkoxy group, and a halogen atom. The same applies to the alkoxyalkyl group indicated by R_{b}.

R_{b} is preferably a straight-chain or branched alkyl group, a cycloalkyl group, or an aryl group. A straight-chain or branched alkyl group and a cycloalkyl group are more preferable.

Examples of a ring which two R_{b}'s form by linking with each other include an alicyclic hydrocarbon group, an aromatic hydrocarbon group, a heterocyclic hydrocarbon group, or a derivative thereof, and the like.

Examples of a specific structure of the group which is represented by General Formula (d-1) include the structures which are disclosed in paragraph “0466” in US2012/0135348A1; however, the present invention is not limited thereto.

The compound (C) particularly preferably has a structure which is represented by General Formula (6) below.

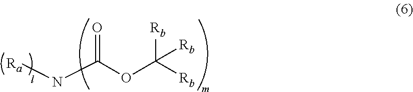

In General Formula (6), Rₐ represents a hydrogen atom, an alkyl group, a cycloalkyl group, an aryl group, or an aralkyl group. When l is 2, two Rₐ's may be the same as or different from each other and the two Rₐ's may link with each other to form a hetero ring with a nitrogen atom in the formula. The hetero ring may include a hetero atom other than the nitrogen atom in the formula.

R_{b} has the same meaning as Rb in General Formula (d-1) and the preferable examples thereof are also the same.

l represents an integer of 0 to 2, m represents an integer of 1 to 3, and l+m=3 is satisfied.

In General Formula (6), an alkyl group, a cycloalkyl group, an aryl group, and an aralkyl group as Rₐ may be substituted with the same groups as the groups described above as the groups with which the alkyl group, the cycloalkyl group, the aryl group, and the aralkyl group as R_{b} may be substituted.

Preferable examples of the alkyl group, the cycloalkyl group, the aryl group, and the aralkyl group (the alkyl group, the cycloalkyl group, the aryl group, and the aralkyl group may be substituted with the groups described above) of Rₐ include the same groups as the preferable examples described above regarding R_{b}.

In addition, a hetero ring which the Rₐ form by linking with each other preferably has 20 or less carbon atoms and examples thereof include a group which is derived from a heterocyclic compound—such as pyrrolidine, piperidine, morpholine, 1,4,5,6-tetrahydropyrimidine, 1,2,3,4-tetrahydroquinoline, 1,2,3,6-tetrahydropyridine, homopiperazine, 4-azabenzimidazole, benzotriazole, 5-azabenzotriazole, 1H-1,2,3-triazole, 1,4,7-triazacyclononane, tetrazole, 7-azaindole, indazole, benzimidazole, imidazo[1,2-a]pyridine, (1 S,4S)-(+)-2,5-diazabicyclo[2.2.1]heptane, 1,5,7-triazabicyclo[4.4.0]dec-5-en, indole, indoline, 1,2,3,4-tetrahydroquinoxaline, perhydroxuinoline, and 1,5,9-triazacyclododecane, a group which substitutes a group which is derived from these heterocyclic compounds with one or more types or one or more of a group which is derived from a straight-chain or branched alkane, a group which is derived from cycloalkane, a group which is derived from an aromatic compound, a group which is derived from a heterocyclic compound, a hydroxyl group, a cyano group, an amino group, a pyrrolidino group, a piperidino group, a morpholino group, and a functional group such as an oxo group, and the like.

Specific examples of particularly preferable compounds (G) in the present invention include the compounds disclosed in paragraph “0475” in US2012/0135348A1; however, the present invention is not limited thereto.

It is possible to synthesize a compound which is represented by General Formula (6) based on JP2007-298569A, JP2009-199021 A, and the like.

In the present invention, it is possible to use a low molecular compound (G) as one type individually or in a mixture of two or more types.

The content of the compounds (G) in the actinic ray-sensitive or radiation-sensitive resin composition of the present invention is preferably 0.001 mass % to 20 mass %, more preferably 0.001 mass % to 10 mass %, and even more preferably 0.01 mass % to 5 mass % on the basis of the entirety of the solid content of the composition.

(4) Onium Salt

In addition, the composition of the present invention may include an onium salt as a basic compound. Examples of onium salt include an onium salt which is represented by General Formula (6A) or (6B) below. The onium salt is expected to control the diffusion of generated acid in a resist system in a relationship with the acid strength of a photo-acid generator which is normally used in a resist composition.

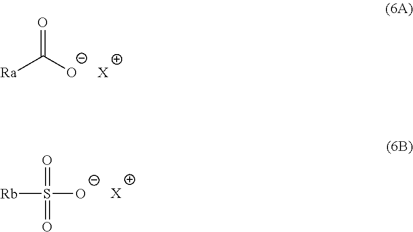

In General Formula (6A),

Ra represents an organic group. Here, organic groups in which carbon atoms which are directly bonded with the carboxylic acid group in the formula are substituted with fluorine atoms are excluded.

X⁺ represents an onium cation.

In General Formula (6B),

Rb represents an organic group. Here, an organic group in which carbon atoms which are directly bonded with the sulfonic acid group in the formula are substituted with fluorine atoms is excluded.

X⁺ represents an onium cation.

With regard to the organic group which is represented by Ra and Rb, the atoms which are directly bonded with the carboxylic acid group or the sulfonic acid group in the formula are preferably carbon atoms. However, in this case, in order to make the acid relatively weaker than the acid which is generated from the photo-acid generator described above, the carbon atoms which are directly bonded with a sulfonic acid group or a carboxylic acid group are not substituted with fluorine atoms.

Examples of the organic group which is represented by Ra and Rb include an alkyl group with 1 to 20 carbon atoms, a cycloalkyl group with 3 to 20 carbon atoms, an aryl group with 6 to 30 carbon atoms, an aralkyl group with 7 to 30 carbon atoms, a heterocyclic group with 3 to 30 carbon atoms, and the like. With regard to the groups, some or all of the hydrogen atoms may be substituted.

Examples of a substituent group which the alkyl group, the cycloalkyl group, the aryl group, the aralkyl group, and the heterocyclic group described above may have include a hydroxyl group, a halogen atom, an alkoxy group, a lactone group, an alkyl carbonyl group, and the like.

Examples of the onium cation which is represented by X⁺ in General Formulas (6A) and (6B) include a sulfonium cation, an ammonium cation, an iodonium cation, a phosphonium cation, a diazonium cation, and the like, and a sulfonium cation is more preferable among these.

The sulfonium cation is preferably, for example, an arylsulfonium cation which has at least one aryl group, and more preferably a triarylsulfonium cation. The aryl group may have a substituent group and the aryl group is preferably a phenyl group.

Examples of the sulfonium cation and the iodonium cation also preferably include the sulfonium cation structure of General Formula (ZI) in the compound (B) or the iodonium cation structure in General Formula (ZII) described above.

Specific structures of the onium salt which is represented by General Formula (6A) and (6B) will be given below.

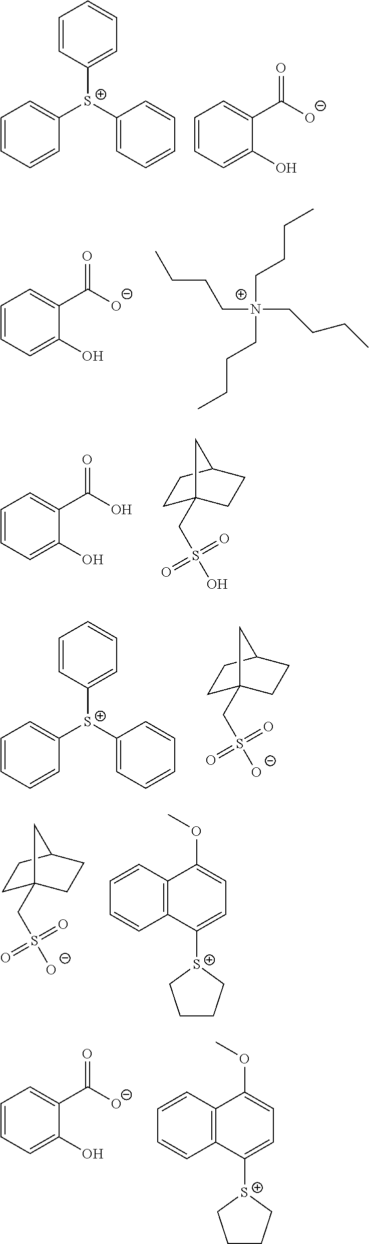

In a case where the composition of the present invention contains onium salt which is represented by General Formula (6A) or (6B), the content ratio thereof is normally 0.01 mass % to 10 mass %, and preferably 0.1 mass % to 5 mass % on the basis of the solid content of the actinic ray-sensitive or radiation-sensitive resin composition.

(5) Betaine Compound

Furthermore, with regard to the composition of the present invention, it is also possible to preferably use compounds (also referred to below as betaine compounds) which have both an onium salt structure and an acid anion structure in one molecule, such as the compounds which are included in Formula (I) in JP2012-189977A, the compounds which are represented by Formula (I) in JP2013-6827A, the compounds which are represented by Formula (I) in JP2013-8020A, and the compounds which are represented by Formula (I) in JP2012-252124A. Examples of the onium salt structure include sulfonium, iodonium, and ammonium structures and sulfonium or iodonium structures are preferable. In addition, the acid anion structure is preferably a sulfonic acid anion or a carboxylic acid anion. Examples of the compound include the following.

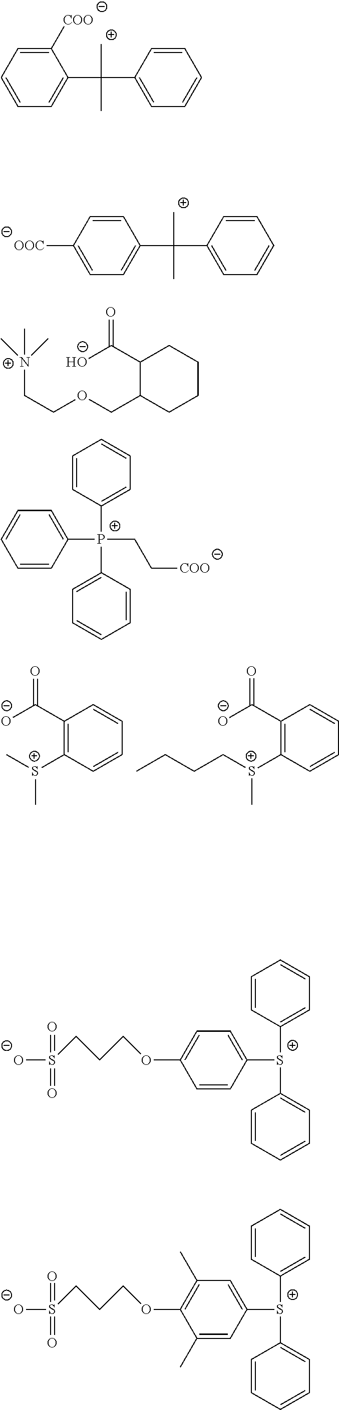

[Solvent]

Examples of a solvent which is able to be used when preparing the actinic ray-sensitive or radiation-sensitive resin composition of the present invention include organic solvents such as alkylene glycol monoalkyl ether carboxylate, alkylene glycol monoalkyl ether, alkyl lactate ester, alkoxypropionic acid alkyl, cyclic lactone (preferably with 4 to 10 carbon atoms), a monoketone compound which may have a ring (preferably with 4 to 10 carbon atoms), alkylene carbonate, alkoxy alkyl acetate, and alkyl pyruvate.

Specific examples of the solvents include the examples described in paragraphs “0441” to “0455” in US2008/0187860A.

In the present invention, a mixed solvent, in which a solvent with a structure which contains a hydroxyl group as an organic solvent is mixed with a solvent which does not contain a hydroxyl group, may be used.

It is possible to appropriately select the exemplified compounds above as the solvent which contains a hydroxyl group and the solvent which does not contain a hydroxyl group; however, the solvent which contains a hydroxyl group is preferably alkylene glycol monoalkyl ether, alkyl lactate, or the like, and more preferably propylene glycol monomethyl ether (PGME, also called 1-methoxy-2-propanol) or ethyl lactate. In addition, the solvent which does not contain a hydroxyl group is preferably alkylene glycol monoalkyl ether acetate, alkyl alkoxy propionate, a monoketone compound which may contain a ring, cyclic lactone, alkyl acetate, and the like, and among these, propylene glycol monomethyl ether acetate (PGMEA, also called 1-methoxy-2-acetoxy propane), ethylethoxy propionate, 2-heptanone, γ-butylolactone, cyclohexanone, and butyl acetate are particularly preferable, and propylene glycol monomethyl ether acetate, ethylethoxy propionate, propylene carbonate, and 2-heptanone are most preferable.

The mixing ratio (mass) of the solvent which contains a hydroxyl group and the solvent which does not contain a hydroxyl group is 1/99 to 99/1, preferably 10/90 to 90/10, and more preferably 20/80 to 60/40. A mixed solvent which contains the solvent, which does not contain a hydroxyl group, in a proportion of 50 mass % or more is particularly preferable in terms of coating uniformity.

The solvent preferably includes propylene glycol monomethyl ether acetate and is preferably a propylene glycol monomethyl ether acetate (PGMEA) independent solvent or a mixed solvent of two or more types which contains propylene glycol monomethyl ether acetate (PGMEA). Preferable specific examples of the mixed solvent include a mixed solvent which includes PGMEA and a ketone-based solvent (cyclohexanone, 2-heptanone, and the like), a mixed solvent which includes PGMEA and a lactone-based solvent (γ-butylolactone and the like), a mixed solvent which includes PGMEA and PGME, a mixed solvent which includes three types of PGMEA, a ketone-based solvent, and a lactone-based solvent, a mixed solvent which includes three types of PGMEA, PGME, and a lactone-based solvent, a mixed solvent which includes three types of PGMEA, PGME, and a ketone-based solvent, and the like; however, the present invention is not limited thereto.

[Surfactant]

The actinic ray-sensitive or radiation-sensitive resin composition in the present invention may or may not further contain a surfactant and, when in a case of being contained, either of a fluorine and/or silicon-based surfactant (a fluorine-based surfactant, a silicon-based surfactant, and a surfactant which has both a fluorine atom and a silicon atom) or two or more types thereof are more preferably contained.

By the actinic ray-sensitive or radiation-sensitive resin composition in the present invention containing a surfactant, it is possible to impart a resist pattern with less adhesion and fewer developing defects with favorable sensitivity and resolution when using an exposure light source of 250 nm or less, and particularly 220 nm or less.

Examples of the fluorine-based and/or silicon-based surfactants include the surfactants described in paragraph “0276” in US2008/0248425A and examples thereof include Eflop EF301 and EF303 (produced by Shin-Akita Kasei Co., Ltd.), Fluorad FC430, 431, and 4430 (produced by Sumitomo 3M Inc.), Megaface F171, F173, F176, F189, F113, F110, F177, F120, and ROS (produced by DIC Corporation), Surflon S-382, SC101, 102, 103, 104, 105, 106, and KH-20 (produced by Asahi Glass Co., Ltd.), Troyzol S-366 (produced by Troy Chemical Industries, Inc.), GF-300 and GF-150 (produced by Toagosei Co., Ltd.), Surflon S-393 (produced by Seimi Chemical Co., Ltd.), Eftop EF121, EF122A, EF122B, RF122C, EF125M, EF135M, EF351, EF352, EF801, EF802, and EF601 (produced by Jemco Inc.), PF636, PF656, PF6320, and PF6520 (produced by Omnova Solutions, Inc.), FTX-204G, 208G, 218G 230G, 204D, 208D, 212D, 218D, and 222D (produced by Neos Co., Ltd.), and the like. In addition, it is also possible to use polysiloxane polymer KP-341 (produced by Shin-Etsu Chemical Co., Ltd.) as a silicon-based surfactant.

In addition, as a surfactant, other than the surfactants known in the art as described above, it is possible to use a surfactant which uses a polymer which has a fluoro aliphatic group which is derived from a fluoro aliphatic compound which is produced by a telomerization method (also referred to as a telomer method) or an oligomerization method (also referred to as an oligomer method). It is possible to synthesize the fluoro aliphatic compound using the method described in JP2002-90991A.

Examples of surfactants which correspond to the described above include Megaface F178, F-470, F-473, F-475, F-476, and F-472 (produced by DIC Corporation), a copolymer of acrylate (or methacrylate) which has a C₆F₁₃ group and (poly(oxyalkylene))acrylate (or methacrylate), a copolymer of acrylate (or methacrylate) which has a C₃F₇ group, (poly(oxyethylene))acrylate (or methacrylate), and (poly(oxypropylene))acrylate (or methacrylate), and the like.

In addition, in the present invention, it is also possible to use other surfactants than the fluorine-based and/or the silicon-based surfactants described in paragraph “0280” in US2008/0248425A.

The surfactants may be used individually or may also be used in various combinations.

In a case where the actinic ray-sensitive or radiation-sensitive resin composition contains a surfactant, the usage amount of the surfactant is preferably 0.0001 mass % to 2 mass % and more preferably 0.0005 mass % to 1 mass % with respect to the total amount of the actinic ray-sensitive or radiation-sensitive resin composition (excluding the solvent).

On the other hand, by setting the added amount of the surfactant to 10 ppm or less with respect to the total amount of the actinic ray-sensitive or radiation-sensitive resin composition (excluding the solvent), the surface uneven distribution characteristics of the hydrophobic resin are increased and, due to this, it is possible to make the resist film surface more hydrophobic and it is possible to improve the water conformance during the liquid immersion exposure.

It is possible to prepare the composition of the present invention by appropriately mixing each of the components described above. Here, during the preparation, a step of reducing metal impurities in the composition to the ppb level using an ion-exchange film, a step of filtering impurities such as various types of particles using an appropriate filter, a degassing step, and the like may be performed. Specific description of the steps is given in JP2012-88574A, JP2010-189563A, JP2001-12529A, JP2001-350266A, JP2002-99076A, JP1993-307263A (JP-H5-307263A), JP2010-164980A, WO2006/121162A, JP2010-243866A, JP2010-020297A, and the like.

In addition, the composition of the present invention preferably has a low moisture content. In detail, the moisture content is preferably 2.5 mass % or less, more preferably 1.0 mass % or less, and even more preferably 0.3 mass % or less in the total weight of the composition.

### EXAMPLES

Description will be given below of the present invention using the examples; however, the present invention is not limited thereto.

### SYNTHESIS EXAMPLES

40 g of a mixed solvent of propylene glycol monomethyl ether acetate and propylene glycol monomethyl ether of 6/4 (mass ratio) was added to a three-neck flask in a nitrogen gas stream and heated to 80° C. (solvent 1). Monomers corresponding to the repeating units below were dissolved in the mixed solvent of propylene glycol monomethyl ether acetate and propylene glycol monomethyl ether of 6/4 (mass ratio) at a molar ratio of 30/10/60 respectively and 22 mass % of a monomer solution (400 g) was prepared. Furthermore, a polymerization initiator V-601 (produced by Wako Pure Chemical Industries Ltd.) was added in a proportion of 8 mol % with respect to the monomers and the dissolved solution was added dropwise over 6 hours with respect to the solvent 1 described above. After finishing the dropwise addition, a further reaction was carried out at 80° C. for 2 hours. 74 g of the resin (P-1) was obtained by pouring the cooled reaction liquid into hexane 3600 ml/ethyl acetate 400 ml and filtering and drying the precipitated powder. The weight average molecular weight of the obtained resin (P-1) was 12000 and the dispersity (Mw/Mn) was 1.6.

Apart from using monomers corresponding to each of the repeating units so as to obtain a desired composition ratio (molar ratio), the resins (P-2) to (P-8) and the hydrophobic resins (N-1) to (N-3) were synthesized in the same manner as Synthesis Example 1 described above.

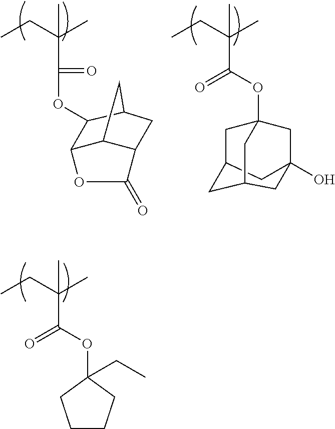

Preparation of Resist Composition

The resist compositions Ar-1 to Ar-13 were prepared by dissolving the components shown in Table 4 below in the solvent shown in the same table to be 3.5 mass % of the total solid content concentration and filtering each resist composition using a polyethylene filter with a pore size of 0.05 μm.

TABLE 4

| | | | Acid generating | | Basic | | | | Hydrophobic | | | Mass |
|---|---|---|---|---|---|---|---|---|---|---|---|---|
| Resist | Resin | Mass/g | agent | Mass/g | compound | Mass/g | Surfactant | Mass/g | resin | Mass/g | Solvent | ratio |
| Ar-1 | (P-1) | 10 | (PAG-1) | 0.8 | (Q-1) | 0.15 | W-1 | 0.04 | (N-1) | 0.06 | A3/B2 | 80/20 |
| Ar-2 | (P-2) | 10 | (PAG-2) | 0.8 | (Q-2) | 0.15 | W-2 | 0.04 | (N-2) | 0.06 | A1/A2/B1 | 50/4/46 |
| Ar-3 | (P-3) | 10 | (PAG-3) | 0.8 | (Q-3) | 0.15 | — | — | (N-3) | 0.06 | A1/B1 | 60/40 |
| Ar-4 | (P-4) | 10 | (PAG-4)/(PAG-1) | 1.2/0.3 | (Q-4) | 0.15 | W-3 | 0.04 | (N-1) | 0.06 | A1/B2 | 80/20 |
| Ar-5 | (P-5) | 10 | (PAG-5) | 0.8 | (Q-5) | 0.15 | W-4 | 0.04 | (N-2) | 0.06 | A2/B3 | 70/30 |
| Ar-6 | (P-6) | 10 | (PAG-1) | 0.8 | (Q-1) | 0.15 | W-1 | 0.04 | (N-3) | 0.06 | A3/B4 | 80/20 |
| Ar-7 | (P-7) | 10 | (PAG-2) | 0.8 | (Q-2) | 0.15 | W-2 | 0.04 | (N-1) | 0.06 | A3/B2 | 80/20 |
| Ar-8 | (P-8) | 10 | (PAG-3) | 0.8 | (Q-3) | 0.15 | W-3 | 0.04 | (N-2) | 0.06 | A1/A2/B1 | 50/4/46 |
| Ar-9 | (P-1)/(P-2) | 5/5 | (PAG-4)/(PAG-1) | 1.2/0.3 | (Q-4) | 0.15 | W-4 | 0.04 | (N-3) | 0.06 | A1/B1 | 60/40 |
| Ar-10 | (P-3) | 10 | (PAG-5) | 0.8 | (Q-5) | 0.15 | W-1 | 0.04 | (N-1) | 0.06 | A1/B2 | 80/20 |
| Ar-11 | (P-4) | 10 | (PAG-1) | 0.8 | (Q-1) | 0.15 | W-2 | 0.04 | (N-2) | 0.06 | A2/B3 | 70/30 |
| Ar-12 | (P-5) | 10 | (PAG-2) | 0.8 | (Q-2) | 0.15 | W-3 | 0.04 | (N-3) | 0.06 | A3/B4 | 80/20 |
| Ar-13 | (P-6) | 10 | (PAG-3) | 0.8 | (Q-3) | 0.15 | W-4 | 0.04 | (N-1) | 0.06 | A3/B2 | 80/20 |

The abbreviations in Table 4 are as follows.

[Resin]

The composition ratio (molar ratio) of the repeating units, the weight average molecular weight, and the dispersity of the resin which was used in the examples will be shown below.

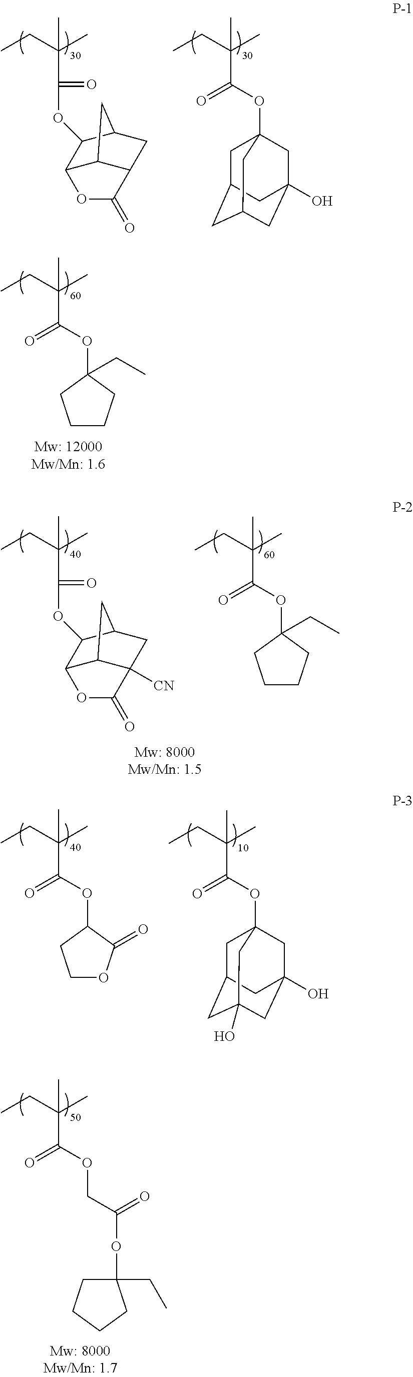

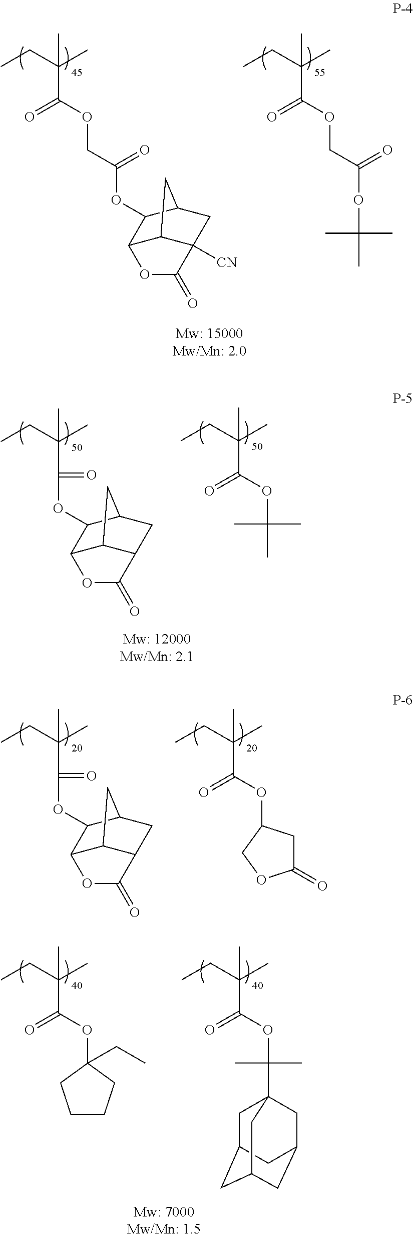

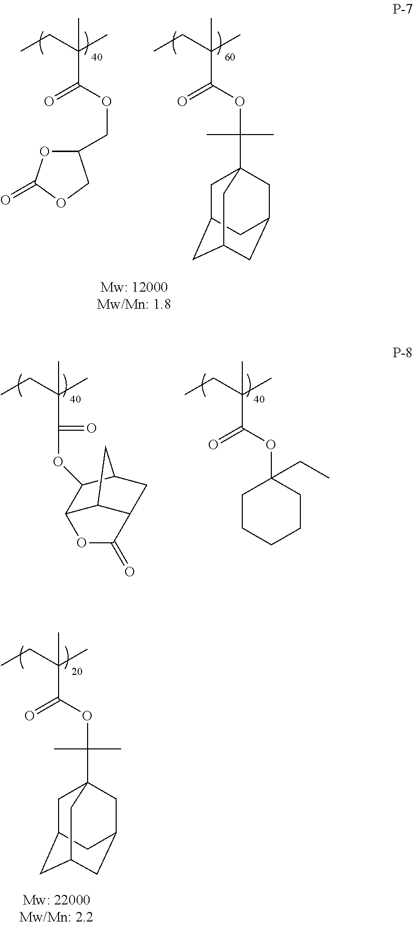

[Acid Generating Agent]

The structure formulas of the acid generating agent will be shown below.

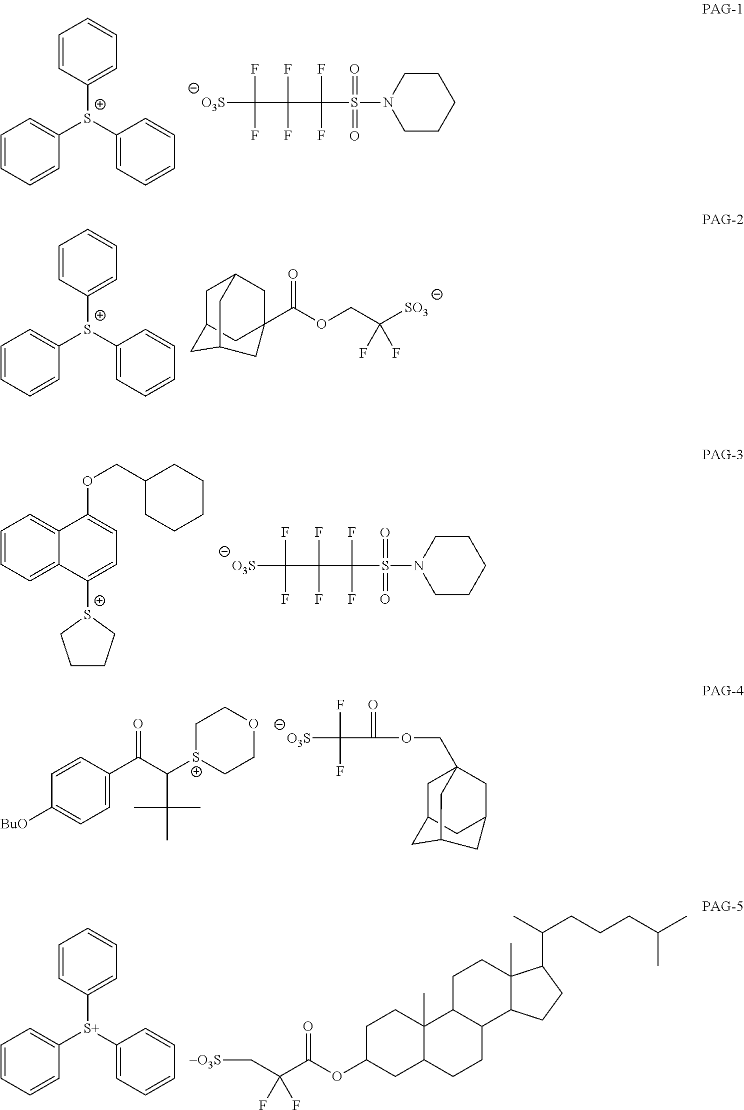

[Basic Compound]

The structure formulas of the basic compound will be shown below.

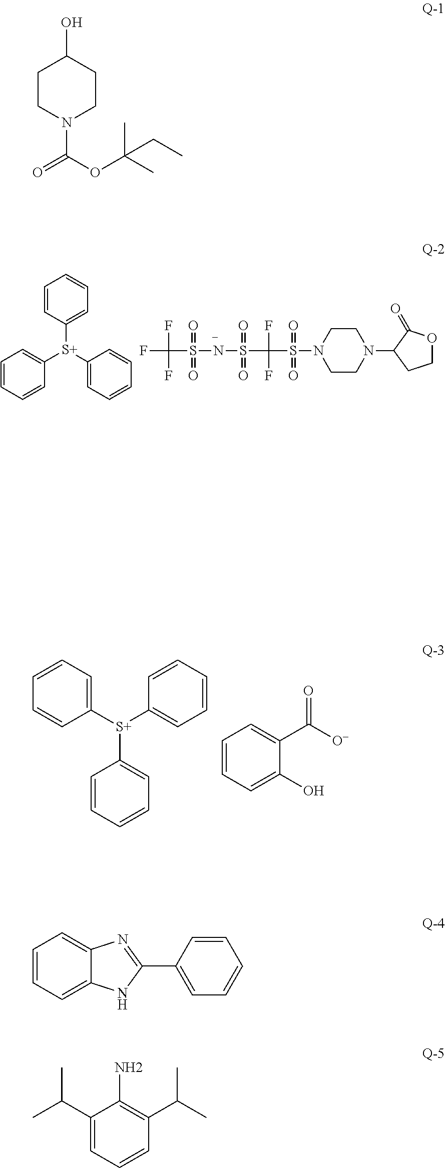

[Hydrophobic Resin]

The composition ratio (molar ratio), the weight average molecular weight, and the dispersity of the hydrophobic resins which are used in the examples are given below.

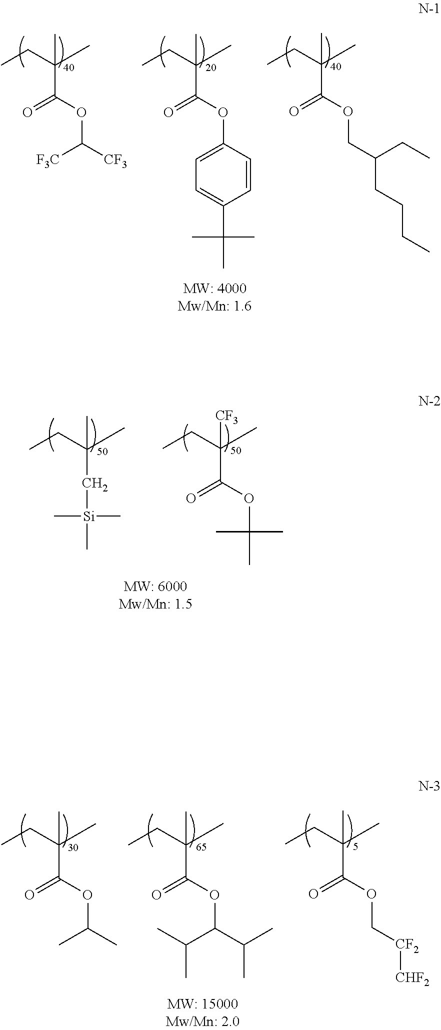

[Surfactant]

W-1: Megaface F176 (produced by DIC Corporation) (fluorine-based)

W2: Megaface R08 (produced by DIC Corporation) (fluorine and silicon-based)

W-3: Polysiloxane polymer KP-341 (produced by Shin-Etsu Chemical Co., Ltd.) (silicon-based)

W-4: PolyFox PF-6320 (produced by Omnova Solutions, Inc.) (fluorine-based)

[Solvent]

A1: Propylene glycol monomethyl ether acetate (PGMEA)

A2: γ-butylolactone

A3: Cyclohexanone

B1: Propylene glycol monomethyl ether (PGME)

B2: Ethyl lacetate

B3: 2-heptanone

B4: Propylene carbonate

### Performance Evaluation

### Examples 1 to 29 and Comparative Examples 1 and 2

### Forming Target Process Pattern: Dry Exposure

A resist pattern was formed by a dry exposure method.

In detail, firstly, an anti-reflection film with a film thickness of 78 nm was formed by coating an organic anti-reflection film ARC29A (produced by Nissan Chemical Industries, Ltd.) on a silicon wafer and carrying out baking at 205° C. for 60 seconds. A resist film with a film thickness of 50 nm was formed by coating the resist composition described above thereon and carrying out baking at 100° C. for 60 seconds.

Subsequently, exposure was performed with respect to the resist film using an ArF excimer laser scanner (manufactured by ASML Corporation; PAS5500, NA 0.75, Annular, outer sigma 0.89, and inner sigma 0.65) through a 1:1 line and space mask with a line width of 80 nm.

The result was heated on a hot plate at 100° C. for 60 seconds directly after the exposure and left to cool to room temperature. Subsequently, developing was carried out by paddling for 30 seconds using the developer described in Table 5 below and, for the examples for which a rinsing liquid is described in Table 5, rinsing was carried out by paddling for 30 seconds using the rinsing liquids described in Table 5 below. Subsequently, a 1:1 line and space pattern with a line width of 80 m was obtained as a target process pattern by rotating the wafer at a rotation speed of 2000 rpm for 30 seconds.

<Forming Target Process Pattern: Liquid Immersion Exposure>

A resist pattern was formed by a liquid immersion exposure method.

In detail, firstly, an anti-reflection film with a film thickness of 91 nm was formed by coating an organic anti-reflection film ARC29SR (produced by Nissan Chemical Industries, Ltd.) on a silicon wafer and carrying out baking at 205° C. for 60 seconds. A resist film with a film thickness of 90 nm was formed by coating the resist composition described above thereon and carrying out baking at 100° C. for 60 seconds.

Subsequently, exposure was performed with respect to the resist film using an ArF excimer laser liquid immersion scanner (XT1700i manufactured by ASML Corporation, NA 1.20, Annular, outer sigma 0.940, inner sigma 0.740, and XY inclination) through a 6% halftone mask with a 60 nm 1:1 line and space pattern. Ultrapure water was used as the immersion liquid. After heating at 100° C. for 60 seconds after that, developing was carried out by paddling for 30 seconds using the developer described in Table 5 below and, for the examples for which a rinsing liquid is described in Table 5, rinsing was carried out by paddling for 30 seconds using the rinsing liquids described in Table 5 below. Subsequently, a 1:1 line and space pattern with a line width of 60 nm was obtained as a target process pattern by rotating the wafer at a rotation speed of 2000 rpm for 30 seconds.

### Examples 30 to 63 and Comparative Examples 3 to 6

### Forming Target Process Pattern: Dry Exposure/Double Development

An anti-reflection film with a film thickness of 86 nm was formed by coating an organic anti-reflection film ARC29A (produced by Nissan Chemical Industries, Ltd.) on a silicon wafer and carrying out baking at 205° C. for 60 seconds. A resist film with a film thickness of 50 nm was formed by coating the resist composition described above thereon and carrying out baking at 100° C. for 60 seconds.

Subsequently, exposure was performed with respect to the resist film using an ArF excimer laser scanner (manufactured by ASML Corporation; PAS5500, NA 0.75, Annular, outer sigma 0.89, and inner sigma 0.65) through a 1:1 line and space mask with a line width of 80 nm.

Subsequently, the result was heated on a hot plate at 95° C. for 60 seconds and left to cool to room temperature. Subsequently, developing was carried out by paddling for 20 seconds using the first developer described in Table 6 below and, for the examples for which a first rinsing liquid is described in Table 6, rinsing was carried out by paddling for 30 seconds using the first rinsing liquids described in Table 6 below.

Subsequently, a 1:1 line and space resist pattern with a line width of 40 nm was obtained as a target process pattern by carrying out developing for 20 seconds using a second developer and, after carrying out rinsing using a second rinsing liquid for the examples for which the second rinsing liquid is described in Table 6, rotating the wafer at a rotation speed of 4000 rpm for 30 seconds.

<Forming Target Process Pattern: Liquid Immersion Exposure/Double Developing>

An anti-reflection film with a film thickness of 98 nm was formed by coating an organic anti-reflection film ARC29A (produced by Nissan Chemical Industries, Ltd.) on a silicon wafer and carrying out baking at 205° C. for 60 seconds. A resist film with a film thickness of 50 nm was formed by coating the resist composition described above thereon and carrying out baking at 90° C. for 60 seconds.

Subsequently, exposure was performed with respect to the resist film using an ArF excimer laser liquid immersion scanner (XT1700i manufactured by ASML Corporation, NA 1.20, C-Quad, outer sigma 0.960, inner sigma 0.709, and XY inclination) through a 6% halftone mask with a 1:1 line and space pattern with a line width of 60 nm. Ultrapure water was used as the immersion liquid. The result was subsequently heated at 95° C. for 60 seconds and left to cool to room temperature. Subsequently, developing was carried out by paddling for 20 seconds using the first developer described in Table 6 below and, for the examples for which the first rinsing liquid is described in Table 6, rinsing was carried out by paddling for 30 seconds using the first rinsing liquids described in Table 6 below.

Subsequently, a 1:1 line and space resist pattern with a line width of 30 nm was obtained as a target process pattern by carrying out developing for 20 seconds using the second developer and, after carrying out rinsing using the second rinsing liquid for the examples for which the second rinsing liquid is described in Table 6, rotating the wafer at a rotation speed of 4000 rpm for 30 seconds.

<Shrinking Step>

A processing agent film (a shrinking agent film) with a film thickness of 100 nm (the film thickness when the surface of the silicon wafer is a reference surface) was formed by coating the processing agents (the shrinking agents) described in Table 5 and Table 6 on each target process pattern obtained as above and, for the examples for which a temperature is described in the processing agent baking temperature column in Table 5 and Table 6, carrying out baking at this temperature for 90 seconds. After that, the processing agent film was cleaned by paddling for 20 seconds using a removal solution. Subsequently, a processed pattern was obtained by rotating the wafer at a rotation speed of 2000 rpm for 30 seconds.

TABLE 5

| | | | | | | | | | | | | Evaluation | |
|---|---|---|---|---|---|---|---|---|---|---|---|---|---|
| | | | | | | | | | | Evaluation | | results | |
| | | | | | | | | | | results | | ArF liquid | |
| | | | | Processing agent | | | | | | ArF dry | | immersion | |
| | | | | Compound | Molecular | | | Processing | | Shrinking | | Shrinking | |
| | Resist | | Rinsing | (x) | weight or | Surfactant | Solvent | agent baking | | amount | | amount | |
| Example | composition | Developer | liquid | (3.8 g) | Mw | (0.01 g) | (96.2 g) | temperature | Removal solution | (nm) | LWR (nm) | (nm) | LWR (nm) |
| Example 1 | Ar-07 | Butyl acetate | — | S-1 | 146 | — | MIBC | 100 C. | Butyl acetate | 2.7 | 8.6 | 2.4 | 7.5 |
| Example 2 | Ar-07 | PGMEA | 1-hexanol | S-2 | 103 | W-A | 1-butanol | 100 C. | PGMEA | 2.2 | 8.7 | 1.9 | 7.6 |
| Example 3 | Ar-07 | Cyclo- | — | S-3 | 138 | — | Diisopentyl ether | 100 C. | Cyclohexanone | 3.2 | 8.5 | 2.9 | 7.4 |
| | | hexanone | | | | | | | | | | | |
| Example 4 | Ar-07 | MAK | — | S-4 | 252 | — | Anisole | 100 C. | MAK | 3.2 | 8.5 | 2.9 | 7.4 |
| Example 5 | Ar-07 | EL | MIBC | S-5 | 419 | — | MIBC | 100 C. | EL | 3.2 | 8.5 | 2.9 | 7.4 |
| Example 6 | Ar-07 | Butyl acetate | — | S-6 | 172 | W-A | Water/1-butanol | 100 C. | Butyl acetate | 3.2 | 8.5 | 2.9 | 7.4 |
| | | | | | | | (mass ratio | | | | | | |
| | | | | | | | 30/70) | | | | | | |
| Example 7 | Ar-07 | PGMEA | — | S-7 | 230 | — | MIBC | 100 C. | PGMEA | 2.7 | 8.6 | 2.4 | 7.5 |
| Example 8 | Ar-07 | Cyclo- | 1-octanol | S-8 | 159 | — | MIBC | 100 C. | Cyclohexanone | 2.2 | 8.7 | 1.9 | 7.6 |
| | | hexanone | | | | | | | | | | | |
| Example 9 | Ar-07 | MAK | — | S-9 | 15000 | — | Water/1-butanol | 100 C. | MAX | 10.2 | 7.7 | 9.9 | 6.6 |
| | | | | | | | (mass ratio | | | | | | |
| | | | | | | | 60/40) | | | | | | |
| Comparative | Ar-07 | Butyl acetate | — | R-1 | 243 | — | MIBC | 100 C. | Butyl acetate | 0.8 | 9.1 | 0.7 | 8.2 |
| Example 1 | | | | | | | | | | | | | |
| Example 10 | Ar-07 | EL | — | S-10 | 1000 | — | MIBC | 100 C. | EL | 5.2 | 8.0 | 4.9 | 6.8 |
| Example 11 | Ar-07 | MAK | — | S-10 | 15000 | — | MIBC | 100 C. | Butyl acetate | 10.2 | 7.7 | 9.9 | 6.6 |
| Example 12 | Ar-07 | PGMEA | — | S-10 | 60000 | — | MIBC | 100 C. | MIBC | 15.2 | 7.5 | 14.9 | 6.4 |
| Example 13 | Ar-07 | MAK | — | S-11 | 15000 | — | Diisopentyl ether | 100 C. | Cyclohexanone | 10.2 | 7.8 | 9.9 | 6.7 |
| Example 14 | Ar-07 | MAK | — | S-12 | 15000 | — | Water/1-butanol | 100 C. | MAK | 10.2 | 7.8 | 9.9 | 6.7 |
| | | | | | | | (mass ratio | | | | | | |
| | | | | | | | 60/40) | | | | | | |
| Example 15 | Ar-07 | Butyl acetate | Decane | S-13 | 15000 | — | MIBC | 100 C. | EL | 10.2 | 7.8 | 9.9 | 6.7 |
| Example 16 | Ar-07 | Butyl acetate | Decane | S-12/S-13 | 15000 | — | MIBC | 100 C. | EL | 10.3 | 7.7 | 10.0 | 6.6 |
| | | | | (mass ratio | | | | | | | | | |
| | | | | 50/50) | | | | | | | | | |
| Example 17 | Ar-07 | Butyl acetate | Decane | S-13 | 15000 | — | MIBC | None | EL | 8.6 | 8.2 | 7.9 | 7.0 |
| Example 18 | Ar-01 | Butyl acetate | — | S-13 | 15000 | — | MIBC | 100 C. | Butyl acetate | 10.3 | 7.8 | 10.0 | 6.7 |
| Example 19 | Ar-02 | PGMEA | — | S-11 | 15000 | — | MIBC | 100 C. | Butyl acetate | 10.2 | 7.8 | 9.9 | 6.7 |
| Example 20 | Ar-03 | Cyclohexanone | — | S-12 | 15000 | W-A | MIBC | 100 C. | Butyl acetate | 10.1 | 7.8 | 10.1 | 6.7 |
| Example 21 | Ar-04 | MAK | — | S-13 | 15000 | — | MIBC | 100 C. | Butyl acetate | 10.2 | 7.8 | 9.9 | 6.7 |
| Example 22 | Ar-05 | EL | — | S-11 | 15000 | — | MIBC | 100 C. | Butyl acetate | 10.2 | 7.8 | 10.0 | 6.7 |
| Example 23 | Ar-06 | Butyl acetate | — | S-12 | 15000 | W-A | MIBC | 100 C. | Butyl acetate | 10.1 | 7.8 | 9.9 | 6.7 |
| Example 24 | Ar-08 | PGMEA | — | S-13 | 1.5000 | — | MIBC | 100 C. | Butyl acetate | 10.2 | 7.8 | 10.1 | 6.7 |
| Example 25 | Ar-09 | Cyclohexanone | — | S-11 | 15000 | — | MIBC | 100 C. | Butyl acetate | 10.2 | 7.8 | 9.9 | 6.7 |
| Example 26 | Ar-10 | MAK | — | S-12 | 15000 | W-A | MIBC | 100 C. | Butyl acetate | 10.1 | 7.8 | 10.0 | 6.7 |
| Example 27 | Ar-11 | EL | — | S-13 | 15000 | — | MIBC | 100 C. | Butyl acetate | 10.2 | 7.8 | 9.9 | 6.7 |
| Example 28 | Ar-12 | MAK | — | S-11 | 15000 | — | MIBC | 100 C. | Butyl acetate | 10.2 | 7.8 | 10.1 | 6.7 |
| Example 29 | Ar-13 | EL | — | S-12 | 15000 | W-A | MIBC | 100 C. | Butyl acetate | 10.2 | 7.8 | 9.9 | 6.7 |
| Comparative | Ar-07 | Butyl acetate | — | R-2 | 20000 | — | MIBC | 100 C. | Butyl acetate | 4.5 | 8.9 | 4.2 | 8.0 |
| Example 2 | | | | | | | | | | | | | |

TABLE 6

| | | | | | | | | | | | | Evaluation results | | | |
|---|---|---|---|---|---|---|---|---|---|---|---|---|---|---|---|
| | | | | | | | | | | | | | | ArF liquid | |
| | | | | | | | | | | | | ArF dry double | | immersion double | |
| | | | | | | Processing agent | | | | | | developing | | developing | |
| | | | First | | Second | Compound | Molecular | | | Processing | | Shrinking | | Shrinking | |
| | Resist | First | rinsing | Second | rinsing | (x) | weight | Surfactant | Solvent | agent baking | Removal | amount | LWR | amount | LWR |
| Example | composition | developper | liquid | developer | liquid | (3.8 g) | or Mw | (0.01 g) | (96.2 g) | temperature | solution | (nm) | (nm) | (nm) | (nm) |
| Example 30 | Ar-07 | TMAH | Water | Butyl | — | S-1 | 146 | — | MIBC | 100 C. | Butyl | 2.1 | 10.9 | 2.0 | 8.6 |
| | | | | acetate | | | | | | | acetate | | | | |
| Example 31 | Ar-07 | TMAH | Water | PGMEA | 1-hexanol | S-2 | 103 | W-A | 1-butanol | 100 C. | PGMEA | 1.6 | 11.0 | 1.5 | 8.7 |
| Example 32 | Ar-07 | TMAH | Water | Cyclohexanone | — | S-3 | 138 | — | Diisopentyl | 100 C. | Cyclohexanone | 2.6 | 10.8 | 2.5 | 8.5 |
| | | | | | | | | | ether | | | | | | |
| Example 33 | Ar-07 | TMAH | Water | MAK | — | S-4 | 252 | — | Anisole | 100 C. | MAK | 2.6 | 10.8 | 2.5 | 8.5 |
| Example 34 | Ar-07 | TMAH | Water | EL | MIBC | S-5 | 419 | — | MIBC | 100 C. | EL | 2.6 | 10.8 | 2.5 | 8.5 |
| Example 35 | Ar-07 | TMAH | Water | Butyl | — | S-6 | 172 | W-A | Water/1-butanol | 100 C. | Butyl | 2.6 | 10.8 | 2.5 | 8.5 |
| | | | | acetate | | | | | (mass ratio | | acetate | | | | |
| | | | | | | | | | 30/70) | | | | | | |
| Example 36 | Ar-07 | TMAH | Water | PGMEA | — | S-7 | 230 | — | MIBC | 100 C. | PGMEA | 2.1 | 10.9 | 2.0 | 8.6 |
| Example 37 | Ar-07 | TMAH | Water | Cyclohexanone | 1-octanol | S-8 | 159 | — | MIBC | 100 C. | Cyclohexanone | 1.6 | 11.0 | 1.5 | 8.7 |
| Example 38 | Ar-07 | TMAH | Water | MAK | — | S-9 | 15000 | — | Water/1-butanol | 100 C. | MAK | 9.6 | 10.0 | 9.5 | 7 7 |
| | | | | | | | | | (mass ratio | | | | | | |
| | | | | | | | | | 60/40) | | | | | | |
| Comparative | Ar-07 | TMAH | Water | Butyl | — | R-1 | 243 | — | MIBC | 100 C. | Butyl | 0.3 | 13.2 | 0.3 | 10.1 |
| Example 3 | | | | acetate | | | | | | | acetate | | | | |
| Example 39 | Ar-07 | TMAH | Water | EL | — | S-10 | 1000 | — | MIBC | 100 C. | EL | 4.6 | 10.2 | 4.5 | 7.9 |
| Example 40 | Ar-07 | TMAH | Water | MAK | — | S-10 | 15000 | — | MIBC | 100 C. | Butyl | 9.6 | 10.0 | 9.5 | 7.7 |
| | | | | | | | | | | | acetate | | | | |
| Example 41 | Ar-07 | TMAH | Water | PGMEA | — | S-10 | 60000 | — | MIBC | 100 C. | MIBC | 14.6 | 9.8 | 14.5 | 7.5 |
| Example 42 | Ar-07 | TMAH | Water | MAK | — | S-11 | 15000 | — | Diisopentyl | 100 C. | Cyclohexanone | 9.6 | 10.1 | 9.5 | 7.8 |
| | | | | | | | | | ether | | | | | | |
| Example 43 | Ar-07 | TMAH | Water | MAK | — | S-12 | 15000 | — | Water/1-butanol | 100 C. | MAK | 9.6 | 10.1 | 9.5 | 7.8 |
| | | | | | | | | | (mass ratio | | | | | | |
| | | | | | | | | | 60/40) | | | | | | |
| Example 44 | Ar-07 | TMAH | Water | Butyl | Decane | S-13 | 15000 | — | MIBC | 100 C. | EL | 9.6 | 10.1 | 9.5 | 7.8 |
| | | | | acetate | | | | | | | | | | | |
| Example 45 | Ar-07 | TMAH | Water | Butyl | Decane | S-12/S-13 | 15000 | — | MIBC | 100 C. | EL | 9.7 | 10.0 | 9.6 | 7.7 |
| | | | | acetate | | (mass ratio | | | | | | | | | |
| | | | | | | 50/50) | | | | | | | | | |
| Example 46 | Ar-07 | TMAH | Water | Butyl | Decane | S-13 | 15000 | — | MIBC | None | EL | 7.6 | 10.4 | 8.6 | 8.1 |
| | | | | acetate | | | | | | | | | | | |
| Example 47 | Ar-01 | TMAH | Water | Butyl | — | S-13 | 15000 | — | MIBC | 100 C. | Butyl | 9.6 | 10.0 | 9.5 | 7.7 |
| | | | | acetate | | | | | | | acetate | | | | |
| Example 48 | Ar-02 | TMAH | Water | PGMEA | — | S-11 | 15000 | — | MIBC | 100 C. | Butyl | 9.6 | 10.1 | 9.5 | 7.8 |
| | | | | | | | | | | | acetate | | | | |
| Example 49 | Ar-03 | TMAH | Water | Cyclohexanone | — | S-12 | 15000 | W-A | MIBC | 100 C. | Butyl | 9.6 | 10.1 | 9.5 | 7.9 |
| | | | | | | | | | | | acetate | | | | |
| Example 50 | Ar-04 | TMAH | Water | MAK | — | S-13 | 15000 | — | MIBC | 100 C. | Butyl | 9.6 | 10.2 | 9.5 | 7.8 |
| | | | | | | | | | | | acetate | | | | |
| Example 51 | Ar-05 | TMAH | Water | EL | — | S-11 | 15000 | — | MIBC | 100 C. | Butyl | 9.6 | 10.0 | 9.5 | 7.7 |
| | | | | | | | | | | | acetate | | | | |
| Example 52 | Ar-06 | TMAH | Water | Butyl | — | S-12 | 15000 | W-A | MIBC | 100 C. | Butyl | 9.6 | 10.1 | 9.5 | 7.8 |
| | | | | acetate | | | | | | | acetate | | | | |
| Example 53 | Ar-08 | TMAH | Water | PGMEA | — | S-13 | 15000 | — | MIBC | 100 C. | Butyl | 9.6 | 10.1 | 9.5 | 7.9 |
| | | | | | | | | | | | acetate | | | | |
| Example 54 | Ar-09 | TMAH | Water | Cyclohexanone | — | S-11 | 15000 | — | MIBC | 100 C. | Butyl | 9.6 | 10.0 | 9.5 | 7.8 |
| | | | | | | | | | | | acetate | | | | |
| Example 55 | Ar-10 | TMAH | Water | MAK | — | S-12 | 15000 | W-A | MIBC | 100 C. | Butyl | 9.6 | 10.1 | 9.5 | 7.8 |
| | | | | | | | | | | | acetate | | | | |
| Example 56 | Ar-11 | TMAH | Water | EL | — | S-13 | 15000 | — | MIBC | 100 C. | Butyl | 9.6 | 10.0 | 9.5 | 7.8 |
| | | | | | | | | | | | acetate | | | | |
| Example 57 | Ar-12 | TMAH | Water | MAK | — | S-11 | 15000 | — | MIBC | 100 C. | Butyl | 9.6 | 10.1 | 9.5 | 7.7 |
| | | | | | | | | | | | acetate | | | | |
| Example 58 | Ar-13 | TMAH | Water | EL | — | S-12 | 15000 | W-A | MIBC | 100 C. | Butyl | 9.6 | 10.1 | 9.5 | 7.8 |
| | | | | | | | | | | | acetate | | | | |
| Example 59 | Ar-13 | TMAH | Water | EL | — | S-12 | 15000 | W-A | MIBC | 100 C. | Butyl | 9.6 | 11.1 | 9.5 | 8.8 |
| | | | | | | | | | | | acetate | | | | |
| Comparative | Ar-07 | TMAH | Water | Butyl | — | R-2 | 20000 | — | MIBC | 100 C. | Butyl | 4.2 | 12.2 | 4.4 | 8.9 |
| Example 4 | | | | acetate | | | | | | | acetate | | | | |
| Example 60 | Ar-07 | Organic | — | TMAH | Water | S-1 | 146 | W-A | MIBC | 100 C. | Butyl | 2.5 | 12.2 | 2.4 | 9.9 |
| | | solvent A | | | | | | | | | acetate | | | | |
| Comparative | Ar-07 | Organic | — | TMAH | Water | R-1 | 243 | W-A | MIBC | 100 C. | Butyl | 0.4 | 15.5 | 0.3 | 13.2 |
| Example 5 | | solvent A | | | | | | | | | acetate | | | | |
| Example 61 | Ar-07 | Organic | Decane | TMAH | Water | S-10 | 15000 | W-A | MIBC | 100 C. | Butyl | 8.8 | 10.5 | 8.7 | 8.8 |
| | | solvent A | | | | | | | | | acetate | | | | |
| Example 62 | Ar-07 | Organic | 1-octanol | TMAH | Water | S-10 | 60000 | W-A | MIBC | 100 C. | Butyl | 15.5 | 9.9 | 15.6 | 8.0 |
| | | solvent A | | | | | | | | | acetate | | | | |
| Example 63 | Ar-07 | Organic | — | TMAH | Water | S-11 | 15000 | W-A | MIBC | 100 C. | Butyl | 8.9 | 10.2 | 9.1 | 8.9 |
| | | solvent A | | | | | | | | | acetate | | | | |
| Comparative | Ar-07 | Organic | — | TMAH | Water | R-2 | 20000 | W-A | MIBC | 100 C. | Butyl | 4.4 | 14.5 | 4.2 | 8.9 |
| Example 6 | | solvent A | | | | | | | | | acetate | | | | |

In the processing agent baking temperatures in Table 5 and Table 6 described above, for example, “100C” has the meaning of heating at 100° C.

The abbreviations and the like in Table 5 and Table 6 described above are as follows.

PGMEA: Propylene glycol monomethyl ether acetate

MAK: Methyl amyl ketone

EL: Ethyl lactate

MIBC: 4-methyl-2-pentanol

TMAH: 2.38 mass % of tetramethyl ammonium hydroxide aqueous solution

Organic solvent A: Solvent in which a compound S-1 is mixed in butyl acetate at 2 mass % with respect to the butyl acetate

W-A: Surflon S-111 (produced by Asahi Glass Co., Ltd.)

[Compound (x) and the Like]

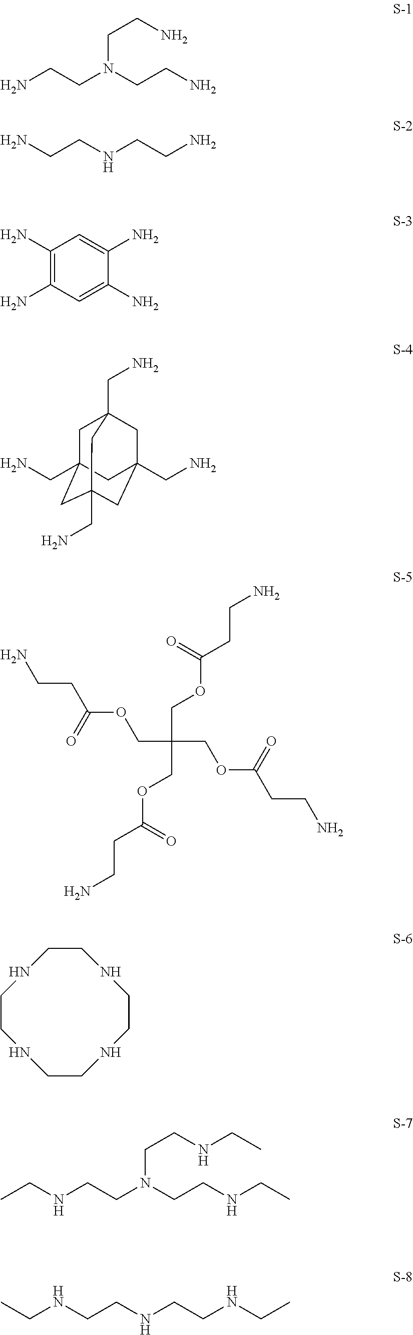

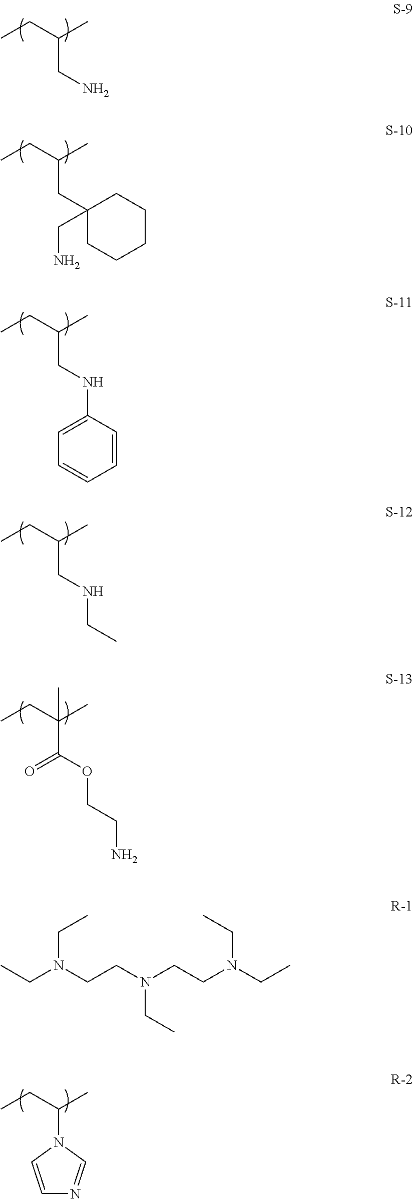

<Evaluation Methods>

Evaluation Method for Shrinking Amount

A space width in the target process pattern and a space width in the processed pattern were measured using a length measurement scanning electron microscope (S9380II manufactured by Hitachi Ltd.) and the difference in the space widths was calculated and set as a shrinking amount (nm). The value being large indicates that the effect of shrinking the space width is high (that is, the pattern refining is excellent) and represents that a favorable performance.

Evaluation Method for Line Width Roughness (LWR)

Measurement was carried out by observing the obtained processed pattern using a length measurement scanning electron microscope (SEM, Hitachi Ltd. S-9380II), measuring the line width at 50 points at equal intervals in a range of 2 μm in the longitudinal direction of the space pattern, and calculating 3σ from the standard deviation thereof. The value being small indicates a favorable performance.

From the results which are shown in the tables described above, it was understood that, in a case of trying to form a line and space pattern which has an ultrafine space width (for example, 60 nm or less) by carrying out the shrinking step, the examples in which the pattern formation method of the present invention was performed had a large shrinking amount and little LWR in the processed pattern compared to the comparative examples.

In addition, it was understood that the examples in which resins with a Mw of 10000 or more were used as the compound (x) had superior evaluation results and that the examples in which resins with a Mw of 50000 or more were used had even more superior evaluation results.

### Examples 64 to 67

### Preparation of Resist Composition

The actinic ray-sensitive or radiation-sensitive resin composition (a chemical amplification type resist composition) shown in Table 7 was prepared by dissolving the components shown in Table 7 below in the solvent shown in the same table so as to be 1.6 mass % of the solid content and filtering each composition using a polyethylene filter with a pore size of 0.05 μm.

TABLE 7

| Resist | Resin | | | | Basic | | | | | Mass |
|---|---|---|---|---|---|---|---|---|---|---|
| composition | (A) | Mass/g | PAG | Mass/g | compound | Mass/g | Surfactant | Mass/g | Solvent | ratio |
| E-1 | Pol-1 | 10 | PAG-6 | 3.00 | Q-6 | 0.90 | W-1 | 0.003 | A1/B1 | 60/40 |
| E-2 | Pol-2 | 10 | PAG-7 | 3.00 | Q-7 | 0.90 | W-1 | 0.003 | A1/B1 | 60/40 |

Regarding the abbreviations in Table 7, the abbreviations not described above are as follows. The composition ratio of the repeating units of the resin Pol-1 and the resin Pol-2 is indicated by the molar ratio.

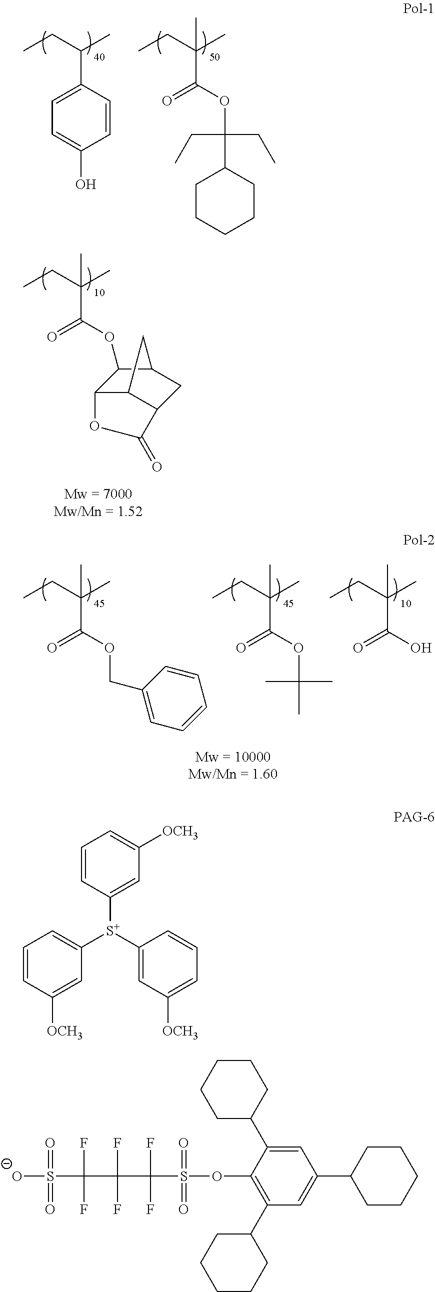

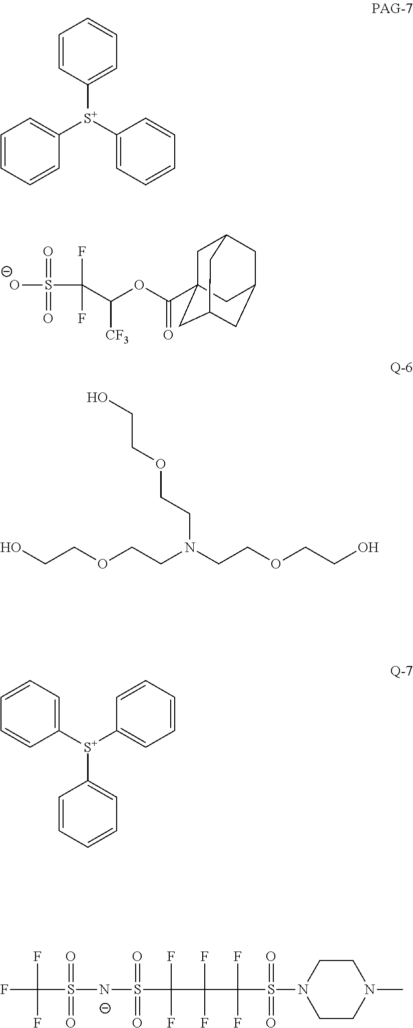

### Example 64

Evaluation was performed on the basis of Example 1 except that the resist composition in Example 1 described above was changed to the resist composition E-1 described above and the exposure source was changed to EUV light (extreme ultraviolet) and it was possible to perform the pattern process.

### Example 65

Evaluation was performed on the basis of Example 1 except that the resist composition in Example 23 described above was changed to the resist composition E-1 described above and the exposure source was changed to EUV light (extreme ultraviolet), and it was possible to perform the pattern process.

### Example 66

Evaluation was performed on the basis of Example 1 except that the resist composition In Example 1 described above was changed to the resist composition E-2 described above and the exposure source was changed to EUV light (extreme ultraviolet), and it was possible to perform the pattern process.

### Example 67

Evaluation was performed on the basis of Example 1 except that the resist composition in Example 23 described above was changed to the resist composition E-2 described above and the exposure source was changed to EUV light (extreme ultraviolet), and it was possible to perform the pattern process.

### Example 68

The target process pattern was formed in the same manner as Example 1 in <Forming target process pattern: liquid immersion exposure> for Example 1 described above, except that, after forming a resist film with a film thickness of 90 nm, a top coat film was further formed on a resist film using the composition OC-5 in Table 3 of the Examples in JP2013-61647A, and a shrinking step was subsequently carried out thereon. It was also possible to perform pattern forming thereon.

According to the present invention, it is possible to provide a pattern formation method, a processing agent which is used for the same, and an electronic-device production method which are able to reliably form a line and space pattern which has an ultrafine space width (for example, 60 nm or less) by being excellent in refining the pattern described above in a pattern formation method which refines a pattern by applying a processing agent to a pattern (that is, carrying out a shrinking step) and are able to form the line and space pattern in a state in which the roughness performance is excellent after the shrinking step is applied.

Description was given of the present invention in detail and also with reference to specific embodiments; however, it is clear to persons skilled in the art that it is possible to add various changes or modifications without departing from the spirit and scope of the invention.

The present application is based on the Japanese patent (JP2013-190735) which was applied for on Sep. 13, 2013 and the content thereof is included here as a reference.

What is claimed is:

1. A pattern formation method comprising:
a step (1) of forming a film using an actinic ray-sensitive or radiation-sensitive resin composition which contains a resin of which, due to a polarity being increased by an action of an acid, solubility decreases with respect to a developer which includes an organic solvent;
a step (2) of exposing the film to an actinic ray or radiation;
a step (3) of forming a target process pattern by developing the film using a developer which includes an organic solvent; and
a step (4) of obtaining a processed pattern by applying a processing agent which includes a compound (x) which has at least one of a primary amino group and a secondary amino group with respect to the target process pattern.

2. The pattern formation method according to claim 1,
wherein the processing agent contains 30 mass % or more of an organic solvent with respect to a total amount of the processing agent.

3. The pattern formation method according to claim 2,
wherein the organic solvent contained in the processing agent is an alcohol-based solvent or an ether-based solvent.

4. The pattern formation method according to claim 1,
wherein the compound (x) is a compound which has a partial structure represented by Formula (1) below as the primary amino group or the secondary amino group,
—NHR (1)
in the formula above,
R represents a hydrogen atom, an aliphatic hydrocarbon group in which a hetero atom may be included, or an aromatic hydrocarbon group in which a hetero atom may be included, and
- represents an atomic bond.

5. The pattern formation method according to claim 1,
wherein the compound (x) is a resin.

6. The pattern formation method according to claim 5,
wherein the resin is a resin which has 30 mol % or more of a repeating unit, which has at least one of a primary amino group and a secondary amino group, with respect to all of the repeating units in the resin.

7. The pattern formation method according to claim 1, further comprising:
a step (3′) of developing using an alkali developer before the step (4).

8. The pattern formation method according to claim 1, further comprising:
a step (5) of bringing a removal solution which is able to dissolve the compound (x) in contact with the processed pattern after the step (4).

9. The pattern formation method according to claim 8,
wherein the removal solution contains an organic solvent.

10. The pattern formation method according to claim 1,
wherein exposure in the step (2) is exposure to light with a wavelength of 250 nm or less or an electron beam.

11. An electronic-device production method, comprising:
the pattern formation method according to claim 1.

12. A processing agent for processing a target process pattern which is obtained by a pattern formation method which has a step (1) of forming a film using an actinic ray-sensitive or radiation-sensitive resin composition which contains a resin of which, due to a polarity being increased by an action of an acid, solubility decreases with respect to a developer which includes an organic solvent, a step (2) of exposing the film to an actinic ray or radiation, and a step (3) of forming the target process pattern by developing the film using a developer which includes an organic solvent,
the processing agent comprising:
a compound (x) which has at least one of a primary amino group and a secondary amino group.

13. The processing agent according to claim 12, further comprising:
30 mass % or more of an organic solvent with respect to a total amount of the processing agent.
